(19) United States
(12) Patent Application Publication
(10) Pub. No.: US 2023/0271989 A1
(43) Pub. Date: Aug. 31, 2023

(54) METAL COMPLEXES

(71) Applicant: Merck Patent GmbH, Darmstadt (DE)

(72) Inventors: Anna HAYER, Darmstadt (DE); Rouven LINGE, Darmstadt (DE); Armin AUCH, Darmstadt (DE); Philipp STOESSEL, Darmstadt (DE); Nils KOENEN, Darmstadt (DE)

(21) Appl. No.: 18/020,281

(22) PCT Filed: Aug. 10, 2021
(86) PCT No.: PCT/EP2021/072214

§ 371 Date: Feb. 8, 2023

(30) Foreign Application Priority Data
Aug. 13, 2020 (EP) 20190795.3

(51) Int. Cl. C07F 15/00; C09K 11/06; H10K 85/60; H10K 50/00

(52) U.S. Cl. CPC C07F 15/0033; C09K 11/06; H10K 85/654; H10K 50/401; C09K 2211/1007; C09K 2211/1018

(57) ABSTRACT

The present invention relates to dinuclear metal complexes and to electronic devices, especially organic electroluminescent devices, comprising these metal complexes.

The present invention relates to dinuclear metal complexes suitable for use as emitters in organic electroluminescent devices.

According to the prior art, triplet emitters used in phosphorescent organic electroluminescent devices (OLEDs) are, in particular, ortho-metallated iridium complexes having aromatic ligands, where the ligands bind to the metal via a negatively charged carbon atom and an uncharged nitrogen atom. WO 2018/041769 discloses dinuclear iridium complexes, particularly for red emission, which can be processed from solution.

In general, the external quantum efficiency of OLED components can be distinctly increased when the transition dipole moment of the emission of the emitter that is present is aligned as horizontally as possible, i.e. in the plane of the emission layer. This effect is known for vacuum-processed singlet and triplet emitters, and for solution-processed singlet emitters. The alignment of solution-processed polymers is also known. By contrast, the orientation of triplet emitters from solution is a technical problem that is still to be solved. For instance, it is known that emitters that can be oriented in the case of vapour deposition are not oriented from solution (e.g. Lampe et al., Chem. Mater. 2016, 28, 712-715). A review article from 2019 (Watanabe et al., Bull. Chem. Soc. Jpn. 2019, 92, 716-728) also describes orientation from solution as an outstanding problem. The fact that compounds that can be vapour-deposited in an oriented manner form non-oriented films from solution is attributed here to differences in the mechanism of film formation with regard to kinetic stability and molecular dynamics in solution.

In the case of vacuum-processed triplet emitters, orientation and hence improvement in the external quantum efficiency of the OLED can be achieved by substituting the optically active ligand with groups that lead to orientation through interaction with the surface in the vapour deposition process. Suitable substituents here are, for example, biphenyl groups or similar groups that are joined to the ligand in the direction of the transition dipole moment. Substituents of this kind that already ensure orientation in the case of vacuum-processed triplet emitters, however, do not lead to significant orientation in the case of solution-processed triplet emitters, and so this concept cannot be applied directly to triplet emitters that are to be processed from solution. Complexes with an acetylacetonate ligand also frequently lead to orientation in the case of vapour deposition, but not in the case of processing from solution.

The problem addressed by the present invention is that of providing novel metal complexes which can be processed from solution and which are suitable as emitters for use in OLEDs. A particular problem addressed is that of providing emitters that lead to orientation in the case of application from solution and which thus lead to an improvement in the external quantum efficiency of the OLED.

It has been found that, surprisingly, the dinuclear iridium complexes described hereinafter that are substituted by linear long-chain aromatic groups lead to orientation and hence a distinct improvement in external quantum efficiency in the OLED when processed from solution. The present invention therefore provides these complexes and organic electroluminescent devices comprising these complexes.

The invention provides a compound of the following formula (1):

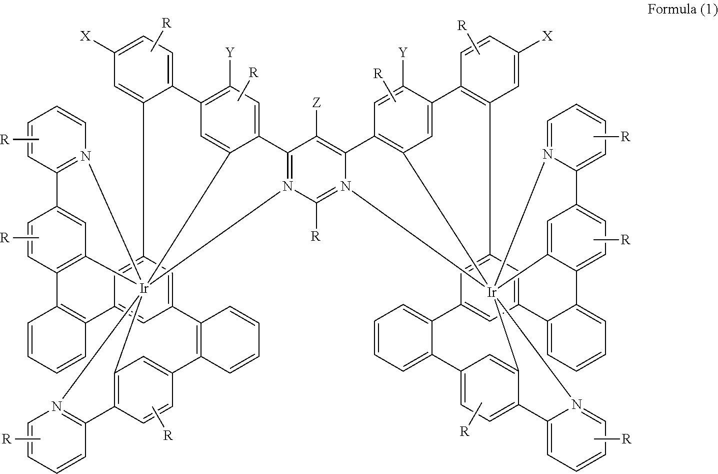

where the symbols and indices used are as follows:
X is the same or different at each instance and is a group of the
formula —(Ar)ₙ—R;
Y is the same or different at each instance and is R or X;
Z is the same or different and is R or X;
Ar is the same or different at each instance and is a divalent group selected from the structures (Ar1) to (Ar7)

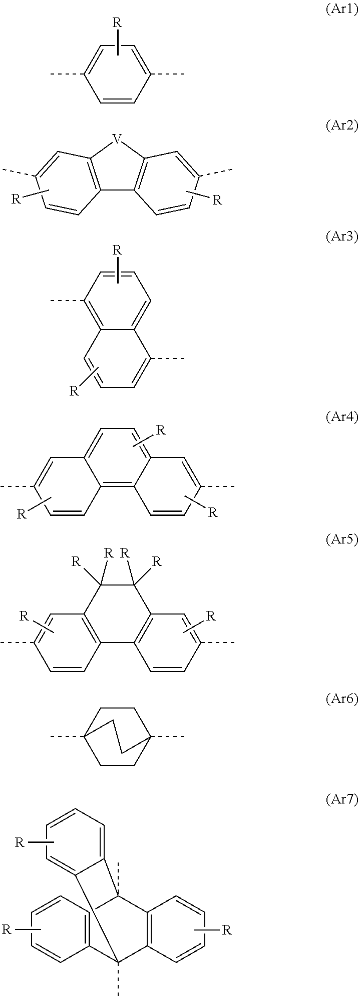

where the dotted bond represents the linkage of the units and V is CR₂, O, S or NR;
n is the same or different at each instance and is an integer from 3 to 20, with the proviso that, in each —(Ar)ₙ—R unit, at least 5 phenyl and/or cyclohexyl groups are joined to one another in a linear manner;
R may occur once or more than once and is the same or different at each instance and is H, D, F, Cl, Br, I, N(R¹)₂, CN, NO₂, OR¹, SR¹, COOH, C(═O)N(R¹)₂, Si(R¹)₃, B(OR¹)₂, C(═O)R¹, P(═O)(R¹)₂, S(═O)R¹, S(═O)₂R¹, OSOR¹, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R¹ radicals, where one or more nonadjacent CH₂ groups may be replaced by Si(R¹)₂, C═O, NR¹, O, S or CONR¹, or an aromatic or heteroaromatic ring system which has 5 to 40 aromatic ring atoms and may be substituted in each case by one or more R¹ radicals; at the same time, two R radicals together may also form a ring system;
R¹ is the same or different at each instance and is H, D, F, Cl, Br, I, N(R²)₂, CN, NO₂, OR², SR², Si(R²)₃, B(OR²)₂, C(═O)R², P(═O)(R²)₂, S(═O)R², S(═O)₂R², OSO₂R², a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R² radicals, where one or more nonadjacent CH₂ groups may be replaced by Si(R²)₂, C═O, NR², O, S or CONR², or an aromatic or heteroaromatic ring system which has 5 to 40 aromatic ring atoms and may be substituted in each case by one or more R² radicals; at the same time, two or more R¹ radicals together may form a ring system;
R² is the same or different at each instance and is H, D, F or an aliphatic, aromatic or heteroaromatic organic radical, especially a hydrocarbyl radical, having 1 to 20 carbon atoms, in which one or more hydrogen atoms may also be replaced by F.

The characterizing feature of the compound of the invention is the presence of two X groups, which are aromatic or heteroaromatic groups or cyclic aliphatic groups joined in a linear manner. What is meant here in the definition of n “with the proviso that, in each —(Ar)ₙ—R unit, at least 5 phenyl and/or cyclohexyl groups are joined to one another in a linear manner” is that the structure X has at least 5 phenyl or cyclohexane groups joined to one another, counting only the phenyl or cyclohexane groups that are joined in direct succession and not potential substituents on these structures. The structures (Ar1) and (Ar3) here each bear one phenyl group, the structures (Ar2), (Ar4) and (Ar5) each bear two phenyl groups, and the structures (Ar6) and (Ar7) each bear one cyclohexane group, where the structure (Ar7) in the context of this invention is also referred to as a cyclohexane group even if aromatic groups are fused onto this structure. Thus, if the X group is formed, for example, from (Ar1) groups only, it must be the case that n 5 for X to have at least 5 phenyl groups joined to one another. If X, by contrast, is formed from a combination of (Ar1) and (Ar2) groups, it may also be the case that n=3 if there is one (Ar1) group and two (Ar2) groups.

When two R or R¹ radicals together form a ring system, it may be mono- or polycyclic, aliphatic, heteroaliphatic, aromatic or heteroaromatic. In this case, the radicals which together form a ring system may be adjacent, meaning that these radicals are bonded to the same carbon atom or to carbon atoms directly bonded to one another, or they may be further removed from one another. Preference is given to this kind of ring formation in radicals bonded to carbon atoms directly bonded to one another or to the same carbon atom.

The wording that two or more radicals together may form a ring, in the context of the present description, should be understood to mean, inter alia, that the two radicals are joined to one another by a chemical bond with formal elimination of two hydrogen atoms. This is illustrated by the following scheme:

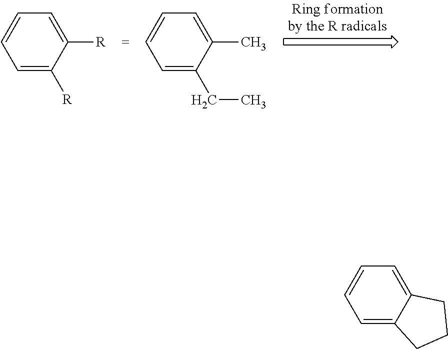

In addition, however, the abovementioned wording shall also be understood to mean that, if one of the two radicals is hydrogen, the second radical binds to the position to which the hydrogen atom was bonded, forming a ring. This shall be illustrated by the following scheme:

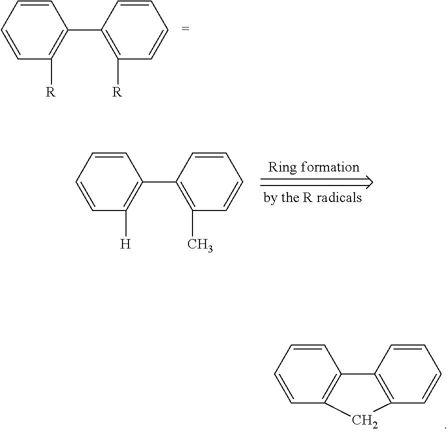

The formation of an aromatic or heteroaromatic ring system shall be illustrated by the following scheme:

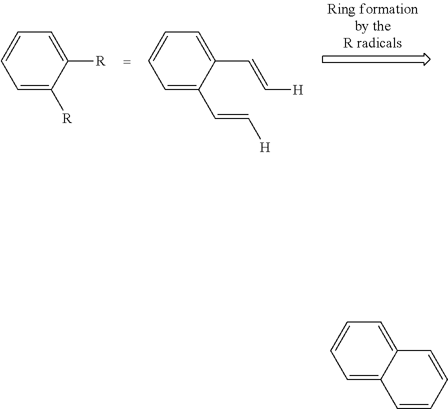

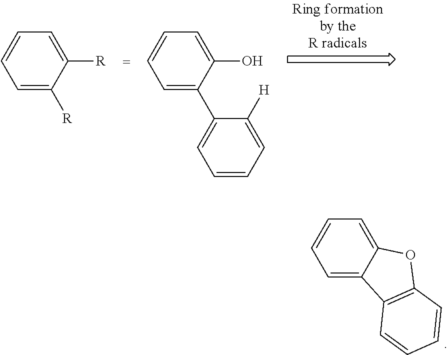

An aryl group in the context of this invention contains 6 to 40 carbon atoms, a heteroaryl group in the context of this invention contains 2 to 40 carbon atoms and at least one heteroatom, with the proviso that the sum total of carbon atoms and heteroatoms is at least 5. The heteroatoms are preferably selected from N, O and/or S. Here, an aryl group or heteroaryl group is understood to mean either a simple aromatic cycle, i.e. benzene, or a simple heteroaromatic cycle, for example pyridine, pyrimidine, thiophene, etc., or a fused aryl or heteroaryl group, for example naphthalene, anthracene, phenanthrene, quinoline, isoquinoline, etc.

An aromatic ring system in the context of this invention contains 6 to 40 carbon atoms in the ring system. A heteroaromatic ring system in the context of this invention contains 1 to 40 carbon atoms and at least one heteroatom in the ring system, with the proviso that the sum total of carbon atoms and heteroatoms is at least 5. The heteroatoms are preferably selected from N, O and/or S. An aromatic or heteroaromatic ring system in the context of this invention shall be understood to mean a system which does not necessarily contain only aryl or heteroaryl groups, but in which it is also possible for a plurality of aryl or heteroaryl groups to be interrupted by a nonaromatic unit (preferably less than 10% of the atoms other than H), for example a carbon, nitrogen or oxygen atom or a carbonyl group. For example, systems such as 9,9′-spirobifluorene, 9,9-diarylfluorene, triarylamine, diaryl ethers, stilbene, etc. shall thus also be regarded as aromatic ring systems in the context of this invention, and likewise systems in which two or more aryl groups are interrupted, for example, by a linear or cyclic alkyl group or by a silyl group. In addition, systems in which two or more aryl or heteroaryl groups are bonded directly to one another, for example biphenyl, terphenyl, quaterphenyl or bipyridine, shall likewise be regarded as an aromatic or heteroaromatic ring system. The aromatic or heteroaromatic ring system is preferably a system in which two or more aryl or heteroaryl groups are joined to one another directly by a single bond, or is fluorene, spirobifluorene or another aryl or heteroaryl group to which an optionally substituted indene group is used, for example indenocarbazole.

In the context of the present invention, the term “alkyl group” is used as an umbrella term for linear, branched and cyclic alkyl groups. Analogously, the terms “alkenyl group” and “alkynyl group” are used as umbrella terms for linear, branched and cyclic alkenyl and alkynyl groups respectively.

In the context of the present invention, a C₁- to C₂₀-alkyl group in which individual hydrogen atoms or CH₂ groups may also be substituted by the abovementioned groups is understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl radicals. An alkenyl group is understood to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is understood to mean, for example, ethynyl, propynyl, butynyl, pentynyl, hexynyl, heptynyl or octynyl. A C₁- to C₂₀-alkoxy group as present for OR¹ or OR² is understood to mean, for example, methoxy, trifluoromethoxy, ethoxy, n-propoxy, i-propoxy, n-butoxy, i-butoxy, s-butoxy, t-butoxy or 2-methylbutoxy.

An aromatic or heteroaromatic ring system which has 5-40 aromatic ring atoms and may also be substituted in each case by the abovementioned radicals and which may be joined to the aromatic or heteroaromatic system via any desired positions is understood to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

For illustration, the compound of the invention is elucidated in detail hereinafter: The compound contains a pyrimidine group that coordinates to one iridium via each of the two nitrogen atoms. Two phenyl groups are bonded to the pyrimidine, each of which coordinates to one of the two iridium atoms via a carbon atom. Bonded to each of these two phenyl groups is a 1,3,5-tris(ortho-phenyl)benzene group, and each of these constitutes the bridgehead of the polypodal complex. There are another two optionally substituted phenylpyridine subligands that are each bonded to these 1,3,5-tris(ortho-phenyl)benzene groups. Each of the two iridium atoms is thus coordinated to two phenylpyridine subligands and one phenylpyrimidine subligand, where the pyrimidine group coordinates to both iridium atoms.

What is meant by the term “subligand” for the two phenylpyridine ligands in the context of this application is that this would be a bidentate ligand if the 1,3,5-tris(ortho-phenyl)benzene group were absent. However, as a result of the formal abstraction of a hydrogen atom on the phenylpyridine and the linkage to the 1,3,5-tris(ortho-phenyl)benzene group, it is not a separate ligand but a portion of the dodecadentate ligand which thus arises, i.e. a ligand having a total of 12 coordination sites, and so the term “subligand” is used therefor.

The bond of the ligand to the iridium may either be a coordinate bond or a covalent bond, or the covalent fraction of the bond may vary according to the ligand. When it is said in the present application that the ligand or subligand coordinates or binds to Ir, this refers in the context of the present application to any kind of bond of the ligand or subligand to the Ir, irrespective of the covalent share of the bond.

A preferred embodiment of the invention is the compounds of the following formulae (1a):

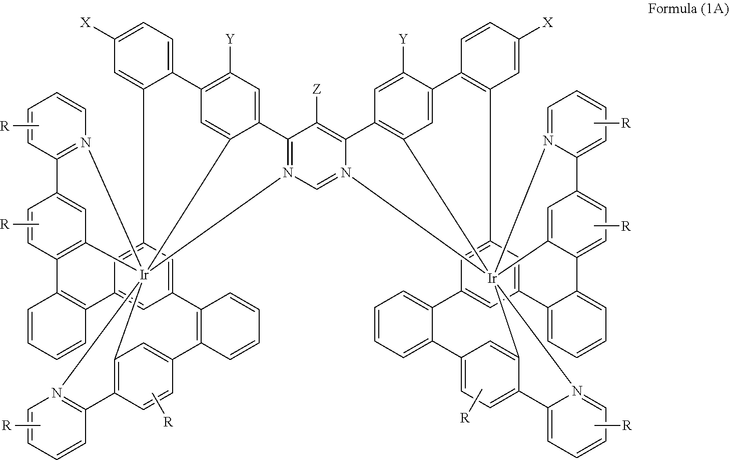

where the symbols used have the definitions given above.

In a preferred embodiment of the invention, the two substituents X are the same.

In one embodiment of the invention, Y and Z are H. In a further embodiment of the invention, each Y group is a group of the formula —(Ar)ₙ—R where the two Y groups are preferably the same, but may be the same as or different from the X groups, and Z is H. In yet a further embodiment of the invention, the two Y groups are H, and Z is a group of the formula —(Ar)ₙ—R that may be the same as or different from the X groups.

Preferred embodiments of the formula (1) or (1a) are therefore the structures of the following formulae (1a-1), (1a-2) or (1a-3):

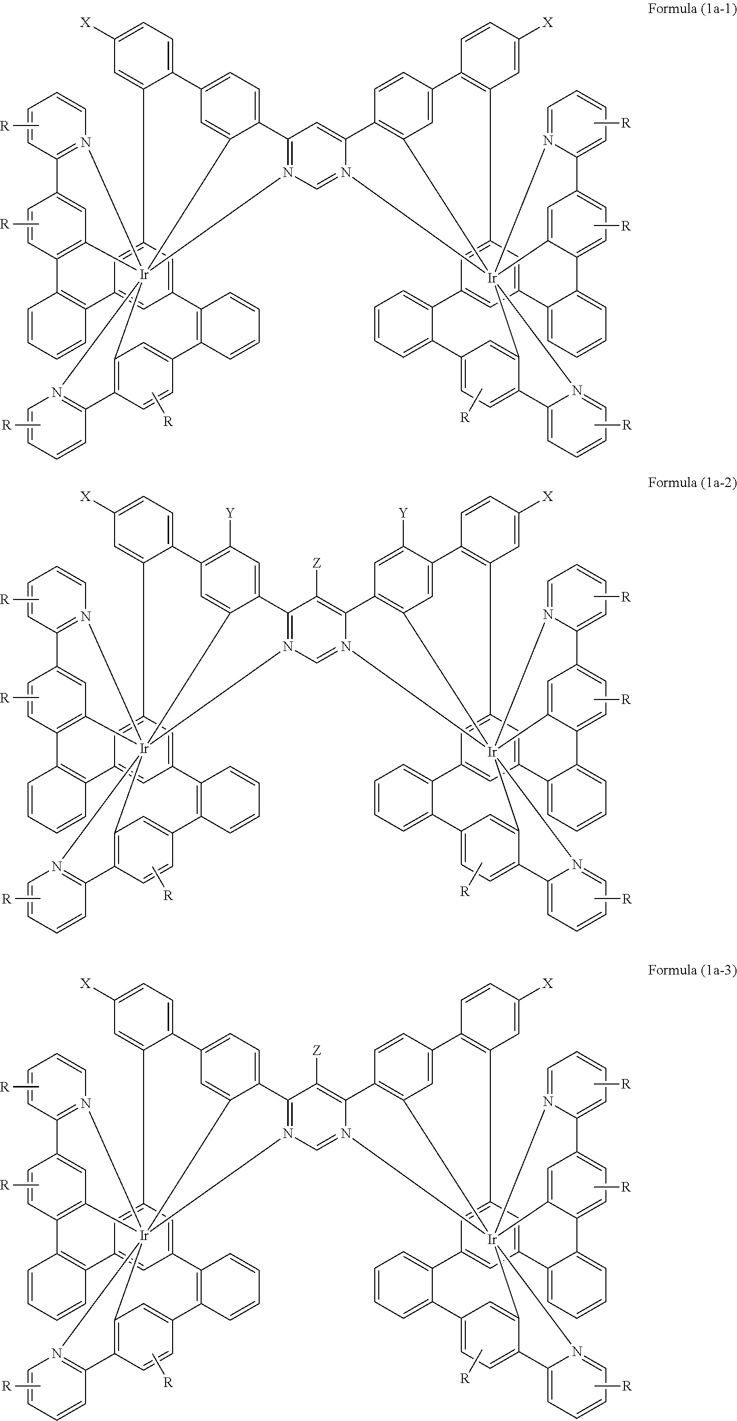

where the two groups X chosen are each the same, and where the Y groups in formula (1a-2) are each a —(Ar)ₙ—R group and are the same, and where the Z group in formula (1a-3) is a —(Ar)ₙ—R group. Particular preference is given to the compounds of the formula (1a-1).

The R radical in the —(Ar)ₙ—R group is preferably the same or different at each instance and is H, a linear alkyl group having 1 to 10 carbon atoms or a branched or cyclic alkyl group having 3 to 10 carbon atoms, especially H.

Preferred Ar groups that form the structures X and optionally also Y and Z are set out hereinafter. As described above, these are the bivalent structures (Ar1) to (Ar7), which may each be the same or different. What is common to the (Ar1) to (Ar7) groups is that they lead via the para linkage, or in formula (Ar3) via a linkage similar to the para linkage, to a linear linkage of the units within the X or Y or Z group. This is essential since only then do the compounds of the invention show orientation on deposition from solution.

Preferred embodiments of the structures (Ar1) are the following structures (Ar1a) to (Ar1f):

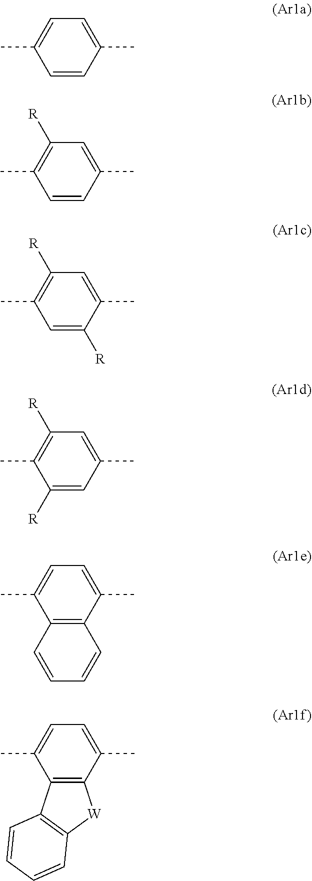

where the dotted bonds represent the linkage of the structures, W is C(R¹)₂, O, S or NR¹, and R and R¹ have the definitions given above. W here is preferably O or S.

Preferred substituents R in the structures (Ar1 b) to (Ar1d) are the same or different at each instance and are selected from the group consisting of a linear alkyl group having 1 to 20 carbon atoms or a branched or cyclic alkyl group having 3 to 20 carbon atoms, each of which may be substituted by one or more R¹ radicals, but are preferably unsubstituted, or an aromatic ring system which has 6 to 12 aromatic ring atoms and may be substituted by one or more R¹ radicals, where R¹ is preferably a linear alkyl group having 1 to 20 carbon atoms or a branched or cyclic alkyl group having 3 to 20 carbon atoms, or an OR¹ group where R¹ is a linear alkyl group having 1 to 20 carbon atoms or a branched or cyclic alkyl group having 3 to 20 carbon atoms.

When W in formula (Ar1f) is C(R¹)₂, R¹ is preferably a linear alkyl group having 1 to 20 carbon atoms or a branched or cyclic alkyl group having 3 to 20 carbon atoms. When W in formula (Ar1f) is NR¹, R¹ is preferably an aromatic ring system which has 6 to 24 aromatic ring atoms, preferably 6 to 12 aromatic ring atoms, and may be substituted by one or more alkyl groups each having 1 to 20 carbon atoms.

Preferred embodiments of the structures (Ar2) are the structures (Ar2a) and (Ar2b)

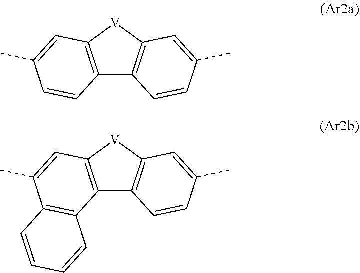

where the dotted bonds represent the linkage of the structures, and R and V have the definitions given above.

Particularly preferred embodiments of the structure (Ar2) are the following structures (Ar2a-1) to (Ar2a-5) and (Ar2b-1):

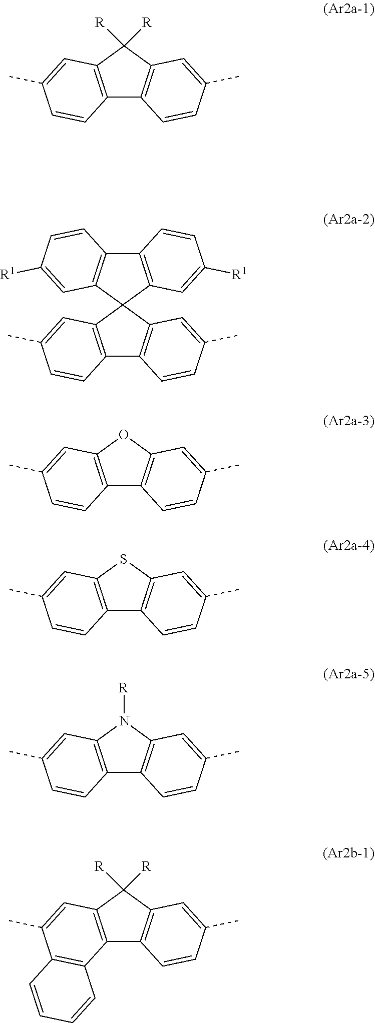

where the dotted bonds represent the linkage of the structure, and R and R¹ have the definitions given above.

Preferred substituents R in the structures (Ar2a-1) and (Ar2b-1) are the same or different at each instance and are selected from the group consisting of a linear alkyl group having 1 to 20 carbon atoms or a branched or cyclic alkyl group having 3 to 20 carbon atoms, each of which may be substituted by one or more R¹ radicals, but are preferably unsubstituted, or an aromatic ring system which has 6 to 12 aromatic ring atoms and may be substituted by one or more R¹ radicals, where R¹ is preferably a linear alkyl group having 1 to 20 carbon atoms or a branched or cyclic alkyl group having 3 to 20 carbon atoms.

Preferred substituents R¹ in the structures (Ar2a-2) are the same or different at each instance and are selected from the group consisting of H, a linear alkyl group having 1 to 20 carbon atoms or a branched or cyclic alkyl group having 3 to 20 carbon atoms, each of which may be substituted by one or more R² radicals, but are preferably unsubstituted.

Preferred substituents R in the structures (Ar2a-5) are the same or different at each instance and are selected from the group consisting of an aromatic or heteroaromatic ring system which has 6 to 18 aromatic ring atoms and may be substituted by one or more R¹ radicals, preferably an aromatic ring system which has 6 to 12 aromatic ring atoms and may be substituted by one or more R¹ radicals, where R¹ is preferably a linear alkyl group having 1 to 20 carbon atoms or a branched or cyclic alkyl group having 3 to 20 carbon atoms.

Preferred embodiments of the structures (Ar3) are the following structures (Ar3a):

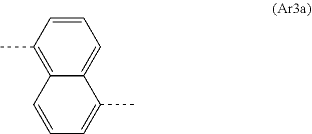

where the dotted bonds represent the linkage of the structure.

Preferred embodiments of the structures (Ar4) are the following structures (Ar4a) and (Ar4b):

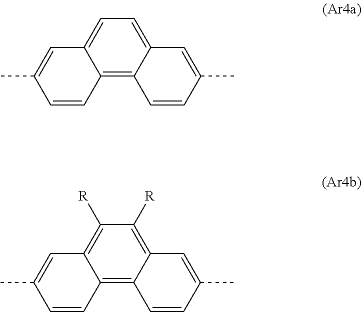

where the dotted bonds represent the linkage of the structure, and R has the definitions given above.

Preferred substituents R in the structures (Ar4b) are the same or different at each instance and are selected from the group consisting of a linear alkyl group having 1 to 20 carbon atoms or a branched or cyclic alkyl group having 3 to 20 carbon atoms, each of which may be substituted by one or more R¹ radicals, but are preferably unsubstituted, or an aromatic ring system which has 6 to 12 aromatic ring atoms and may be substituted by one or more R¹ radicals, where R¹ is preferably a linear alkyl group having 1 to 20 carbon atoms or a branched or cyclic alkyl group having 3 to 20 carbon atoms.

Preferred embodiments of the structures (Ar5) are the following structures (Ar5a) and (Ar5b):

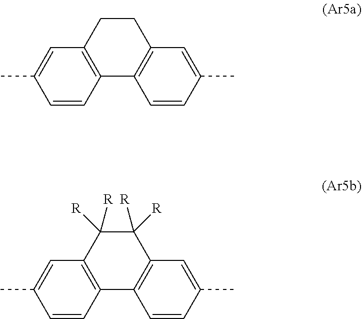

where the dotted bonds represent the linkage of the structure, and R has the definitions given above.

Preferred substituents R in the structures (Ar5b) are the same or different at each instance and are selected from the group consisting of H, a linear alkyl group having 1 to 20 carbon atoms or a branched or cyclic alkyl group having 3 to 20 carbon atoms, each of which may be substituted by one or more R¹ radicals, but are preferably unsubstituted.

Preferred embodiments of the structures (Ar7) are the following structures (Ar7a):

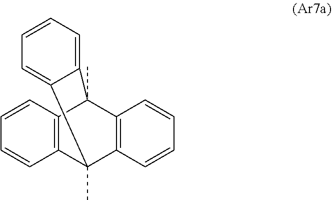 [SMILES: C[C@]12c3ccccc3[C@@](C)(c3ccccc31)c1ccccc12]

where the dotted bonds represent linkage of the structure.

In a preferred embodiment of the invention, at least one Ar group is the same or different at each instance and is selected from the structures (Ar1) and/or (Ar2), more preferably at least two Ar groups and most preferably at least 3 Ar groups. Especially preferably, all Ar groups are selected from the structures (Ar1) and/or (Ar2). The structures (Ar1) are preferably the same or different at each instance and are selected from the structures (Ar1a) to (Ar1 d), and the structures (Ar2) from the structures (Ar2a), more preferably the structures (Ar2a-1).

When the R or R¹ radicals in the structures (Ar1) or (Ar7), or in the preferred structures set out above, are linear, branched or cyclic alkyl groups, the alkyl groups have preferably 1 to 15 carbon atoms, more preferably 1 to 12 carbon atoms and most preferably 1 to 10 carbon atoms. Examples of suitable alkyl groups as substituents R or R¹ in the structures (Ar1) to (Ar7), and in the preferred structures, are methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl. The alkyl groups may each also have one or more stereocentres, in which case it is possible to use either the enantiomerically pure or diastereomerically pure structures or the corresponding racemates.

As described above, n is an integer from 3 to 20, with the proviso that at least 5 phenyl or cyclohexane groups are joined to one another in a linear manner. In a preferred embodiment of the invention, n is an integer from 5 to 20, especially from 5 to 15. More preferably, n is chosen such that a total of 8 to 24 phenyl or cyclohexane groups are joined to one another in a linear manner, more preferably 12 to 24 phenyl or cyclohexane groups and most preferably 15 to 20 phenyl or cyclohexane groups. As described above, the structures (Ar2), (Ar4) and (Ar5) each contribute two phenyl groups.

Preferred embodiments of the phenylpyridine subligands are described hereinafter. When the phenylpyridine subligands in formula (1) are substituted by one or more R radicals, these substituents are preferably bonded as shown in the following formula (2):

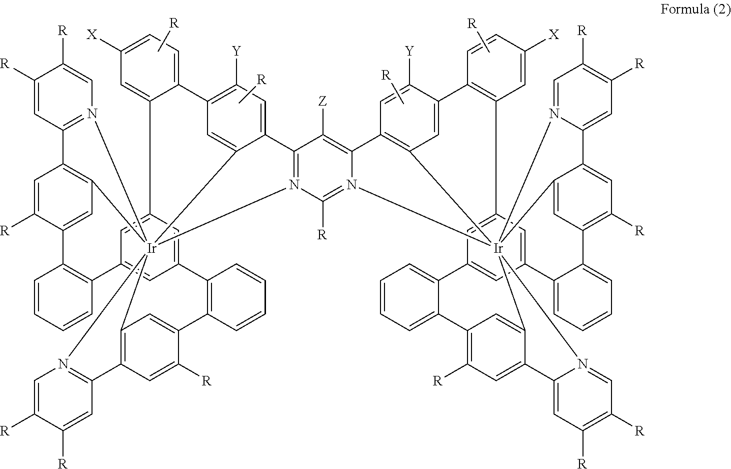

where the symbols used have the definitions detailed above.

The same preferred positions of the R radicals on the phenylpyridine subligands are also applicable in the preferred structures.

Preference is given to the structures of the following formula (2a):

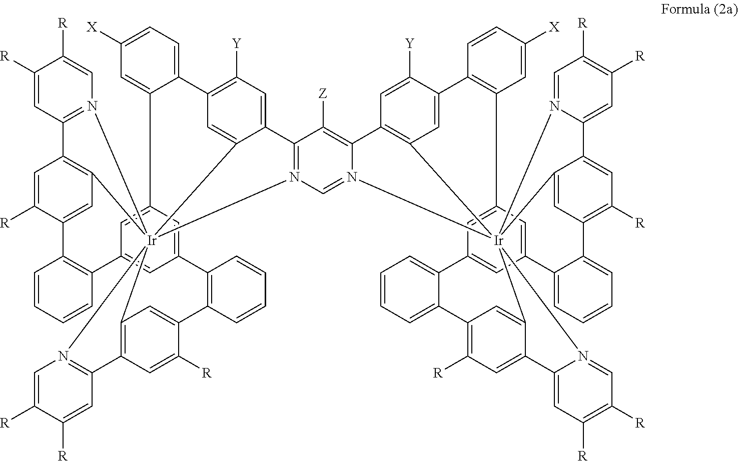

where the symbols used have the definitions given above.

It is preferably the case in respect of the substituents on the phenylpyridine subligands that each of the four subligands has the same substitution. Further preferably, each phenylpyridine subligand has a maximum of three substituents R that are not H, more preferably a maximum of two substituents R. When two substituents R that are not H are bonded to the pyridine ring, preferably at least one of the two substituents is an alkyl group. More preferably, not more than one substituent R on the pyridine is a group other than H. In a further preferred embodiment of the invention, the phenyl group of the phenylpyridine subligand contains a substituent R bonded in the para position to the iridium, where this substituent R is preferably selected from aromatic ring systems which have 6 to 24 aromatic ring atoms, preferably 6 to 12 aromatic ring atoms, and may each be substituted by one or more R¹ radicals, where R¹ is preferably selected from linear alkyl groups having 1 to 10 carbon atoms or branched or cyclic alkyl groups having 3 to 10 carbon atoms, where R is especially an unsubstituted phenyl group. In a further preferred embodiment of the invention, the pyridine group of the phenylpyridine subligand contains a substituent R bonded in the para position to the nitrogen atom, where this substituent R is preferably selected from a linear alkyl group having 1 to 10 carbon atoms or a branched or cyclic alkyl group having 3 to 10 carbon atoms, especially a methyl group.

The R radicals on the phenylpyridine subligands in formula (1) or the preferred embodiments are preferably the same or different at each instance and are selected from the group consisting of H, D, F, OR¹, CN, a straight-chain alkyl group having 1 to 10 carbon atoms or a branched or cyclic alkyl group having 3 to 10 carbon atoms, where each alkyl group may be substituted by one or more R¹ radicals, or an aromatic or heteroaromatic ring system which has 5 to 30 aromatic ring atoms and may be substituted in each case by one or more R¹ radicals; at the same time, two adjacent R radicals together may also form a mono- or polycyclic, aliphatic or aromatic ring system. More preferably, these R radicals are the same or different at each instance and are selected from the group consisting of H, D, F, OR¹, a straight-chain alkyl group having 1 to 6 carbon atoms or a branched or cyclic alkyl group having 3 to 10 carbon atoms, where one or more hydrogen atoms may be replaced by D or F, or an aromatic or heteroaromatic ring system which has 5 to 24 aromatic ring atoms, preferably 6 to 13 aromatic ring atoms, and may be substituted in each case by one or more R¹ radicals; at the same time, two adjacent R radicals together may also form a mono- or polycyclic, aliphatic or aromatic ring system. Particularly preferred aromatic ring systems are phenyl which may also be substituted by one or two alkyl groups each having 1 to 6 carbon atoms, or biphenyl.

Preferred R¹ radicals bonded to R are the same or different at each instance and are H, D, F, CN, a straight-chain alkyl group having 1 to 10 carbon atoms or a branched or cyclic alkyl group having 3 to 10 carbon atoms, where each alkyl group may be substituted by one or more R² radicals, or an aromatic or heteroaromatic ring system which has 5 to 24 aromatic ring atoms and may be substituted in each case by one or more R² radicals; at the same time, two or more adjacent R¹ radicals together may form a mono- or polycyclic aliphatic ring system. Particularly preferred R¹ radicals bonded to R are the same or different at each instance and are H, F, CN, a straight-chain alkyl group having 1 to 5 carbon atoms or a branched or cyclic alkyl group having 3 to 5 carbon atoms, each of which may be substituted by one or more R² radicals, or an aromatic or heteroaromatic ring system which has 5 to 13 aromatic ring atoms and may be substituted in each case by one or more R² radicals; at the same time, two or more adjacent R¹ radicals together may form a mono- or polycyclic aliphatic ring system.

Preferred R² radicals are the same or different at each instance and are H, F or an aliphatic hydrocarbyl radical having 1 to 5 carbon atoms or an aromatic hydrocarbyl radical having 6 to 12 carbon atoms; at the same time, two or more R² substituents together may also form a mono- or polycyclic aliphatic ring system.

The abovementioned preferred embodiments are combinable with one another as desired within the scope of the claim. In a particularly preferred embodiment of the invention, the abovementioned preferred embodiments apply simultaneously.

The compounds of the invention are chiral structures. According to the exact structure of the complexes and ligands, the formation of diastereomers and of several pairs of enantiomers is possible.

In that case, the complexes of the invention include both the mixtures of the different diastereomers or the corresponding racemates and the individual isolated diastereomers or enantiomers. The diastereomer pairs can be separated by conventional methods, e.g. by chromatography or by fractional crystallization. The racemate separation can be effected via fractional crystallization of diastereomeric pairs of salts or on chiral columns by customary methods.

Examples of suitable compounds of the invention are adduced hereinafter. In these example structures, the X groups have the following general structure:

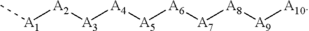

Structures 1 to 34 adduced below are suitable structures for A₁ to A₁₀. A₁ binds to the metal complex via the dotted bond, and the last Aₙ group in the structures in the table below has a hydrogen atom in place of the dotted bond. Asymmetric groups (groups 3, 4, 6, 9, 10 and 18) may be joined to the previous group via either of the two dotted lines. For better clarity, only one isomeric form was given in these cases.

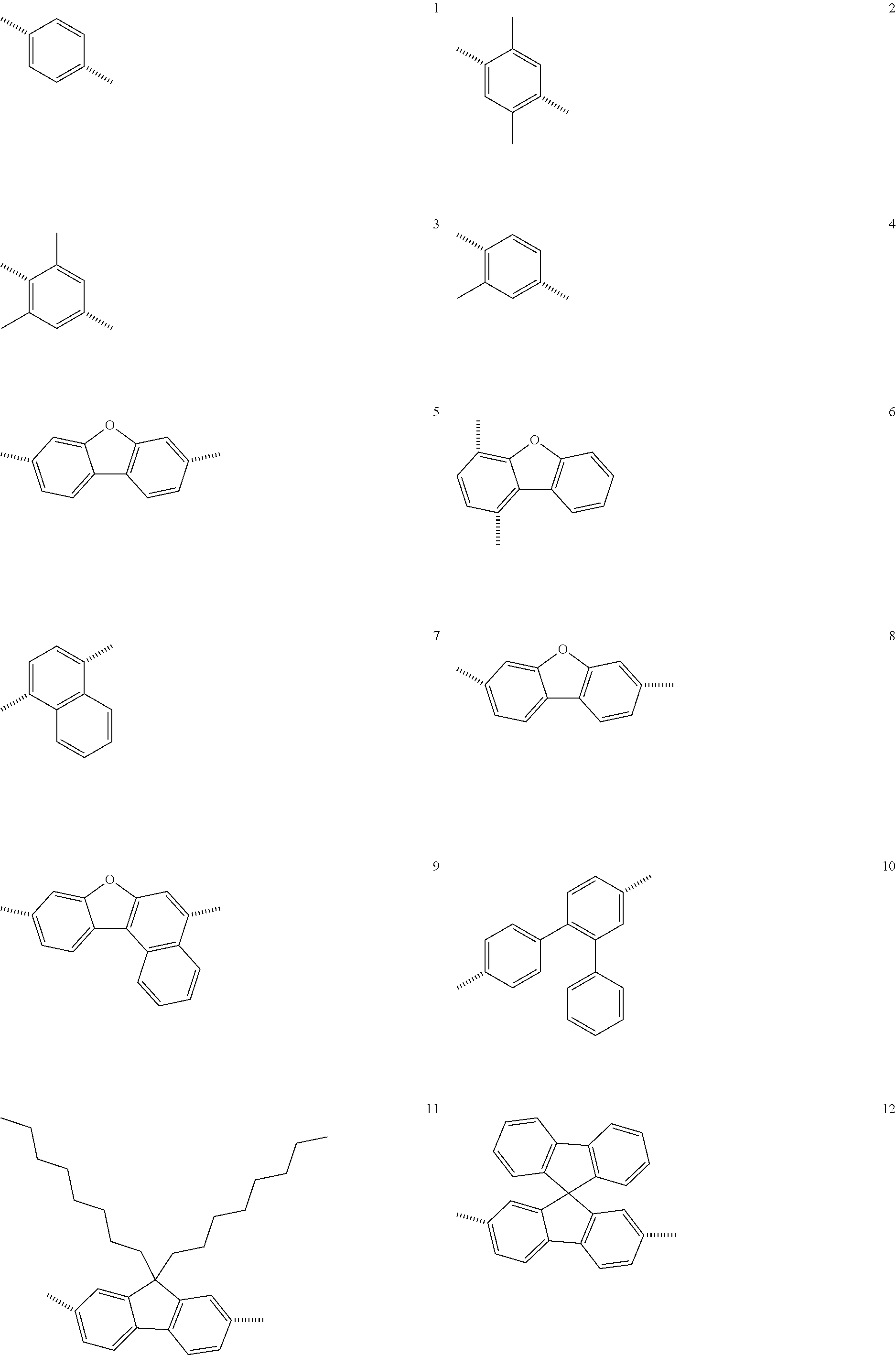

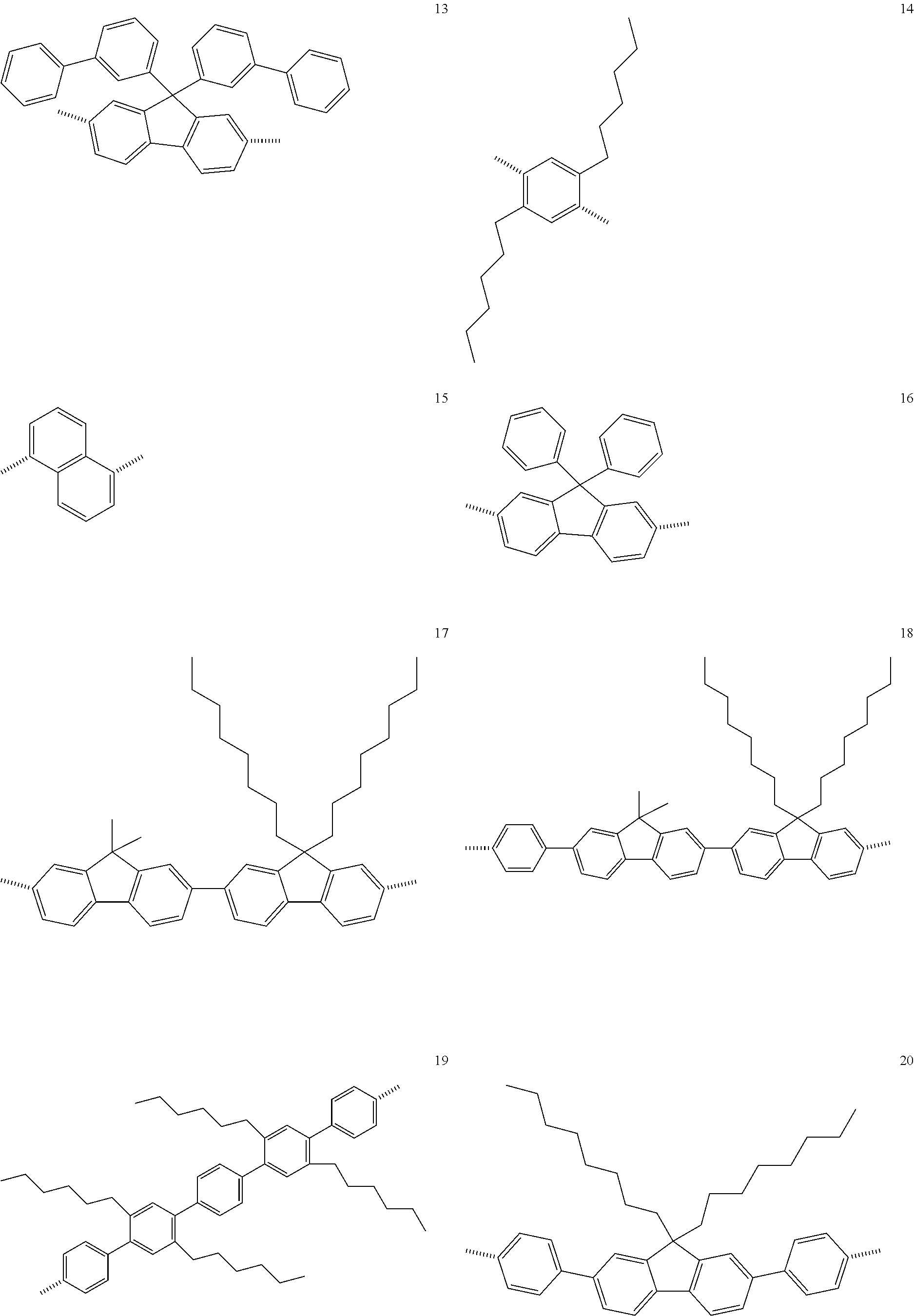

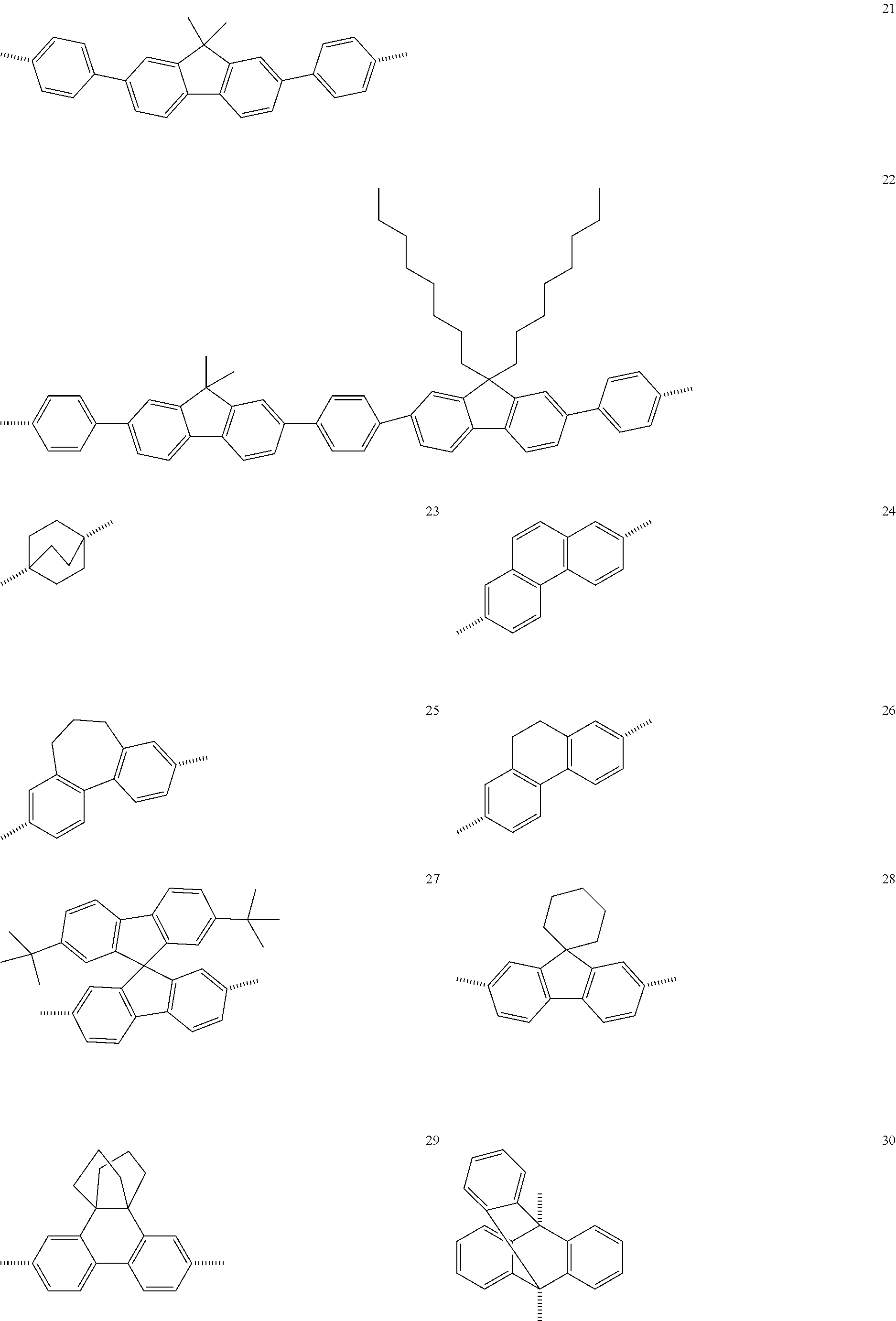

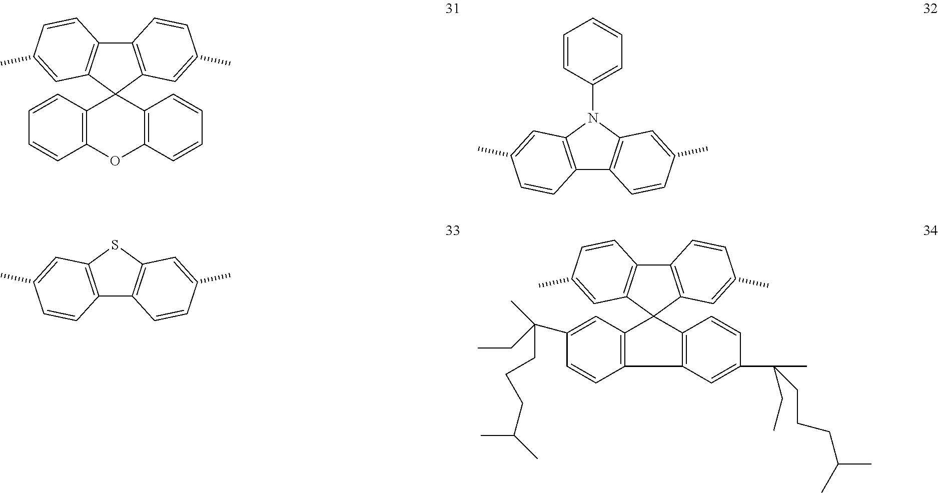

The suitable X groups shown in the table below can be constructed from the structures 1 to 34 shown above:

| X | A1 | A2 | A3 | A4 | A5 | A6 | A7 | A8 | A9 | A10 |
|---|---|---|---|---|---|---|---|---|---|---|
| 1 | 1 | 17 | 18 | 18 | — | — | — | — | — | — |
| 2 | 2 | 17 | 18 | 18 | — | — | — | — | — | — |
| 3 | 3 | 17 | 18 | 18 | — | — | — | — | — | — |
| 4 | 4 | 17 | 18 | 18 | — | — | — | — | — | — |
| 5 | 5 | 17 | 18 | 18 | — | — | — | — | — | — |
| 6 | 6 | 17 | 18 | 18 | — | — | — | — | — | — |
| 7 | 7 | 17 | 18 | 18 | — | — | — | — | — | — |
| 8 | 10 | 17 | 18 | 18 | — | — | — | — | — | — |
| 9 | 14 | 17 | 18 | 18 | — | — | — | — | — | — |
| 10 | 15 | 17 | 18 | 18 | — | — | — | — | — | — |
| 11 | 19 | 17 | 18 | 18 | — | — | — | — | — | — |
| 12 | 20 | 17 | 18 | 18 | — | — | — | — | — | — |
| 13 | 21 | 17 | 18 | 18 | — | — | — | — | — | — |
| 14 | 22 | 17 | 18 | 18 | — | — | — | — | — | — |
| 15 | 23 | 17 | 18 | 18 | — | — | — | — | — | — |
| 16 | 24 | 17 | 18 | 18 | — | — | — | — | — | — |
| 17 | 25 | 17 | 18 | 18 | — | — | — | — | — | — |
| 18 | 26 | 17 | 18 | 18 | — | — | — | — | — | — |
| 19 | 27 | 17 | 18 | 18 | — | — | — | — | — | — |
| 20 | 1 | 17 | 18 | 18 | 18 | — | — | — | — | — |
| 21 | 2 | 17 | 18 | 18 | 18 | — | — | — | — | — |
| 22 | 3 | 17 | 18 | 18 | 18 | — | — | — | — | — |
| 23 | 4 | 17 | 18 | 18 | 18 | — | — | — | — | — |
| 24 | 5 | 17 | 18 | 18 | 18 | — | — | — | — | — |
| 25 | 6 | 17 | 18 | 18 | 18 | — | — | — | — | — |
| 26 | 7 | 17 | 18 | 18 | 18 | — | — | — | — | — |
| 27 | 10 | 17 | 18 | 18 | 18 | — | — | — | — | — |
| 28 | 14 | 17 | 18 | 18 | 18 | — | — | — | — | — |
| 29 | 15 | 17 | 18 | 18 | 18 | — | — | — | — | — |
| 30 | 19 | 17 | 18 | 18 | 18 | — | — | — | — | — |
| 31 | 20 | 17 | 18 | 18 | 18 | — | — | — | — | — |
| 32 | 21 | 17 | 18 | 18 | 18 | — | — | — | — | — |
| 33 | 22 | 17 | 18 | 18 | 18 | — | — | — | — | — |
| 34 | 23 | 17 | 18 | 18 | 18 | — | — | — | — | — |
| 35 | 24 | 17 | 18 | 18 | 18 | — | — | — | — | — |
| 36 | 25 | 17 | 18 | 18 | 18 | — | — | — | — | — |
| 37 | 26 | 17 | 18 | 18 | 18 | — | — | — | — | — |
| 38 | 27 | 17 | 18 | 18 | 18 | — | — | — | — | — |
| 39 | 1 | 4 | 1 | 8 | 1 | 8 | 18 | — | — | — |
| 40 | 2 | 4 | 1 | 8 | 1 | 8 | 18 | — | — | — |
| 41 | 3 | 4 | 1 | 8 | 1 | 8 | 18 | — | — | — |
| 42 | 4 | 4 | 1 | 8 | 1 | 8 | 18 | — | — | — |
| 43 | 5 | 4 | 1 | 8 | 1 | 8 | 18 | — | — | — |
| 44 | 6 | 4 | 1 | 8 | 1 | 8 | 18 | — | — | — |
| 45 | 7 | 4 | 1 | 8 | 1 | 8 | 18 | — | — | — |
| 46 | 10 | 4 | 1 | 8 | 1 | 8 | 18 | — | — | — |
| 47 | 14 | 4 | 1 | 8 | 1 | 8 | 18 | — | — | — |
| 48 | 15 | 4 | 1 | 8 | 1 | 8 | 18 | — | — | — |
| 49 | 19 | 4 | 1 | 8 | 1 | 8 | 18 | — | — | — |
| 50 | 20 | 4 | 1 | 8 | 1 | 8 | 18 | — | — | — |
| 51 | 21 | 4 | 1 | 8 | 1 | 8 | 18 | — | — | — |
| 52 | 22 | 4 | 1 | 8 | 1 | 8 | 18 | — | — | — |
| 53 | 23 | 4 | 1 | 8 | 1 | 8 | 18 | — | — | — |
| 54 | 24 | 4 | 1 | 8 | 1 | 8 | 18 | — | — | — |
| 55 | 25 | 4 | 1 | 8 | 1 | 8 | 18 | — | — | — |
| 56 | 26 | 4 | 1 | 8 | 1 | 8 | 18 | — | — | — |
| 57 | 27 | 4 | 1 | 8 | 1 | 8 | 18 | — | — | — |
| 58 | 1 | 1 | 13 | 1 | 21 | 13 | 21 | 13 | — | — |
| 59 | 1 | 2 | 13 | 1 | 21 | 13 | 21 | 13 | — | — |
| 60 | 1 | 3 | 13 | 1 | 21 | 13 | 21 | 13 | — | — |
| 61 | 1 | 4 | 13 | 1 | 21 | 13 | 21 | 13 | — | — |
| 62 | 1 | 6 | 13 | 1 | 21 | 13 | 21 | 13 | — | — |
| 63 | 1 | 7 | 13 | 1 | 21 | 13 | 21 | 13 | — | — |
| 64 | 1 | 9 | 13 | 1 | 21 | 13 | 21 | 13 | — | — |
| 65 | 1 | 23 | 1 | 21 | 22 | 16 | — | — | — | — |
| 66 | 1 | 24 | 1 | 21 | 22 | 16 | — | — | — | — |
| 67 | 1 | 25 | 1 | 21 | 22 | 16 | — | — | — | — |
| 68 | 1 | 26 | 1 | 21 | 22 | 16 | — | — | — | — |
| 69 | 1 | 27 | 1 | 21 | 22 | 16 | — | — | — | — |
| 70 | 4 | 13 | 14 | 13 | 14 | 13 | 14 | 13 | 14 | 13 |
| 71 | 4 | 13 | 1 | 13 | 1 | 13 | 1 | 13 | 1 | 13 |
| 72 | 4 | 13 | 2 | 13 | 2 | 13 | 2 | 13 | 2 | 13 |
| 73 | 4 | 13 | 4 | 13 | 4 | 13 | 4 | 13 | 4 | 13 |
| 74 | 4 | 13 | 7 | 13 | 7 | 13 | 7 | 13 | 7 | 13 |
| 75 | 4 | 13 | 23 | 13 | 23 | 13 | 23 | 13 | 23 | 13 |
| 76 | 4 | 13 | 26 | 13 | 26 | 13 | 26 | 13 | 26 | 13 |
| 77 | 1 | 13 | 14 | 13 | 14 | 13 | 14 | 13 | 14 | 13 |
| 78 | 1 | 13 | 1 | 13 | 1 | 13 | 1 | 13 | 1 | 13 |
| 79 | 1 | 13 | 2 | 13 | 2 | 13 | 2 | 13 | 2 | 13 |
| 80 | 1 | 13 | 4 | 13 | 4 | 13 | 4 | 13 | 4 | 13 |
| 81 | 1 | 13 | 7 | 13 | 7 | 13 | 7 | 13 | 7 | 13 |
| 82 | 1 | 13 | 23 | 13 | 23 | 13 | 23 | 13 | 23 | 13 |
| 83 | 1 | 13 | 26 | 13 | 26 | 13 | 26 | 13 | 26 | 13 |
| 84 | 4 | 27 | 14 | 27 | 14 | 27 | 14 | 27 | 14 | 27 |
| 85 | 4 | 27 | 1 | 27 | 1 | 27 | 1 | 27 | 1 | 27 |
| 86 | 4 | 27 | 2 | 27 | 2 | 27 | 2 | 27 | 2 | 27 |
| 87 | 4 | 27 | 4 | 27 | 4 | 27 | 4 | 27 | 4 | 27 |
| 88 | 4 | 27 | 7 | 27 | 7 | 27 | 7 | 27 | 7 | 27 |
| 89 | 4 | 27 | 23 | 27 | 23 | 27 | 23 | 27 | 23 | 27 |
| 90 | 4 | 27 | 26 | 27 | 26 | 27 | 26 | 27 | 26 | 27 |
| 91 | 1 | 27 | 14 | 27 | 14 | 27 | 14 | 27 | 14 | 27 |
| 92 | 1 | 27 | 1 | 27 | 1 | 27 | 1 | 27 | 1 | 27 |
| 93 | 1 | 27 | 2 | 27 | 2 | 27 | 2 | 27 | 2 | 27 |
| 94 | 1 | 27 | 4 | 27 | 4 | 27 | 4 | 27 | 4 | 27 |
| 95 | 1 | 27 | 7 | 27 | 7 | 27 | 7 | 27 | 7 | 27 |
| 96 | 1 | 27 | 23 | 27 | 23 | 27 | 23 | 27 | 23 | 27 |
| 97 | 1 | 27 | 26 | 27 | 26 | 27 | 26 | 27 | 26 | 27 |
| 98 | 4 | 11 | 14 | 11 | 14 | 11 | 14 | 11 | 14 | 11 |
| 99 | 4 | 11 | 1 | 11 | 1 | 11 | 1 | 11 | 1 | 11 |
| 100 | 4 | 11 | 2 | 11 | 2 | 11 | 2 | 11 | 2 | 11 |
| 101 | 4 | 11 | 4 | 11 | 4 | 11 | 4 | 11 | 4 | 11 |
| 102 | 4 | 11 | 7 | 11 | 7 | 11 | 7 | 11 | 7 | 11 |
| 103 | 4 | 11 | 23 | 11 | 23 | 11 | 23 | 11 | 23 | 11 |
| 104 | 4 | 11 | 26 | 11 | 26 | 11 | 26 | 11 | 26 | 11 |
| 105 | 1 | 11 | 14 | 11 | 14 | 11 | 14 | 11 | 14 | 11 |
| 106 | 1 | 11 | 1 | 11 | 1 | 11 | 1 | 11 | 1 | 11 |
| 107 | 1 | 11 | 2 | 11 | 2 | 11 | 2 | 11 | 2 | 11 |
| 108 | 1 | 11 | 4 | 11 | 4 | 11 | 4 | 11 | 4 | 11 |
| 109 | 1 | 11 | 7 | 11 | 7 | 11 | 7 | 11 | 7 | 11 |
| 110 | 1 | 11 | 23 | 11 | 23 | 11 | 23 | 11 | 23 | 11 |
| 111 | 1 | 11 | 26 | 11 | 26 | 11 | 26 | 11 | 26 | 11 |
| 112 | 1 | 17 | 1 | 18 | 18 | — | — | — | — | — |
| 113 | 2 | 17 | 2 | 18 | 18 | — | — | — | — | — |
| 114 | 3 | 17 | 3 | 18 | 18 | — | — | — | — | — |
| 115 | 4 | 17 | 4 | 18 | 18 | — | — | — | — | — |
| 116 | 5 | 17 | 5 | 18 | 18 | — | — | — | — | — |
| 117 | 6 | 17 | 6 | 18 | 18 | — | — | — | — | — |
| 118 | 7 | 17 | 7 | 18 | 18 | — | — | — | — | — |
| 119 | 10 | 17 | 10 | 18 | 18 | — | — | — | — | — |
| 120 | 14 | 17 | 14 | 18 | 18 | — | — | — | — | — |
| 121 | 15 | 17 | 15 | 18 | 18 | — | — | — | — | — |
| 122 | 19 | 17 | 19 | 18 | 18 | — | — | — | — | — |
| 123 | 20 | 17 | 20 | 18 | 18 | — | — | — | — | — |
| 124 | 21 | 17 | 21 | 18 | 18 | — | — | — | — | — |
| 125 | 22 | 17 | 22 | 18 | 18 | — | — | — | — | — |
| 126 | 23 | 17 | 23 | 18 | 18 | — | — | — | — | — |
| 127 | 24 | 17 | 24 | 18 | 18 | — | — | — | — | — |
| 128 | 25 | 17 | 25 | 18 | 18 | — | — | — | — | — |
| 129 | 26 | 17 | 26 | 18 | 18 | — | — | — | — | — |
| 130 | 27 | 17 | 27 | 18 | 18 | — | — | — | — | — |
| 131 | 1 | 21 | 18 | 18 | — | — | — | — | — | — |
| 132 | 2 | 21 | 18 | 18 | — | — | — | — | — | — |
| 133 | 3 | 21 | 18 | 18 | — | — | — | — | — | — |
| 134 | 4 | 21 | 18 | 18 | — | — | — | — | — | — |
| 135 | 5 | 21 | 18 | 18 | — | — | — | — | — | — |
| 136 | 6 | 21 | 18 | 18 | — | — | — | — | — | — |
| 137 | 7 | 21 | 18 | 18 | — | — | — | — | — | — |
| 138 | 10 | 21 | 18 | 18 | — | — | — | — | — | — |
| 139 | 14 | 21 | 18 | 18 | — | — | — | — | — | — |
| 140 | 15 | 21 | 18 | 18 | — | — | — | — | — | — |
| 141 | 19 | 21 | 18 | 18 | — | — | — | — | — | — |
| 142 | 20 | 21 | 18 | 18 | — | — | — | — | — | — |
| 143 | 21 | 21 | 18 | 18 | — | — | — | — | — | — |
| 144 | 22 | 21 | 18 | 18 | — | — | — | — | — | — |
| 145 | 23 | 21 | 18 | 18 | — | — | — | — | — | — |
| 146 | 24 | 21 | 18 | 18 | — | — | — | — | — | — |
| 147 | 25 | 21 | 18 | 18 | — | — | — | — | — | — |
| 148 | 26 | 21 | 18 | 18 | — | — | — | — | — | — |
| 149 | 27 | 21 | 18 | 18 | — | — | — | — | — | — |
| 150 | 1 | 22 | 18 | 18 | — | — | — | — | — | — |
| 151 | 2 | 22 | 18 | 18 | — | — | — | — | — | — |
| 152 | 3 | 22 | 18 | 18 | — | — | — | — | — | — |
| 153 | 4 | 22 | 18 | 18 | — | — | — | — | — | — |
| 154 | 5 | 22 | 18 | 18 | — | — | — | — | — | — |
| 155 | 6 | 22 | 18 | 18 | — | — | — | — | — | — |
| 156 | 7 | 22 | 18 | 18 | — | — | — | — | — | — |
| 157 | 10 | 22 | 18 | 18 | — | — | — | — | — | — |
| 158 | 14 | 22 | 18 | 18 | — | — | — | — | — | — |
| 159 | 15 | 22 | 18 | 18 | — | — | — | — | — | — |
| 160 | 19 | 22 | 18 | 18 | — | — | — | — | — | — |
| 161 | 20 | 22 | 18 | 18 | — | — | — | — | — | — |
| 162 | 21 | 22 | 18 | 18 | — | — | — | — | — | — |
| 163 | 22 | 22 | 18 | 18 | — | — | — | — | — | — |
| 164 | 23 | 22 | 18 | 18 | — | — | — | — | — | — |
| 165 | 24 | 22 | 18 | 18 | — | — | — | — | — | — |
| 166 | 25 | 22 | 18 | 18 | — | — | — | — | — | — |
| 167 | 26 | 22 | 18 | 18 | — | — | — | — | — | — |
| 168 | 27 | 22 | 18 | 18 | — | — | — | — | — | — |
| 169 | 18 | 1 | 18 | 18 | — | — | — | — | — | — |
| 170 | 18 | 2 | 18 | 18 | — | — | — | — | — | — |
| 171 | 18 | 3 | 18 | 18 | — | — | — | — | — | — |
| 172 | 18 | 4 | 18 | 18 | — | — | — | — | — | — |
| 173 | 18 | 5 | 18 | 18 | — | — | — | — | — | — |
| 174 | 18 | 6 | 18 | 18 | — | — | — | — | — | — |
| 175 | 18 | 7 | 18 | 18 | — | — | — | — | — | — |
| 176 | 18 | 10 | 18 | 18 | — | — | — | — | — | — |
| 177 | 18 | 14 | 18 | 18 | — | — | — | — | — | — |
| 178 | 18 | 15 | 18 | 18 | — | — | — | — | — | — |
| 179 | 18 | 19 | 18 | 18 | — | — | — | — | — | — |
| 180 | 18 | 20 | 18 | 18 | — | — | — | — | — | — |
| 181 | 18 | 21 | 18 | 18 | — | — | — | — | — | — |
| 182 | 18 | 22 | 18 | 18 | — | — | — | — | — | — |
| 183 | 18 | 23 | 18 | 18 | — | — | — | — | — | — |
| 184 | 18 | 24 | 18 | 18 | — | — | — | — | — | — |
| 185 | 18 | 25 | 18 | 18 | — | — | — | — | — | — |
| 186 | 18 | 26 | 18 | 18 | — | — | — | — | — | — |
| 187 | 18 | 27 | 18 | 18 | — | — | — | — | — | — |
| 188 | 18 | 28 | 18 | 18 | — | — | — | — | — | — |
| 189 | 18 | 29 | 18 | 18 | — | — | — | — | — | — |
| 190 | 18 | 30 | 18 | 18 | — | — | — | — | — | — |
| 191 | 18 | 31 | 18 | 18 | — | — | — | — | — | — |
| 192 | 18 | 32 | 18 | 18 | — | — | — | — | — | — |
| 193 | 18 | 33 | 18 | 18 | — | — | — | — | — | — |
| 194 | 18 | 34 | 18 | 18 | — | — | — | — | — | — |
| 195 | 28 | 28 | 18 | 18 | — | — | — | — | — | — |
| 196 | 29 | 29 | 18 | 18 | — | — | — | — | — | — |
| 197 | 30 | 30 | 18 | 18 | — | — | — | — | — | — |
| 198 | 31 | 31 | 18 | 18 | — | — | — | — | — | — |
| 199 | 32 | 32 | 18 | 18 | — | — | — | — | — | — |
| 200 | 33 | 33 | 18 | 18 | — | — | — | — | — | — |
| 201 | 34 | 34 | 18 | 18 | — | — | — | — | — | — |
| 202 | 1 | 28 | 1 | 28 | 11 | 28 | — | — | — | — |
| 203 | 1 | 29 | 1 | 29 | 11 | 29 | — | — | — | — |
| 204 | 1 | 30 | 1 | 30 | 11 | 30 | — | — | — | — |
| 205 | 1 | 31 | 1 | 31 | 11 | 31 | — | — | — | — |
| 206 | 1 | 32 | 1 | 32 | 11 | 32 | — | — | — | — |
| 207 | 1 | 33 | 1 | 33 | 11 | 33 | — | — | — | — |
| 208 | 1 | 34 | 1 | 34 | 11 | 34 | — | — | — | — |
| 209 | 1 | 8 | 1 | 8 | 1 | — | — | — | — | — |
| 210 | 2 | 8 | 2 | 8 | 2 | — | — | — | — | — |
| 211 | 3 | 8 | 3 | 8 | 3 | — | — | — | — | — |
| 212 | 4 | 8 | 4 | 8 | 4 | — | — | — | — | — |
| 213 | 5 | 8 | 5 | 8 | 5 | — | — | — | — | — |
| 214 | 6 | 8 | 6 | 8 | 6 | — | — | — | — | — |
| 215 | 7 | 8 | 7 | 8 | 7 | — | — | — | — | — |
| 216 | 8 | 8 | 8 | 8 | 8 | — | — | — | — | — |
| 217 | 9 | 8 | 9 | 8 | 9 | — | — | — | — | — |
| 218 | 10 | 8 | 10 | 8 | 10 | — | — | — | — | — |
| 219 | 11 | 8 | 11 | 8 | 11 | — | — | — | — | — |
| 220 | 12 | 8 | 12 | 8 | 12 | — | — | — | — | — |
| 221 | 13 | 8 | 13 | 8 | 13 | — | — | — | — | — |
| 222 | 14 | 8 | 14 | 8 | 14 | — | — | — | — | — |
| 223 | 15 | 8 | 15 | 8 | 15 | — | — | — | — | — |
| 224 | 16 | 8 | 16 | 8 | 16 | — | — | — | — | — |
| 225 | 1 | 8 | 1 | 8 | 1 | 8 | — | — | — | — |
| 226 | 2 | 8 | 2 | 8 | 2 | 8 | — | — | — | — |
| 227 | 3 | 8 | 3 | 8 | 3 | 8 | — | — | — | — |
| 228 | 4 | 8 | 4 | 8 | 4 | 8 | — | — | — | — |
| 229 | 5 | 8 | 5 | 8 | 5 | 8 | — | — | — | — |
| 230 | 6 | 8 | 6 | 8 | 6 | 8 | — | — | — | — |
| 231 | 7 | 8 | 7 | 8 | 7 | 8 | — | — | — | — |
| 232 | 8 | 8 | 8 | 8 | 8 | 8 | — | — | — | — |
| 233 | 9 | 8 | 9 | 8 | 9 | 8 | — | — | — | — |
| 234 | 10 | 8 | 10 | 8 | 10 | 8 | — | — | — | — |
| 235 | 11 | 8 | 11 | 8 | 11 | 8 | — | — | — | — |
| 236 | 12 | 8 | 12 | 8 | 12 | 8 | — | — | — | — |
| 237 | 13 | 8 | 13 | 8 | 13 | 8 | — | — | — | — |
| 238 | 14 | 8 | 14 | 8 | 14 | 8 | — | — | — | — |
| 239 | 15 | 8 | 15 | 8 | 15 | 8 | — | — | — | — |
| 240 | 16 | 8 | 16 | 8 | 16 | 8 | — | — | — | — |
| 241 | 1 | 8 | 1 | 8 | 1 | 11 | — | — | — | — |
| 242 | 2 | 8 | 2 | 8 | 2 | 11 | — | — | — | — |
| 243 | 3 | 8 | 3 | 8 | 3 | 11 | — | — | — | — |
| 244 | 4 | 8 | 4 | 8 | 4 | 11 | — | — | — | — |
| 245 | 5 | 8 | 5 | 8 | 5 | 11 | — | — | — | — |
| 246 | 6 | 8 | 6 | 8 | 6 | 11 | — | — | — | — |
| 247 | 7 | 8 | 7 | 8 | 7 | 11 | — | — | — | — |
| 248 | 8 | 8 | 8 | 8 | 8 | 11 | — | — | — | — |
| 249 | 9 | 8 | 9 | 8 | 9 | 11 | — | — | — | — |
| 250 | 10 | 8 | 10 | 8 | 10 | 11 | — | — | — | — |
| 251 | 11 | 8 | 11 | 8 | 11 | 11 | — | — | — | — |
| 252 | 12 | 8 | 12 | 8 | 12 | 11 | — | — | — | — |
| 253 | 13 | 8 | 13 | 8 | 13 | 11 | — | — | — | — |
| 254 | 14 | 8 | 14 | 8 | 14 | 11 | — | — | — | — |
| 255 | 15 | 8 | 15 | 8 | 15 | 11 | — | — | — | — |
| 256 | 16 | 8 | 16 | 8 | 16 | 11 | — | — | — | — |
| 257 | 1 | 11 | 1 | 11 | 1 | 11 | — | — | — | — |
| 258 | 2 | 11 | 2 | 11 | 2 | 11 | — | — | — | — |
| 259 | 3 | 11 | 3 | 11 | 3 | 11 | — | — | — | — |
| 260 | 4 | 11 | 4 | 11 | 4 | 11 | — | — | — | — |
| 261 | 5 | 11 | 5 | 11 | 5 | 11 | — | — | — | — |
| 262 | 6 | 11 | 6 | 11 | 6 | 11 | — | — | — | — |
| 263 | 7 | 11 | 7 | 11 | 7 | 11 | — | — | — | — |
| 264 | 8 | 11 | 8 | 11 | 8 | 11 | — | — | — | — |
| 265 | 9 | 11 | 9 | 11 | 9 | 11 | — | — | — | — |
| 266 | 10 | 11 | 10 | 11 | 10 | 11 | — | — | — | — |
| 267 | 11 | 11 | 11 | 11 | 11 | 11 | — | — | — | — |
| 268 | 12 | 11 | 12 | 11 | 12 | 11 | — | — | — | — |
| 269 | 13 | 11 | 13 | 11 | 13 | 11 | — | — | — | — |
| 270 | 14 | 11 | 14 | 11 | 14 | 11 | — | — | — | — |
| 271 | 15 | 11 | 15 | 11 | 15 | 11 | — | — | — | — |
| 272 | 16 | 11 | 16 | 11 | 16 | 11 | — | — | — | — |
| 273 | 1 | 18 | 1 | 20 | 20 | — | — | — | — | — |
| 274 | 1 | 18 | 1 | 20 | 20 | 1 | — | — | — | — |
| 275 | 1 | 18 | 1 | 20 | 20 | 2 | — | — | — | — |
| 276 | 1 | 18 | 1 | 20 | 20 | 3 | — | — | — | — |
| 277 | 1 | 18 | 1 | 20 | 20 | 4 | — | — | — | — |
| 278 | 1 | 18 | 1 | 20 | 20 | 5 | — | — | — | — |
| 279 | 1 | 18 | 1 | 20 | 20 | 6 | — | — | — | — |
| 280 | 1 | 18 | 1 | 20 | 20 | 7 | — | — | — | — |
| 281 | 1 | 18 | 1 | 20 | 20 | 8 | — | — | — | — |
| 282 | 1 | 18 | 1 | 20 | 20 | 9 | — | — | — | — |
| 283 | 1 | 18 | 1 | 20 | 20 | 10 | — | — | — | — |
| 284 | 1 | 18 | 1 | 20 | 20 | 11 | — | — | — | — |
| 285 | 1 | 18 | 1 | 20 | 20 | 12 | — | — | — | — |

These X groups shown above can, for example, be joined via the dotted bonds to the following bimetallic complexes:

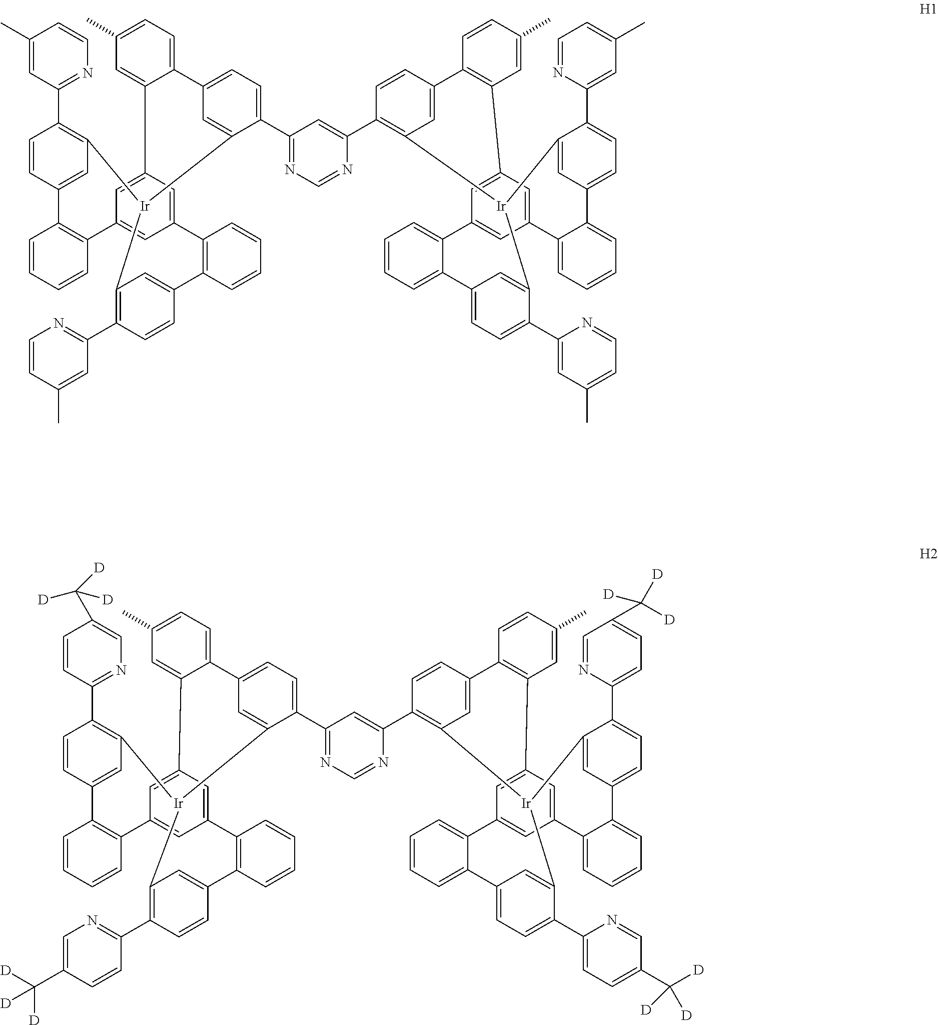

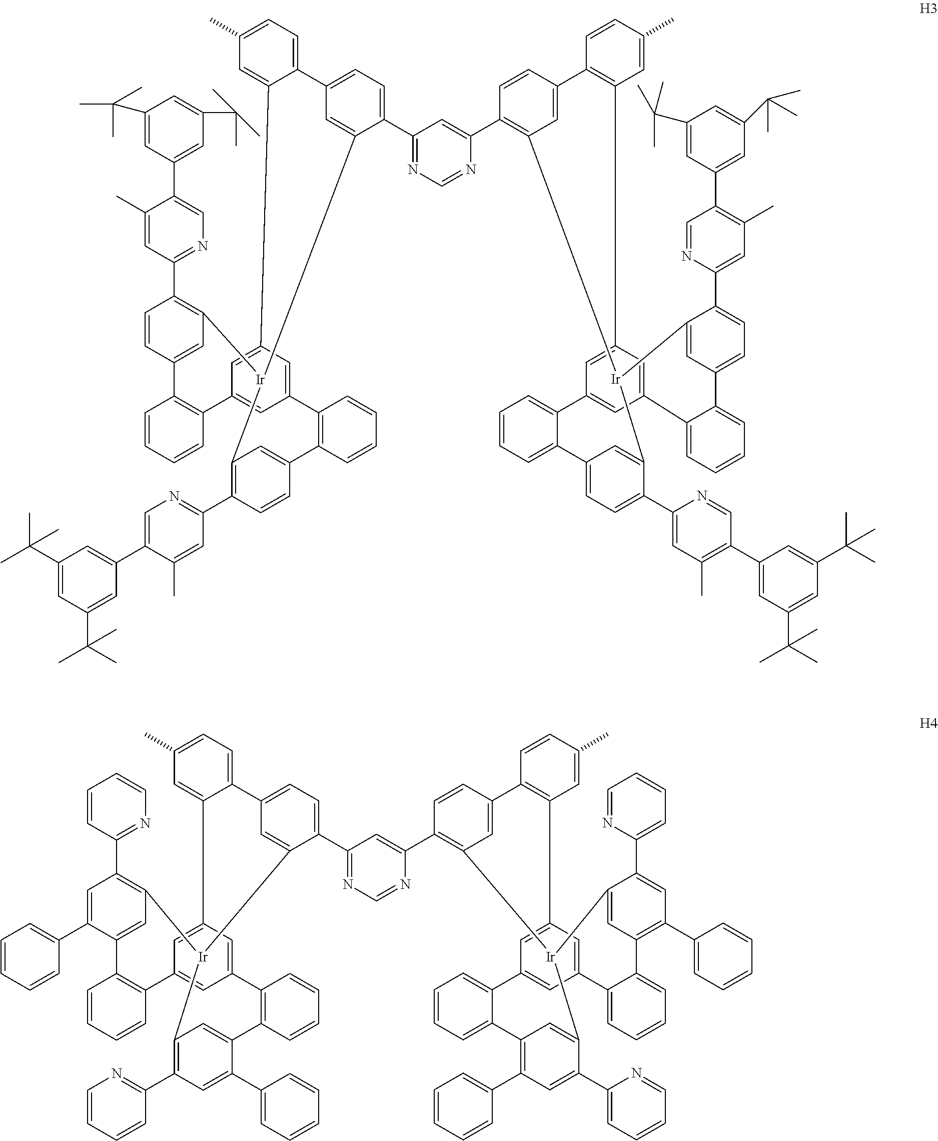

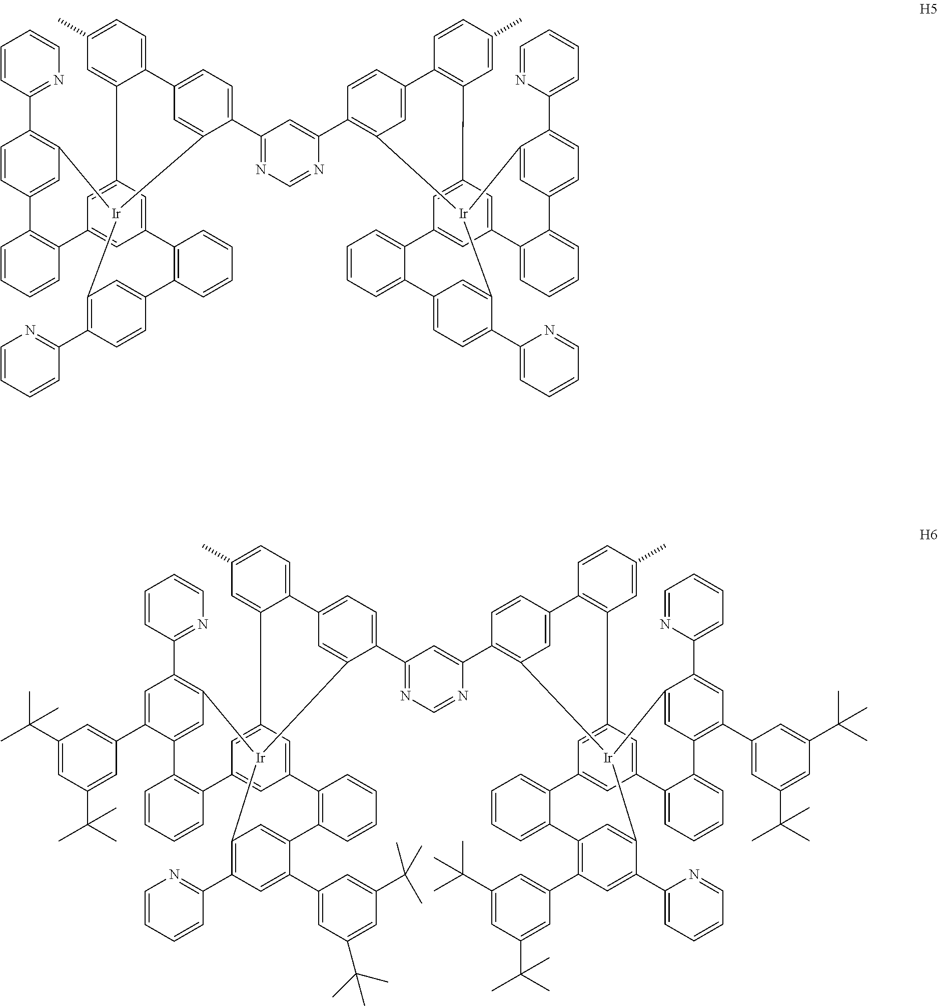

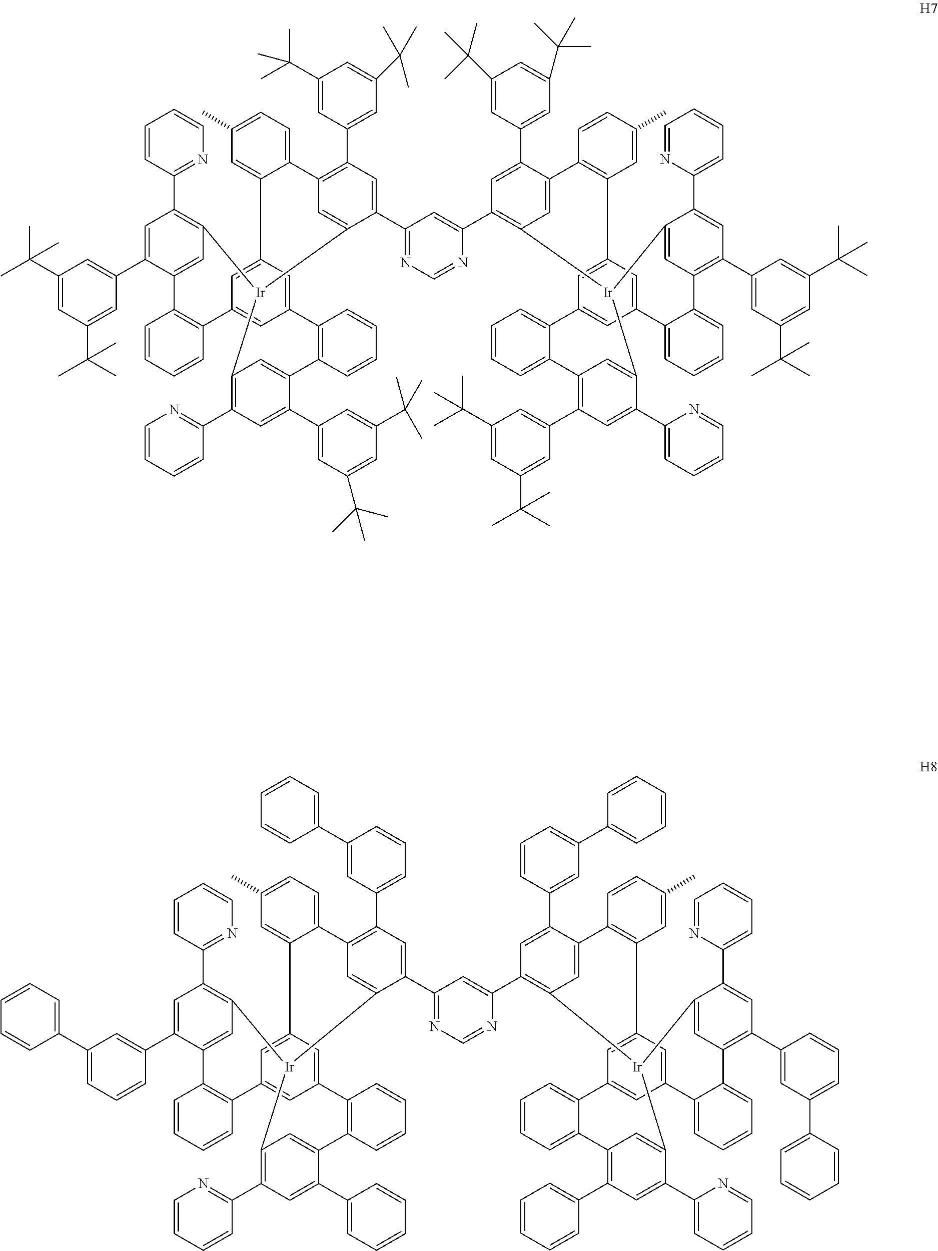

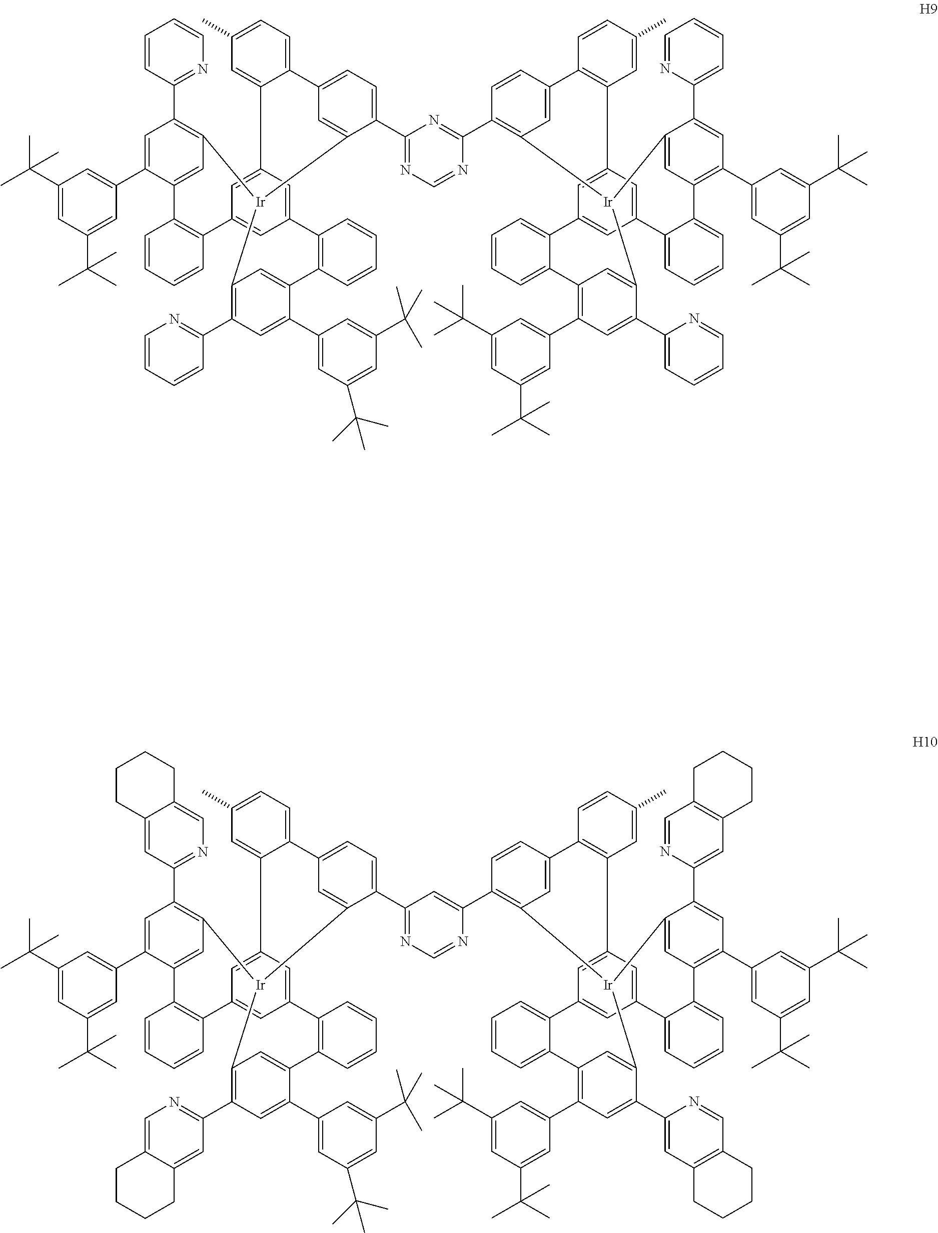

H1-H10 in the table above are each joined to the X groups via the two dotted lines. All the X groups shown above may be joined to any of the complexes H1 to H10. This is shown by way of example in the table below for H1 and the groups X1-X285 in the following table:

| | H | X |
|---|---|---|
| 1 | H1 | X1 |
| 2 | H1 | X2 |
| 3 | H1 | X3 |
| 4 | H1 | X4 |
| 5 | H1 | X5 |
| 6 | H1 | X6 |
| 7 | H1 | X7 |
| 8 | H1 | X8 |
| 9 | H1 | X9 |
| 10 | H1 | X10 |
| 11 | H1 | X11 |
| 12 | H1 | X12 |
| 13 | H1 | X13 |
| 14 | H1 | X14 |
| 15 | H1 | X15 |
| 16 | H1 | X16 |
| 17 | H1 | X17 |
| 18 | H1 | X18 |
| 19 | H1 | X19 |
| 20 | H1 | X20 |
| 21 | H1 | X21 |
| 22 | H1 | X22 |
| 23 | H1 | X23 |
| 24 | H1 | X24 |
| 25 | H1 | X25 |
| 26 | H1 | X26 |
| 27 | H1 | X27 |
| 28 | H1 | X28 |
| 29 | H1 | X29 |
| 30 | H1 | X30 |
| 31 | H1 | X31 |
| 32 | H1 | X32 |
| 33 | H1 | X33 |
| 34 | H1 | X34 |
| 35 | H1 | X35 |
| 36 | H1 | X36 |
| 37 | H1 | X37 |
| 38 | H1 | X38 |
| 39 | H1 | X39 |
| 40 | H1 | X40 |
| 41 | H1 | X41 |
| 42 | H1 | X42 |
| 43 | H1 | X43 |
| 44 | H1 | X44 |
| 45 | H1 | X45 |
| 46 | H1 | X46 |
| 47 | H1 | X47 |
| 48 | H1 | X48 |
| 49 | H1 | X49 |
| 50 | H1 | X50 |
| 51 | H1 | X51 |
| 52 | H1 | X52 |
| 53 | H1 | X53 |
| 54 | H1 | X54 |
| 55 | H1 | X55 |
| 56 | H1 | X56 |
| 57 | H1 | X57 |
| 58 | H1 | X58 |
| 59 | H1 | X59 |
| 60 | H1 | X60 |
| 61 | H1 | X61 |
| 62 | H1 | X62 |
| 63 | H1 | X63 |
| 64 | H1 | X64 |
| 65 | H1 | X65 |
| 66 | H1 | X66 |
| 67 | H1 | X67 |
| 68 | H1 | X68 |
| 69 | H1 | X69 |
| 70 | H1 | X70 |
| 71 | H1 | X71 |
| 72 | H1 | X72 |
| 73 | H1 | X73 |
| 74 | H1 | X74 |
| 75 | H1 | X75 |
| 76 | H1 | X76 |
| 77 | H1 | X77 |
| 78 | H1 | X78 |
| 79 | H1 | X79 |
| 80 | H1 | X80 |
| 81 | H1 | X81 |
| 82 | H1 | X82 |
| 83 | H1 | X83 |
| 84 | H1 | X84 |
| 85 | H1 | X85 |
| 86 | H1 | X86 |
| 87 | H1 | X87 |
| 88 | H1 | X88 |
| 89 | H1 | X89 |
| 90 | H1 | X90 |
| 91 | H1 | X91 |
| 92 | H1 | X92 |
| 93 | H1 | X93 |
| 94 | H1 | X94 |
| 95 | H1 | X95 |
| 96 | H1 | X96 |
| 97 | H1 | X97 |
| 98 | H1 | X98 |
| 99 | H1 | X99 |
| 100 | H1 | X100 |
| 101 | H1 | X101 |
| 102 | H1 | X102 |
| 103 | H1 | X103 |
| 104 | H1 | X104 |
| 105 | H1 | X105 |
| 106 | H1 | X106 |
| 107 | H1 | X107 |
| 108 | H1 | X108 |
| 109 | H1 | X109 |
| 110 | H1 | X110 |
| 111 | H1 | X111 |
| 112 | H1 | X112 |
| 113 | H1 | X113 |
| 114 | H1 | X114 |
| 115 | H1 | X115 |
| 116 | H1 | X116 |
| 117 | H1 | X117 |
| 118 | H1 | X118 |
| 119 | H1 | X119 |
| 120 | H1 | X120 |
| 121 | H1 | X121 |
| 122 | H1 | X122 |
| 123 | H1 | X123 |
| 124 | H1 | X124 |
| 125 | H1 | X125 |
| 126 | H1 | X126 |
| 127 | H1 | X127 |
| 128 | H1 | X128 |
| 129 | H1 | X129 |
| 130 | H1 | X130 |
| 131 | H1 | X131 |
| 132 | H1 | X132 |
| 133 | H1 | X133 |
| 134 | H1 | X134 |
| 135 | H1 | X135 |
| 136 | H1 | X136 |
| 137 | H1 | X137 |
| 138 | H1 | X138 |
| 139 | H1 | X139 |
| 140 | H1 | X140 |
| 141 | H1 | X141 |
| 142 | H1 | X142 |
| 143 | H1 | X143 |
| 144 | H1 | X144 |
| 145 | H1 | X145 |
| 146 | H1 | X146 |
| 147 | H1 | X147 |
| 148 | H1 | X148 |
| 149 | H1 | X149 |
| 150 | H1 | X150 |
| 151 | H1 | X151 |
| 152 | H1 | X152 |
| 153 | H1 | X153 |
| 154 | H1 | X154 |
| 155 | H1 | X155 |
| 156 | H1 | X156 |
| 157 | H1 | X157 |
| 158 | H1 | X158 |
| 159 | H1 | X159 |
| 160 | H1 | X160 |
| 161 | H1 | X161 |
| 162 | H1 | X162 |
| 163 | H1 | X163 |
| 164 | H1 | X164 |
| 165 | H1 | X165 |
| 166 | H1 | X166 |
| 167 | H1 | X167 |
| 168 | H1 | X168 |
| 169 | H1 | X169 |
| 170 | H1 | X170 |
| 171 | H1 | X171 |
| 172 | H1 | X172 |
| 173 | H1 | X173 |
| 174 | H1 | X174 |
| 175 | H1 | X175 |
| 176 | H1 | X176 |
| 177 | H1 | X177 |
| 178 | H1 | X178 |
| 179 | H1 | X179 |
| 180 | H1 | X180 |
| 181 | H1 | X181 |
| 182 | H1 | X182 |
| 183 | H1 | X183 |
| 184 | H1 | X184 |
| 185 | H1 | X185 |
| 186 | H1 | X186 |
| 187 | H1 | X187 |
| 188 | H1 | X188 |
| 189 | H1 | X189 |
| 190 | H1 | X190 |
| 191 | H1 | X191 |
| 192 | H1 | X192 |
| 193 | H1 | X193 |
| 194 | H1 | X194 |
| 195 | H1 | X195 |
| 196 | H1 | X196 |
| 197 | H1 | X197 |
| 198 | H1 | X198 |
| 199 | H1 | X199 |
| 200 | H1 | X200 |
| 201 | H1 | X201 |
| 202 | H1 | X202 |
| 203 | H1 | X203 |
| 204 | H1 | X204 |
| 205 | H1 | X205 |
| 206 | H1 | X206 |
| 207 | H1 | X207 |
| 208 | H1 | X208 |
| 209 | H1 | X209 |
| 210 | H1 | X210 |
| 211 | H1 | X211 |
| 212 | H1 | X212 |
| 213 | H1 | X213 |
| 214 | H1 | X214 |
| 215 | H1 | X215 |
| 216 | H1 | X216 |
| 217 | H1 | X217 |
| 218 | H1 | X218 |
| 219 | H1 | X219 |
| 220 | H1 | X220 |
| 221 | H1 | X221 |
| 222 | H1 | X222 |
| 223 | H1 | X223 |
| 224 | H1 | X224 |
| 225 | H1 | X225 |
| 226 | H1 | X226 |
| 227 | H1 | X227 |
| 228 | H1 | X228 |
| 229 | H1 | X229 |
| 230 | H1 | X230 |
| 231 | H1 | X231 |
| 232 | H1 | X232 |
| 233 | H1 | X233 |
| 234 | H1 | X234 |
| 235 | H1 | X235 |
| 236 | H1 | X236 |
| 237 | H1 | X237 |
| 238 | H1 | X238 |
| 239 | H1 | X239 |
| 240 | H1 | X240 |
| 241 | H1 | X241 |
| 242 | H1 | X242 |
| 243 | H1 | X243 |
| 244 | H1 | X244 |
| 245 | H1 | X245 |
| 246 | H1 | X246 |
| 247 | H1 | X247 |
| 248 | H1 | X248 |
| 249 | H1 | X249 |
| 250 | H1 | X250 |
| 251 | H1 | X251 |
| 252 | H1 | X252 |
| 253 | H1 | X253 |
| 254 | H1 | X254 |
| 255 | H1 | X255 |
| 256 | H1 | X256 |
| 257 | H1 | X257 |
| 258 | H1 | X258 |
| 259 | H1 | X259 |
| 260 | H1 | X260 |
| 261 | H1 | X261 |
| 262 | H1 | X262 |
| 263 | H1 | X263 |
| 264 | H1 | X264 |
| 265 | H1 | X265 |
| 266 | H1 | X266 |
| 267 | H1 | X267 |
| 268 | H1 | X268 |
| 269 | H1 | X269 |
| 270 | H1 | X270 |
| 271 | H1 | X271 |
| 272 | H1 | X272 |
| 273 | H1 | X273 |
| 274 | H1 | X274 |
| 275 | H1 | X275 |
| 276 | H1 | X276 |
| 277 | H1 | X277 |
| 278 | H1 | X278 |
| 279 | H1 | X279 |
| 280 | H1 | X280 |
| 281 | H1 | X281 |
| 282 | H1 | X282 |
| 283 | H1 | X283 |
| 284 | H1 | X284 |
| 285 | H1 | X285 |

The complexes of the invention can especially be prepared by the route described hereinafter. For this purpose, the 12-dentate ligand is prepared, which, rather than the X and optionally Y and/or Z groups, contains reactive leaving groups in each case, and then coordinates to the iridium metals via an ortho-metallation reaction. It is alternatively also possible first to synthesize the metal complex that still does not contain any reactive leaving groups, and then to introduce the reactive leaving groups in the complex. Suitable reactive leaving groups are, for example, halogen, especially chlorine, bromine or iodine, triflate, tosylate or a boronic acid derivative, for example boronic acid or a boronic ester. The X and optionally Y and/or Z groups may then be reacted by a coupling reaction with a compound A-(Ar)ₙ—R where A is a reactive leaving group, for example halogen, especially chlorine, bromine or iodine, triflate, tosylate or a boronic acid derivative, for example boronic acid or a boronic ester. In general, all C—C coupling reactions are suitable here, especially Suzuki coupling. Such reactions are known to the person skilled in the art, who will have no difficulty at all in applying these to the compounds of the invention.

Therefore, the present invention further provides a process for preparing the compound of the invention by reacting a compound substituted by reactive leaving groups in place of X and optionally Y and/or Z with a compound A-(Ar)ₙ—R, where A is a reactive leaving group. This reaction is preferably a Suzuki coupling.

For the processing of the compounds of the invention from a liquid phase, for example by spin-coating or by printing methods, formulations of the compounds of the invention are required. These formulations may, for example, be solutions, dispersions or emulsions. For this purpose, it may be preferable to use mixtures of two or more solvents. The solvents are preferably selected from hydrocarbons, alcohols, esters, ethers, ketones and amines. Suitable preferred solvents are selected, for example, from toluene, anisole, o, m- or p-xylene, methyl benzoate, methylene, tetralin, veratrole, THF, methyl-THF, THP, chlorobenzene, dioxane, phenoxytoluene, especially 3-phenoxytoluene, (-)-fenchone, 1,2,3,5-tetramethylbenzene, 1,2,4,5-tetramethylbenzene, 1-methylnaphthalene, 1-ethylnaphthalene, decylbenzene, phenylnaphthalene, menthyl isovalerate, para-tolyl isobutyrate, cyclohexyl hexanoate, ethyl para-toluate, ethyl ortho-toluate, ethyl meta-toluate, decahydronaphthalene, ethyl 2-methoxybenzoate, dibutylaniline, dicyclohexyl ketone, isosorbide dimethyl ether, decahydronaphthalene, 2-methylbiphenyl, ethyl octanoate, octyl octanoate, diethyl sebacate, 3,3-dimethylbiphenyl, 1,4-dimethylnaphthalene, 2,2′-dimethylbiphenyl, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents.

The present invention therefore further provides a formulation comprising at least one compound of the invention and at least one further compound. The further compound may, for example, be a solvent, especially one of the abovementioned solvents or a mixture of these solvents. The further compound may alternatively be a further organic or inorganic compound which is likewise used in the electronic device, for example a matrix material. This further compound may also be polymeric.

The above-described compound of the invention, or the preferred embodiments detailed above, may be used as active component in an electronic device. The present invention thus further provides for the use of a compound of the invention in an electronic device. The present invention still further provides an electronic device comprising at least one compound of the invention.

An electronic device is understood to mean any device comprising anode, cathode and at least one layer, said layer comprising at least one organic or organometallic compound. The electronic device of the invention thus comprises anode, cathode and at least one layer containing at least one compound of the invention. Preferred electronic devices are selected from the group consisting of organic electroluminescent devices (OLEDs, PLEDs), organic infrared electroluminescence sensors, organic integrated circuits (O-ICs), organic field-effect transistors (O-FETs), organic thin-film transistors (O-TFTs), organic light-emitting transistors (O-LETs), organic solar cells (O-SCs), the latter being understood to mean both purely organic solar cells and dye-sensitized solar cells (Gratzel cells), organic optical detectors, organic photoreceptors, organic field-quench devices (O-FQDs), light-emitting electrochemical cells (LECs), oxygen sensors and organic laser diodes (0-lasers), comprising at least one compound of the invention in at least one layer. Particular preference is given to organic electroluminescent devices. Active components are generally the organic or inorganic materials introduced between the anode and cathode, for example charge injection, charge transport or charge blocker materials, but especially emission materials and matrix materials. The compounds of the invention exhibit particularly good properties as emission material in organic electroluminescent devices. A preferred embodiment of the invention is therefore organic electroluminescent devices.

The organic electroluminescent device comprises cathode, anode and at least one emitting layer. Apart from these layers, it may comprise still further layers, for example in each case one or more hole injection layers, hole transport layers, hole blocker layers, electron transport layers, electron injection layers, exciton blocker layers, electron blocker layers, charge generation layers and/or organic or inorganic p/n junctions. At the same time, it is possible that one or more hole transport layers are p-doped, for example with metal oxides such as MoO₃ or WO₃ or with (per)fluorinated electron-deficient aromatic systems, and/or that one or more electron transport layers are n-doped. It is likewise possible for interlayers to be introduced between two emitting layers, these having, for example, an exciton-blocking function and/or controlling the charge balance in the electroluminescent device. However, it should be pointed out that not necessarily every one of these layers need be present.

In this case, it is possible for the organic electroluminescent device to contain an emitting layer, or for it to contain a plurality of emitting layers. If a plurality of emission layers are present, these preferably have several emission maxima between 380 nm and 750 nm overall, such that the overall result is white emission; in other words, various emitting compounds which may fluoresce or phosphoresce are used in the emitting layers. Especially preferred are three-layer systems where the three layers exhibit blue, green and orange or red emission (for the basic construction see, for example, WO 2005/011013), or systems having more than three emitting layers. The system may also be a hybrid system wherein one or more layers fluoresce and one or more other layers phosphoresce. White-emitting organic electroluminescent devices may be used for lighting applications or else with colour filters for full-colour displays. White-emitting OLEDs can also be implemented by means of tandem OLEDs. In addition, white-emitting OLEDs can also be implemented in that two or more emitters that emit light in a different colour, one of which is a compound of the invention, are present in an emitting layer, such that the emitted light from the individual emitters adds up to white light.

In a preferred embodiment of the invention, the organic electroluminescent device comprises the compound of the invention as emitting compound in one or more emitting layers.

Many of the compounds of the invention emit light in the red spectral region. But it is also possible, by suitable choice of the ligands and substitution patterns, either to move the emission into the infrared region or to subject it to a hypsochromic shift, preferably into the orange or yellow region.

When the compound of the invention is used as an emitting compound in an emitting layer, it is preferably used in combination with one or more matrix materials; the terms “matrix material” and “host material” are used synonymously hereinafter. The mixture of the compound of the invention and the matrix material contains between 0.1% and 99% by weight, preferably between 3% and 90% by weight, more preferably between 5% and 40% by weight and especially between 10% and 25% by weight of the compound of the invention, based on the overall mixture of emitter and matrix material. Correspondingly, the mixture contains between 99.9% and 1% by weight, preferably between 97% and 10% by weight, more preferably between 95% and 60% by weight and especially between 90% and 75% by weight of the matrix material, based on the overall mixture of emitter and matrix material.

The matrix material used may generally be any materials which are known for the purpose according to the prior art. The triplet level of the matrix material is preferably higher than the triplet level of the emitter.

Suitable matrix materials for the compounds of the invention are ketones, phosphine oxides, sulfoxides and sulfones, for example according to WO 2004/013080, WO 2004/093207, WO 2006/005627 or WO 2010/006680, triarylamines, carbazole derivatives, e.g. CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example according to WO 2007/063754 or WO 2008/056746, indenocarbazole derivatives, for example according to WO 2010/136109 or WO 2011/000455, azacarbazoles, for example according to EP 1617710, EP 1617711, EP 1731584, JP 2005/347160, bipolar matrix materials, for example according to WO 2007/137725, silanes, for example according to WO 2005/111172, azaboroles or boronic esters, for example according to WO 2006/117052, diazasilole derivatives, for example according to WO 2010/054729, diazaphosphole derivatives, for example according to WO 2010/054730, triazine derivatives, for example according to WO 2010/015306, WO 2007/063754 or WO 2008/056746, zinc complexes, for example according to EP 652273 or WO 2009/062578, dibenzofuran derivatives, for example according to WO 2009/148015 or WO 2015/169412, carbazoleamines or bridged carbazole derivatives, for example according to US 2009/0136779, WO 2010/050778, WO 2011/042107 or WO 2011/088877.

It may also be preferable to use a plurality of different matrix materials as a mixture, especially at least one electron-conducting matrix material and at least one hole-conducting matrix material. A preferred combination is, for example, the use of a triazine, pyrimidine, quinazoline or quinoxaline derivative with a triarylamine derivative or a carbazole derivative as mixed matrix for the metal complex of the invention. Preference is likewise given to the use of a mixture of a charge-transporting matrix material and an electrically inert matrix material (called a “wide bandgap host”) having no significant involvement, if any, in the charge transport, as described, for example, in WO 2010/108579 or WO 2016/184540. Preference is likewise given to the use of two electron-transporting matrix materials, for example triazine derivatives and lactam derivatives, as described, for example, in WO 2014/094964.

Depicted below are examples of compounds that are suitable as matrix materials for the compounds of the invention.

Preferred electron-transporting matrix materials are selected from the group consisting of triazine derivatives, pyrimidine derivatives, quinazoline derivatives and quinoxaline derivatives. Preferred triazine, pyrimidine, quinazoline or quinoxaline derivatives that can be used as a mixture together with the compounds of the invention are the compounds of the following formulae (19), (20), (21) and (22):

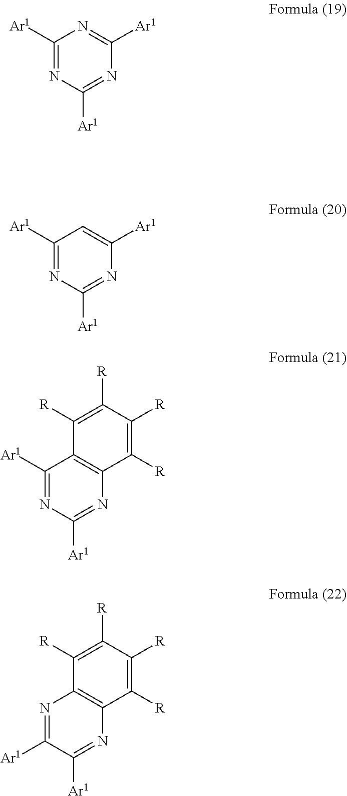

where R and R¹ have the definitions given above and Ar¹ is the same or different at each instance and is an aromatic or heteroaromatic ring system which has 5 to 40 aromatic ring atoms and may be substituted in each case by one or more R¹ radicals.

Particular preference is given to the triazine derivatives of the formula (19) and the quinazoline derivatives of the formula (21), especially the triazine derivatives of the formula (19).

In a preferred embodiment of the invention, Ar¹ in the formulae (19) to (22) is the same or different at each instance and is an aromatic or heteroaromatic ring system which has 6 to 30 aromatic ring atoms, especially 6 to 24 aromatic ring atoms, and may be substituted by one or more R¹ radicals.

Examples of suitable triazine compounds that may be used as matrix materials together with the compounds of the invention are the compounds depicted in the following table:

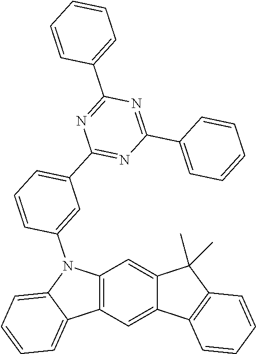 [SMILES: CC1(C)c2ccccc2-c2cc3c4ccccc4n(-c4cccc(-c5nc(-c6ccccc6)nc(-c6ccccc6)n5)c4)c3cc21]

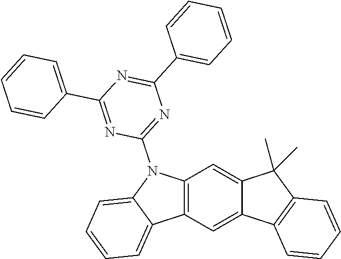 [SMILES: CC1(C)c2ccccc2-c2cc3c4ccccc4n(-c4nc(-c5ccccc5)nc(-c5ccccc5)n4)c3cc21]

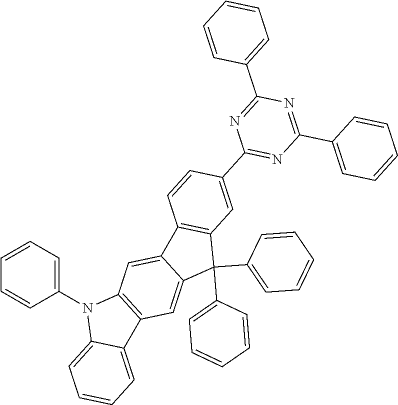 [SMILES: c1ccc(-c2nc(-c3ccccc3)nc(-c3ccc4c(c3)C(c3ccccc3)(c3ccccc3)c3cc5c6ccccc6n(-c6ccccc6)c5cc3-4)n2)cc1]

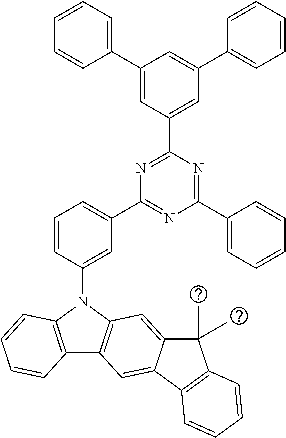 [SMILES: CC1(C)c2ccccc2-c2cc3c4ccccc4n(-c4cccc(-c5nc(-c6ccccc6)nc(-c6cc(-c7ccccc7)cc(-c7ccccc7)c6)n5)c4)c3cc21]

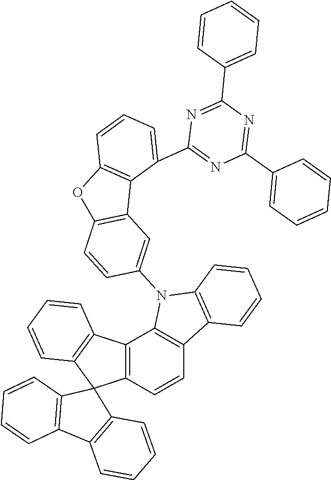 [SMILES: c1ccc(-c2nc(-c3ccccc3)nc(-c3cccc4oc5ccc(-n6c7ccccc7c7ccc8c(c76)-c6ccccc6C86c7ccccc7-c7ccccc76)cc5c34)n2)cc1]

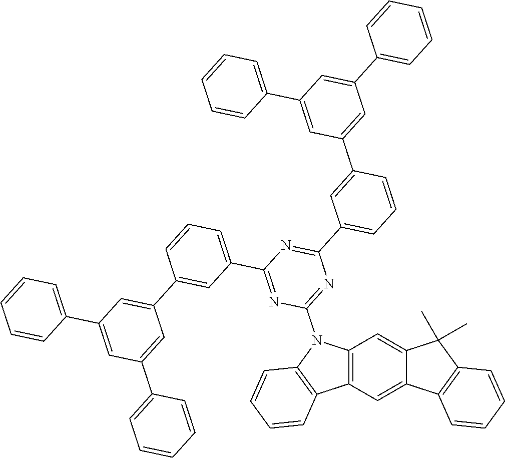 [SMILES: CC1(C)c2ccccc2-c2cc3c4ccccc4n(-c4nc(-c5cccc(-c6cc(-c7ccccc7)cc(-c7ccccc7)c6)c5)nc(-c5cccc(-c6cc(-c7ccccc7)cc(-c7ccccc7)c6)c5)n4)c3cc21]

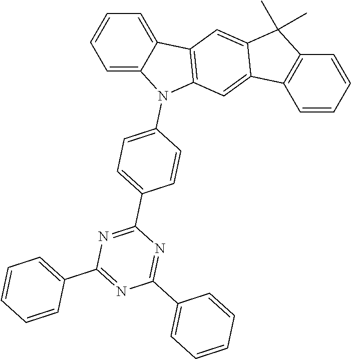 [SMILES: CC1(C)c2ccccc2-c2cc3c(cc21)c1ccccc1n3-c1ccc(-c2nc(-c3ccccc3)nc(-c3ccccc3)n2)cc1]

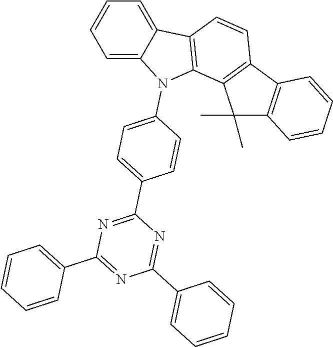 [SMILES: CC1(C)c2ccccc2-c2ccc3c4ccccc4n(-c4ccc(-c5nc(-c6ccccc6)nc(-c6ccccc6)n5)cc4)c3c21]

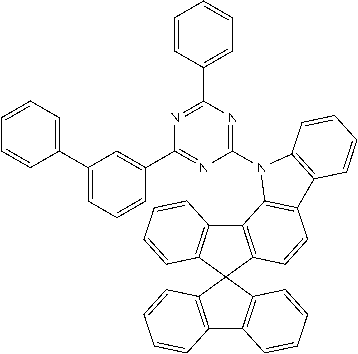 [SMILES: c1ccc(-c2cccc(-c3nc(-c4ccccc4)nc(-n4c5ccccc5c5ccc6c(c54)-c4ccccc4C64c5ccccc5-c5ccccc54)n3)c2)cc1]

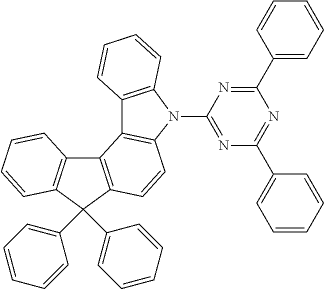 [SMILES: c1ccc(-c2nc(-c3ccccc3)nc(-n3c4ccccc4c4c5c(ccc43)C(c3ccccc3)(c3ccccc3)c3ccccc3-5)n2)cc1]

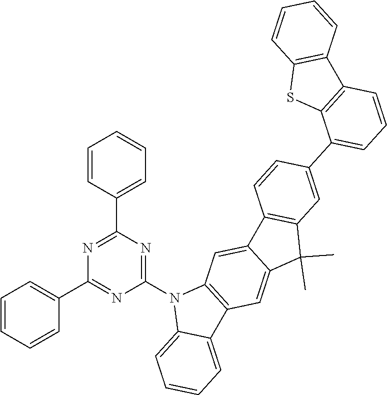 [SMILES: CC1(C)c2cc(-c3cccc4c3sc3ccccc34)ccc2-c2cc3c(cc21)c1ccccc1n3-c1nc(-c2ccccc2)nc(-c2ccccc2)n1]

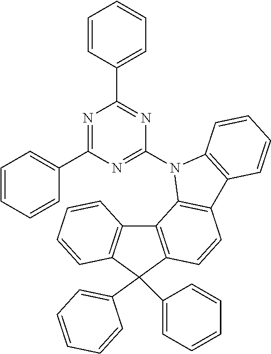 [SMILES: c1ccc(-c2nc(-c3ccccc3)nc(-n3c4ccccc4c4ccc5c(c43)-c3ccccc3C5(c3ccccc3)c3ccccc3)n2)cc1]

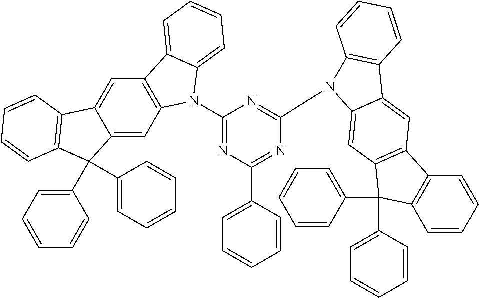 [SMILES: c1ccc(-c2nc(-n3c4ccccc4c4cc5c(cc43)C(c3ccccc3)(c3ccccc3)c3ccccc3-5)nc(-n3c4ccccc4c4cc5c(cc43)C(c3ccccc3)(c3ccccc3)c3ccccc3-5)n2)cc1]

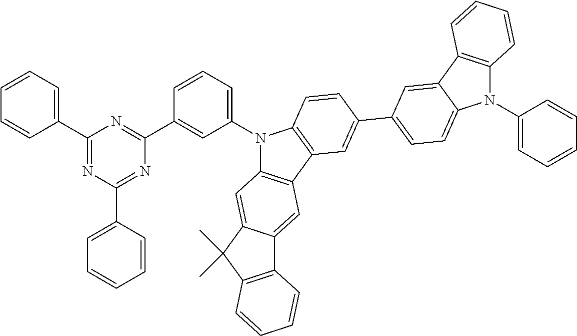 [SMILES: CC1(C)c2ccccc2-c2cc3c4cc(-c5ccc6c(c5)c5ccccc5n6-c5ccccc5)ccc4n(-c4cccc(-c5nc(-c6ccccc6)nc(-c6ccccc6)n5)c4)c3cc21]

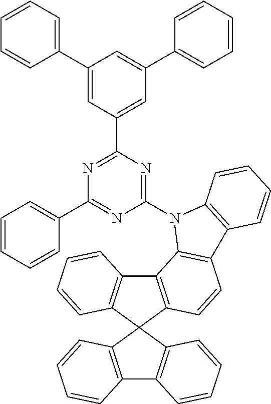 [SMILES: c1ccc(-c2cc(-c3ccccc3)cc(-c3nc(-c4ccccc4)nc(-n4c5ccccc5c5ccc6c(c54)-c4ccccc4C64c5ccccc5-c5ccccc54)n3)c2)cc1]

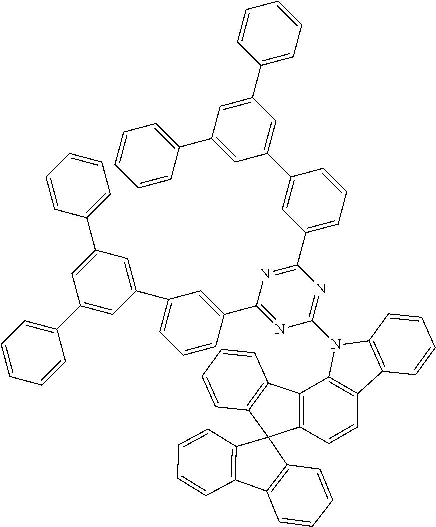 [SMILES: c1ccc(-c2cc(-c3ccccc3)cc(-c3cccc(-c4nc(-c5cccc(-c6cc(-c7ccccc7)cc(-c7ccccc7)c6)c5)nc(-n5c6ccccc6c6ccc7c(c65)-c5ccccc5C75c6ccccc6-c6ccccc65)n4)c3)c2)cc1]

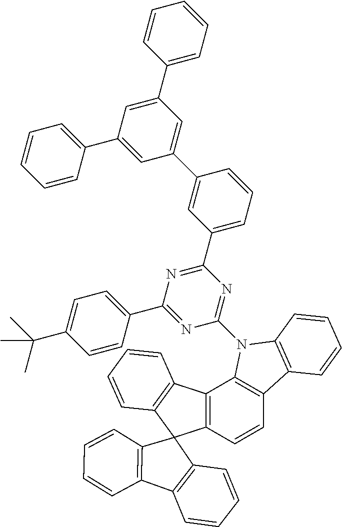 [SMILES: CC(C)(C)c1ccc(-c2nc(-c3cccc(-c4cc(-c5ccccc5)cc(-c5ccccc5)c4)c3)nc(-n3c4ccccc4c4ccc5c(c43)-c3ccccc3C53c4ccccc4-c4ccccc43)n2)cc1]

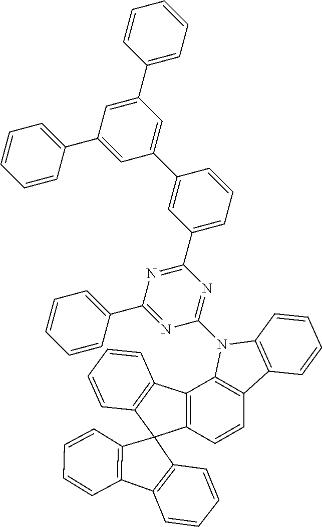 [SMILES: c1ccc(-c2cc(-c3ccccc3)cc(-c3cccc(-c4nc(-c5ccccc5)nc(-n5c6ccccc6c6ccc7c(c65)-c5ccccc5C75c6ccccc6-c6ccccc65)n4)c3)c2)cc1]

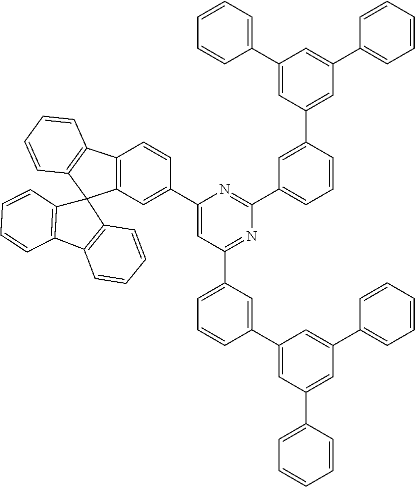 [SMILES: c1ccc(-c2cc(-c3ccccc3)cc(-c3cccc(-c4cc(-c5ccc6c(c5)C5(c7ccccc7-c7ccccc75)c5ccccc5-6)nc(-c5cccc(-c6cc(-c7ccccc7)cc(-c7ccccc7)c6)c5)n4)c3)c2)cc1]

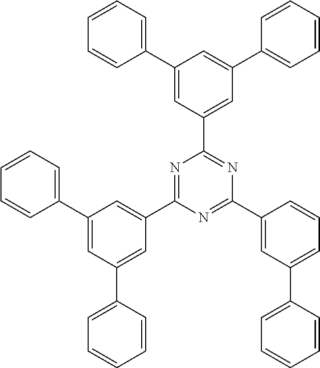 [SMILES: c1ccc(-c2cccc(-c3nc(-c4cc(-c5ccccc5)cc(-c5ccccc5)c4)nc(-c4cc(-c5ccccc5)cc(-c5ccccc5)c4)n3)c2)cc1]

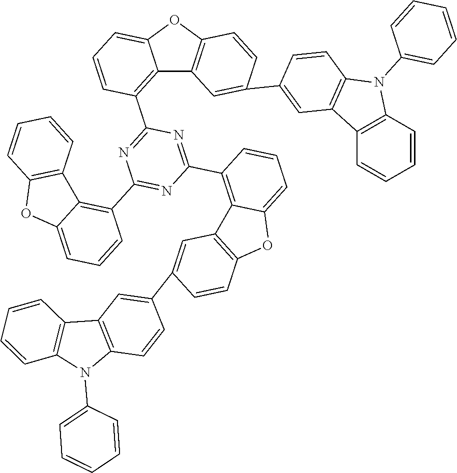 [SMILES: c1ccc(-n2c3ccccc3c3cc(-c4ccc5oc6cccc(-c7nc(-c8cccc9oc%10ccccc%10c89)nc(-c8cccc9oc%10ccc(-c%11ccc%12c(c%11)c%11ccccc%11n%12-c%11ccccc%11)cc%10c89)n7)c6c5c4)ccc32)cc1]

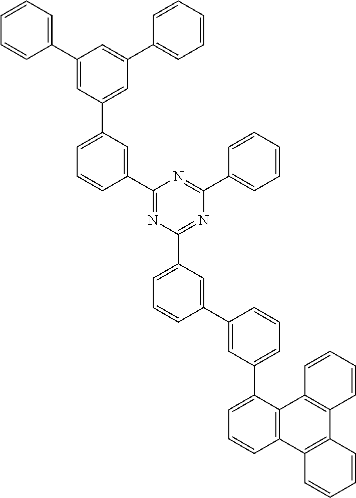 [SMILES: c1ccc(-c2cc(-c3ccccc3)cc(-c3cccc(-c4nc(-c5ccccc5)nc(-c5cccc(-c6cccc(-c7cccc8c9ccccc9c9ccccc9c78)c6)c5)n4)c3)c2)cc1]

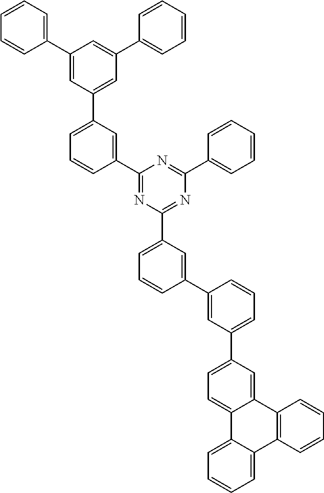 [SMILES: c1ccc(-c2cc(-c3ccccc3)cc(-c3cccc(-c4nc(-c5ccccc5)nc(-c5cccc(-c6cccc(-c7ccc8c9ccccc9c9ccccc9c8c7)c6)c5)n4)c3)c2)cc1]

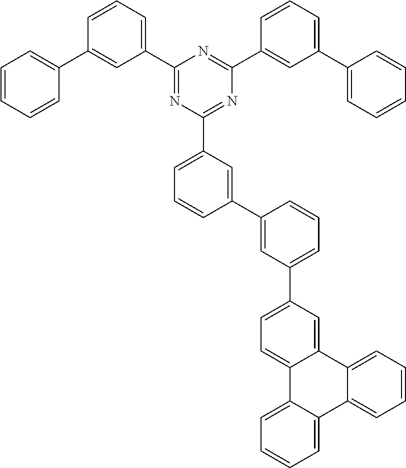 [SMILES: c1ccc(-c2cccc(-c3nc(-c4cccc(-c5ccccc5)c4)nc(-c4cccc(-c5cccc(-c6ccc7c8ccccc8c8ccccc8c7c6)c5)c4)n3)c2)cc1]

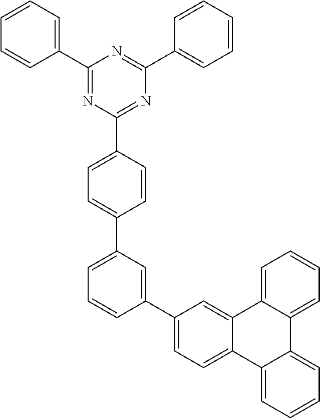 [SMILES: c1ccc(-c2nc(-c3ccccc3)nc(-c3ccc(-c4cccc(-c5ccc6c7ccccc7c7ccccc7c6c5)c4)cc3)n2)cc1]

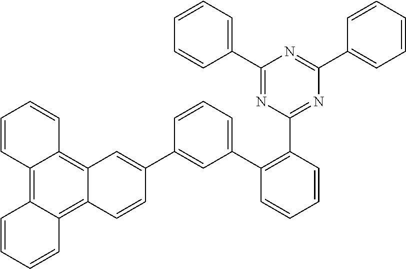 [SMILES: c1ccc(-c2nc(-c3ccccc3)nc(-c3ccccc3-c3cccc(-c4ccc5c6ccccc6c6ccccc6c5c4)c3)n2)cc1]

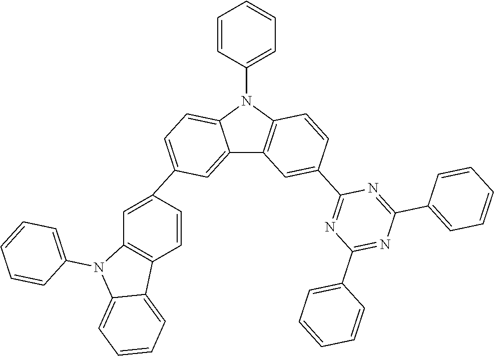 [SMILES: c1ccc(-c2nc(-c3ccccc3)nc(-c3ccc4c(c3)c3cc(-c5ccc6c7ccccc7n(-c7ccccc7)c6c5)ccc3n4-c3ccccc3)n2)cc1]

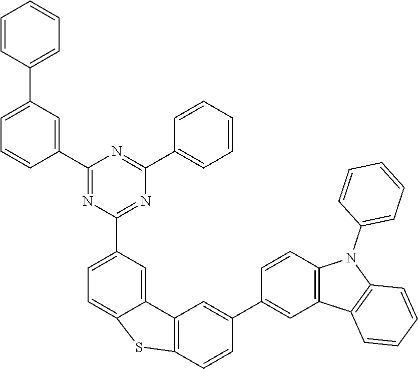 [SMILES: c1ccc(-c2cccc(-c3nc(-c4ccccc4)nc(-c4ccc5sc6ccc(-c7ccc8c(c7)c7ccccc7n8-c7ccccc7)cc6c5c4)n3)c2)cc1]

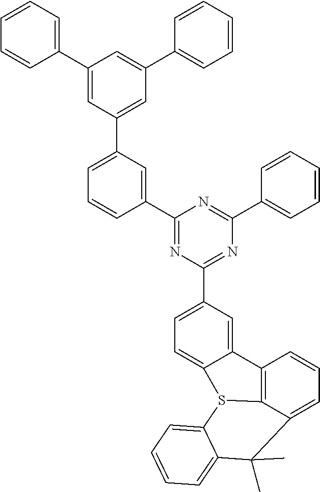

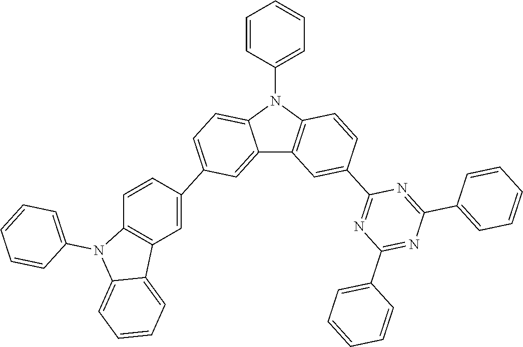 [SMILES: c1ccc(-c2nc(-c3ccccc3)nc(-c3ccc4c(c3)c3cc(-c5ccc6c(c5)c5ccccc5n6-c5ccccc5)ccc3n4-c3ccccc3)n2)cc1]

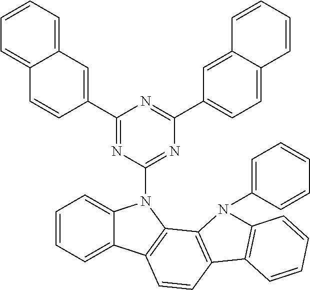 [SMILES: c1ccc(-n2c3ccccc3c3ccc4c5ccccc5n(-c5nc(-c6ccc7ccccc7c6)nc(-c6ccc7ccccc7c6)n5)c4c32)cc1]

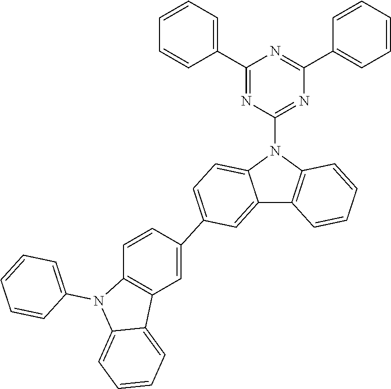 [SMILES: c1ccc(-c2nc(-c3ccccc3)nc(-n3c4ccccc4c4cc(-c5ccc6c(c5)c5ccccc5n6-c5ccccc5)ccc43)n2)cc1]

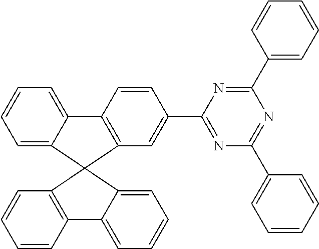 [SMILES: c1ccc(-c2nc(-c3ccccc3)nc(-c3ccc4c(c3)C3(c5ccccc5-c5ccccc53)c3ccccc3-4)n2)cc1]

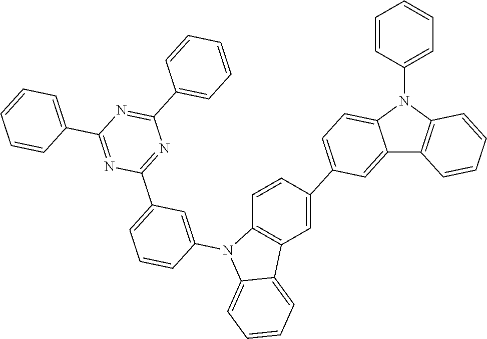 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

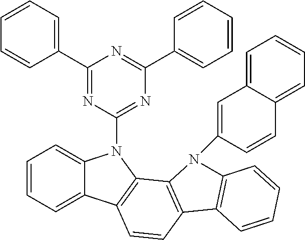 [SMILES: c1ccc(-c2nc(-c3ccccc3)nc(-n3c4ccccc4c4ccc5c6ccccc6n(-c6ccc7ccccc7c6)c5c43)n2)cc1]

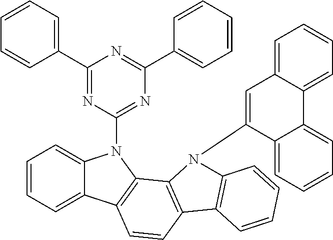 [SMILES: c1ccc(-c2nc(-c3ccccc3)nc(-n3c4ccccc4c4ccc5c6ccccc6n(-c6cc7ccccc7c7ccccc67)c5c43)n2)cc1]

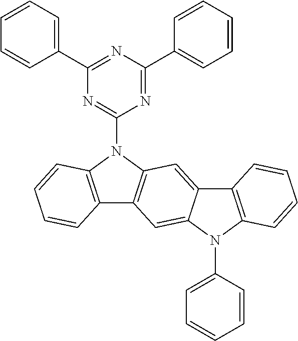 [SMILES: c1ccc(-c2nc(-c3ccccc3)nc(-n3c4ccccc4c4cc5c(cc43)c3ccccc3n5-c3ccccc3)n2)cc1]

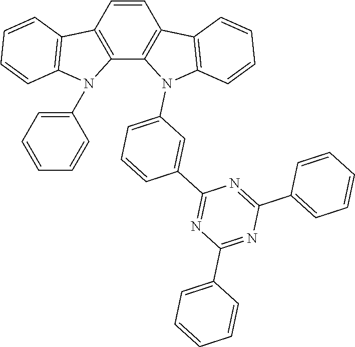 [SMILES: c1ccc(-c2nc(-c3ccccc3)nc(-c3cccc(-n4c5ccccc5c5ccc6c7ccccc7n(-c7ccccc7)c6c54)c3)n2)cc1]

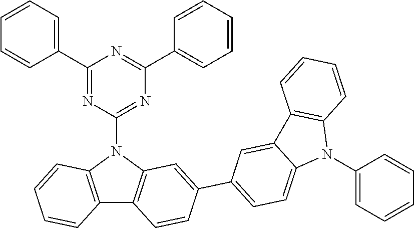 [SMILES: c1ccc(-c2nc(-c3ccccc3)nc(-n3c4ccccc4c4ccc(-c5ccc6c(c5)c5ccccc5n6-c5ccccc5)cc43)n2)cc1]

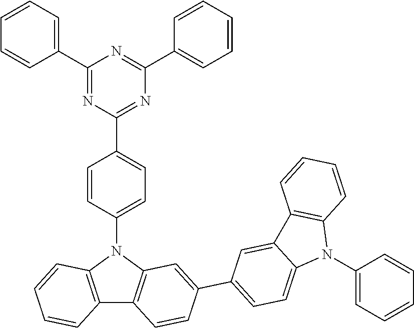 [SMILES: c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1]

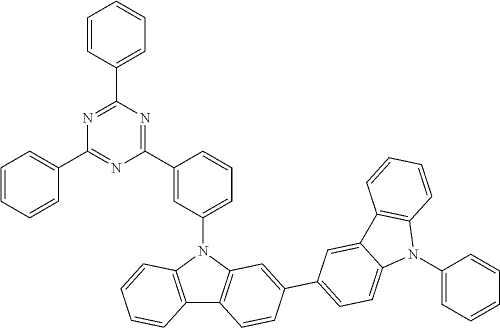 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

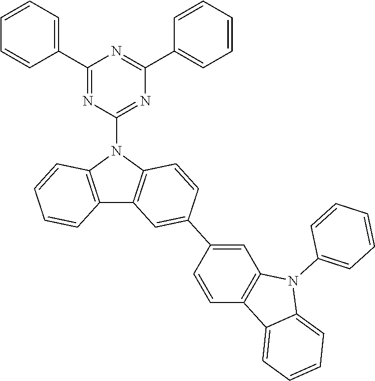 [SMILES: c1ccc(-c2nc(-c3ccccc3)nc(-n3c4ccccc4c4cc(-c5ccc6c7ccccc7n(-c7ccccc7)c6c5)ccc43)n2)cc1]

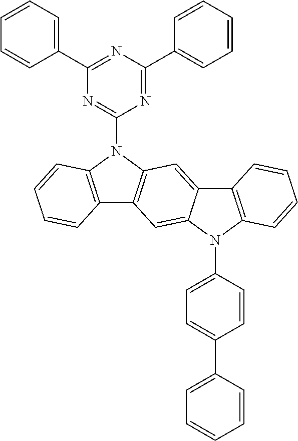 [SMILES: c1ccc(-c2ccc(-n3c4ccccc4c4cc5c(cc43)c3ccccc3n5-c3nc(-c4ccccc4)nc(-c4ccccc4)n3)cc2)cc1]

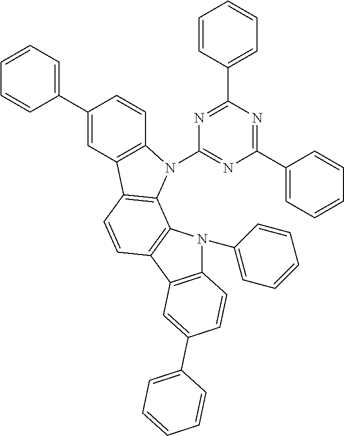 [SMILES: c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1]

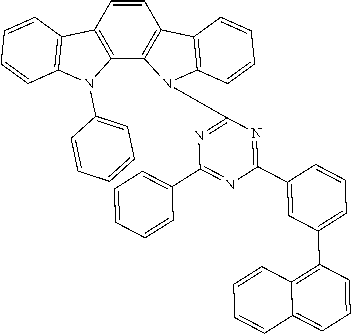 [SMILES: c1ccc(-c2nc(-c3cccc(-c4cccc5ccccc45)c3)nc(-n3c4ccccc4c4ccc5c6ccccc6n(-c6ccccc6)c5c43)n2)cc1]

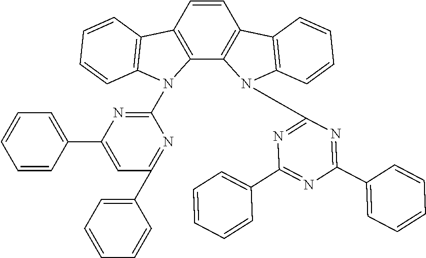 [SMILES: c1ccc(-c2cc(-c3ccccc3)nc(-n3c4ccccc4c4ccc5c6ccccc6n(-c6nc(-c7ccccc7)nc(-c7ccccc7)n6)c5c43)n2)cc1]

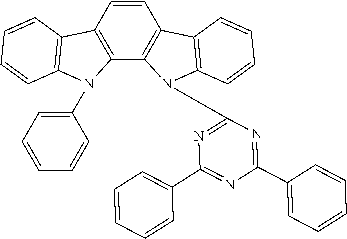 [SMILES: c1ccc(-c2nc(-c3ccccc3)nc(-n3c4ccccc4c4ccc5c6ccccc6n(-c6ccccc6)c5c43)n2)cc1]

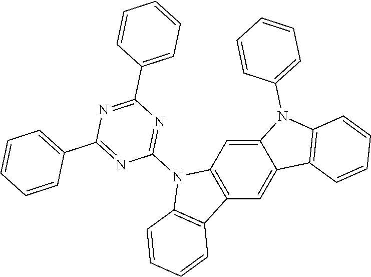 [SMILES: c1ccc(-c2nc(-c3ccccc3)nc(-n3c4ccccc4c4cc5c6ccccc6n(-c6ccccc6)c5cc43)n2)cc1]

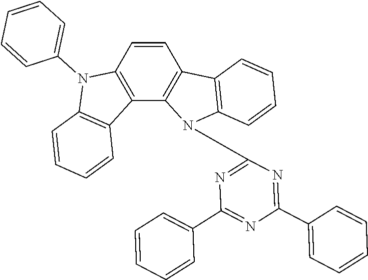 [SMILES: c1ccc(-c2nc(-c3ccccc3)nc(-n3c4ccccc4c4ccc5c(c6ccccc6n5-c5ccccc5)c43)n2)cc1]

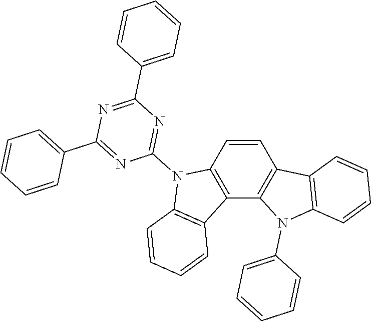 [SMILES: c1ccc(-c2nc(-c3ccccc3)nc(-n3c4ccccc4c4c3ccc3c5ccccc5n(-c5ccccc5)c34)n2)cc1]

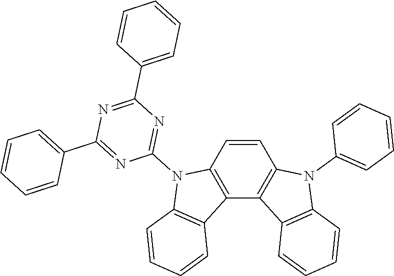 [SMILES: c1ccc(-c2nc(-c3ccccc3)nc(-n3c4ccccc4c4c5c6ccccc6n(-c6ccccc6)c5ccc43)n2)cc1]

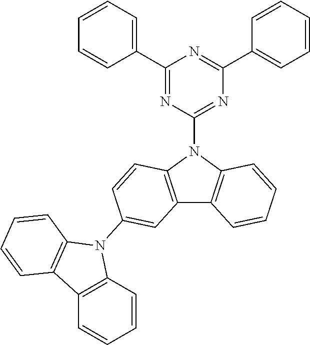 [SMILES: c1ccc(-c2nc(-c3ccccc3)nc(-n3c4ccccc4c4cc(-n5c6ccccc6c6ccccc65)ccc43)n2)cc1]

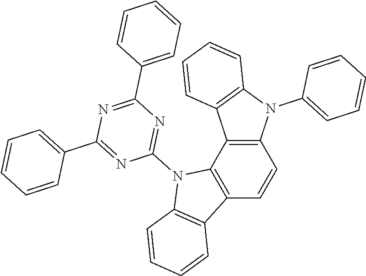 [SMILES: c1ccc(-c2nc(-c3ccccc3)nc(-n3c4ccccc4c4ccc5c(c6ccccc6n5-c5ccccc5)c43)n2)cc1]

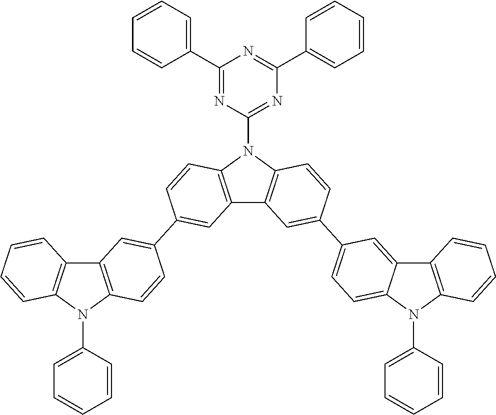 [SMILES: c1ccc(-c2nc(-c3ccccc3)nc(-n3c4ccc(-c5ccc6c(c5)c5ccccc5n6-c5ccccc5)cc4c4cc(-c5ccc6c(c5)c5ccccc5n6-c5ccccc5)ccc43)n2)cc1]

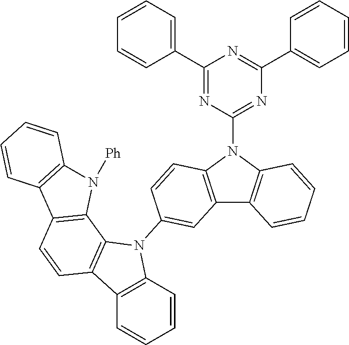 [SMILES: c1ccc(-c2nc(-c3ccccc3)nc(-n3c4ccccc4c4cc(-n5c6ccccc6c6ccc7c8ccccc8n(-c8ccccc8)c7c65)ccc43)n2)cc1]

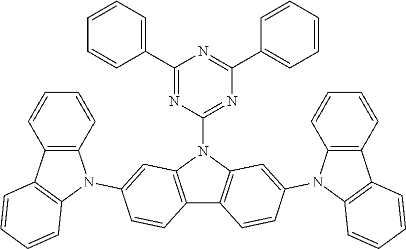 [SMILES: c1ccc(-c2nc(-c3ccccc3)nc(-n3c4cc(-n5c6ccccc6c6ccccc65)ccc4c4ccc(-n5c6ccccc6c6ccccc65)cc43)n2)cc1]

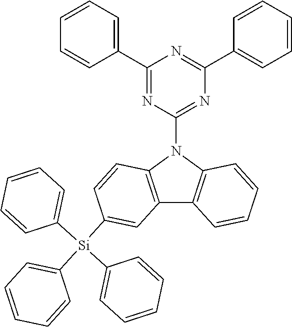 [SMILES: c1ccc(-c2nc(-c3ccccc3)nc(-n3c4ccccc4c4cc([Si](c5ccccc5)(c5ccccc5)c5ccccc5)ccc43)n2)cc1]

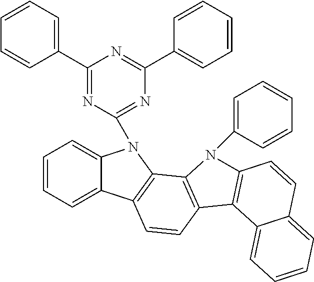 [SMILES: c1ccc(-c2nc(-c3ccccc3)nc(-n3c4ccccc4c4ccc5c6c7ccccc7ccc6n(-c6ccccc6)c5c43)n2)cc1]

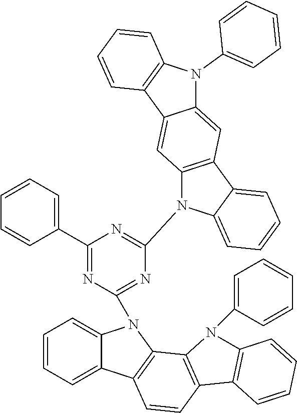 [SMILES: c1ccc(-c2nc(-n3c4ccccc4c4cc5c(cc43)c3ccccc3n5-c3ccccc3)nc(-n3c4ccccc4c4ccc5c6ccccc6n(-c6ccccc6)c5c43)n2)cc1]

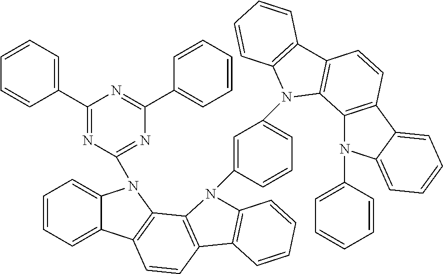 [SMILES: c1ccc(-c2nc(-c3ccccc3)nc(-n3c4ccccc4c4ccc5c6ccccc6n(-c6cccc(-n7c8ccccc8c8ccc9c%10ccccc%10n(-c%10ccccc%10)c9c87)c6)c5c43)n2)cc1]

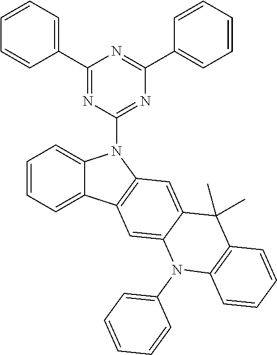 [SMILES: CC1(C)c2ccccc2N(c2ccccc2)c2cc3c4ccccc4n(-c4nc(-c5ccccc5)nc(-c5ccccc5)n4)c3cc21]

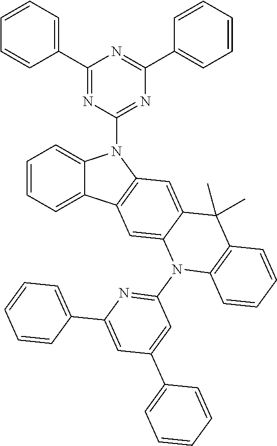 [SMILES: CC1(C)c2ccccc2N(c2cc(-c3ccccc3)cc(-c3ccccc3)n2)c2cc3c4ccccc4n(-c4nc(-c5ccccc5)nc(-c5ccccc5)n4)c3cc21]

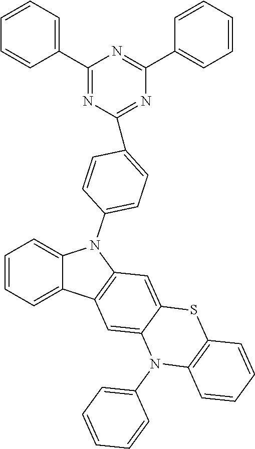 [SMILES: c1ccc(-c2nc(-c3ccccc3)nc(-c3ccc(-n4c5ccccc5c5cc6c(cc54)Sc4ccccc4N6c4ccccc4)cc3)n2)cc1]

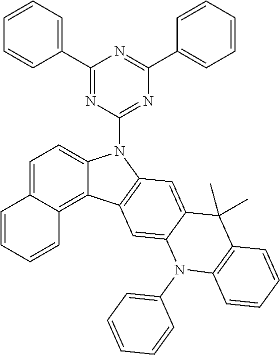 [SMILES: CC1(C)c2ccccc2N(c2ccccc2)c2cc3c4c5ccccc5ccc4n(-c4nc(-c5ccccc5)nc(-c5ccccc5)n4)c3cc21]

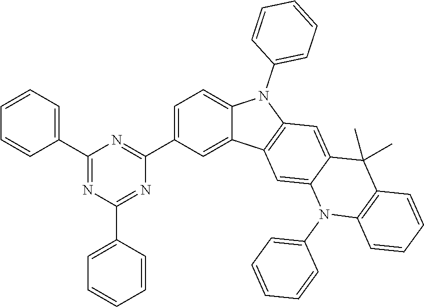 [SMILES: CC1(C)c2ccccc2N(c2ccccc2)c2cc3c4cc(-c5nc(-c6ccccc6)nc(-c6ccccc6)n5)ccc4n(-c4ccccc4)c3cc21]

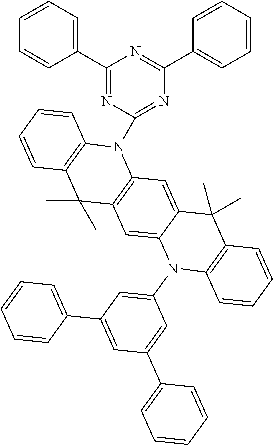 [SMILES: CC1(C)c2ccccc2N(c2cc(-c3ccccc3)cc(-c3ccccc3)c2)c2cc3c(cc21)N(c1nc(-c2ccccc2)nc(-c2ccccc2)n1)c1ccccc1C3(C)C]

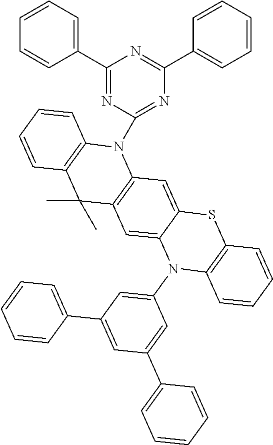 [SMILES: CC1(C)c2ccccc2N(c2nc(-c3ccccc3)nc(-c3ccccc3)n2)c2cc3c(cc21)N(c1cc(-c2ccccc2)cc(-c2ccccc2)c1)c1ccccc1S3]

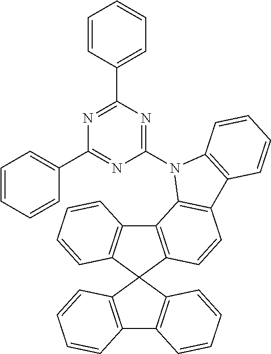 [SMILES: c1ccc(-c2nc(-c3ccccc3)nc(-n3c4ccccc4c4ccc5c(c43)-c3ccccc3C53c4ccccc4-c4ccccc43)n2)cc1]

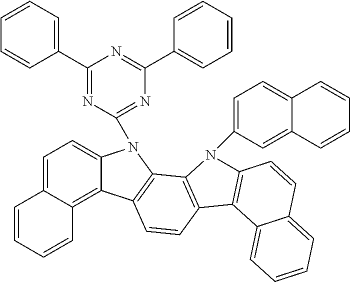 [SMILES: c1ccc(-c2nc(-c3ccccc3)nc(-n3c4ccc5ccccc5c4c4ccc5c6c7ccccc7ccc6n(-c6ccc7ccccc7c6)c5c43)n2)cc1]

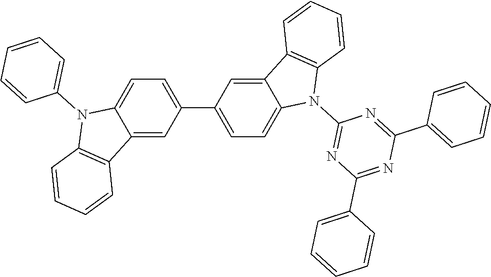 [SMILES: c1ccc(-c2nc(-c3ccccc3)nc(-n3c4ccccc4c4cc(-c5ccc6c(c5)c5ccccc5n6-c5ccccc5)ccc43)n2)cc1]

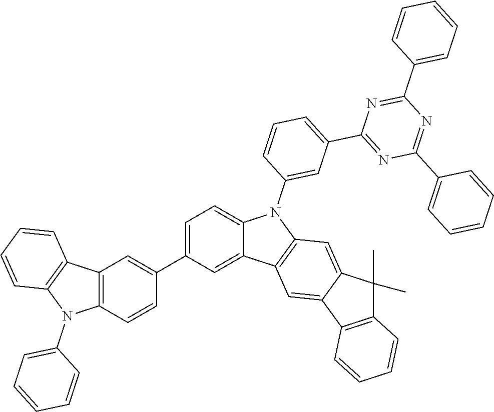 [SMILES: CC1(C)c2ccccc2-c2cc3c4cc(-c5ccc6c(c5)c5ccccc5n6-c5ccccc5)ccc4n(-c4cccc(-c5nc(-c6ccccc6)nc(-c6ccccc6)n5)c4)c3cc21]

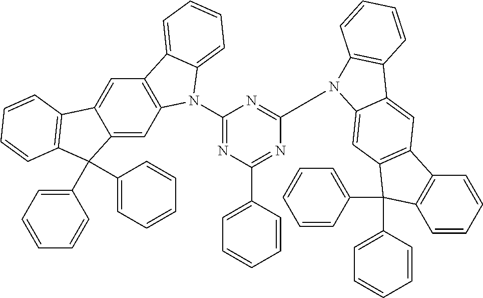 [SMILES: c1ccc(-c2nc(-n3c4ccccc4c4cc5c(cc43)C(c3ccccc3)(c3ccccc3)c3ccccc3-5)nc(-n3c4ccccc4c4cc5c(cc43)C(c3ccccc3)(c3ccccc3)c3ccccc3-5)n2)cc1]

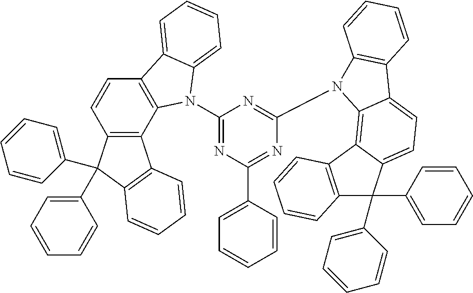 [SMILES: c1ccc(-c2nc(-n3c4ccccc4c4ccc5c(c43)-c3ccccc3C5(c3ccccc3)c3ccccc3)nc(-n3c4ccccc4c4ccc5c(c43)-c3ccccc3C5(c3ccccc3)c3ccccc3)n2)cc1]

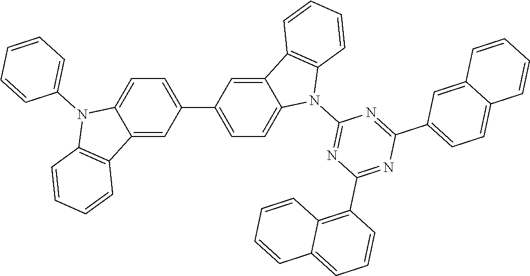 [SMILES: c1ccc(-n2c3ccccc3c3cc(-c4ccc5c(c4)c4ccccc4n5-c4nc(-c5ccc6ccccc6c5)nc(-c5cccc6ccccc56)n4)ccc32)cc1]

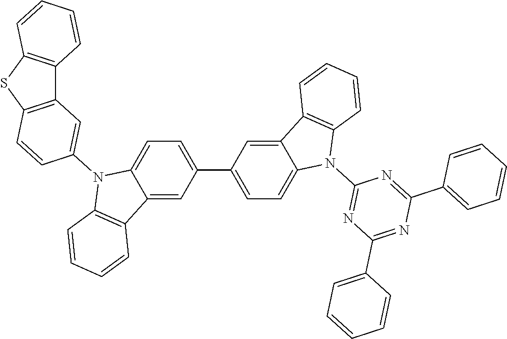 [SMILES: c1ccc(-c2nc(-c3ccccc3)nc(-n3c4ccccc4c4cc(-c5ccc6c(c5)c5ccccc5n6-c5ccc6sc7ccccc7c6c5)ccc43)n2)cc1]

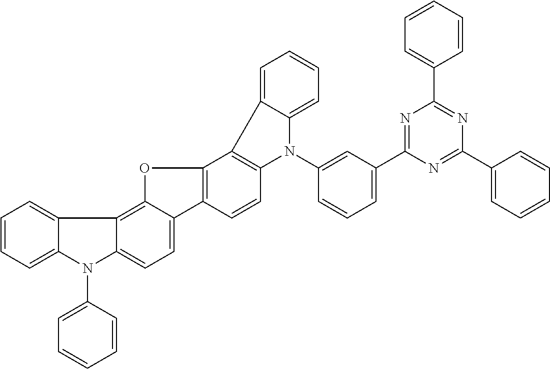 [SMILES: c1ccc(-c2nc(-c3ccccc3)nc(-c3cccc(-n4c5ccccc5c5c6oc7c(ccc8c7c7ccccc7n8-c7ccccc7)c6ccc54)c3)n2)cc1]

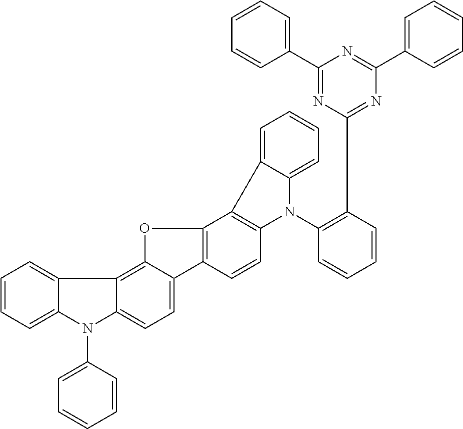 [SMILES: c1ccc(-c2nc(-c3ccccc3)nc(-c3ccccc3-n3c4ccccc4c4c5oc6c(ccc7c6c6ccccc6n7-c6ccccc6)c5ccc43)n2)cc1]

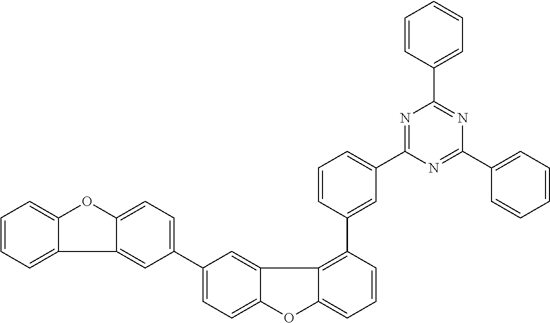 [SMILES: c1ccc(-c2nc(-c3ccccc3)nc(-c3cccc(-c4cccc5oc6ccc(-c7ccc8oc9ccccc9c8c7)cc6c45)c3)n2)cc1]

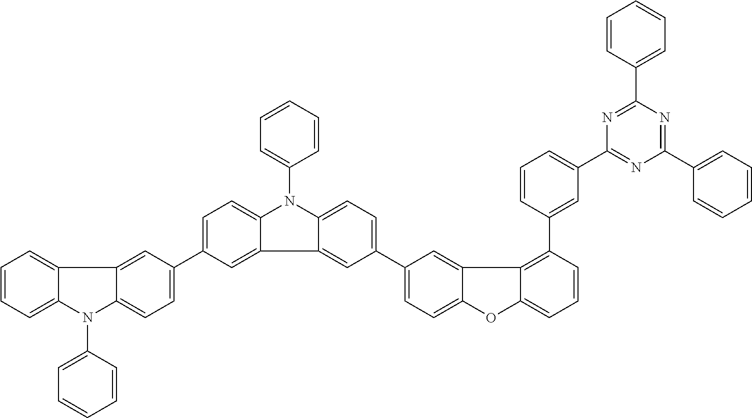 [SMILES: c1ccc(-c2nc(-c3ccccc3)nc(-c3cccc(-c4cccc5oc6ccc(-c7ccc8c(c7)c7cc(-c9ccc%10c(c9)c9ccccc9n%10-c9ccccc9)ccc7n8-c7ccccc7)cc6c45)c3)n2)cc1]

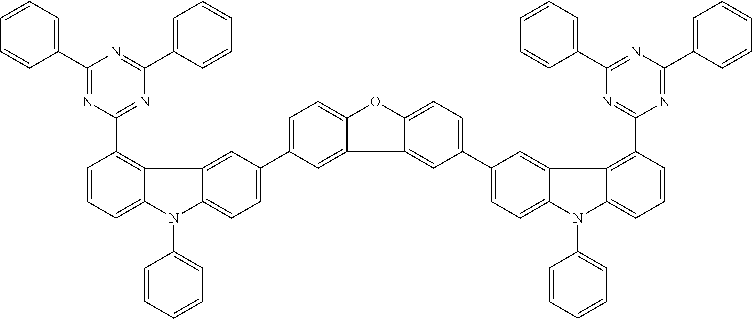 [SMILES: c1ccc(-c2nc(-c3ccccc3)nc(-c3cccc4c3c3cc(-c5ccc6oc7ccc(-c8ccc9c(c8)c8c(-c%10nc(-c%11ccccc%11)nc(-c%11ccccc%11)n%10)cccc8n9-c8ccccc8)cc7c6c5)ccc3n4-c3ccccc3)n2)cc1]

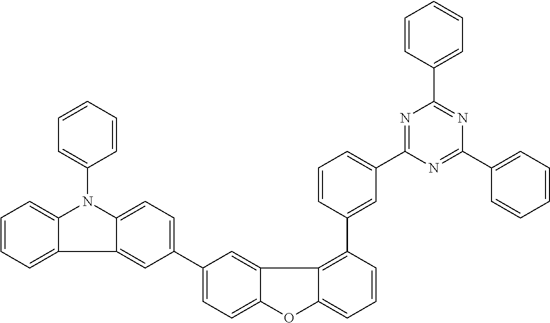 [SMILES: c1ccc(-c2nc(-c3ccccc3)nc(-c3cccc(-c4cccc5oc6ccc(-c7ccc8c(c7)c7ccccc7n8-c7ccccc7)cc6c45)c3)n2)cc1]

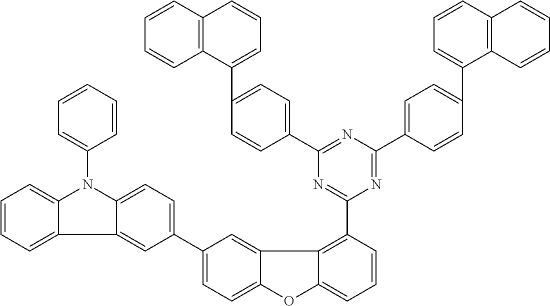 [SMILES: c1ccc(-n2c3ccccc3c3cc(-c4ccc5oc6cccc(-c7nc(-c8ccc(-c9cccc%10ccccc9%10)cc8)nc(-c8ccc(-c9cccc%10ccccc9%10)cc8)n7)c6c5c4)ccc32)cc1]

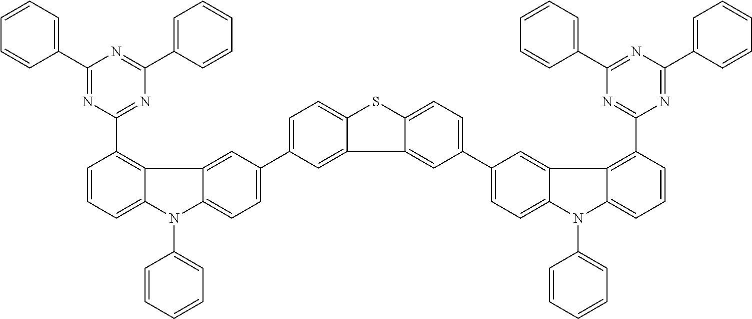 [SMILES: c1ccc(-c2nc(-c3ccccc3)nc(-c3cccc4c3c3cc(-c5ccc6sc7ccc(-c8ccc9c(c8)c8c(-c%10nc(-c%11ccccc%11)nc(-c%11ccccc%11)n%10)cccc8n9-c8ccccc8)cc7c6c5)ccc3n4-c3ccccc3)n2)cc1]

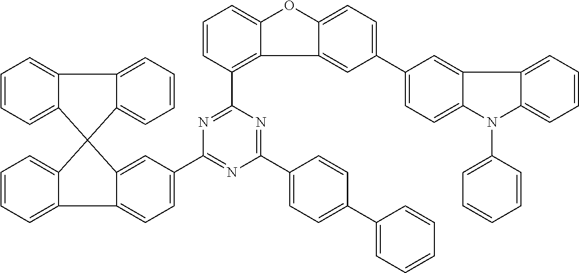 [SMILES: c1ccc(-c2ccc(-c3nc(-c4ccc5c(c4)C4(c6ccccc6-c6ccccc64)c4ccccc4-5)nc(-c4cccc5oc6ccc(-c7ccc8c(c7)c7ccccc7n8-c7ccccc7)cc6c45)n3)cc2)cc1]

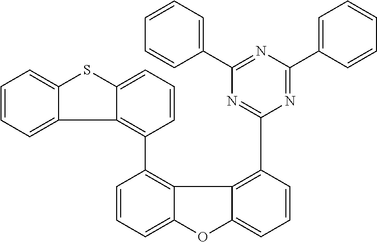 [SMILES: c1ccc(-c2nc(-c3ccccc3)nc(-c3cccc4oc5cccc(-c6cccc7sc8ccccc8c67)c5c34)n2)cc1]

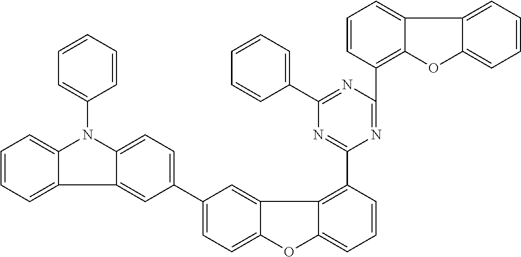 [SMILES: c1ccc(-c2nc(-c3cccc4c3oc3ccccc34)nc(-c3cccc4oc5ccc(-c6ccc7c(c6)c6ccccc6n7-c6ccccc6)cc5c34)n2)cc1]

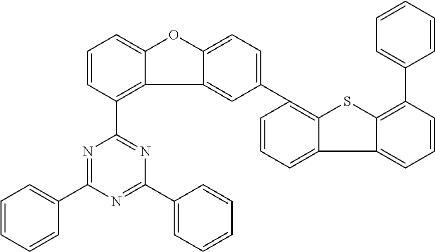 [SMILES: c1ccc(-c2nc(-c3ccccc3)nc(-c3cccc4oc5ccc(-c6cccc7c6sc6c(-c8ccccc8)cccc67)cc5c34)n2)cc1]

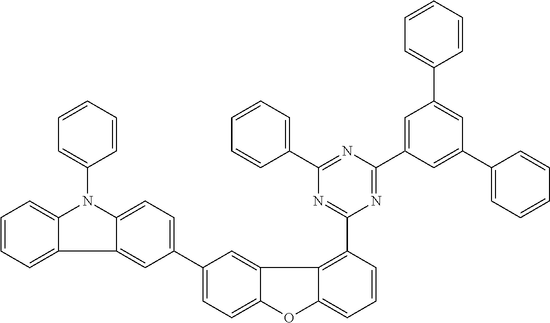 [SMILES: c1ccc(-c2cc(-c3ccccc3)cc(-c3nc(-c4ccccc4)nc(-c4cccc5oc6ccc(-c7ccc8c(c7)c7ccccc7n8-c7ccccc7)cc6c45)n3)c2)cc1]

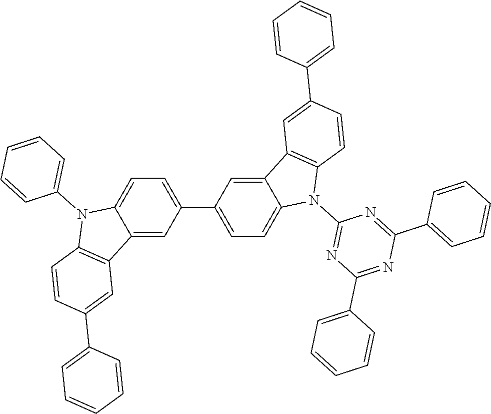 [SMILES: c1ccc(-c2ccc3c(c2)c2cc(-c4ccc5c(c4)c4cc(-c6ccccc6)ccc4n5-c4nc(-c5ccccc5)nc(-c5ccccc5)n4)ccc2n3-c2ccccc2)cc1]

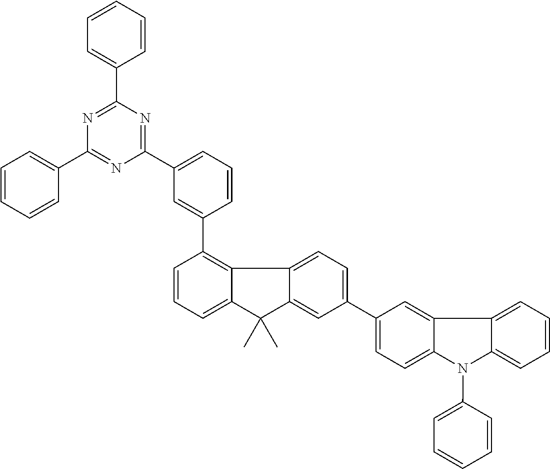 [SMILES: CC1(C)c2cc(-c3ccc4c(c3)c3ccccc3n4-c3ccccc3)ccc2-c2c(-c3cccc(-c4nc(-c5ccccc5)nc(-c5ccccc5)n4)c3)cccc21]

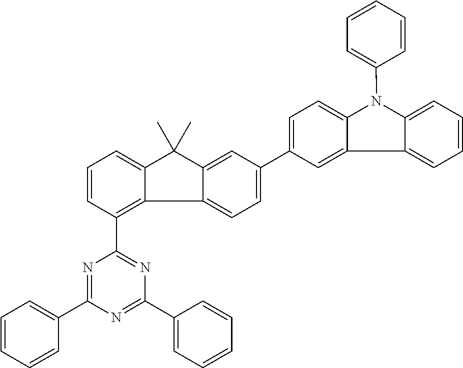 [SMILES: CC1(C)c2cc(-c3ccc4c(c3)c3ccccc3n4-c3ccccc3)ccc2-c2c(-c3nc(-c4ccccc4)nc(-c4ccccc4)n3)cccc21]

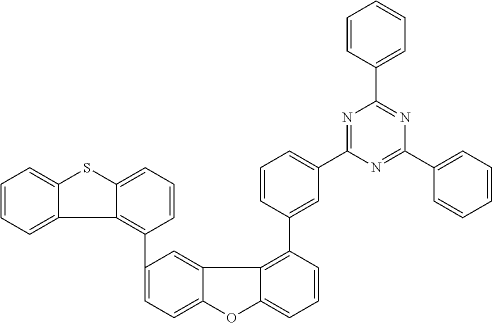 [SMILES: c1ccc(-c2nc(-c3ccccc3)nc(-c3cccc(-c4cccc5oc6ccc(-c7cccc8sc9ccccc9c78)cc6c45)c3)n2)cc1]

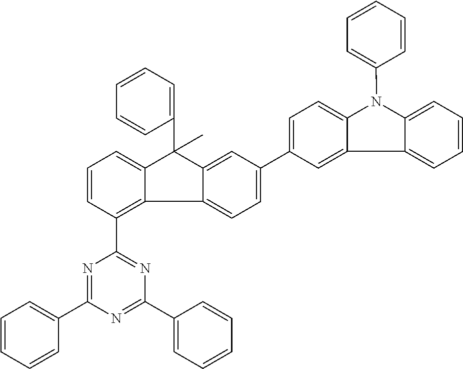 [SMILES: CC1(c2ccccc2)c2cc(-c3ccc4c(c3)c3ccccc3n4-c3ccccc3)ccc2-c2c(-c3nc(-c4ccccc4)nc(-c4ccccc4)n3)cccc21]

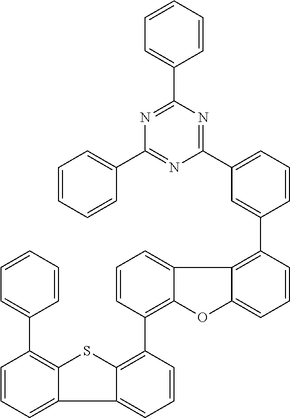 [SMILES: c1ccc(-c2nc(-c3ccccc3)nc(-c3cccc(-c4cccc5oc6c(-c7cccc8c7sc7c(-c9ccccc9)cccc78)cccc6c45)c3)n2)cc1]

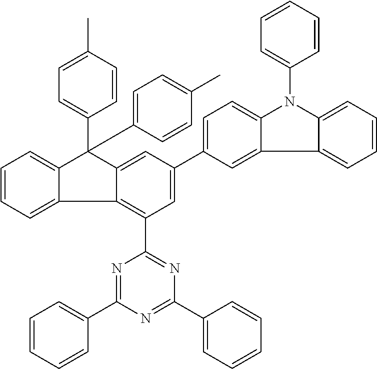 [SMILES: Cc1ccc(C2(c3ccc(C)cc3)c3ccccc3-c3c(-c4nc(-c5ccccc5)nc(-c5ccccc5)n4)cc(-c4ccc5c(c4)c4ccccc4n5-c4ccccc4)cc32)cc1]

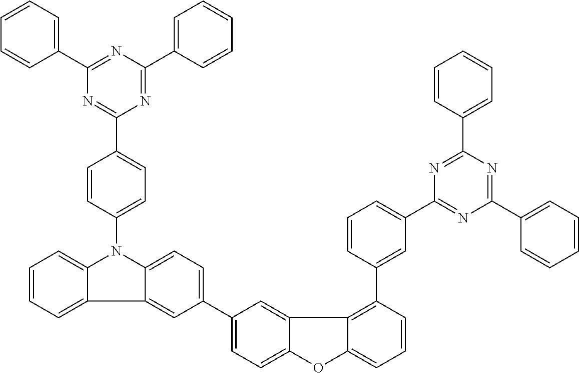 [SMILES: c1ccc(-c2nc(-c3ccccc3)nc(-c3ccc(-n4c5ccccc5c5cc(-c6ccc7oc8cccc(-c9cccc(-c%10nc(-c%11ccccc%11)nc(-c%11ccccc%11)n%10)c9)c8c7c6)ccc54)cc3)n2)cc1]

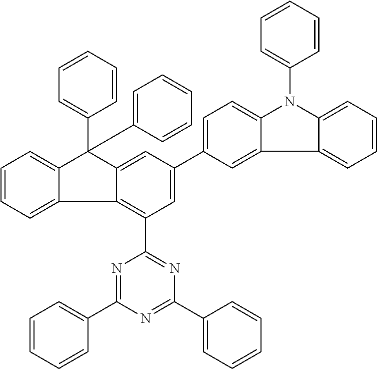 [SMILES: c1ccc(-c2nc(-c3ccccc3)nc(-c3cc(-c4ccc5c(c4)c4ccccc4n5-c4ccccc4)cc4c3-c3ccccc3C4(c3ccccc3)c3ccccc3)n2)cc1]

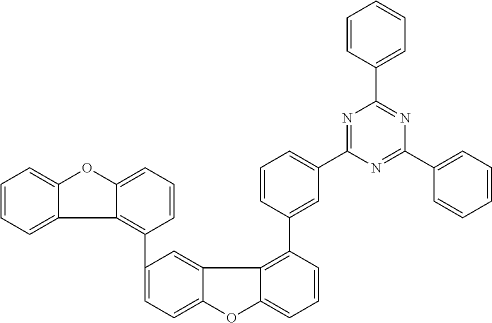 [SMILES: c1ccc(-c2nc(-c3ccccc3)nc(-c3cccc(-c4cccc5oc6ccc(-c7cccc8oc9ccccc9c78)cc6c45)c3)n2)cc1]

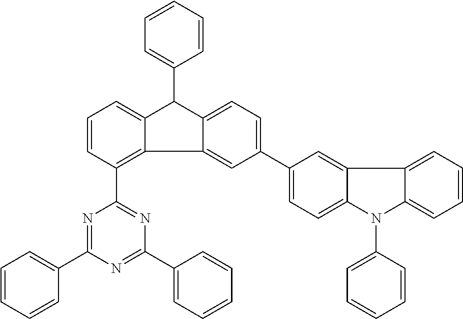 [SMILES: c1ccc(-c2nc(-c3ccccc3)nc(-c3cccc4c3-c3cc(-c5ccc6c(c5)c5ccccc5n6-c5ccccc5)ccc3C4c3ccccc3)n2)cc1]

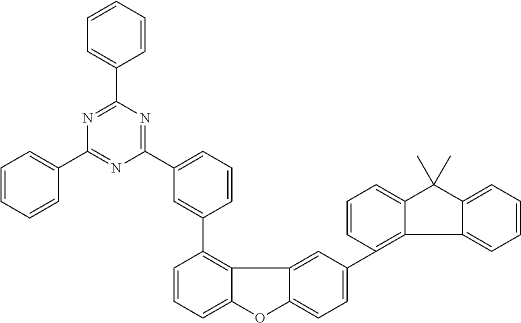 [SMILES: CC1(C)c2ccccc2-c2c(-c3ccc4oc5cccc(-c6cccc(-c7nc(-c8ccccc8)nc(-c8ccccc8)n7)c6)c5c4c3)cccc21]

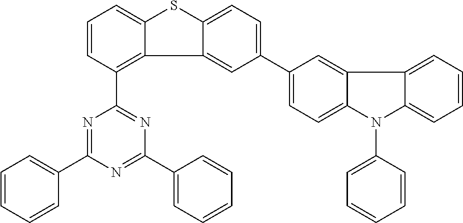 [SMILES: c1ccc(-c2nc(-c3ccccc3)nc(-c3cccc4sc5ccc(-c6ccc7c(c6)c6ccccc6n7-c6ccccc6)cc5c34)n2)cc1]

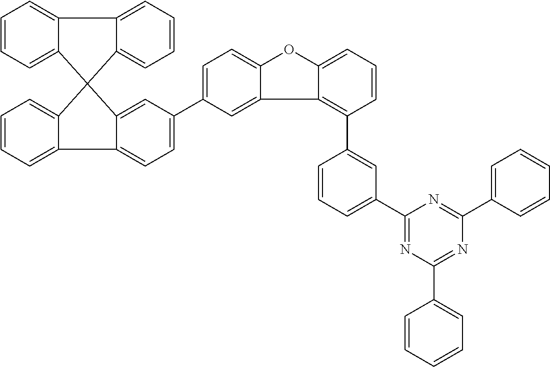 [SMILES: c1ccc(-c2nc(-c3ccccc3)nc(-c3cccc(-c4cccc5oc6ccc(-c7ccc8c(c7)C7(c9ccccc9-c9ccccc97)c7ccccc7-8)cc6c45)c3)n2)cc1]

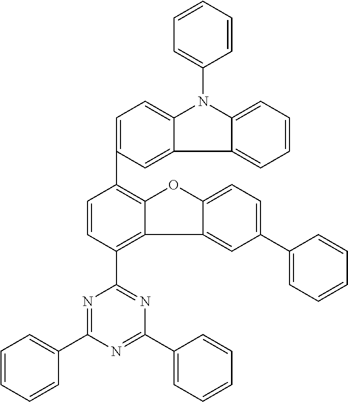 [SMILES: c1ccc(-c2ccc3oc4c(-c5ccc6c(c5)c5ccccc5n6-c5ccccc5)ccc(-c5nc(-c6ccccc6)nc(-c6ccccc6)n5)c4c3c2)cc1]

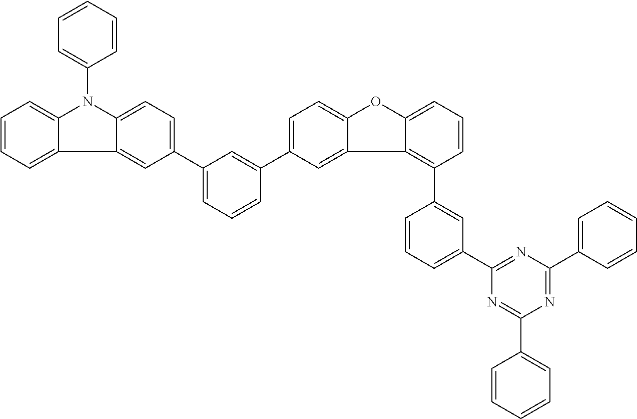 [SMILES: c1ccc(-c2nc(-c3ccccc3)nc(-c3cccc(-c4cccc5oc6ccc(-c7cccc(-c8ccc9c(c8)c8ccccc8n9-c8ccccc8)c7)cc6c45)c3)n2)cc1]

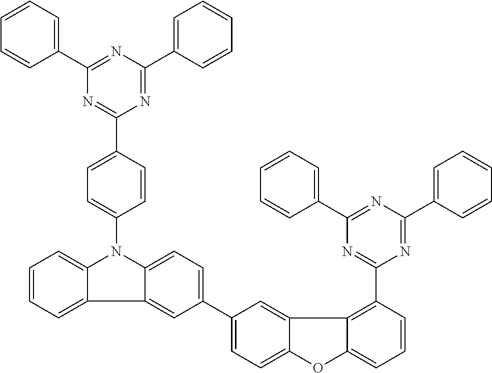 [SMILES: c1ccc(-c2nc(-c3ccccc3)nc(-c3ccc(-n4c5ccccc5c5cc(-c6ccc7oc8cccc(-c9nc(-c%10ccccc%10)nc(-c%10ccccc%10)n9)c8c7c6)ccc54)cc3)n2)cc1]

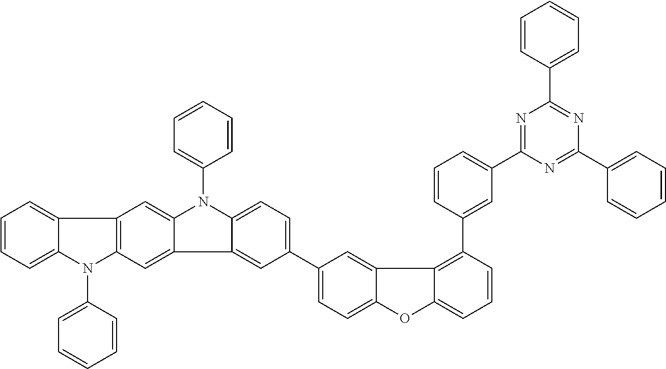 [SMILES: c1ccc(-c2nc(-c3ccccc3)nc(-c3cccc(-c4cccc5oc6ccc(-c7ccc8c(c7)c7cc9c(cc7n8-c7ccccc7)c7ccccc7n9-c7ccccc7)cc6c45)c3)n2)cc1]

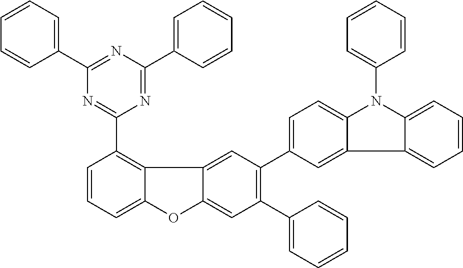 [SMILES: c1ccc(-c2nc(-c3ccccc3)nc(-c3cccc4oc5cc(-c6ccccc6)c(-c6ccc7c(c6)c6ccccc6n7-c6ccccc6)cc5c34)n2)cc1]

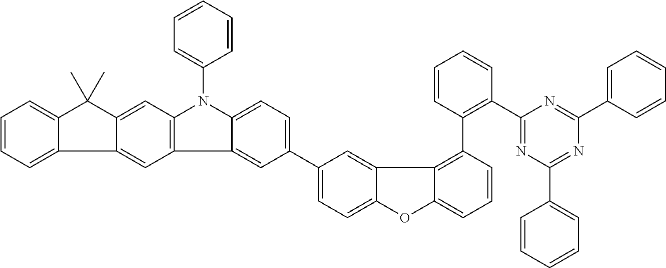 [SMILES: CC1(C)c2ccccc2-c2cc3c4cc(-c5ccc6oc7cccc(-c8ccccc8-c8nc(-c9ccccc9)nc(-c9ccccc9)n8)c7c6c5)ccc4n(-c4ccccc4)c3cc21]

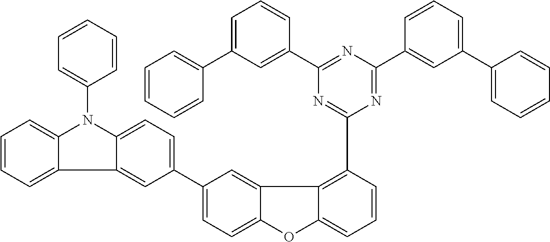 [SMILES: c1ccc(-c2cccc(-c3nc(-c4cccc(-c5ccccc5)c4)nc(-c4cccc5oc6ccc(-c7ccc8c(c7)c7ccccc7n8-c7ccccc7)cc6c45)n3)c2)cc1]

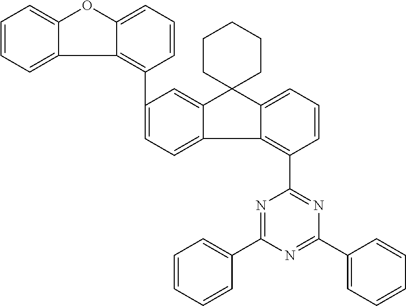 [SMILES: c1ccc(-c2nc(-c3ccccc3)nc(-c3cccc4c3-c3ccc(-c5cccc6oc7ccccc7c56)cc3C43CCCCC3)n2)cc1]

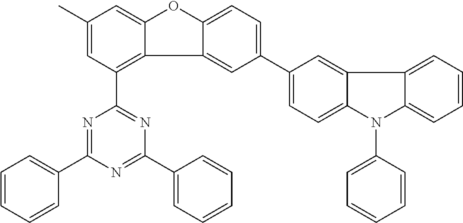 [SMILES: Cc1cc(-c2nc(-c3ccccc3)nc(-c3ccccc3)n2)c2c(c1)oc1ccc(-c3ccc4c(c3)c3ccccc3n4-c3ccccc3)cc12]

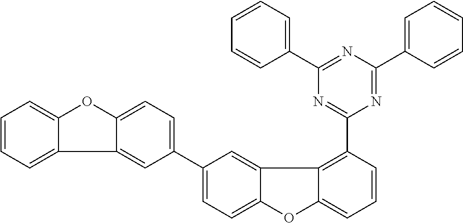 [SMILES: c1ccc(-c2nc(-c3ccccc3)nc(-c3cccc4oc5ccc(-c6ccc7oc8ccccc8c7c6)cc5c34)n2)cc1]

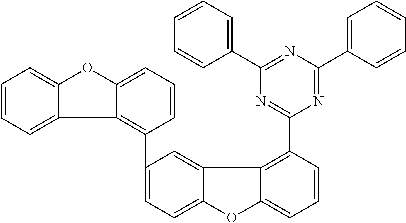 [SMILES: c1ccc(-c2nc(-c3ccccc3)nc(-c3cccc4oc5ccc(-c6cccc7oc8ccccc8c67)cc5c34)n2)cc1]

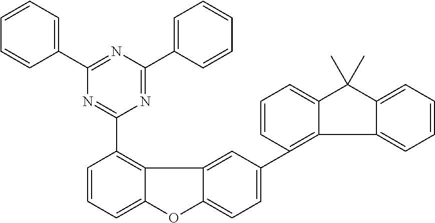 [SMILES: CC1(C)c2ccccc2-c2c(-c3ccc4oc5cccc(-c6nc(-c7ccccc7)nc(-c7ccccc7)n6)c5c4c3)cccc21]

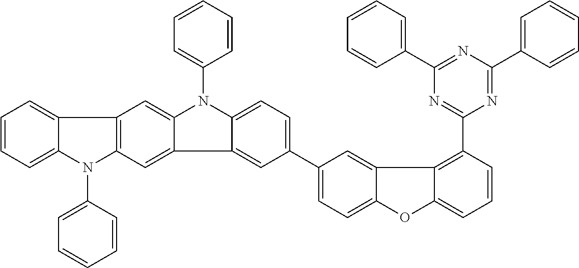 [SMILES: c1ccc(-c2nc(-c3ccccc3)nc(-c3cccc4oc5ccc(-c6ccc7c(c6)c6cc8c(cc6n7-c6ccccc6)c6ccccc6n8-c6ccccc6)cc5c34)n2)cc1]

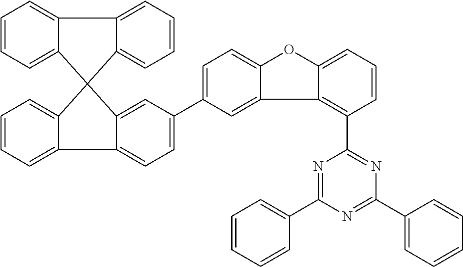 [SMILES: c1ccc(-c2nc(-c3ccccc3)nc(-c3cccc4oc5ccc(-c6ccc7c(c6)C6(c8ccccc8-c8ccccc86)c6ccccc6-7)cc5c34)n2)cc1]

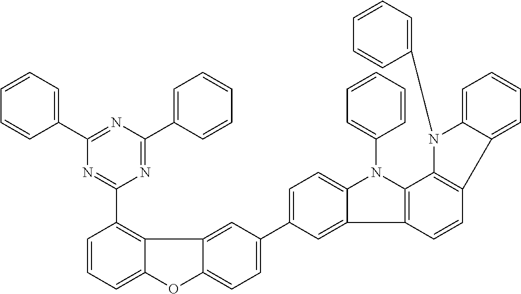 [SMILES: c1ccc(-c2nc(-c3ccccc3)nc(-c3cccc4oc5ccc(-c6ccc7c(c6)c6ccc8c9ccccc9n(-c9ccccc9)c8c6n7-c6ccccc6)cc5c34)n2)cc1]

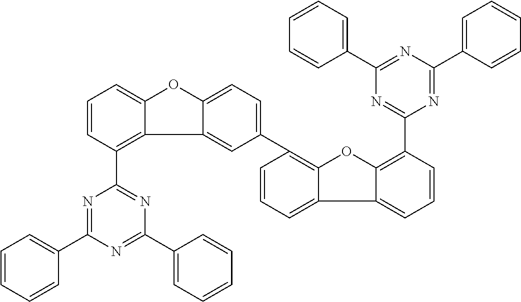 [SMILES: c1ccc(-c2nc(-c3ccccc3)nc(-c3cccc4c3oc3c(-c5ccc6oc7cccc(-c8nc(-c9ccccc9)nc(-c9ccccc9)n8)c7c6c5)cccc34)n2)cc1]

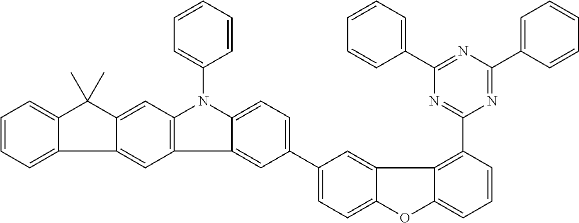 [SMILES: CC1(C)c2ccccc2-c2cc3c4cc(-c5ccc6oc7cccc(-c8nc(-c9ccccc9)nc(-c9ccccc9)n8)c7c6c5)ccc4n(-c4ccccc4)c3cc21]

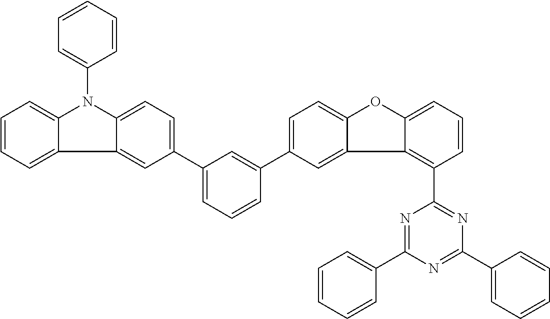 [SMILES: c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1]

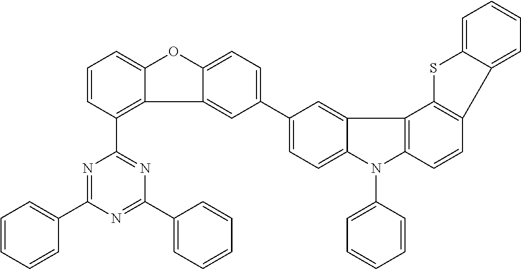 [SMILES: c1ccc(-c2nc(-c3ccccc3)nc(-c3cccc4oc5ccc(-c6ccc7c(c6)c6c8sc9ccccc9c8ccc6n7-c6ccccc6)cc5c34)n2)cc1]

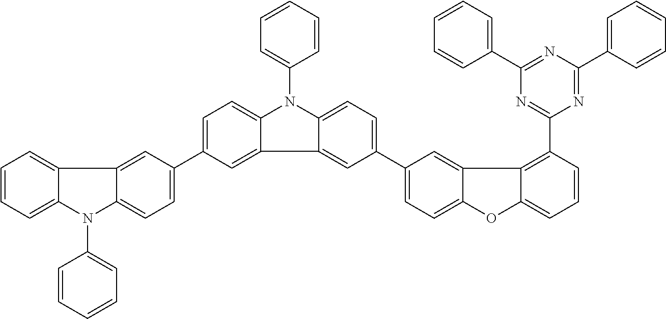 [SMILES: c1ccc(-c2nc(-c3ccccc3)nc(-c3cccc4oc5ccc(-c6ccc7c(c6)c6cc(-c8ccc9c(c8)c8ccccc8n9-c8ccccc8)ccc6n7-c6ccccc6)cc5c34)n2)cc1]

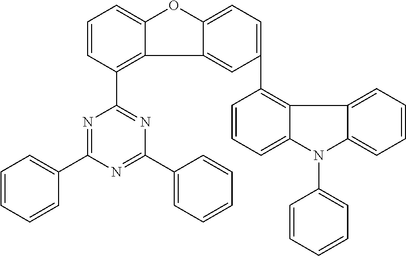 [SMILES: c1ccc(-c2nc(-c3ccccc3)nc(-c3cccc4oc5ccc(-c6cccc7c6c6ccccc6n7-c6ccccc6)cc5c34)n2)cc1]

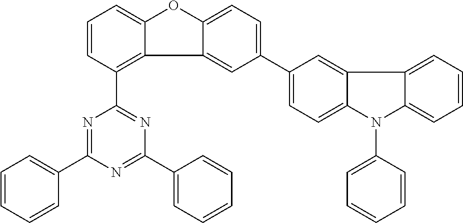 [SMILES: c1ccc(-c2nc(-c3ccccc3)nc(-c3cccc4oc5ccc(-c6ccc7c(c6)c6ccccc6n7-c6ccccc6)cc5c34)n2)cc1]

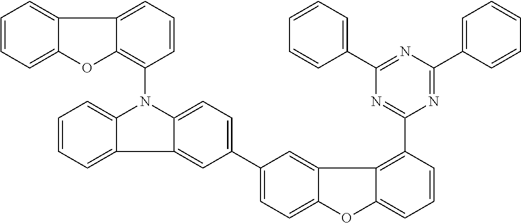 [SMILES: c1ccc(-c2nc(-c3ccccc3)nc(-c3cccc4oc5ccc(-c6ccc7c(c6)c6ccccc6n7-c6cccc7c6oc6ccccc67)cc5c34)n2)cc1]

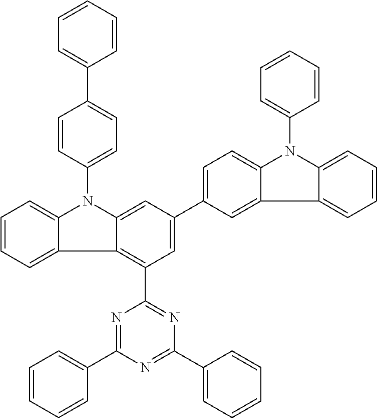 [SMILES: c1ccc(-c2ccc(-n3c4ccccc4c4c(-c5nc(-c6ccccc6)nc(-c6ccccc6)n5)cc(-c5ccc6c(c5)c5ccccc5n6-c5ccccc5)cc43)cc2)cc1]

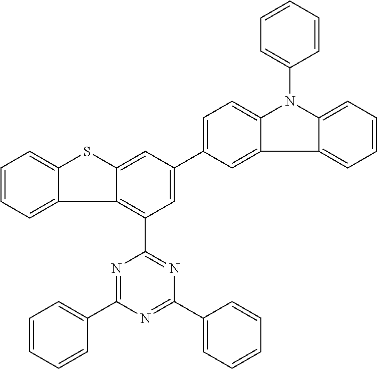 [SMILES: c1ccc(-c2nc(-c3ccccc3)nc(-c3cc(-c4ccc5c(c4)c4ccccc4n5-c4ccccc4)cc4sc5ccccc5c34)n2)cc1]

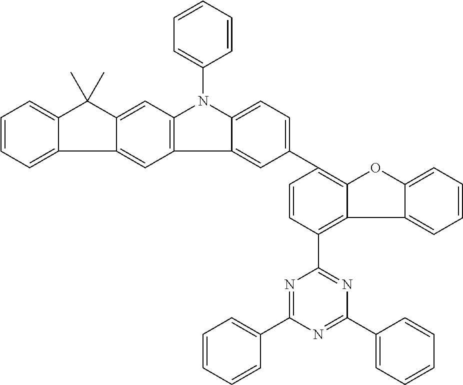 [SMILES: CC1(C)c2ccccc2-c2cc3c4cc(-c5ccc(-c6nc(-c7ccccc7)nc(-c7ccccc7)n6)c6c5oc5ccccc56)ccc4n(-c4ccccc4)c3cc21]

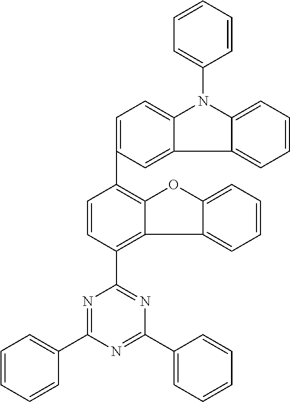 [SMILES: c1ccc(-c2nc(-c3ccccc3)nc(-c3ccc(-c4ccc5c(c4)c4ccccc4n5-c4ccccc4)c4oc5ccccc5c34)n2)cc1]

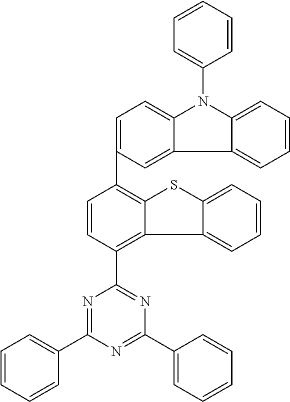 [SMILES: c1ccc(-c2nc(-c3ccccc3)nc(-c3ccc(-c4ccc5c(c4)c4ccccc4n5-c4ccccc4)c4sc5ccccc5c34)n2)cc1]

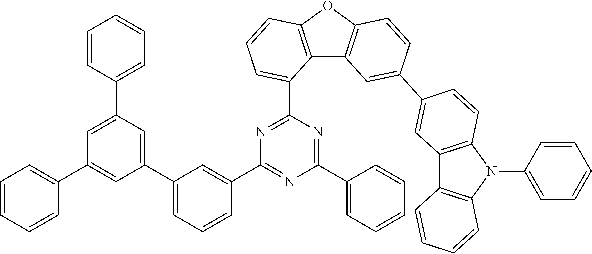 [SMILES: c1ccc(-c2cc(-c3ccccc3)cc(-c3cccc(-c4nc(-c5ccccc5)nc(-c5cccc6oc7ccc(-c8ccc9c(c8)c8ccccc8n9-c8ccccc8)cc7c56)n4)c3)c2)cc1]

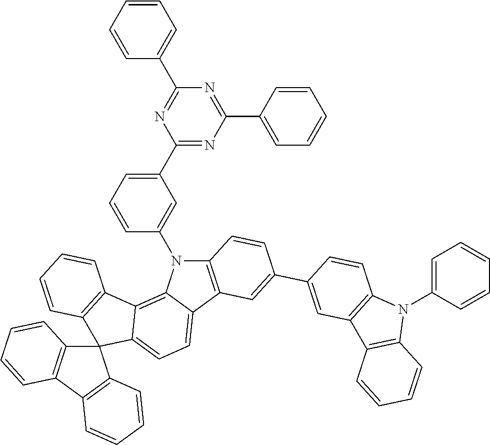 [SMILES: c1ccc(-c2nc(-c3ccccc3)nc(-c3cccc(-n4c5ccc(-c6ccc7c(c6)c6ccccc6n7-c6ccccc6)cc5c5ccc6c(c54)-c4ccccc4C64c5ccccc5-c5ccccc54)c3)n2)cc1]

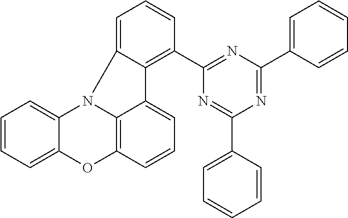 [SMILES: c1ccc(-c2nc(-c3ccccc3)nc(-c3cccc4c3c3cccc5c3n4-c3ccccc3O5)n2)cc1]

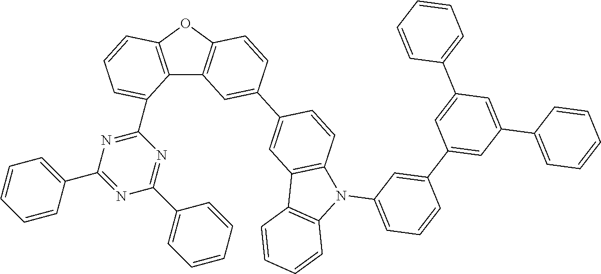 [SMILES: c1ccc(-c2cc(-c3ccccc3)cc(-c3cccc(-n4c5ccccc5c5cc(-c6ccc7oc8cccc(-c9nc(-c%10ccccc%10)nc(-c%10ccccc%10)n9)c8c7c6)ccc54)c3)c2)cc1]

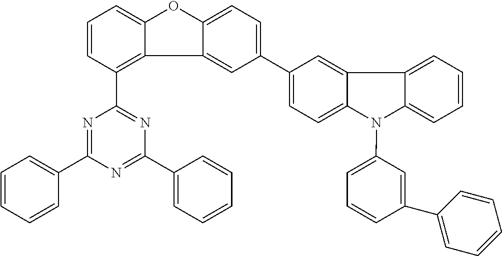 [SMILES: c1ccc(-c2cccc(-n3c4ccccc4c4cc(-c5ccc6oc7cccc(-c8nc(-c9ccccc9)nc(-c9ccccc9)n8)c7c6c5)ccc43)c2)cc1]

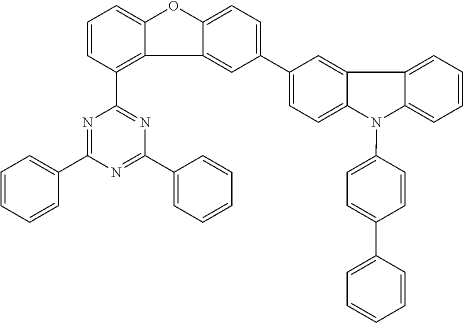 [SMILES: c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1]

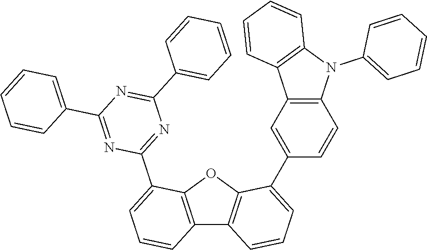 [SMILES: c1ccc(-c2nc(-c3ccccc3)nc(-c3cccc4c3oc3c(-c5ccc6c(c5)c5ccccc5n6-c5ccccc5)cccc34)n2)cc1]

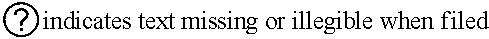

Examples of suitable quinazoline compounds are the compounds depicted in the following table:

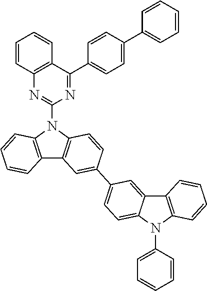 [SMILES: c1ccc(-c2ccc(-c3nc(-n4c5ccccc5c5cc(-c6ccc7c(c6)c6ccccc6n7-c6ccccc6)ccc54)nc4ccccc34)cc2)cc1]

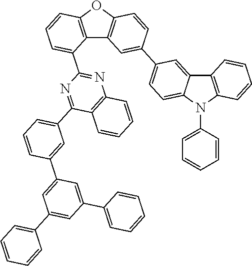 [SMILES: c1ccc(-c2cc(-c3ccccc3)cc(-c3cccc(-c4nc(-c5cccc6oc7ccc(-c8ccc9c(c8)c8ccccc8n9-c8ccccc8)cc7c56)nc5ccccc45)c3)c2)cc1]

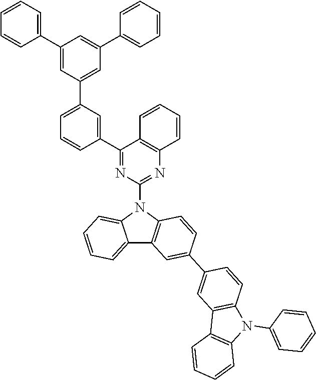 [SMILES: c1ccc(-c2cc(-c3ccccc3)cc(-c3cccc(-c4nc(-n5c6ccccc6c6cc(-c7ccc8c(c7)c7ccccc7n8-c7ccccc7)ccc65)nc5ccccc45)c3)c2)cc1]

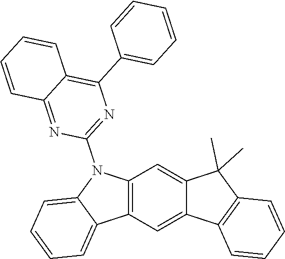 [SMILES: CC1(C)c2ccccc2-c2cc3c4ccccc4n(-c4nc(-c5ccccc5)c5ccccc5n4)c3cc21]

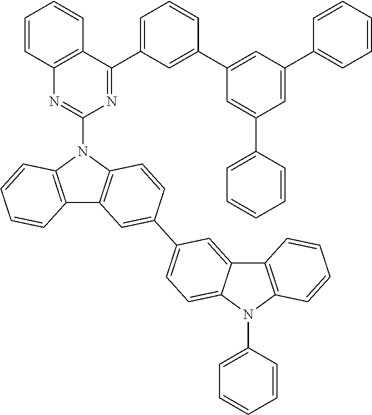 [SMILES: c1ccc(-c2cc(-c3ccccc3)cc(-c3cccc(-c4nc(-n5c6ccccc6c6cc(-c7ccc8c(c7)c7ccccc7n8-c7ccccc7)ccc65)nc5ccccc45)c3)c2)cc1]

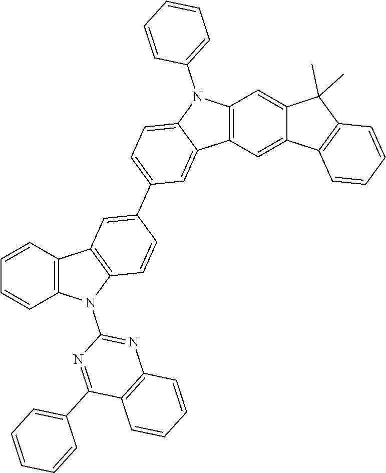 [SMILES: CC1(C)c2ccccc2-c2cc3c4cc(-c5ccc6c(c5)c5ccccc5n6-c5nc(-c6ccccc6)c6ccccc6n5)ccc4n(-c4ccccc4)c3cc21]

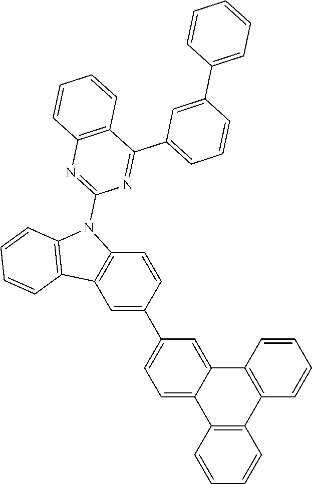 [SMILES: c1ccc(-c2cccc(-c3nc(-n4c5ccccc5c5cc(-c6ccc7c8ccccc8c8ccccc8c7c6)ccc54)nc4ccccc34)c2)cc1]

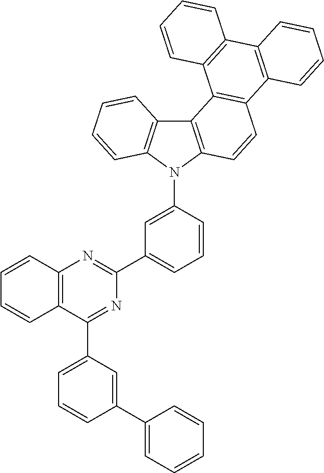 [SMILES: c1ccc(-c2cccc(-c3nc(-c4cccc(-n5c6ccccc6c6c7c8ccccc8c8ccccc8c7ccc65)c4)nc4ccccc34)c2)cc1]

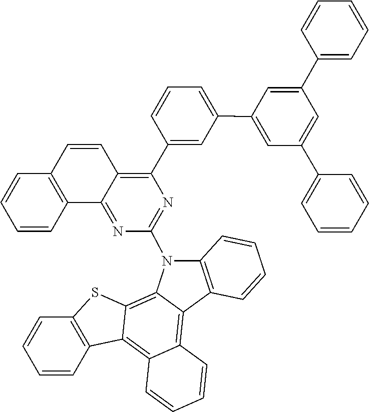 [SMILES: c1ccc(-c2cc(-c3ccccc3)cc(-c3cccc(-c4nc(-n5c6ccccc6c6c7ccccc7c7c8ccccc8sc7c65)nc5c4ccc4ccccc45)c3)c2)cc1]

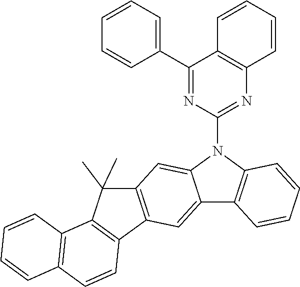 [SMILES: CC1(C)c2cc3c(cc2-c2ccc4ccccc4c21)c1ccccc1n3-c1nc(-c2ccccc2)c2ccccc2n1]

Preferred biscarbazoles are the structures of the following formulae (23) and (24):

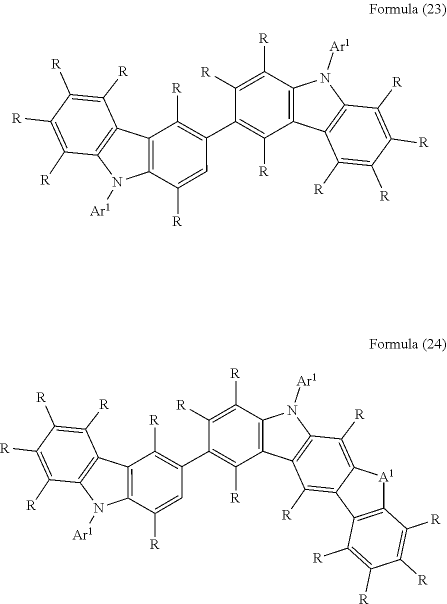

where Ar¹ and R have the definitions given above and A¹ is CR₂, NR, O or S. In a preferred embodiment of the invention, A¹ is CR₂.

Preferred embodiments of the compounds of the formulae (23) and (24) are the compounds of the following formulae (23a) and (24a):

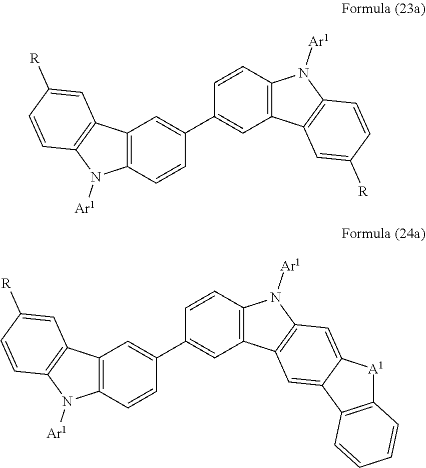

where the symbols used have the definitions given above.

Examples of suitable compounds of formulae (23) and (24) are the compounds depicted below:

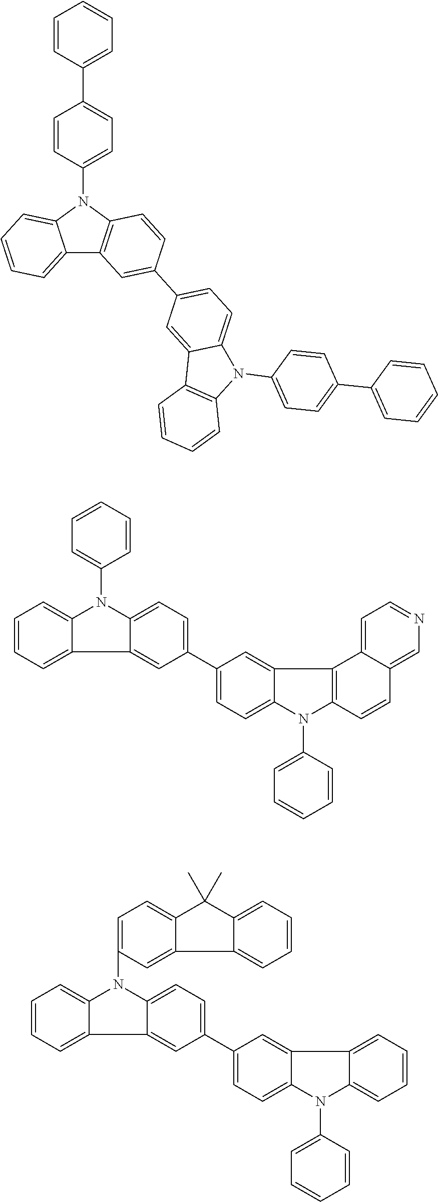 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-n2c3ccccc3c3cc(-c4ccc5c(c4)c4c6ccncc6ccc4n5-c4ccccc4)ccc32)cc1 ; CC1(C)c2ccccc2-c2cc(-n3c4ccccc4c4cc(-c5ccc6c(c5)c5ccccc5n6-c5ccccc5)ccc43)ccc21]

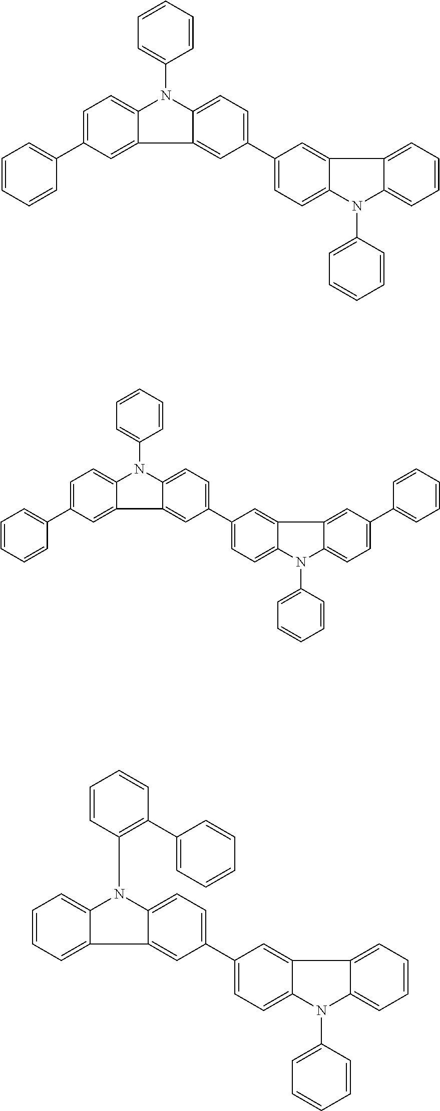 [SMILES: c1ccc(-c2ccc3c(c2)c2cc(-c4ccc5c(c4)c4ccccc4n5-c4ccccc4)ccc2n3-c2ccccc2)cc1 ; c1ccc(-c2ccc3c(c2)c2cc(-c4ccc5c(c4)c4cc(-c6ccccc6)ccc4n5-c4ccccc4)ccc2n3-c2ccccc2)cc1 ; c1ccc(-c2ccccc2-n2c3ccccc3c3cc(-c4ccc5c(c4)c4ccccc4n5-c4ccccc4)ccc32)cc1]

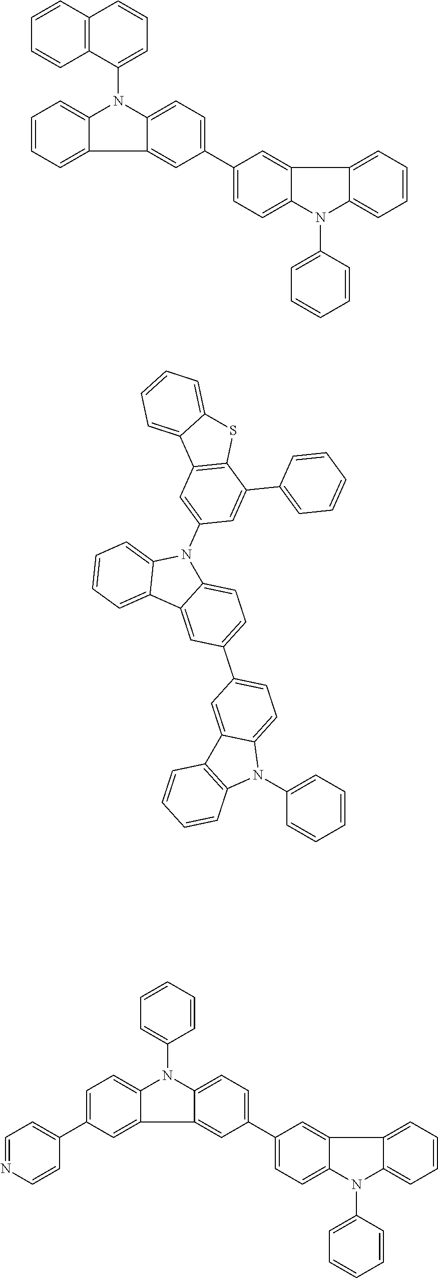 [SMILES: c1ccc(-n2c3ccccc3c3cc(-c4ccc5c(c4)c4ccccc4n5-c4cccc5ccccc45)ccc32)cc1 ; c1ccc(-c2cc(-n3c4ccccc4c4cc(-c5ccc6c(c5)c5ccccc5n6-c5ccccc5)ccc43)cc3c2sc2ccccc23)cc1 ; c1ccc(-n2c3ccccc3c3cc(-c4ccc5c(c4)c4cc(-c6ccncc6)ccc4n5-c4ccccc4)ccc32)cc1]

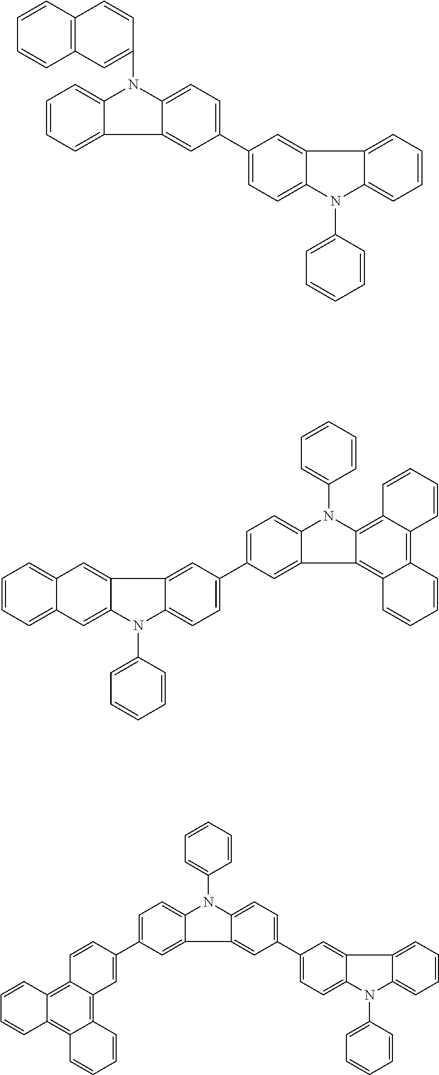 [SMILES: c1ccc(-n2c3ccccc3c3cc(-c4ccc5c(c4)c4ccccc4n5-c4ccc5ccccc5c4)ccc32)cc1 ; c1ccc(-n2c3ccc(-c4ccc5c(c4)c4c6ccccc6c6ccccc6c4n5-c4ccccc4)cc3c3cc4ccccc4cc32)cc1 ; c1ccc(-n2c3ccccc3c3cc(-c4ccc5c(c4)c4cc(-c6ccc7c8ccccc8c8ccccc8c7c6)ccc4n5-c4ccccc4)ccc32)cc1]

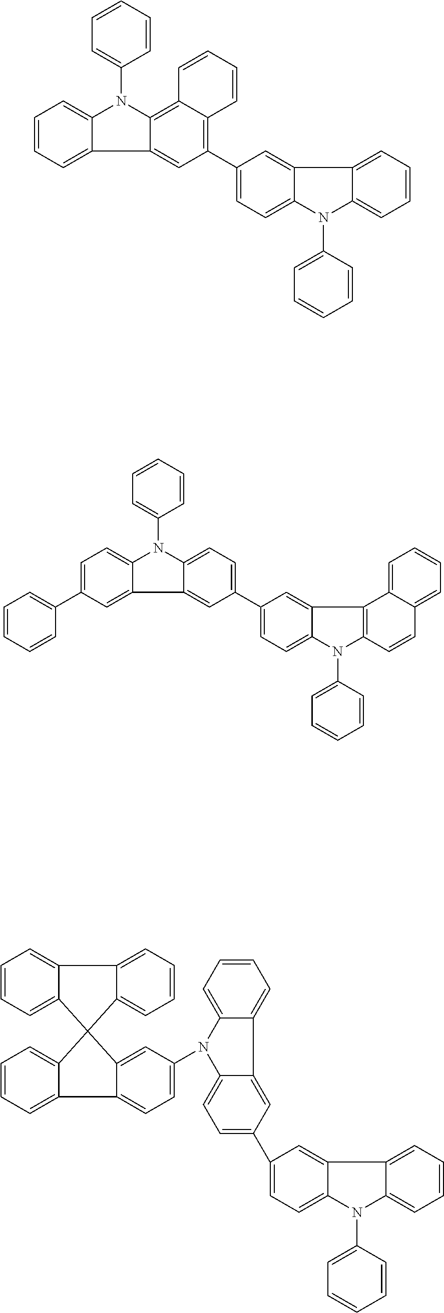 [SMILES: c1ccc(-n2c3ccccc3c3cc(-c4cc5c6ccccc6n(-c6ccccc6)c5c5ccccc45)ccc32)cc1 ; c1ccc(-c2ccc3c(c2)c2cc(-c4ccc5c(c4)c4c6ccccc6ccc4n5-c4ccccc4)ccc2n3-c2ccccc2)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1]

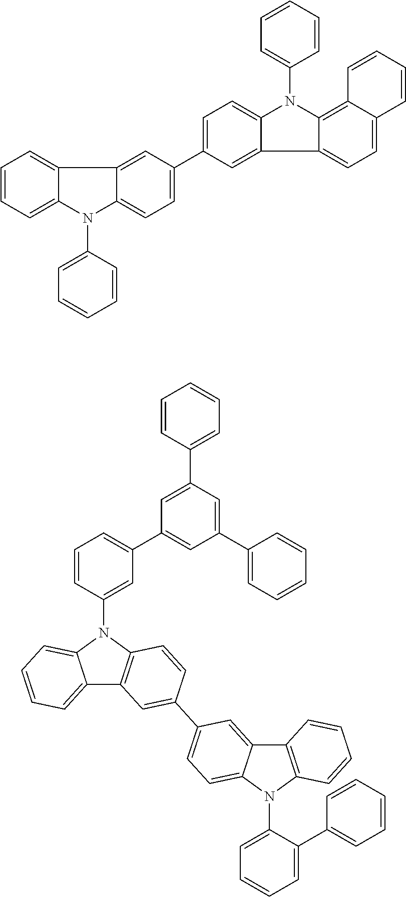 [SMILES: c1ccc(-n2c3ccccc3c3cc(-c4ccc5c(c4)c4ccc6ccccc6c4n5-c4ccccc4)ccc32)cc1 ; c1ccc(-c2cc(-c3ccccc3)cc(-c3cccc(-n4c5ccccc5c5cc(-c6ccc7c(c6)c6ccccc6n7-c6ccccc6-c6ccccc6)ccc54)c3)c2)cc1]

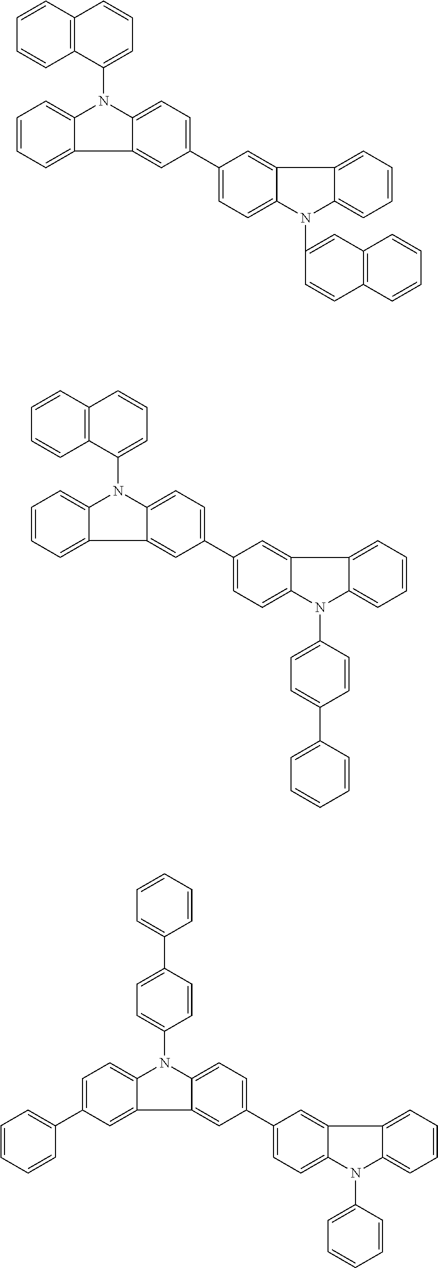 [SMILES: c1ccc2cc(-n3c4ccccc4c4cc(-c5ccc6c(c5)c5ccccc5n6-c5cccc6ccccc56)ccc43)ccc2c1 ; c1ccc(-c2ccc(-n3c4ccccc4c4cc(-c5ccc6c(c5)c5ccccc5n6-c5cccc6ccccc56)ccc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1]

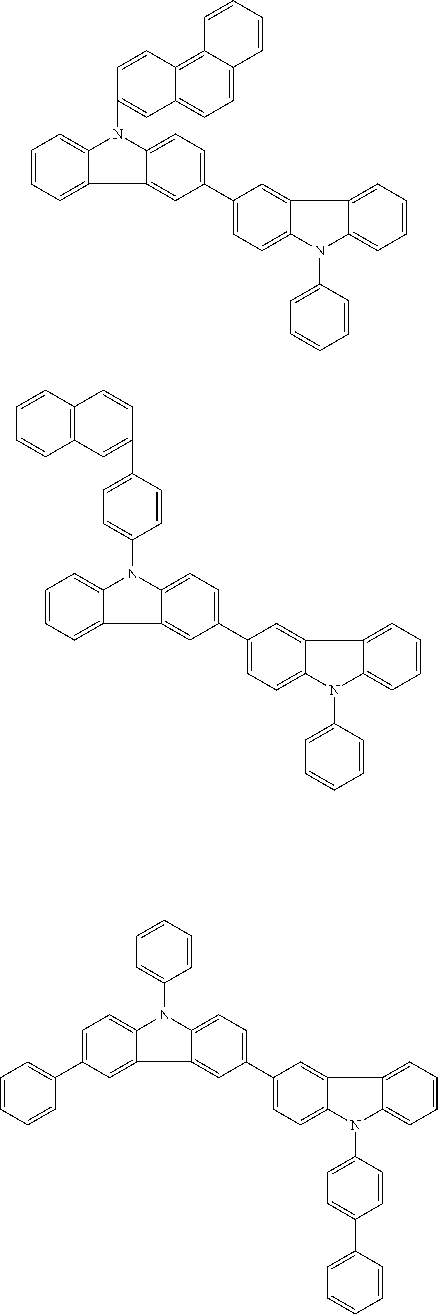 [SMILES: c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc(-c5ccc6ccccc6c5)cc4)ccc32)cc1 ; c1ccc(-c2ccc(-n3c4ccccc4c4cc(-c5ccc6c(c5)c5cc(-c7ccccc7)ccc5n6-c5ccccc5)ccc43)cc2)cc1]

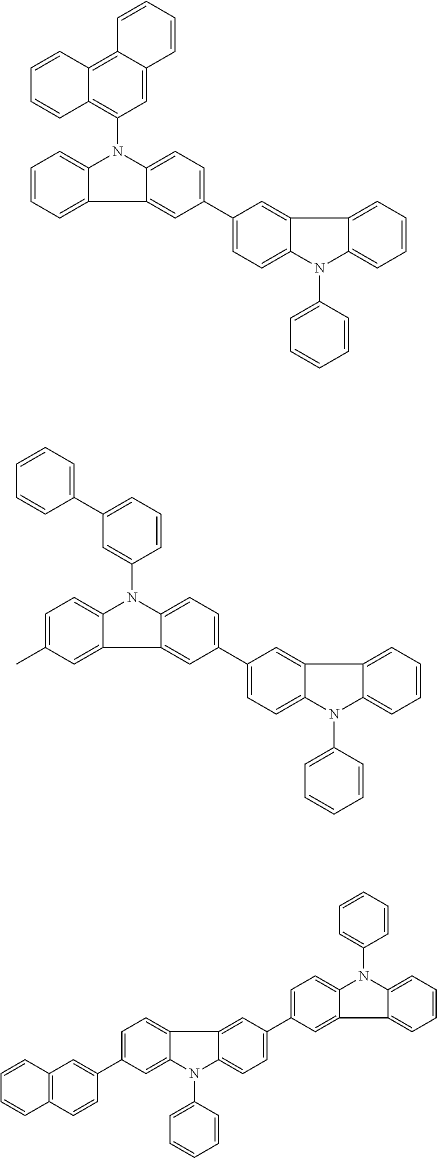 [SMILES: c1ccc(-n2c3ccccc3c3cc(-c4ccc5c(c4)c4ccccc4n5-c4cc5ccccc5c5ccccc45)ccc32)cc1 ; Cc1ccc2c(c1)c1cc(-c3ccc4c(c3)c3ccccc3n4-c3ccccc3)ccc1n2-c1cccc(-c2ccccc2)c1 ; c1ccc(-n2c3ccccc3c3cc(-c4ccc5c(c4)c4ccc(-c6ccc7ccccc7c6)cc4n5-c4ccccc4)ccc32)cc1]

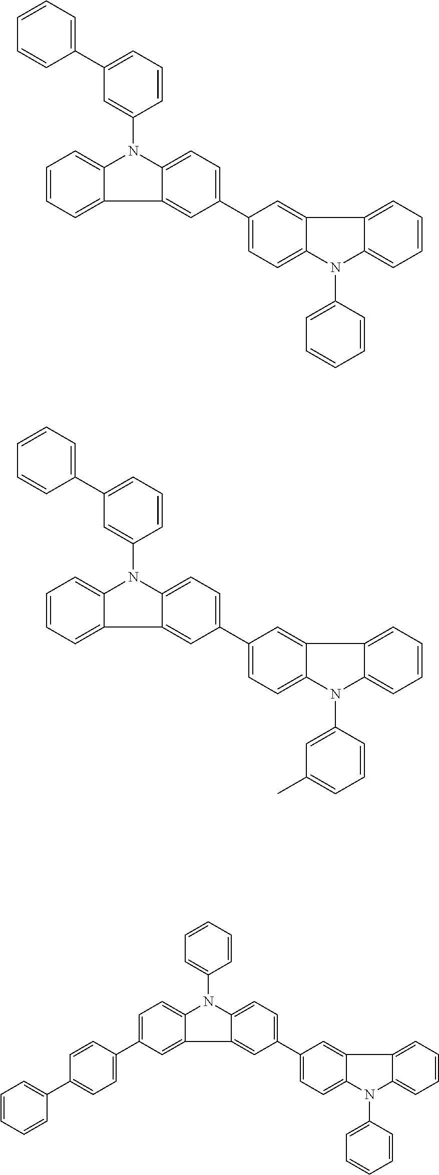 [SMILES: c1ccc(-c2cccc(-n3c4ccccc4c4cc(-c5ccc6c(c5)c5ccccc5n6-c5ccccc5)ccc43)c2)cc1 ; Cc1cccc(-n2c3ccccc3c3cc(-c4ccc5c(c4)c4ccccc4n5-c4cccc(-c5ccccc5)c4)ccc32)c1 ; c1ccc(-c2ccc(-c3ccc4c(c3)c3cc(-c5ccc6c(c5)c5ccccc5n6-c5ccccc5)ccc3n4-c3ccccc3)cc2)cc1]

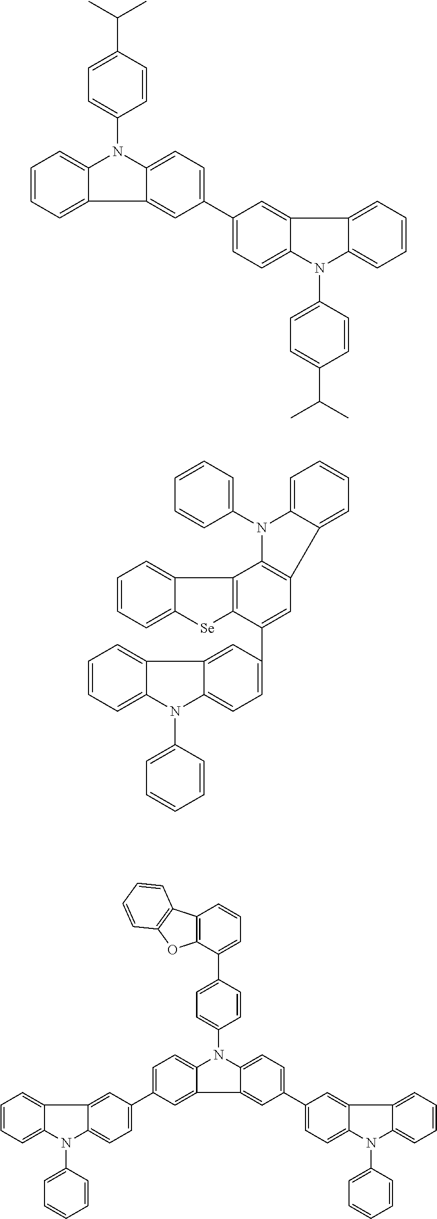 [SMILES: CC(C)c1ccc(-n2c3ccccc3c3cc(-c4ccc5c(c4)c4ccccc4n5-c4ccc(C(C)C)cc4)ccc32)cc1 ; c1ccc(-n2c3ccccc3c3cc(-c4cc5c6ccccc6n(-c6ccccc6)c5c5c4[se]c4ccccc45)ccc32)cc1 ; c1ccc(-n2c3ccccc3c3cc(-c4ccc5c(c4)c4cc(-c6ccc7c(c6)c6ccccc6n7-c6ccccc6)ccc4n5-c4ccc(-c5cccc6c5oc5ccccc56)cc4)ccc32)cc1]

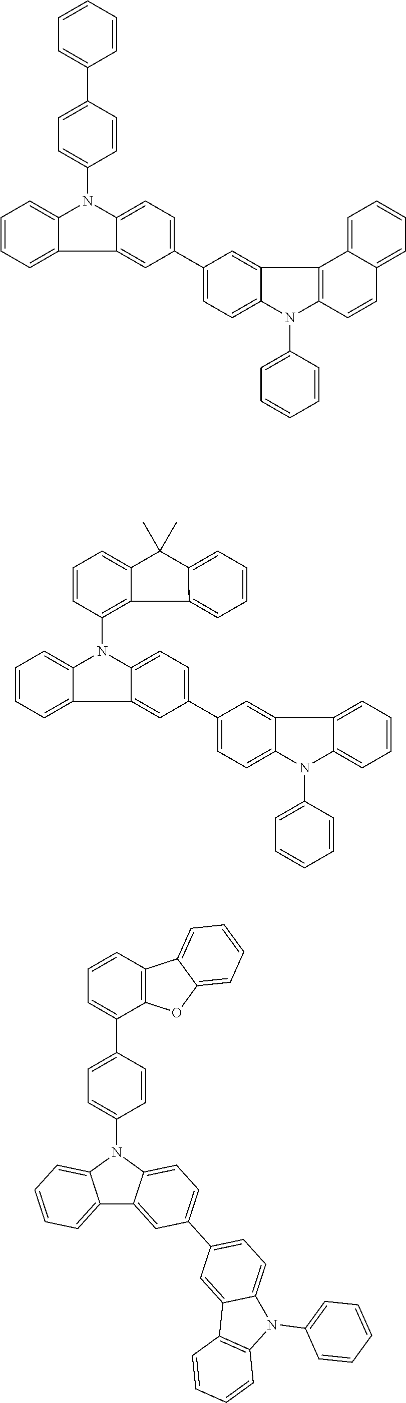 [SMILES: c1ccc(-c2ccc(-n3c4ccccc4c4cc(-c5ccc6c(c5)c5c7ccccc7ccc5n6-c5ccccc5)ccc43)cc2)cc1 ; CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc(-c5cccc6c5oc5ccccc56)cc4)ccc32)cc1]

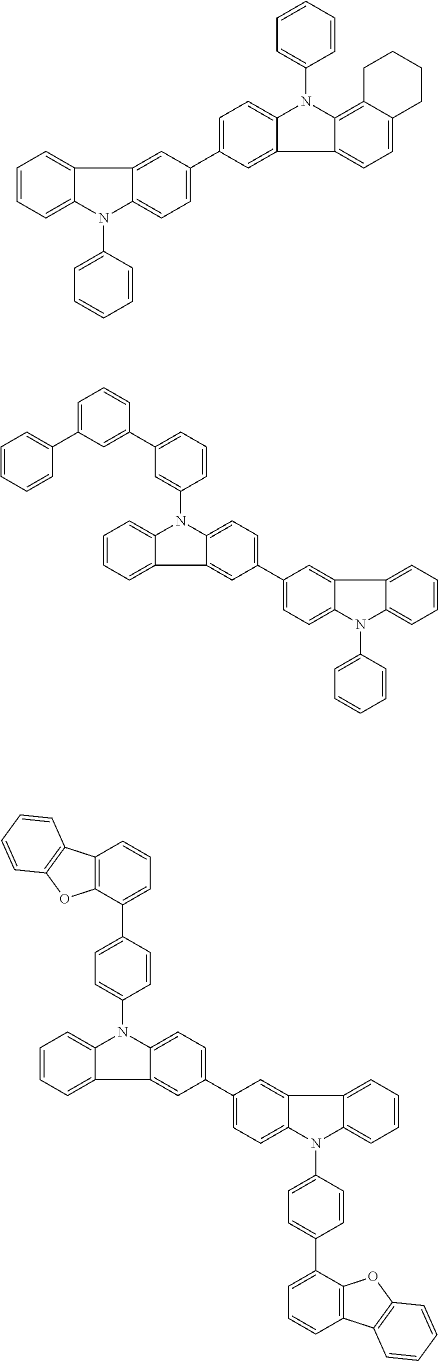 [SMILES: c1ccc(-n2c3ccccc3c3cc(-c4ccc5c(c4)c4ccc6c(c4n5-c4ccccc4)CCCC6)ccc32)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc2c(c1)oc1c(-c3ccc(-n4c5ccccc5c5cc(-c6ccc7c(c6)c6ccccc6n7-c6ccc(-c7cccc8c7oc7ccccc78)cc6)ccc54)cc3)cccc12]

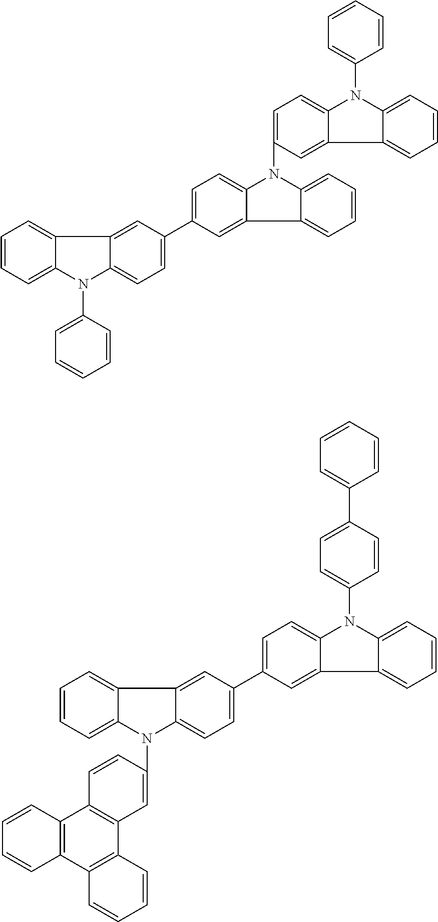 [SMILES: c1ccc(-n2c3ccccc3c3cc(-c4ccc5c(c4)c4ccccc4n5-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc6c7ccccc7c7ccccc7c6c5)ccc43)cc2)cc1]

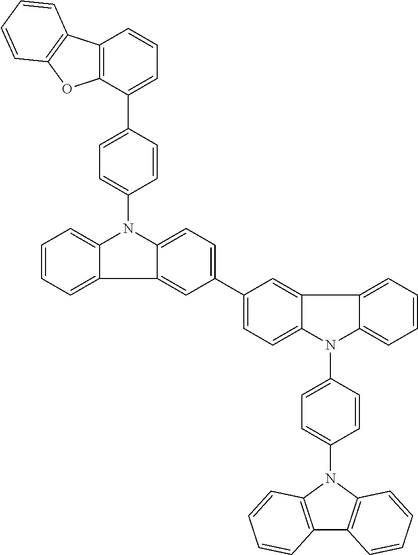 [SMILES: c1ccc2c(c1)oc1c(-c3ccc(-n4c5ccccc5c5cc(-c6ccc7c(c6)c6ccccc6n7-c6ccc(-n7c8ccccc8c8ccccc87)cc6)ccc54)cc3)cccc12]

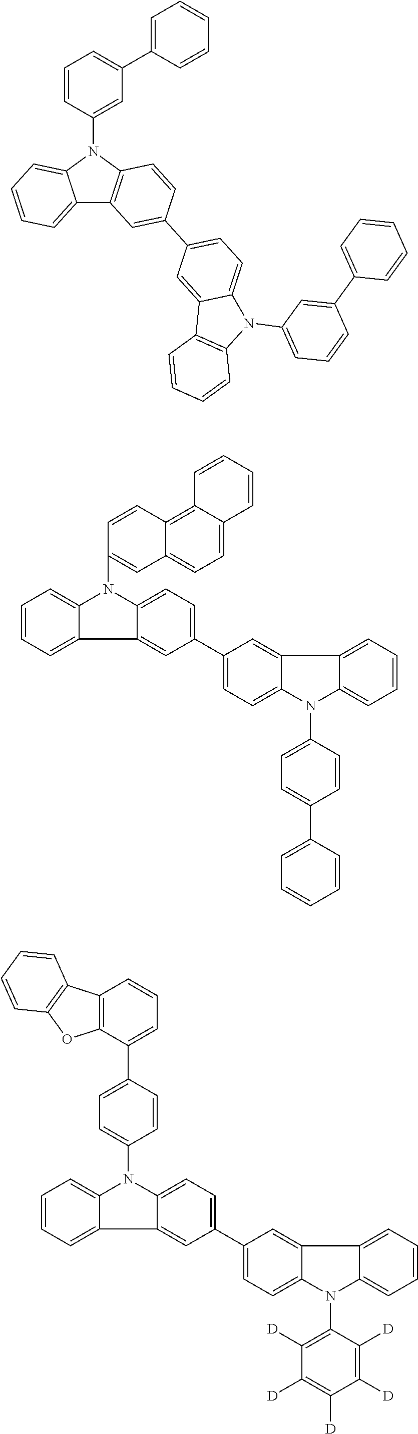 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccc(-n3c4ccccc4c4cc(-c5ccc6c(c5)c5ccccc5n6-c5ccc6c(ccc7ccccc76)c5)ccc43)cc2)cc1 ; [2H]c1c([2H])c([2H])c(-n2c3ccccc3c3cc(-c4ccc5c(c4)c4ccccc4n5-c4ccc(-c5cccc6c5oc5ccccc56)cc4)ccc32)c([2H])c1[2H]]

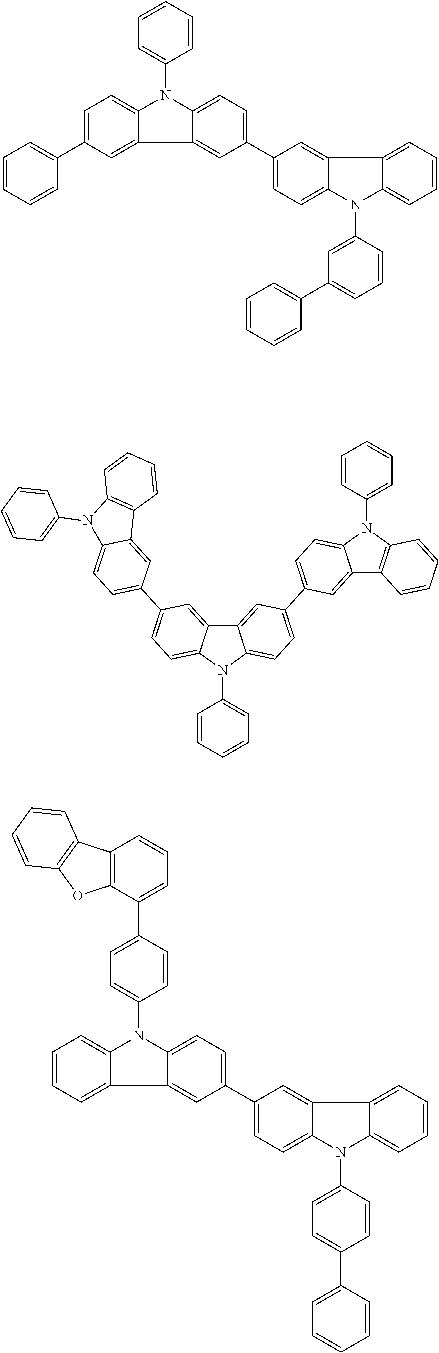 [SMILES: c1ccc(-c2cccc(-n3c4ccccc4c4cc(-c5ccc6c(c5)c5cc(-c7ccccc7)ccc5n6-c5ccccc5)ccc43)c2)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-c2ccc(-n3c4ccccc4c4cc(-c5ccc6c(c5)c5ccccc5n6-c5ccc(-c6cccc7c6oc6ccccc67)cc5)ccc43)cc2)cc1]

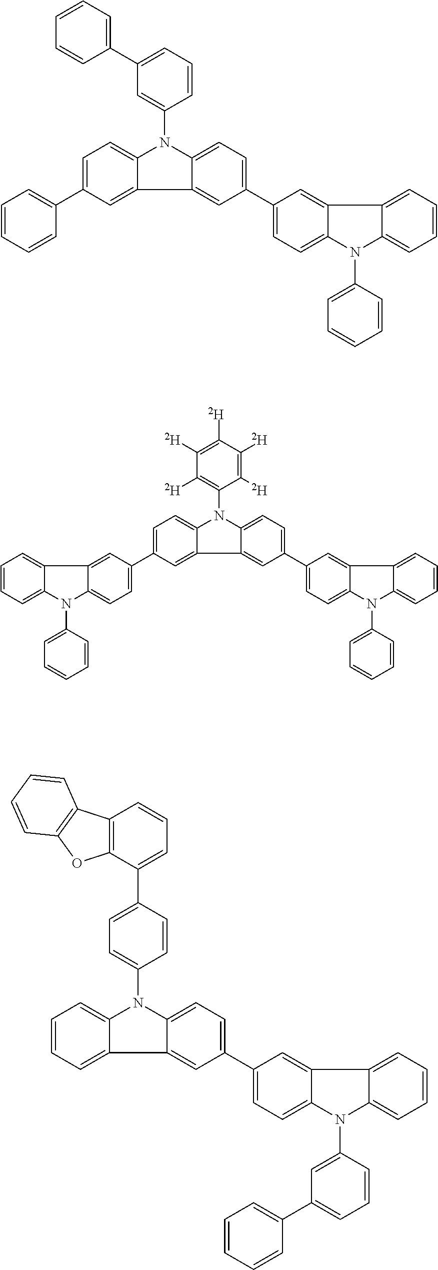 [SMILES: c1ccc(-c2cccc(-n3c4ccc(-c5ccccc5)cc4c4cc(-c5ccc6c(c5)c5ccccc5n6-c5ccccc5)ccc43)c2)cc1 ; [2H]c1c([2H])c([2H])c(-n2c3ccc(-c4ccc5c(c4)c4ccccc4n5-c4ccccc4)cc3c3cc(-c4ccc5c(c4)c4ccccc4n5-c4ccccc4)ccc32)c([2H])c1[2H] ; c1ccc(-c2cccc(-n3c4ccccc4c4cc(-c5ccc6c(c5)c5ccccc5n6-c5ccc(-c6cccc7c6oc6ccccc67)cc5)ccc43)c2)cc1]

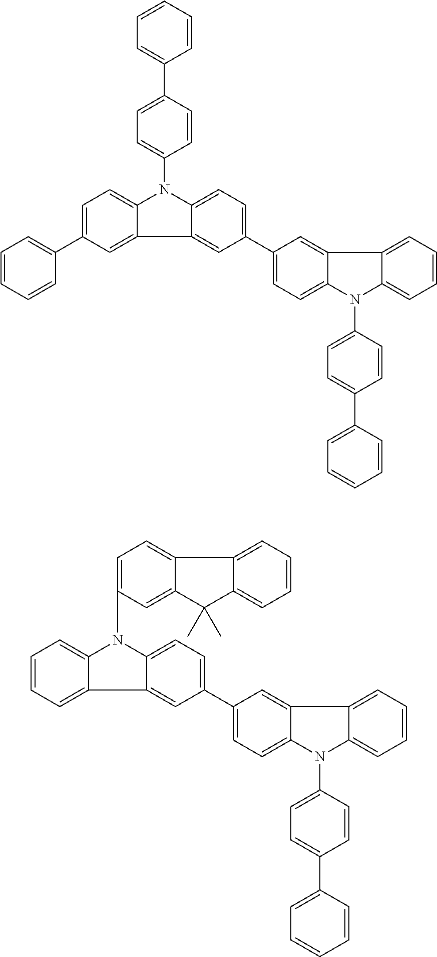 [SMILES: c1ccc(-c2ccc(-n3c4ccccc4c4cc(-c5ccc6c(c5)c5cc(-c7ccccc7)ccc5n6-c5ccc(-c6ccccc6)cc5)ccc43)cc2)cc1 ; CC1(C)c2ccccc2-c2ccc(-n3c4ccccc4c4cc(-c5ccc6c(c5)c5ccccc5n6-c5ccc(-c6ccccc6)cc5)ccc43)cc21]

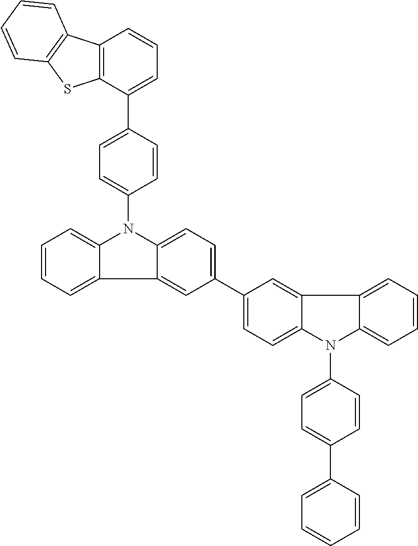 [SMILES: c1ccc(-c2ccc(-n3c4ccccc4c4cc(-c5ccc6c(c5)c5ccccc5n6-c5ccc(-c6cccc7c6sc6ccccc67)cc5)ccc43)cc2)cc1]

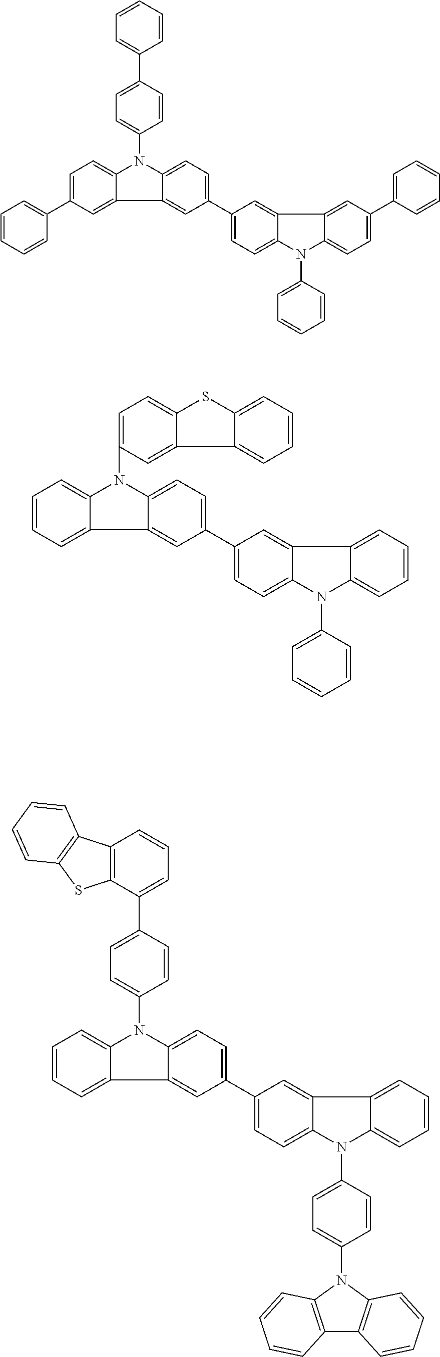 [SMILES: c1ccc(-c2ccc(-n3c4ccc(-c5ccccc5)cc4c4cc(-c5ccc6c(c5)c5cc(-c7ccccc7)ccc5n6-c5ccccc5)ccc43)cc2)cc1 ; c1ccc(-n2c3ccccc3c3cc(-c4ccc5c(c4)c4ccccc4n5-c4ccc5sc6ccccc6c5c4)ccc32)cc1 ; c1ccc2c(c1)sc1c(-c3ccc(-n4c5ccccc5c5cc(-c6ccc7c(c6)c6ccccc6n7-c6ccc(-n7c8ccccc8c8ccccc87)cc6)ccc54)cc3)cccc12]

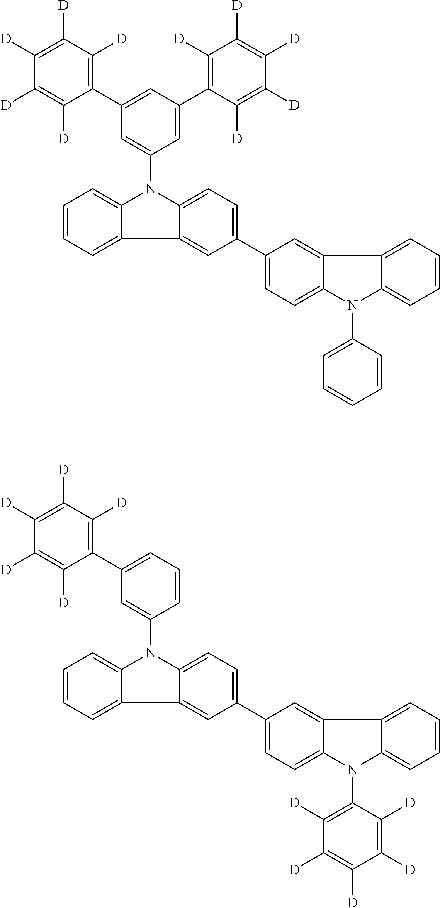 [SMILES: [2H]c1c([2H])c([2H])c(-c2cc(-c3c([2H])c([2H])c([2H])c([2H])c3[2H])cc(-n3c4ccccc4c4cc(-c5ccc6c(c5)c5ccccc5n6-c5ccccc5)ccc43)c2)c([2H])c1[2H] ; [2H]c1c([2H])c([2H])c(-c2cccc(-n3c4ccccc4c4cc(-c5ccc6c(c5)c5ccccc5n6-c5c([2H])c([2H])c([2H])c([2H])c5[2H])ccc43)c2)c([2H])c1[2H]]

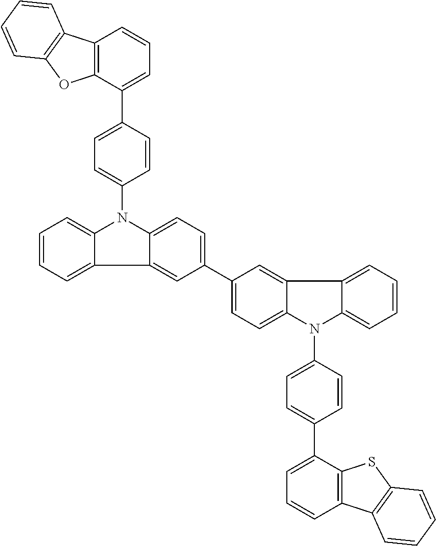 [SMILES: c1ccc2c(c1)oc1c(-c3ccc(-n4c5ccccc5c5cc(-c6ccc7c(c6)c6ccccc6n7-c6ccc(-c7cccc8c7sc7ccccc78)cc6)ccc54)cc3)cccc12]

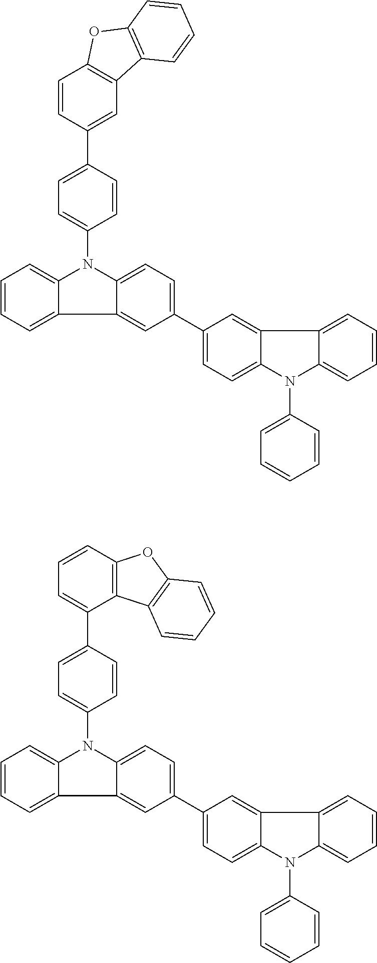 [SMILES: c1ccc(-n2c3ccccc3c3cc(-c4ccc5c(c4)c4ccccc4n5-c4ccc(-c5ccc6oc7ccccc7c6c5)cc4)ccc32)cc1 ; c1ccc(-n2c3ccccc3c3cc(-c4ccc5c(c4)c4ccccc4n5-c4ccc(-c5cccc6oc7ccccc7c56)cc4)ccc32)cc1]

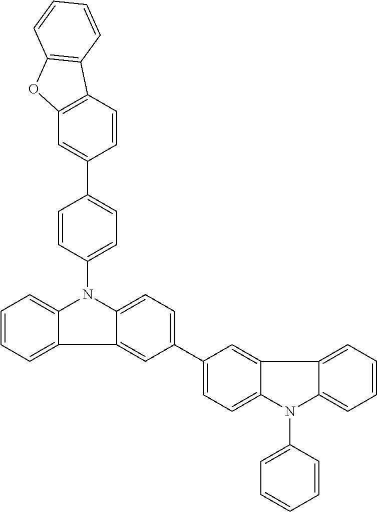 [SMILES: c1ccc(-n2c3ccccc3c3cc(-c4ccc5c(c4)c4ccccc4n5-c4ccc(-c5ccc6c(c5)oc5ccccc56)cc4)ccc32)cc1]

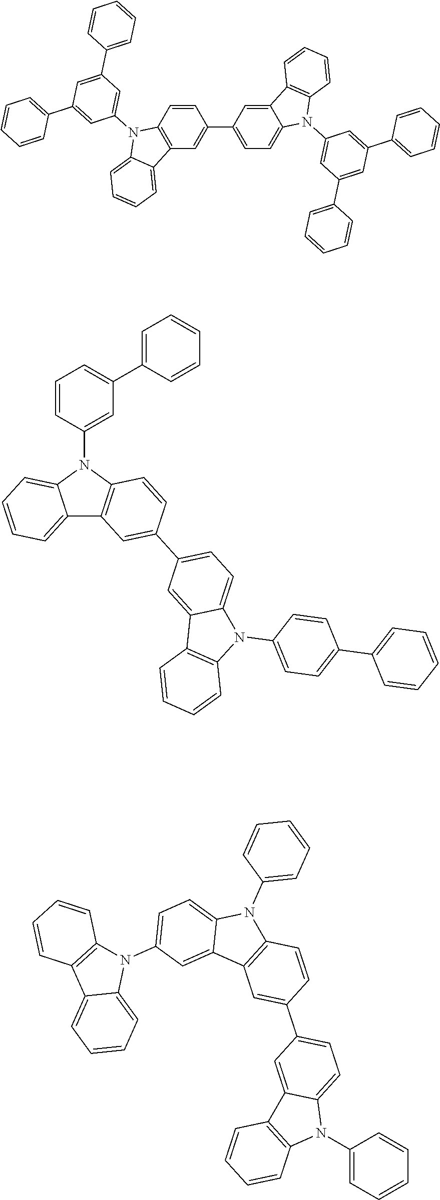 [SMILES: c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-n2c3ccccc3c3cc(-c4ccc5c(c4)c4cc(-n6c7ccccc7c7ccccc76)ccc4n5-c4ccccc4)ccc32)cc1]

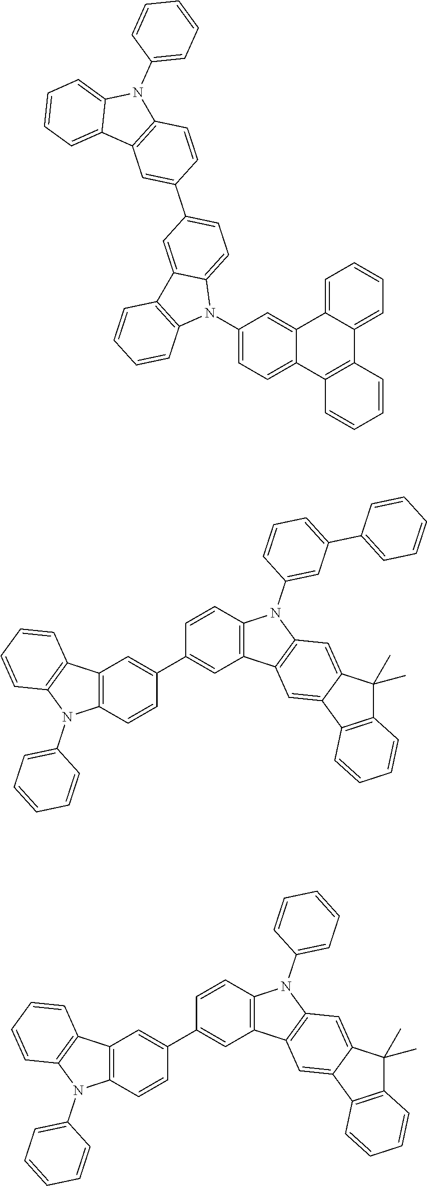 [SMILES: c1ccc(-n2c3ccccc3c3cc(-c4ccc5c(c4)c4ccccc4n5-c4ccc5c6ccccc6c6ccccc6c5c4)ccc32)cc1 ; CC1(C)c2ccccc2-c2cc3c4cc(-c5ccc6c(c5)c5ccccc5n6-c5ccccc5)ccc4n(-c4cccc(-c5ccccc5)c4)c3cc21 ; CC1(C)c2ccccc2-c2cc3c4cc(-c5ccc6c(c5)c5ccccc5n6-c5ccccc5)ccc4n(-c4ccccc4)c3cc21]

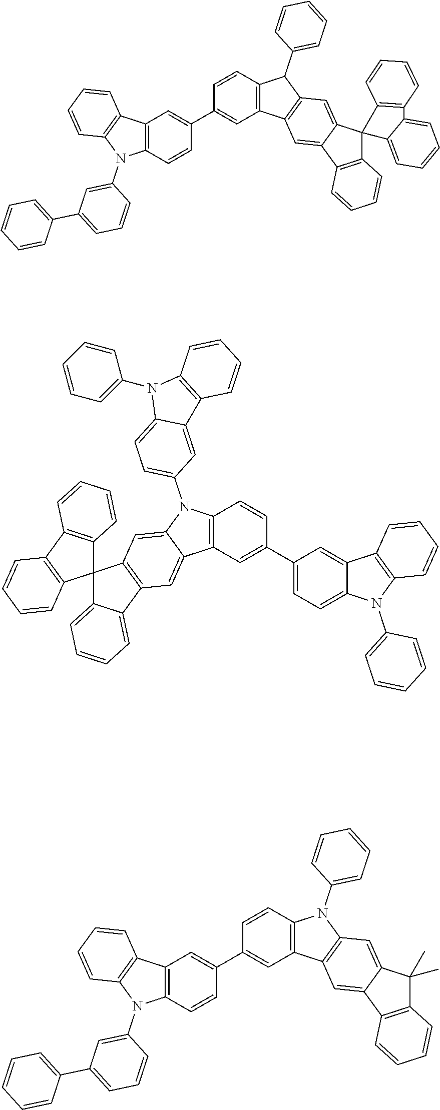 [SMILES: c1ccc(-c2cccc(-n3c4ccccc4c4cc(-c5ccc6c(c5)-c5cc7c(cc5C6c5ccccc5)C5(c6ccccc6-c6ccccc65)c5ccccc5-7)ccc43)c2)cc1 ; c1ccc(-n2c3ccccc3c3cc(-c4ccc5c(c4)c4cc6c(cc4n5-c4ccc5c(c4)c4ccccc4n5-c4ccccc4)C4(c5ccccc5-c5ccccc54)c4ccccc4-6)ccc32)cc1 ; CC1(C)c2ccccc2-c2cc3c4cc(-c5ccc6c(c5)c5ccccc5n6-c5cccc(-c6ccccc6)c5)ccc4n(-c4ccccc4)c3cc21]

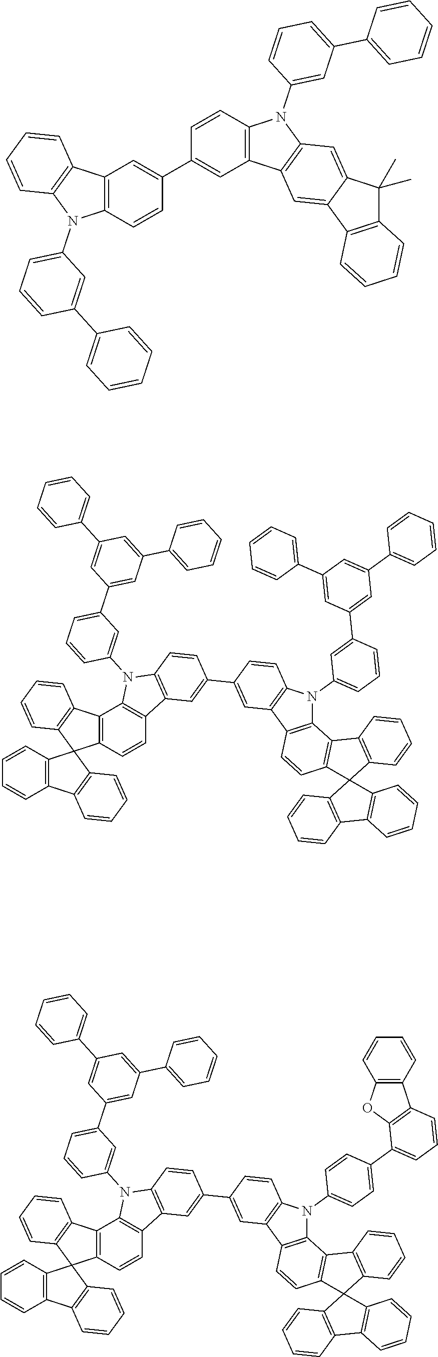 [SMILES: CC1(C)c2ccccc2-c2cc3c4cc(-c5ccc6c(c5)c5ccccc5n6-c5cccc(-c6ccccc6)c5)ccc4n(-c4cccc(-c5ccccc5)c4)c3cc21 ; c1ccc(-c2cc(-c3ccccc3)cc(-c3cccc(-n4c5ccc(-c6ccc7c(c6)c6ccc8c(c6n7-c6cccc(-c7cc(-c9ccccc9)cc(-c9ccccc9)c7)c6)-c6ccccc6C86c7ccccc7-c7ccccc76)cc5c5ccc6c(c54)-c4ccccc4C64c5ccccc5-c5ccccc54)c3)c2)cc1 ; c1ccc(-c2cc(-c3ccccc3)cc(-c3cccc(-n4c5ccc(-c6ccc7c(c6)c6ccc8c(c6n7-c6ccc(-c7cccc9c7oc7ccccc79)cc6)-c6ccccc6C86c7ccccc7-c7ccccc76)cc5c5ccc6c(c54)-c4ccccc4C64c5ccccc5-c5ccccc54)c3)c2)cc1]

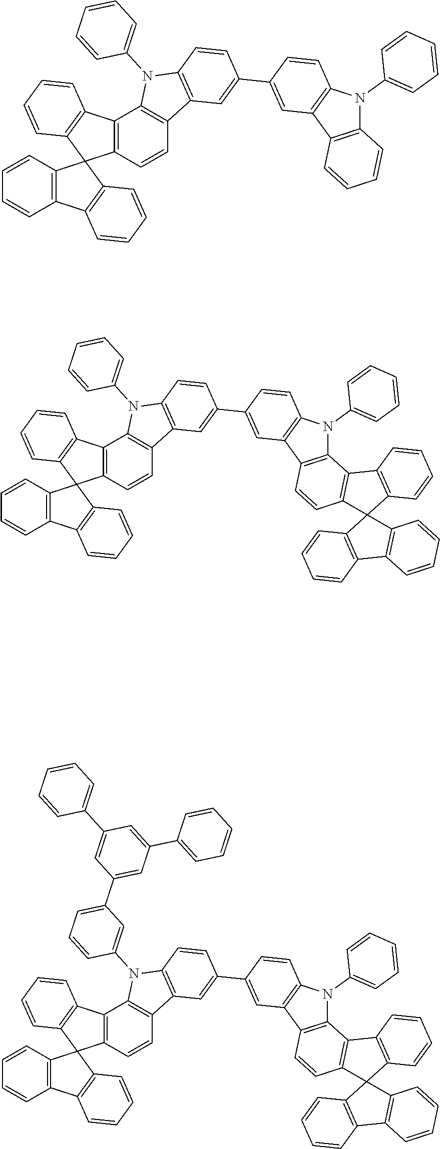 [SMILES: c1ccc(-n2c3ccccc3c3cc(-c4ccc5c(c4)c4ccc6c(c4n5-c4ccccc4)-c4ccccc4C64c5ccccc5-c5ccccc54)ccc32)cc1 ; c1ccc(-n2c3ccc(-c4ccc5c(c4)c4ccc6c(c4n5-c4ccccc4)-c4ccccc4C64c5ccccc5-c5ccccc54)cc3c3ccc4c(c32)-c2ccccc2C42c3ccccc3-c3ccccc32)cc1 ; c1ccc(-c2cc(-c3ccccc3)cc(-c3cccc(-n4c5ccc(-c6ccc7c(c6)c6ccc8c(c6n7-c6ccccc6)-c6ccccc6C86c7ccccc7-c7ccccc76)cc5c5ccc6c(c54)-c4ccccc4C64c5ccccc5-c5ccccc54)c3)c2)cc1]

Preferred bridged carbazoles are the structures of the following formula (25):

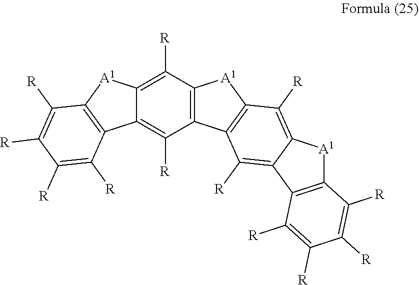

where A¹ and R have the definitions given above and A¹ is preferably the same or different at each instance and is selected from the group consisting of NAr¹ and CR₂.

Preferred dibenzofuran derivatives are the compounds of the following formula (26):

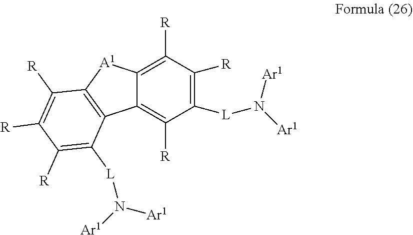

where the oxygen may also be replaced by sulfur so as to form a dibenzothiophene, L is a single bond or an aromatic or heteroaromatic ring system which has 5 to 30 aromatic ring atoms and may also be substituted by one or more R radicals, and R and Ar¹ have the definitions given above. It is also possible here for the two Ar¹ groups that bind to the same nitrogen atom, or for one Ar¹ group and one L group that bind to the same nitrogen atom, to be bonded to one another, for example to give a carbazole.

Examples of suitable dibenzofuran derivatives are the compounds depicted below.

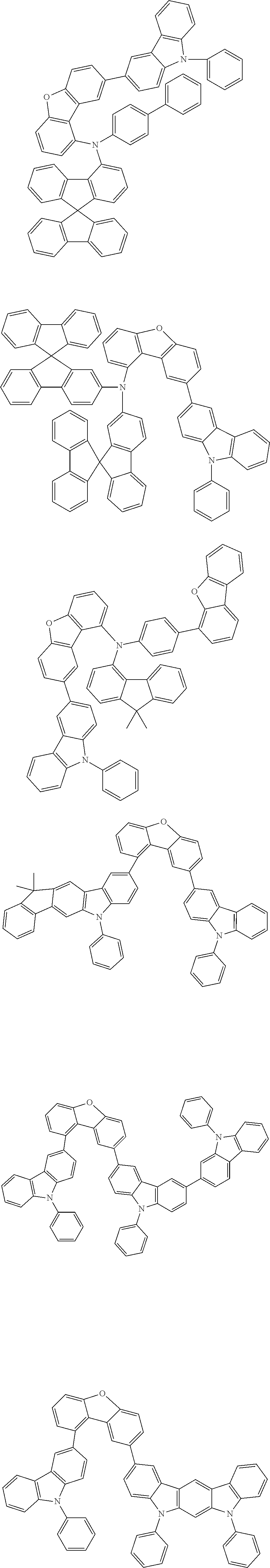

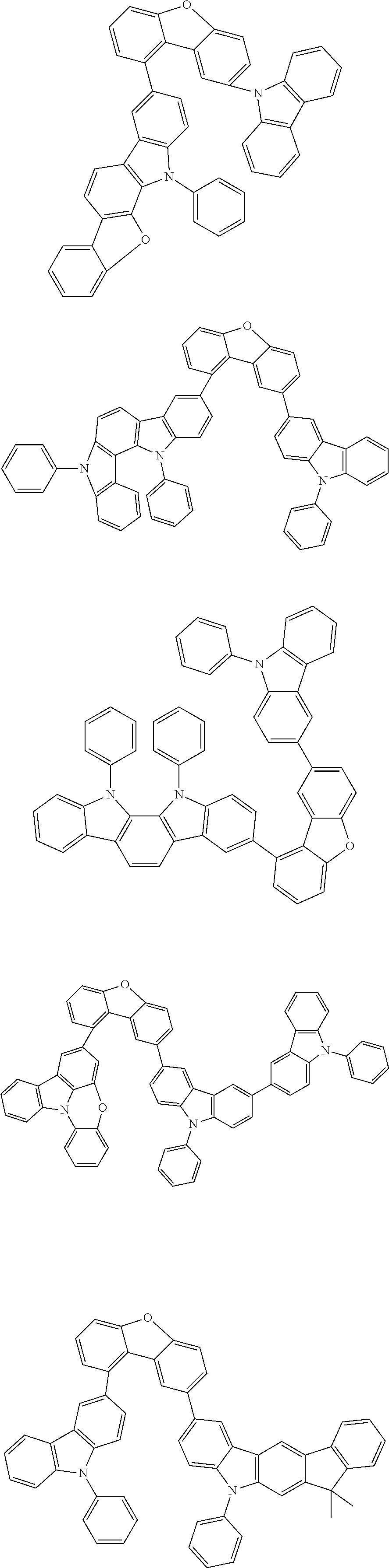

Suitable compounds that can be used as wide bandgap matrix materials are the compounds of the following formula (27):

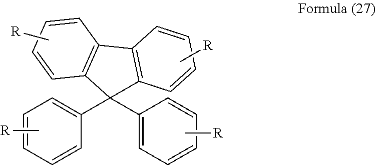

where R has the definitions given above and is preferably the same or different at each instance and is H, D, a linear alkyl group having 1 to 10 carbon atoms, a branched or cyclic alkyl group having 3 to 10 carbon atoms or an aromatic ring system having 6 to 24 aromatic ring atoms, which may also be substituted by one or more alkyl groups having 1 to 10 carbon atoms, but is preferably unsubstituted.

Examples of materials which can be used as wide bandgap matrix materials:

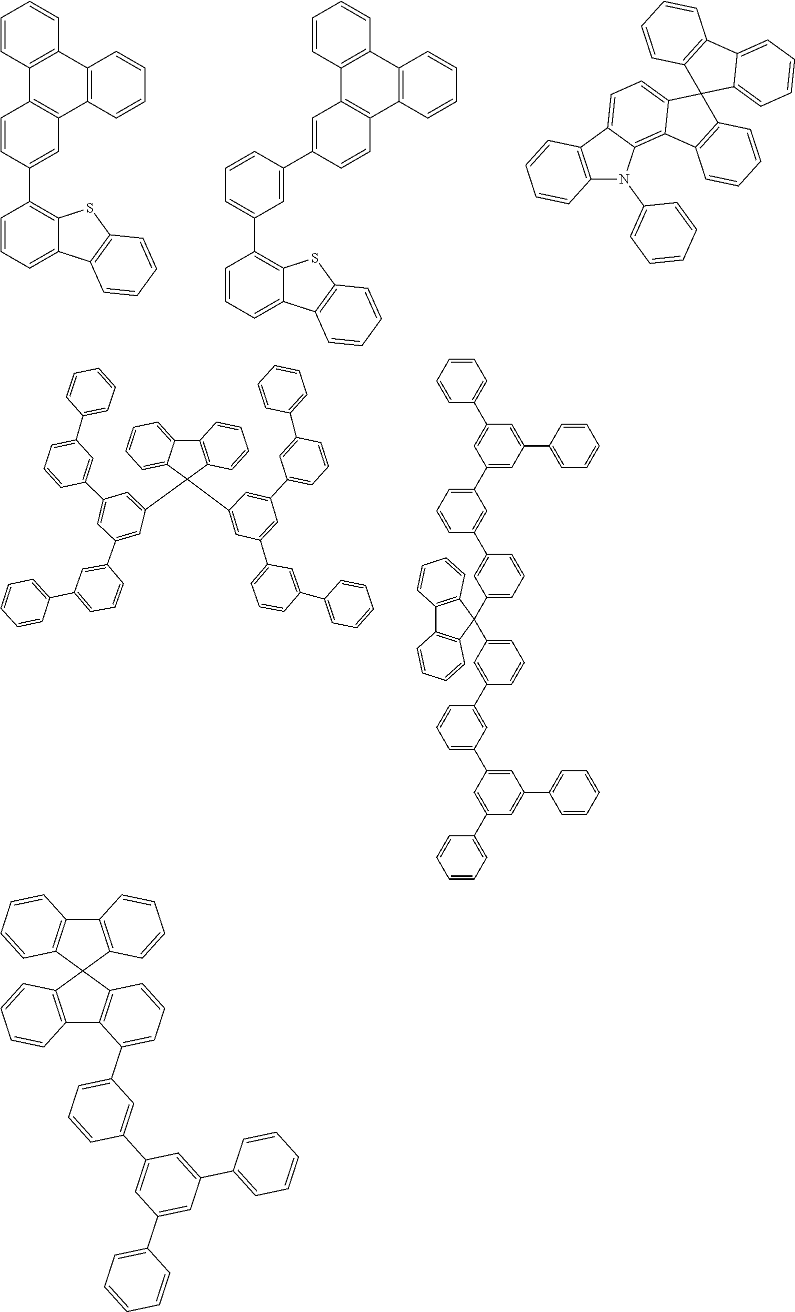

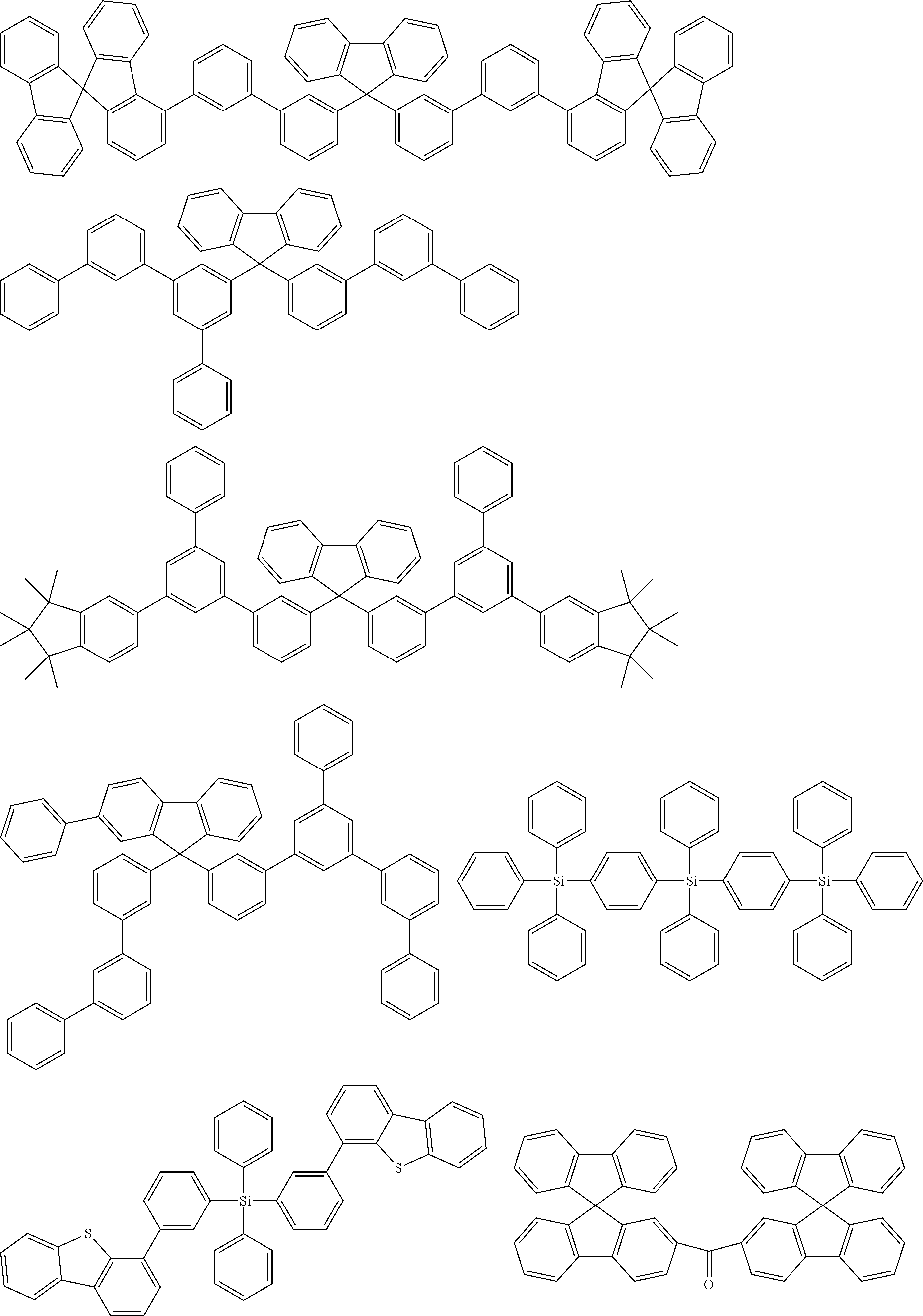

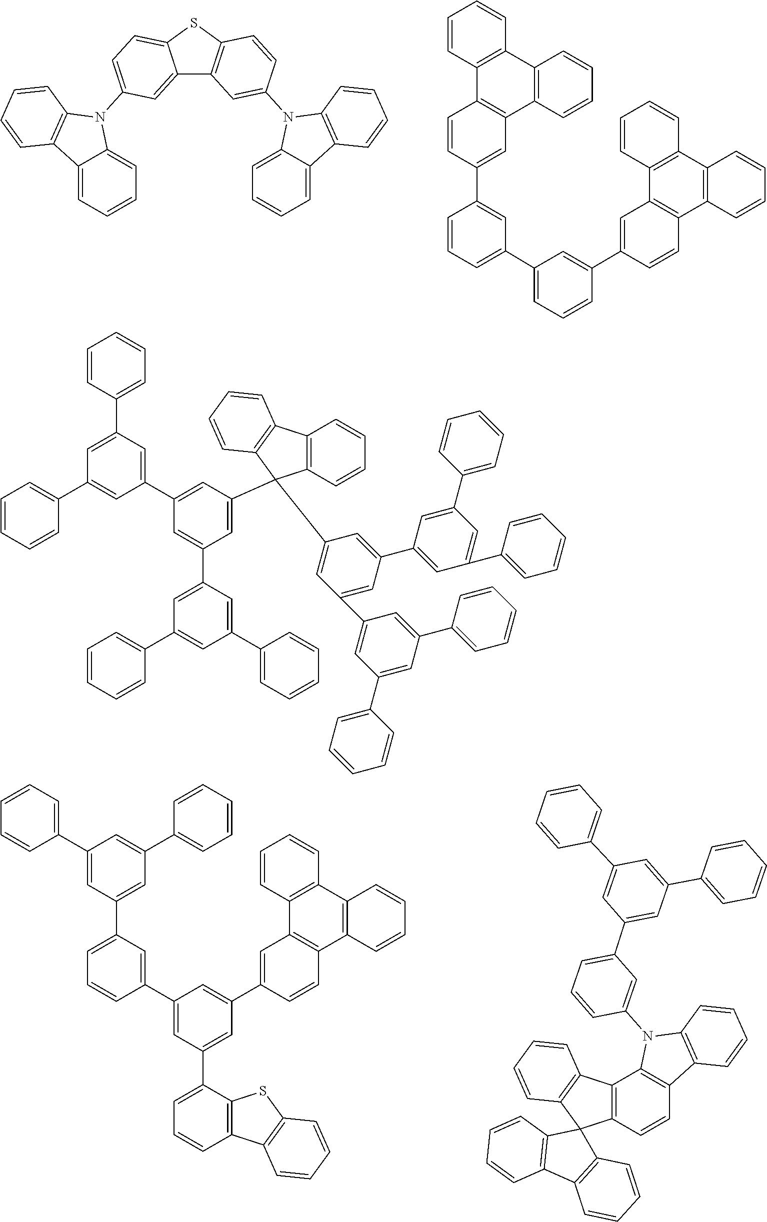

It is further preferable to use a mixture of two or more triplet emitters, especially two triplet emitters, together with one or more matrix materials.

In this case, the triplet emitter having the shorter-wave emission spectrum serves as co-matrix for the triplet emitter having the longer-wave emission spectrum. In the present case, in general, the compound of the formula (1) is the triplet emitter having the longer-wave emission maximum. For example, the compounds of the invention can be combined with a metal complex emitting at shorter wavelength, for example a blue-, green- or yellow-emitting metal complex, as co-matrix.

A preferred mixture in the emitting layer comprises an electron-transporting host material, what is called a “wide bandgap” host material which, owing to its electronic properties, is not involved to a significant degree, if at all, in the charge transport in the layer, a co-dopant which is a triplet emitter which emits at a shorter wavelength than the compound of the invention, and a compound of the invention.

A further preferred mixture in the emitting layer comprises an electron-transporting host material, what is called a “wide bandgap” host material which, owing to its electronic properties, is not involved to a significant degree, if at all, in the charge transport in the layer, a hole-transporting host material, a co-dopant which is a triplet emitter which emits at a shorter wavelength than the compound of the invention, and a compound of the invention.

Examples of the emitters described above can be found in applications WO 00/70655, WO 2001/41512, WO 2002/02714, WO 2002/15645, EP 1191613, EP 1191612, EP 1191614, WO 05/033244, WO 05/019373, US 2005/0258742, WO 2009/146770, WO 2010/015307, WO 2010/031485, WO 2010/054731, WO 2010/054728, WO 2010/086089, WO 2010/099852, WO 2010/102709, WO 2011/032626, WO 2011/066898, WO 2011/157339, WO 2012/007086, WO 2014/008982, WO 2014/023377, WO 2014/094961, WO 2014/094960, WO 2015/036074, WO 2015/104045, WO 2015/117718, WO 2016/015815, WO 2016/124304, WO 2017/032439, WO 2018/011186, WO 2018/041769, WO 2019/020538, WO 2018/178001, WO 2019/115423 and WO 2019/158453. In general, all phosphorescent complexes as used for phosphorescent OLEDs according to the prior art and as known to those skilled in the art in the field of organic electroluminescence are suitable, and the person skilled in the art will be able to use further phosphorescent complexes without exercising inventive skill.

Examples of suitable triplet emitters that may be used as co-dopants for the compounds of the invention are depicted in the table below.

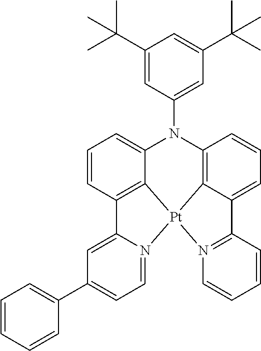

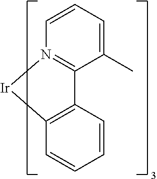

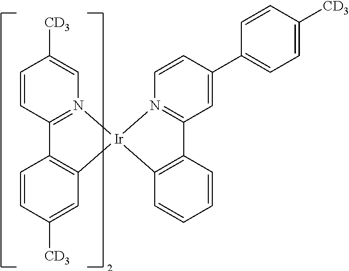

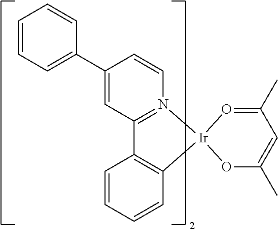

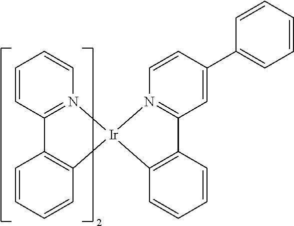

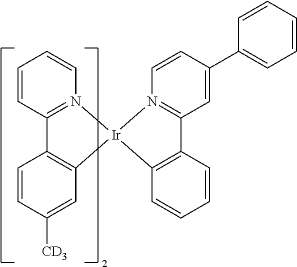

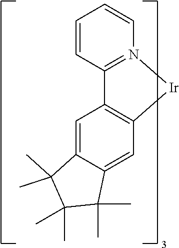

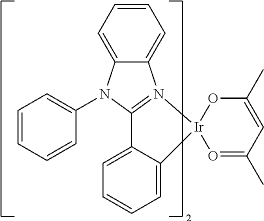

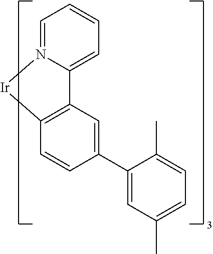

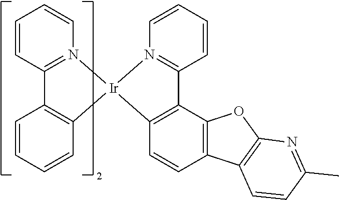

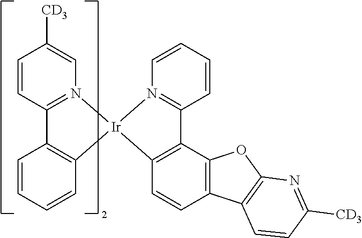

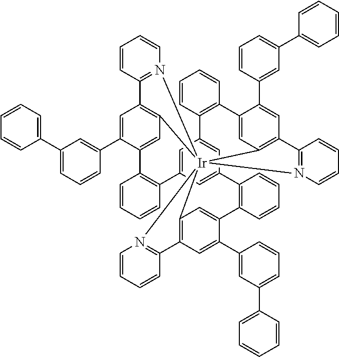

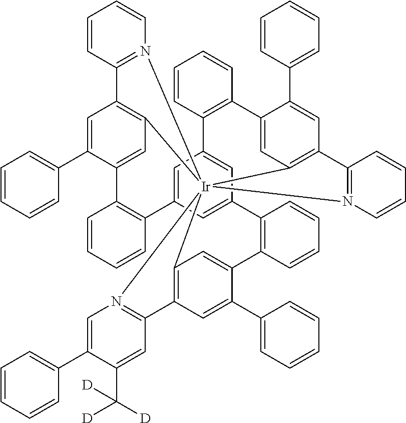

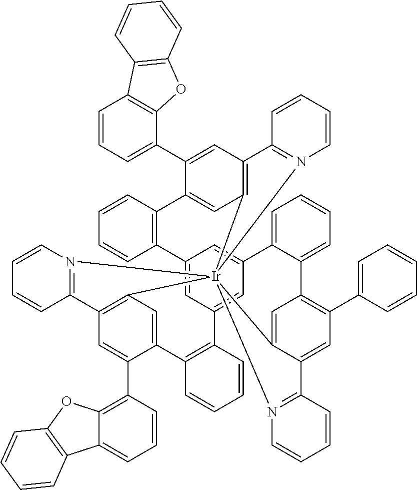

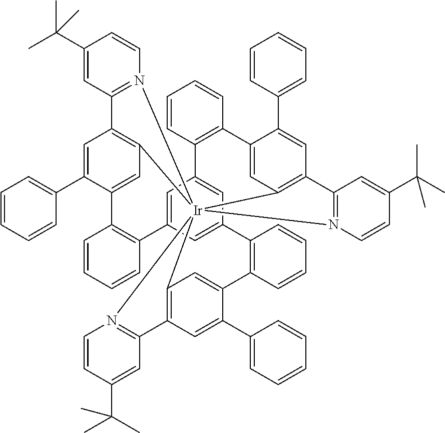

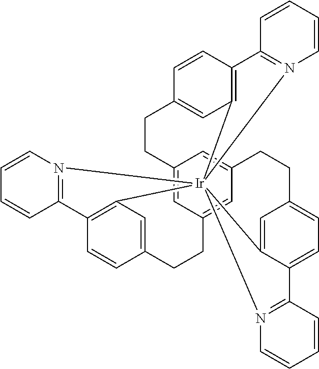

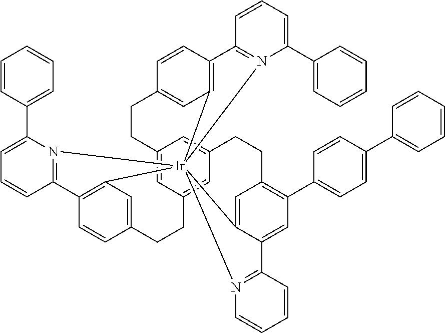

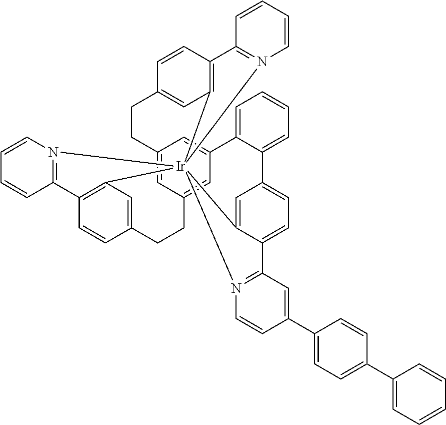

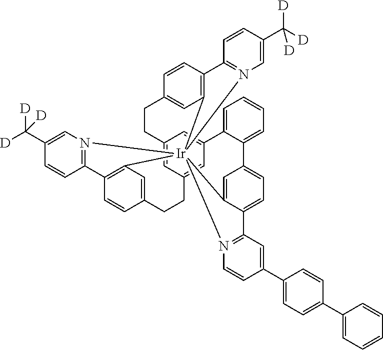

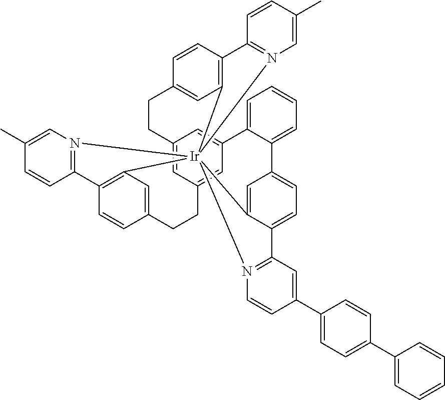

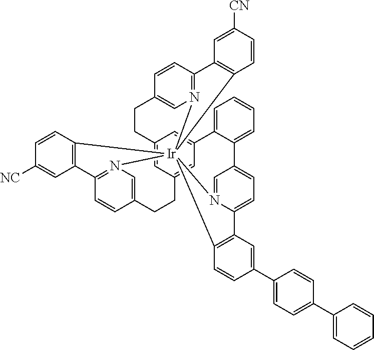

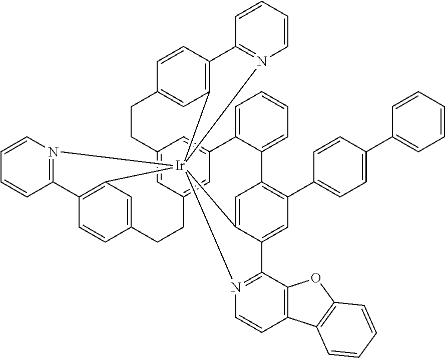

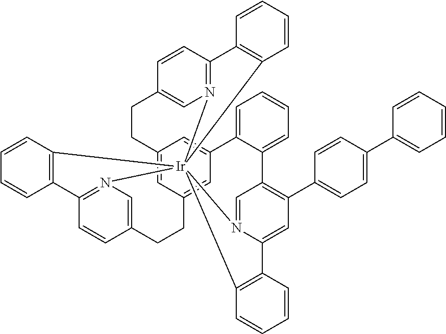

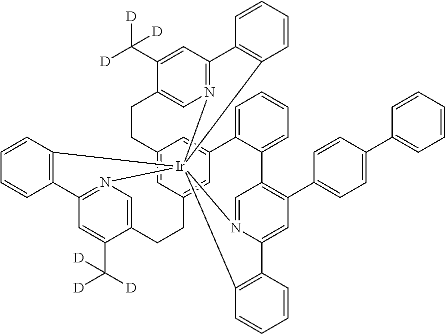

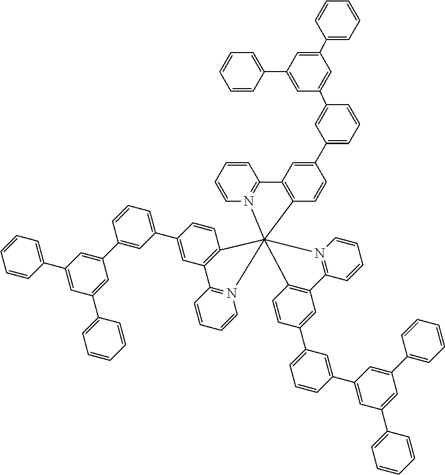

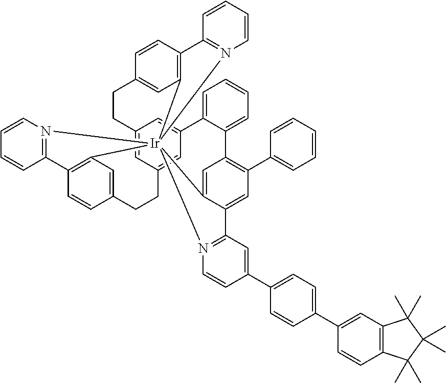

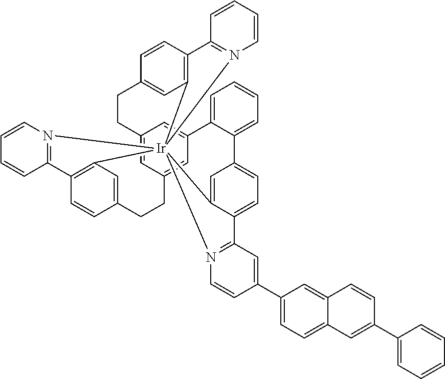

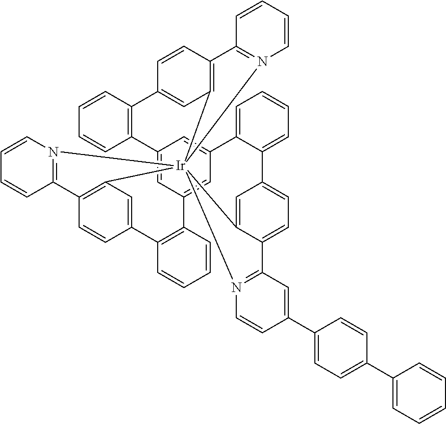

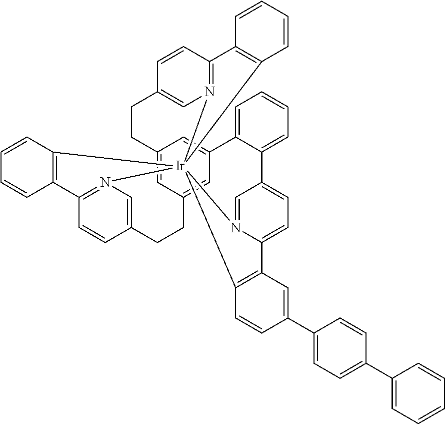

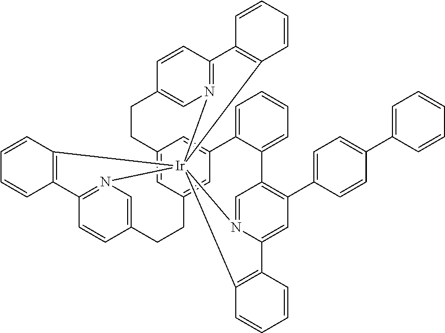

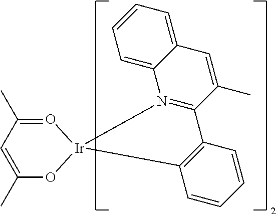

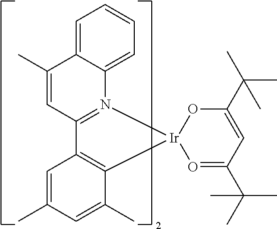

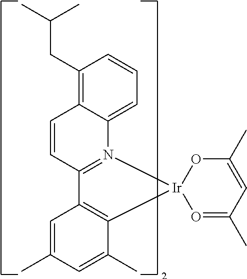

Preferred cathodes are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Mg/Ag, Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). Likewise useful for this purpose are organic alkali metal complexes, e.g. Liq (lithium quinolinate). The layer thickness of this layer is preferably between 0.5 and 5 nm.

Preferred anodes are materials having a high work function. Preferably, the anode has a work function of greater than 4.5 eV versus vacuum.

Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (O-SC) or the emission of light (OLED/PLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers, for example PEDOT, PANI or derivatives of these polymers. It is further preferable when a p-doped hole transport material is applied to the anode as hole injection layer, in which case suitable p-dopants are metal oxides, for example MoO₃ or WO₃, or (per)fluorinated electron-deficient aromatic systems. Further suitable p-dopants are HAT-CN (hexacyanohexaazatriphenylene) or the compound NPD9 from Novaled. Such a layer simplifies hole injection into materials having a low HOMO, i.e. a large HOMO in terms of magnitude.

In the further layers, it is generally possible to use any materials as used according to the prior art for the layers, and the person skilled in the art is able, without exercising inventive skill, to combine any of these materials with the materials of the invention in an electronic device.

The device is correspondingly (according to the application) structured, contact-connected and finally hermetically sealed, since the lifetime of such devices is severely shortened in the presence of water and/or air.

Additionally preferred is an organic electroluminescent device, characterized in that one or more layers are coated by a sublimation process. In this case, the materials are applied by vapour deposition in vacuum sublimation systems at an initial pressure of typically less than 10⁻⁵ mbar, preferably less than 10⁻⁶ mbar. It is also possible that the initial pressure is even lower or even higher, for example less than 10⁻⁷ mbar.

Preference is likewise given to an organic electroluminescent device, characterized in that one or more layers are coated by the OVPD (organic vapour phase deposition) method or with the aid of a carrier gas sublimation. In this case, the materials are applied at a pressure between 10⁻⁵ mbar and 1 bar. A special case of this method is the OVJP (organic vapour jet printing) method, in which the materials are applied directly by a nozzle and thus structured.

Preference is additionally given to an organic electroluminescent device, characterized in that one or more layers are produced from solution, for example by spin-coating, or by any printing method, for example screen printing, flexographic printing, offset printing or nozzle printing, but more preferably LITI (light-induced thermal imaging, thermal transfer printing) or inkjet printing. For this purpose, soluble compounds are needed, which are obtained, for example, through suitable substitution. In a preferred embodiment of the invention, the layer comprising the compound of the invention is applied from solution.

The organic electroluminescent device can also be produced as a hybrid system by applying one or more layers from solution and applying one or more other layers by vapour deposition. For example, it is possible to apply a hole transport layer and an emitting layer containing a compound of the invention and a matrix material from solution, and to apply a hole blocker layer and/or an electron transport layer thereto by vapour deposition under reduced pressure.

These methods are known in general terms to those skilled in the art and can be applied by those skilled in the art without difficulty to organic electroluminescent devices comprising compounds of formula (1) or the above-detailed preferred embodiments.

The electronic devices of the invention, especially organic electroluminescent devices, are notable with respect to the prior art in that they can be applied in an oriented manner even in the case of application from solution, which leads to oriented emission and hence to an improvement in external quantum efficiency. This is true by comparison with complexes that are otherwise of the same structure but do not have any X groups. This benefit is not accompanied by any deterioration in the further electronic properties.

The invention is illustrated in more detail by the examples which follow, without any intention of restricting it thereby. The person skilled in the art will be able to use the details given, without exercising inventive skill, to produce further electronic devices of the invention and hence to execute the invention over the entire scope claimed.

### EXAMPLES

The syntheses which follow, unless stated otherwise, are conducted under a protective gas atmosphere in dried solvents. The metal complexes are additionally handled with exclusion of light or under yellow light. The solvents and reagents can be purchased, for example, from Sigma-ALDRICH or ABCR. The respective figures in square brackets or the numbers quoted for individual compounds relate to the CAS numbers of the compounds known from the literature.

Synthesis of the X Groups:

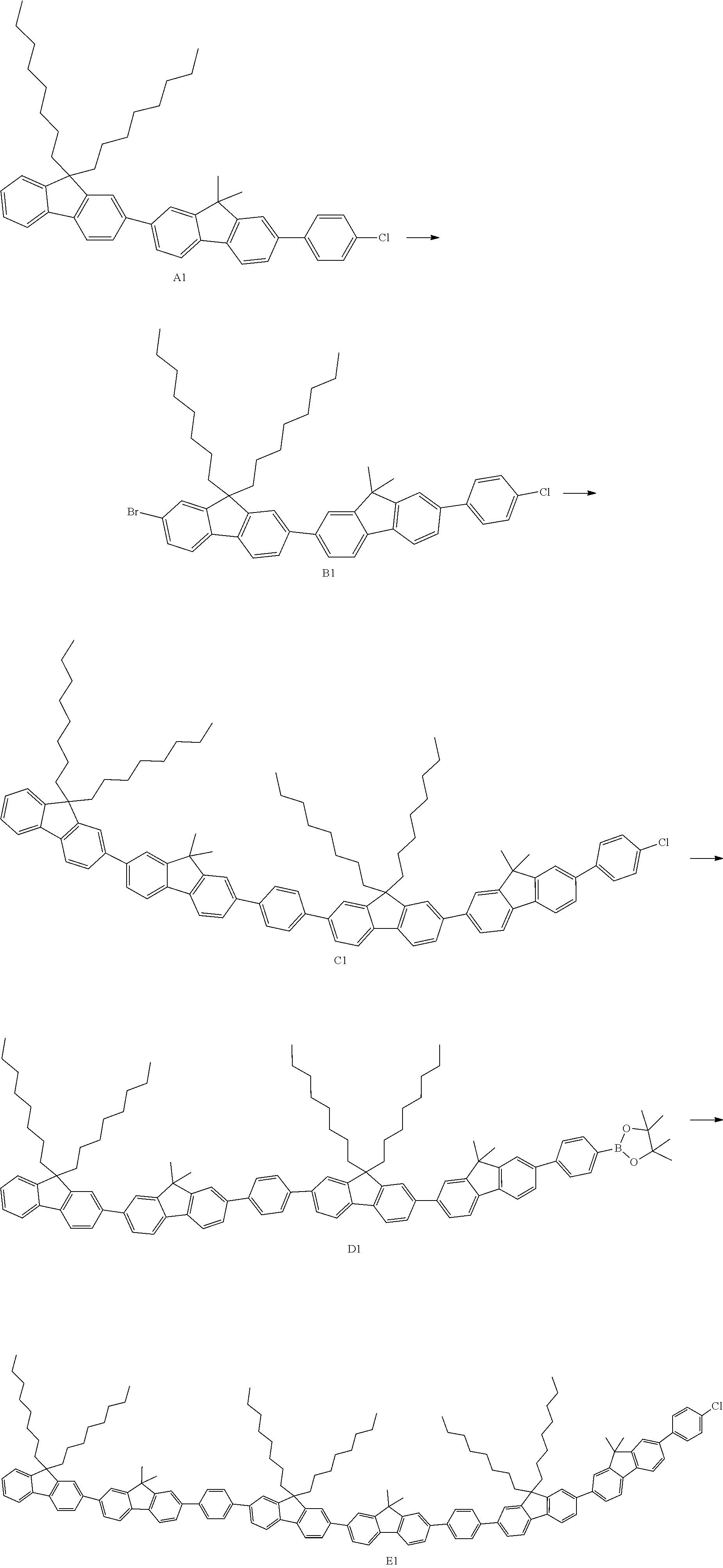

Synthesis of B1

26 g (33.7 mmol) of A1 (CAS 2171483-83-1) is dissolved in 600 ml of dichloromethane. Subsequently, 7.2 g (44 mmol) of N-bromosuccinimide is added in portions, one drop of HBr is added and the mixture is stirred at room temperature. After 48 h, 200 ml of aqueous sodium hydrogensulfite solution (30%) is added and the mixture is stirred for 1 h. Subsequently, the two phases are separated, and the organic phase is extracted with water and then concentrated under reduced pressure. The residue is admixed with 300 ml of n-heptane and refluxed for 1 h. After the mixture has been cooled, the colourless solids are filtered and dried under reduced pressure. Yield: 25.3 g (32 mmol), corresponding to 97% of theory.

The following compounds can be prepared analogously:

| | Reactant | Product |
|---|---|---|
| B2 | 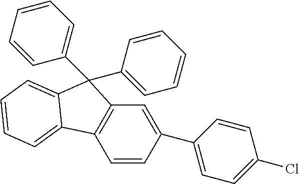 [SMILES: Clc1ccc(-c2ccc3c(c2)C(c2ccccc2)(c2ccccc2)c2ccccc2-3)cc1] | 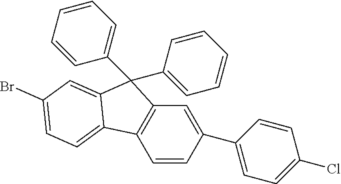 [SMILES: Clc1ccc(-c2ccc3c(c2)C(c2ccccc2)(c2ccccc2)c2cc(Br)ccc2-3)cc1] |
| | CAS 1221237-90-6 | |
| B3 | 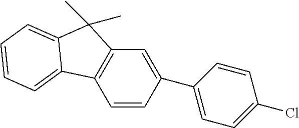 [SMILES: CC1(C)c2ccccc2-c2ccc(-c3ccc(Cl)cc3)cc21] | 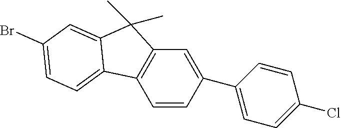 [SMILES: CC1(C)c2cc(Br)ccc2-c2ccc(-c3ccc(Cl)cc3)cc21] |
| | CAS 1221237-82-6 | |
| B4 | 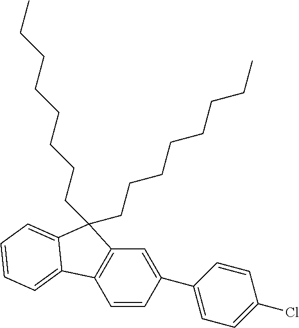 [SMILES: CCCCCCCCC1(CCCCCCCC)c2ccccc2-c2ccc(-c3ccc(Cl)cc3)cc21] | 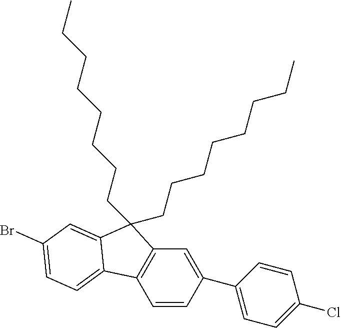 [SMILES: CCCCCCCCC1(CCCCCCCC)c2cc(Br)ccc2-c2ccc(-c3ccc(Cl)cc3)cc21] |
| | CAS1706803-15-7 | |
| B5 | 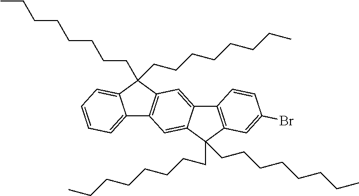 [SMILES: CCCCCCCCC1(CCCCCCCC)c2ccccc2-c2cc3c(cc21)-c1ccc(Br)cc1C3(CCCCCCCC)CCCCCCCC] CAS 929198-27-6 | With NCS rather than NBS 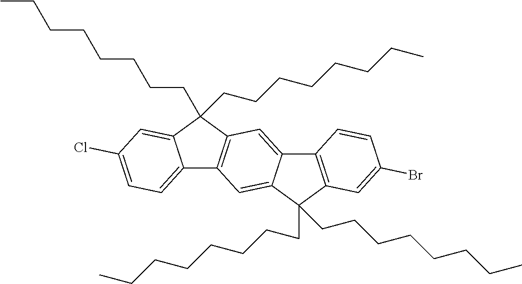 [SMILES: CCCCCCCCC1(CCCCCCCC)c2cc(Cl)ccc2-c2cc3c(cc21)-c1ccc(Br)cc1C3(CCCCCCCC)CCCCCCCC] |
| B6 | C1 | 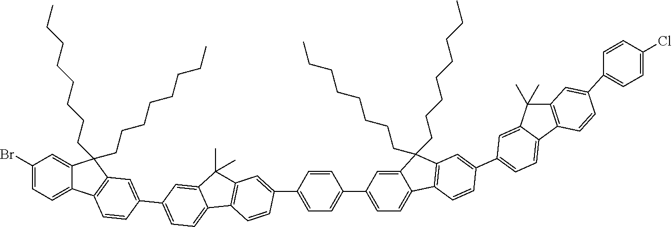 [SMILES: CCCCCCCCC1(CCCCCCCC)c2cc(Br)ccc2-c2ccc(-c3ccc4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc(Cl)cc%10)ccc8-9)ccc6-7)cc5)ccc3-4)cc21] |
| B7 | C2 | 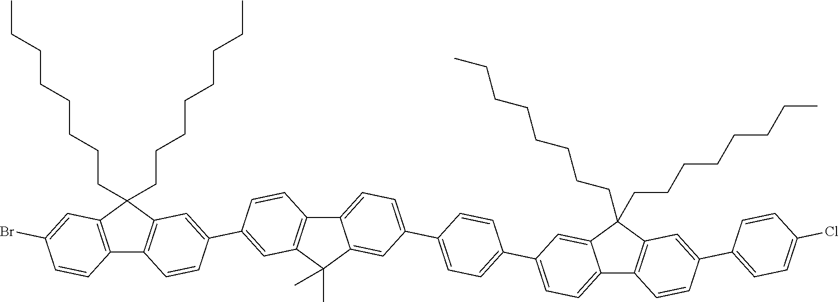 [SMILES: CCCCCCCCC1(CCCCCCCC)c2cc(Br)ccc2-c2ccc(-c3ccc4c(c3)C(C)(C)c3cc(-c5ccc(-c6ccc7c(c6)C(CCCCCCCC)(CCCCCCCC)c6cc(-c8ccc(Cl)cc8)ccc6-7)cc5)ccc3-4)cc21] |
| B8 | C3 | 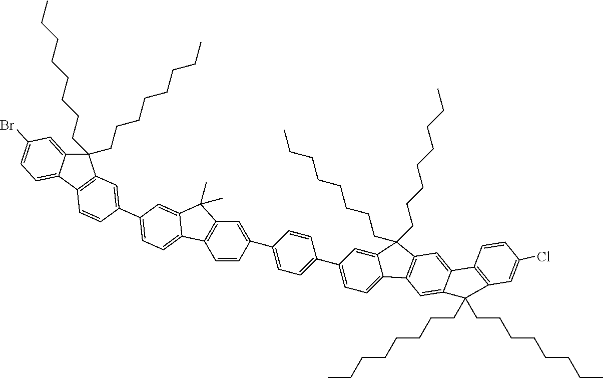 [SMILES: CCCCCCCCC1(CCCCCCCC)c2cc(Br)ccc2-c2ccc(-c3ccc4c(c3)C(C)(C)c3cc(-c5ccc(-c6ccc7c(c6)C(CCCCCCCC)(CCCCCCCC)c6cc8c(cc6-7)C(CCCCCCCC)(CCCCCCCC)c6cc(Cl)ccc6-8)cc5)ccc3-4)cc21] |
| B9 | C4 | 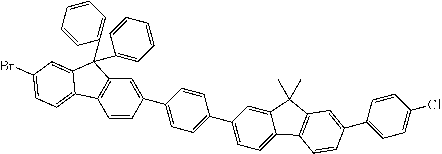 [SMILES: CC1(C)c2cc(-c3ccc(Cl)cc3)ccc2-c2ccc(-c3ccc(-c4ccc5c(c4)C(c4ccccc4)(c4ccccc4)c4cc(Br)ccc4-5)cc3)cc21] |
| B10 | C5 | 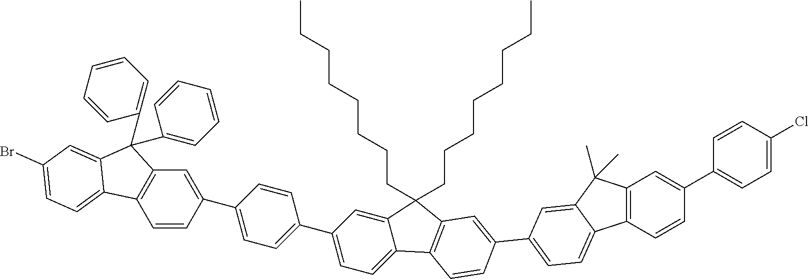 [SMILES: CCCCCCCCC1(CCCCCCCC)c2cc(-c3ccc(-c4ccc5c(c4)C(c4ccccc4)(c4ccccc4)c4cc(Br)ccc4-5)cc3)ccc2-c2ccc(-c3ccc4c(c3)C(C)(C)c3cc(-c5ccc(Cl)cc5)ccc3-4)cc21] |
| B11 | C6 | 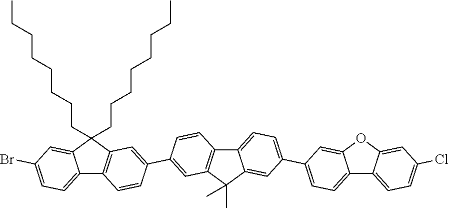 [SMILES: CCCCCCCCC1(CCCCCCCC)c2cc(Br)ccc2-c2ccc(-c3ccc4c(c3)C(C)(C)c3cc(-c5ccc6c(c5)oc5cc(Cl)ccc56)ccc3-4)cc21] |
| B12 | C7 | 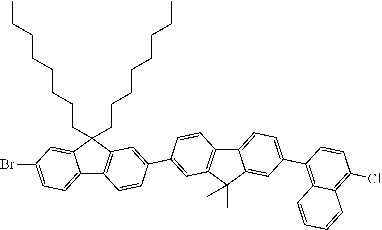 [SMILES: CCCCCCCCC1(CCCCCCCC)c2cc(Br)ccc2-c2ccc(-c3ccc4c(c3)C(C)(C)c3cc(-c5ccc(Cl)c6ccccc56)ccc3-4)cc21] |
| B13 | C8 | 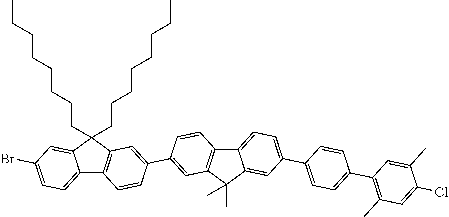 [SMILES: CCCCCCCCC1(CCCCCCCC)c2cc(Br)ccc2-c2ccc(-c3ccc4c(c3)C(C)(C)c3cc(-c5ccc(-c6cc(C)c(Cl)cc6C)cc5)ccc3-4)cc21] |
| B14 | C13 | 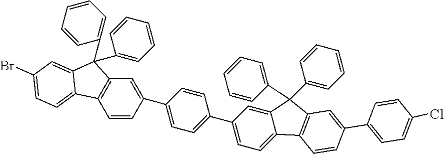 [SMILES: Clc1ccc(-c2ccc3c(c2)C(c2ccccc2)(c2ccccc2)c2cc(-c4ccc(-c5ccc6c(c5)C(c5ccccc5)(c5ccccc5)c5cc(Br)ccc5-6)cc4)ccc2-3)cc1] |

Synthesis of C1:

To 28.0 g (35.5 mmol) of B1, 33.6 g (35.5 mmol) of CAS 2171483-74-0 and 9.8 g (71 mmol) of potassium carbonate are added 1100 ml of THE and 550 ml of water. Subsequently, 373 mg (1.4 mmol) of triphenylphosphine and 325 mg (0.4 mmol) of tri(dibenzylideneacetone)dipalladium are added and the mixture is refluxed for 16 h. Subsequently, water and toluene are added to the reaction mixture, and the phases are separated. The aqueous phase is extracted twice with toluene and the combined organic phases are extracted once with water. The organic phase is filtered through alumina and then concentrated under reduced pressure. The product is purified by repeated crystallization from toluene/n-heptane 1:10 and obtained in solid form.

Yield: 41.0 g (28.8 mmol); 81% of theory.

The following compounds can be prepared analogously:

| | Boronic | | |
|---|---|---|---|
| | ester | Bromide | Product |
| C2 | CAS 2171483- 74-0 | B4 | 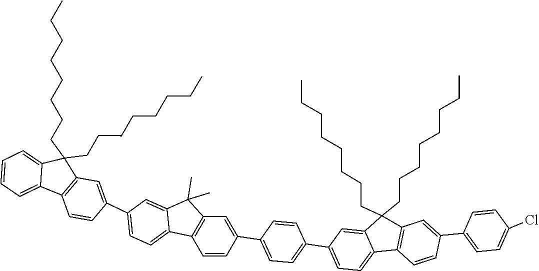 [SMILES: CCCCCCCCC1(CCCCCCCC)c2ccccc2-c2ccc(-c3ccc4c(c3)C(C)(C)c3cc(-c5ccc(-c6ccc7c(c6)C(CCCCCCCC)(CCCCCCCC)c6cc(-c8ccc(Cl)cc8)ccc6-7)cc5)ccc3-4)cc21] |
| C3 | CAS 2171483- 74-0 | B5 | 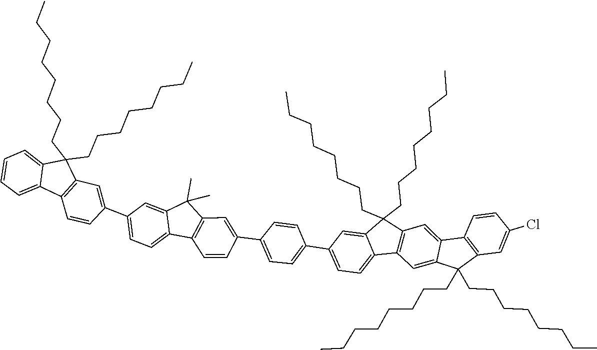 [SMILES: CCCCCCCCC1(CCCCCCCC)c2ccccc2-c2ccc(-c3ccc4c(c3)C(C)(C)c3cc(-c5ccc(-c6ccc7c(c6)C(CCCCCCCC)(CCCCCCCC)c6cc8c(cc6-7)C(CCCCCCCC)(CCCCCCCC)c6cc(Cl)ccc6-8)cc5)ccc3-4)cc21] |
| C4 | CAS 1813574- 72-9 | B3 | 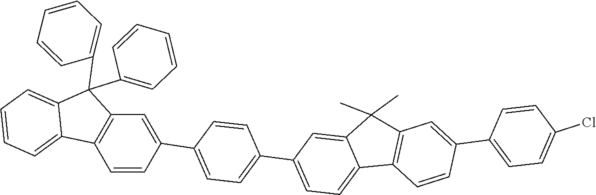 [SMILES: CC1(C)c2cc(-c3ccc(Cl)cc3)ccc2-c2ccc(-c3ccc(-c4ccc5c(c4)C(c4ccccc4)(c4ccccc4)c4ccccc4-5)cc3)cc21] |
| C5 | CAS 1813574- 72-9 | B1 | 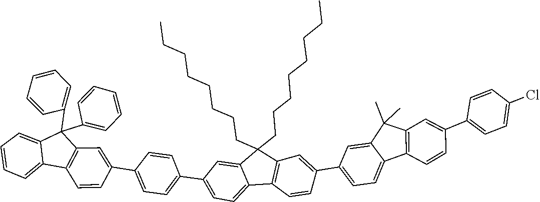 [SMILES: CCCCCCCCC1(CCCCCCCC)c2cc(-c3ccc(-c4ccc5c(c4)C(c4ccccc4)(c4ccccc4)c4ccccc4-5)cc3)ccc2-c2ccc(-c3ccc4c(c3)C(C)(C)c3cc(-c5ccc(Cl)cc5)ccc3-4)cc21] |
| C6 | CAS 2171483- 74-0 | 2244910- 28-7 | 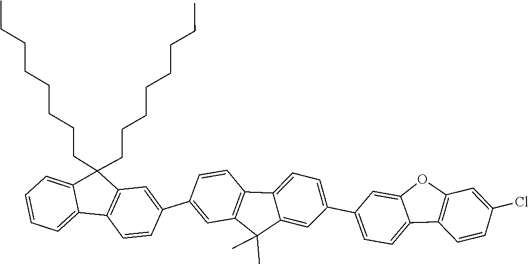 [SMILES: CCCCCCCCC1(CCCCCCCC)c2ccccc2-c2ccc(-c3ccc4c(c3)C(C)(C)c3cc(-c5ccc6c(c5)oc5cc(Cl)ccc56)ccc3-4)cc21] |
| C7 | CAS 2171483- 74-0 | 53220- 82-9 | 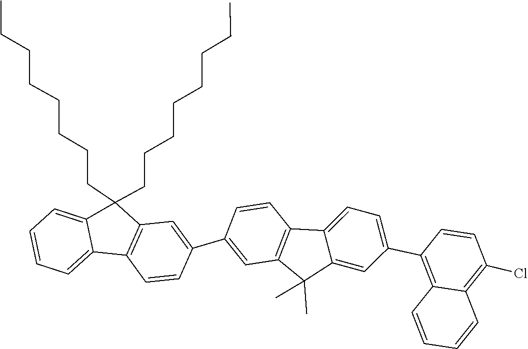 [SMILES: CCCCCCCCC1(CCCCCCCC)c2ccccc2-c2ccc(-c3ccc4c(c3)C(C)(C)c3cc(-c5ccc(Cl)c6ccccc56)ccc3-4)cc21] |
| C8 | CAS 85072- 44-2 | B5 | 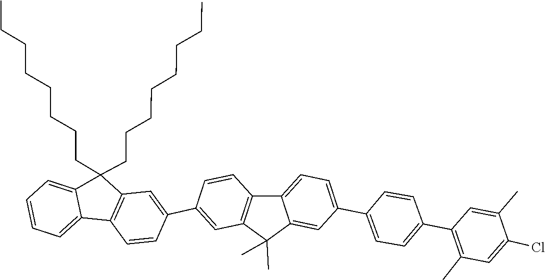 [SMILES: CCCCCCCCC1(CCCCCCCC)c2ccccc2-c2ccc(-c3ccc4c(c3)C(C)(C)c3cc(-c5ccc(-c6cc(C)c(Cl)cc6C)cc5)ccc3-4)cc21] |
| C9 | CAS 85072- 44-2 | B11 | 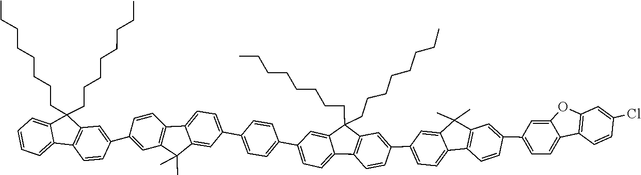 [SMILES: CCCCCCCCC1(CCCCCCCC)c2ccccc2-c2ccc(-c3ccc4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc%11c(c%10)oc%10cc(Cl)ccc%10%11)ccc8-9)ccc6-7)cc5)ccc3-4)cc21] |
| C10 | CAS 85072- 44-2 | B12 | 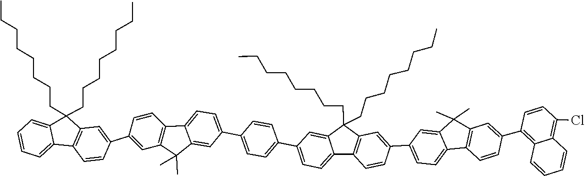 [SMILES: CCCCCCCCC1(CCCCCCCC)c2ccccc2-c2ccc(-c3ccc4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc(Cl)c%11ccccc%10%11)ccc8-9)ccc6-7)cc5)ccc3-4)cc21] |
| C11 | CAS 85072- 44-2 | B13 | 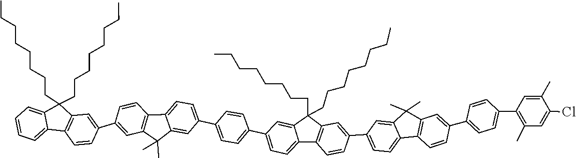 [SMILES: CCCCCCCCC1(CCCCCCCC)c2ccccc2-c2ccc(-c3ccc4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc(-c%11cc(C)c(Cl)cc%11C)cc%10)ccc8-9)ccc6-7)cc5)ccc3-4)cc21] |
| C12 | CAS 1256619- 36-9 | D6 | 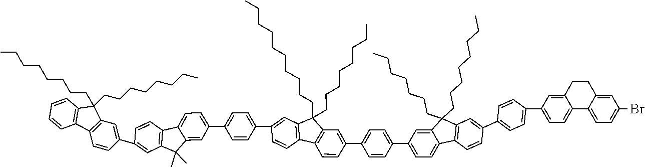 |
| C13 | CAS 1813574- 72-9 | CAS 2268821- 67-4 | 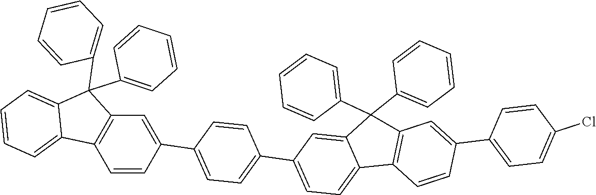 [SMILES: Clc1ccc(-c2ccc3c(c2)C(c2ccccc2)(c2ccccc2)c2cc(-c4ccc(-c5ccc6c(c5)C(c5ccccc5)(c5ccccc5)c5ccccc5-6)cc4)ccc2-3)cc1] |
| C14 | CAS 24388- 23-6 | CAS 198289- 16-6 | 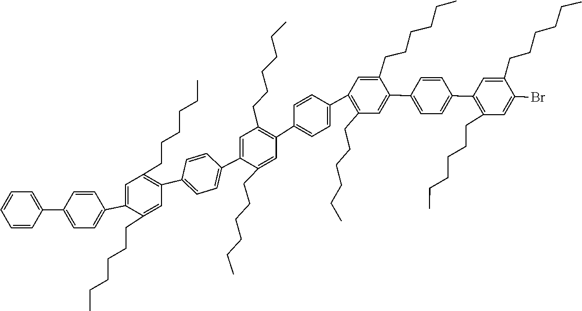 [SMILES: CCCCCCc1cc(-c2ccc(-c3cc(CCCCCC)c(-c4ccc(-c5cc(CCCCCC)c(-c6ccc(-c7cc(CCCCCC)c(-c8ccc(-c9ccccc9)cc8)cc7CCCCCC)cc6)cc5CCCCCC)cc4)cc3CCCCCC)cc2)c(CCCCCC)cc1Br] |

Synthesis of D1:

To 25.3 g (18.7 mmol) of C1, 8.6 g (33.7 mmol) of bis(pinacolato)diboron, 5.5 g (56 mmol) of potassium acetate and 830 mg (1.1 mmol) of trans-dichlorobis(tricyclohexylphosphine)palladium(II) are added 750 ml of dioxane, and the mixture is refluxed for 48 h. Subsequently, toluene and water are added to the reaction mixture, and the phases are separated. The aqueous phase is extracted twice with toluene, and the combined organic phases are extracted twice with water, filtered through alumina and concentrated under reduced pressure. The residue is extracted by stirring with hot ethanol, and the product is obtained in solid form. Yield: 16.0 g (11.1 mmol), 60% of theory.

The following compounds can be prepared analogously:

| | Reactant | |
|---|---|---|
| D2 | C2 | 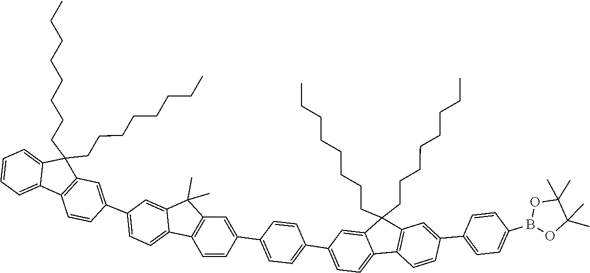 [SMILES: CCCCCCCCC1(CCCCCCCC)c2ccccc2-c2ccc(-c3ccc4c(c3)C(C)(C)c3cc(-c5ccc(-c6ccc7c(c6)C(CCCCCCCC)(CCCCCCCC)c6cc(-c8ccc(B9OC(C)(C)C(C)(C)O9)cc8)ccc6-7)cc5)ccc3-4)cc21] |
| D3 | C3 | 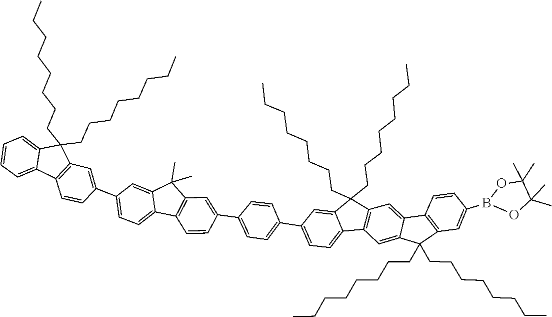 [SMILES: CCCCCCCCC1(CCCCCCCC)c2ccccc2-c2ccc(-c3ccc4c(c3)C(C)(C)c3cc(-c5ccc(-c6ccc7c(c6)C(CCCCCCCC)(CCCCCCCC)c6cc8c(cc6-7)C(CCCCCCCC)(CCCCCCCC)c6cc(B7OC(C)(C)C(C)(C)O7)ccc6-8)cc5)ccc3-4)cc21] |
| D4 | C4 | 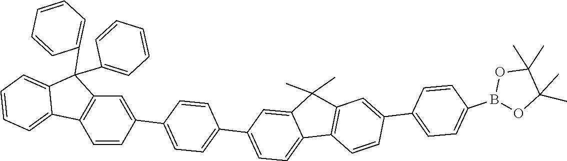 [SMILES: CC1(C)c2cc(-c3ccc(B4OC(C)(C)C(C)(C)O4)cc3)ccc2-c2ccc(-c3ccc(-c4ccc5c(c4)C(c4ccccc4)(c4ccccc4)c4ccccc4-5)cc3)cc21] |
| D5 | C5 | 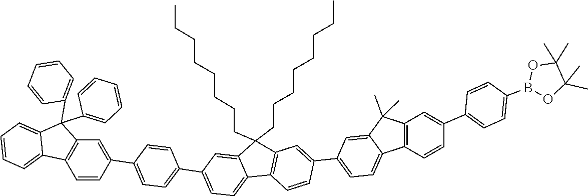 [SMILES: CCCCCCCCC1(CCCCCCCC)c2cc(-c3ccc(-c4ccc5c(c4)C(c4ccccc4)(c4ccccc4)c4ccccc4-5)cc3)ccc2-c2ccc(-c3ccc4c(c3)C(C)(C)c3cc(-c5ccc(B6OC(C)(C)C(C)(C)O6)cc5)ccc3-4)cc21] |
| D6 | E17 | 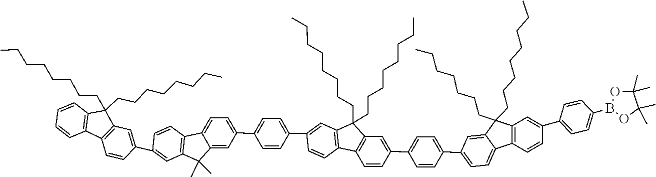 [SMILES: CCCCCCCCC1(CCCCCCC)c2cc(-c3ccc(B4OC(C)(C)C(C)(C)O4)cc3)ccc2-c2ccc(-c3ccc(-c4ccc5c(c4)C(CCCCCCCC)(CCCCCCCC)c4cc(-c6ccc(-c7ccc8c(c7)C(C)(C)c7cc(-c9ccc%10c(c9)C(CCCCCCCC)(CCCCCCCC)c9ccccc9-%10)ccc7-8)cc6)ccc4-5)cc3)cc21] |
| D7 | C12 | 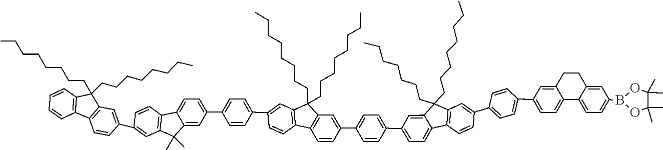 [SMILES: CCCCCCCCC1(CCCCCCC)c2cc(-c3ccc(-c4ccc5c(c4)CCc4cc(B6OC(C)(C)C(C)(C)O6)ccc4-5)cc3)ccc2-c2ccc(-c3ccc(-c4ccc5c(c4)C(CCCCCCCC)(CCCCCCCC)c4cc(-c6ccc(-c7ccc8c(c7)C(C)(C)c7cc(-c9ccc%10c(c9)C(CCCCCCCC)(CCCCCCCC)c9ccccc9-%10)ccc7-8)cc6)ccc4-5)cc3)cc21] |
| D8 | C13 | 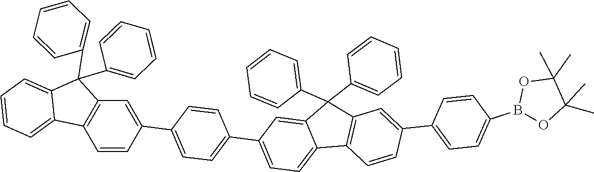 [SMILES: CC1(C)OB(c2ccc(-c3ccc4c(c3)C(c3ccccc3)(c3ccccc3)c3cc(-c5ccc(-c6ccc7c(c6)C(c6ccccc6)(c6ccccc6)c6ccccc6-7)cc5)ccc3-4)cc2)OC1(C)C] |
| D9 | C14 | 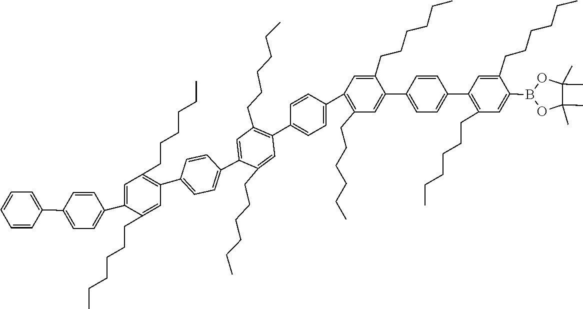 [SMILES: CCCCCCc1cc(-c2ccc(-c3cc(CCCCCC)c(-c4ccc(-c5cc(CCCCCC)c(-c6ccc(-c7cc(CCCCCC)c(-c8ccc(-c9ccccc9)cc8)cc7CCCCCC)cc6)cc5CCCCCC)cc4)cc3CCCCCC)cc2)c(CCCCCC)cc1B1OC(C)(C)C(C)(C)O1] |
| D10 | CAS 2179264- 15-2 | 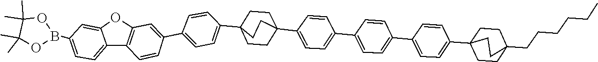 [SMILES: CCCCCCC12CCC(c3ccc(-c4ccc(-c5ccc(C67CCC(c8ccc(-c9ccc%10c(c9)oc9cc(B%11OC(C)(C)C(C)(C)O%11)ccc9%10)cc8)(CC6)CC7)cc5)cc4)cc3)(CC1)CC2] |

Synthesis of E1:

To 5 g (6.4 mmol) of B1, 9.8 g (6.8 mmol) of D1 and 1.8 g (13 mmol) of potassium carbonate are added 800 ml of THE and 400 ml of water. Subsequently, 67 mg (0.26 mmol) of triphenylphosphine and 59 mg (0.06 mmol) of tri(dibenzylideneacetone)dipalladium are added and the mixture is refluxed for 16 h. Subsequently, water and toluene are added to the reaction mixture, and the phases are separated. The aqueous phase is extracted twice with toluene and the combined organic phases are extracted once with water. The organic phase is filtered through alumina and then concentrated under reduced pressure. The product is obtained in solid form by chromatography (SiO₂, heptane/THF 1:20>1:10) and by repeated extraction by stirring from hot toluene.

Yield: 8.5 g (4.2 mmol), 66% of theory.

The following compounds can be prepared analogously:

| | | Boronic | |
|---|---|---|---|
| E | Reactant | ester | Product |
| 2 | B1 | D2 | 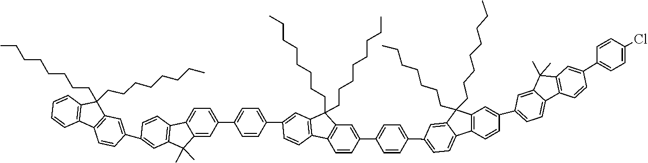 [SMILES: CCCCCCCCC1(CCCCCCC)c2cc(-c3ccc(-c4ccc5c(c4)C(CCCCCCCC)(CCCCCCCC)c4cc(-c6ccc(-c7ccc8c(c7)C(C)(C)c7cc(-c9ccc%10c(c9)C(CCCCCCCC)(CCCCCCCC)c9ccccc9-%10)ccc7-8)cc6)ccc4-5)cc3)ccc2-c2ccc(-c3ccc4c(c3)C(C)(C)c3cc(-c5ccc(Cl)cc5)ccc3-4)cc21] |
| 3 | B1 | D3 | 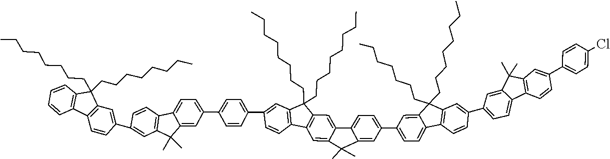 [SMILES: CCCCCCCCC1(CCCCCCC)c2cc(-c3ccc4c(c3)C(C)(C)c3cc(-c5ccc(Cl)cc5)ccc3-4)ccc2-c2ccc(-c3ccc4c(c3)C(C)(C)c3cc5c(cc3-4)C(CCCCCCCC)(CCCCCCCC)c3cc(-c4ccc(-c6ccc7c(c6)C(C)(C)c6cc(-c8ccc9c(c8)C(CCCCCCCC)(CCCCCCCC)c8ccccc8-9)ccc6-7)cc4)ccc3-5)cc21] |
| 4 | B1 | D4 | 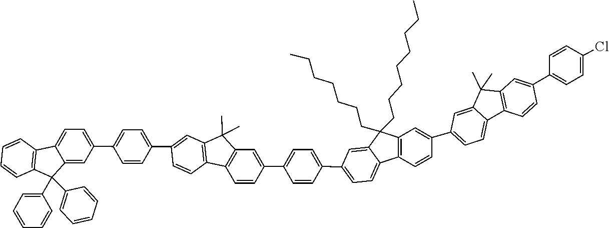 [SMILES: CCCCCCCCC1(CCCCCCC)c2cc(-c3ccc(-c4ccc5c(c4)C(C)(C)c4cc(-c6ccc(-c7ccc8c(c7)C(c7ccccc7)(c7ccccc7)c7ccccc7-8)cc6)ccc4-5)cc3)ccc2-c2ccc(-c3ccc4c(c3)C(C)(C)c3cc(-c5ccc(Cl)cc5)ccc3-4)cc21] |
| 5 | B1 | D5 | 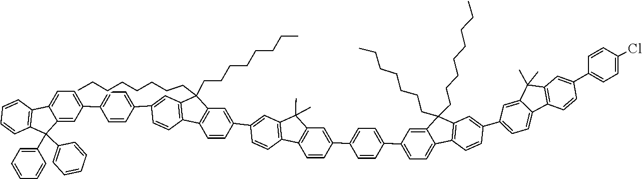 [SMILES: CCCCCCCCC1(CCCCCCC)c2cc(-c3ccc(-c4ccc5c(c4)C(C)(C)c4cc(-c6ccc7c(c6)C(CCCCCCCC)(CCCCCCCC)c6cc(-c8ccc(-c9ccc%10c(c9)C(c9ccccc9)(c9ccccc9)c9ccccc9-%10)cc8)ccc6-7)ccc4-5)cc3)ccc2-c2ccc(-c3ccc4c(c3)C(C)(C)c3cc(-c5ccc(Cl)cc5)ccc3-4)cc21] |
| 6 | B11 | D1 | 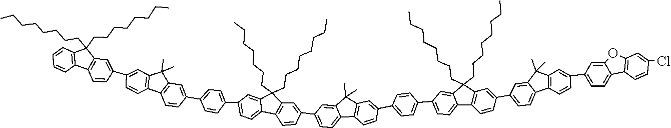 [SMILES: CCCCCCCCC1(CCCCCCC)c2cc(-c3ccc(-c4ccc5c(c4)C(C)(C)c4cc(-c6ccc7c(c6)C(CCCCCCCC)(CCCCCCCC)c6ccccc6-7)ccc4-5)cc3)ccc2-c2ccc(-c3cc(C)c4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc%11c(c%10)oc%10cc(Cl)ccc%10%11)ccc8-9)ccc6-7)cc5)ccc3-4)cc21] |
| 7 | B12 | D1 | 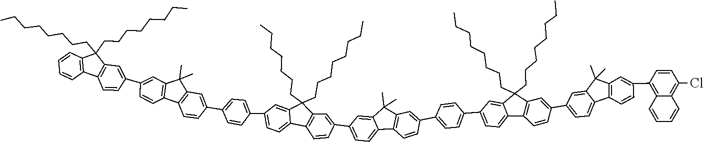 [SMILES: CCCCCCCCC1(CCCCCCC)c2cc(-c3ccc(-c4ccc5c(c4)C(C)(C)c4cc(-c6ccc7c(c6)C(CCCCCCCC)(CCCCCCCC)c6ccccc6-7)ccc4-5)cc3)ccc2-c2ccc(-c3cc(C)c4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc(Cl)c%11ccccc%10%11)ccc8-9)ccc6-7)cc5)ccc3-4)cc21] |
| 8 | B13 | D1 | 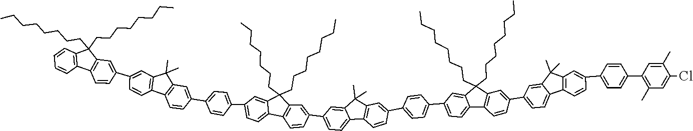 [SMILES: CCCCCCCCC1(CCCCCCC)c2cc(-c3ccc(-c4ccc5c(c4)C(C)(C)c4cc(-c6ccc7c(c6)C(CCCCCCCC)(CCCCCCCC)c6ccccc6-7)ccc4-5)cc3)ccc2-c2ccc(-c3cc(C)c4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc(-c%11cc(C)c(Cl)cc%11C)cc%10)ccc8-9)ccc6-7)cc5)ccc3-4)cc21] |
| 9 | B5 | D1 | 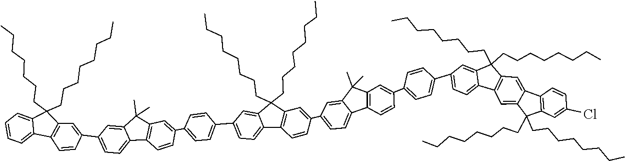 |
| 10 | B6 | D1 | 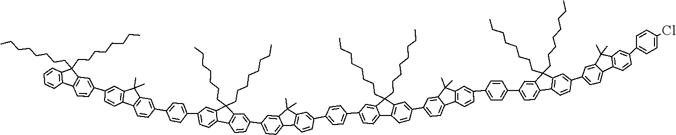 [SMILES: CCCCCCCCC1(CCCCCCC)c2cc(-c3ccc(-c4ccc5c(c4)C(C)(C)c4cc(-c6ccc7c(c6)C(CCCCCCCC)(CCCCCCCC)c6ccccc6-7)ccc4-5)cc3)ccc2-c2ccc(-c3cc(C)c4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc(-c%11ccc%12c(c%11)C(CCCCCCCC)(CCCCCCCC)c%11cc(-c%13ccc%14c(c%13)C(C)(C)c%13cc(-c%15ccc(Cl)cc%15)ccc%13-%14)ccc%11-%12)cc%10)ccc8-9)ccc6-7)cc5)ccc3-4)cc21] |
| 11 | B7 | D1 | 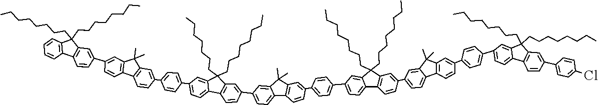 |
| 12 | B8 | D1 | 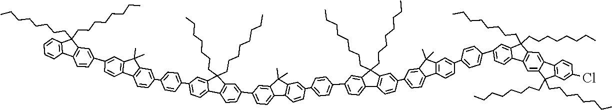 |
| 13 | B9 | D1 | 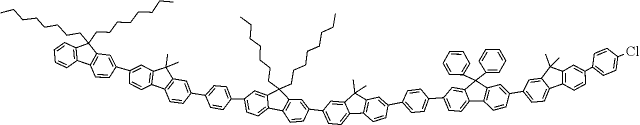 [SMILES: CCCCCCCCC1(CCCCCCC)c2cc(-c3ccc(-c4ccc5c(c4)C(C)(C)c4cc(-c6ccc7c(c6)C(CCCCCCCC)(CCCCCCCC)c6ccccc6-7)ccc4-5)cc3)ccc2-c2ccc(-c3cc(C)c4c(c3)C(C)(C)c3cc(-c5ccc(-c6ccc7c(c6)C(c6ccccc6)(c6ccccc6)c6cc(-c8ccc9c(c8)C(C)(C)c8cc(-c%10ccc(Cl)cc%10)ccc8-9)ccc6-7)cc5)ccc3-4)cc21] |
| 14 | B10 | D1 | 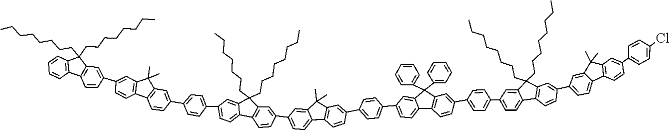 [SMILES: CCCCCCCCC1(CCCCCCC)c2cc(-c3ccc(-c4ccc5c(c4)C(C)(C)c4cc(-c6ccc7c(c6)C(CCCCCCCC)(CCCCCCCC)c6ccccc6-7)ccc4-5)cc3)ccc2-c2ccc(-c3cc(C)c4c(c3)C(C)(C)c3cc(-c5ccc(-c6ccc7c(c6)C(c6ccccc6)(c6ccccc6)c6cc(-c8ccc(-c9ccc%10c(c9)C(CCCCCCCC)(CCCCCCCC)c9cc(-c%11ccc%12c(c%11)C(C)(C)c%11cc(-c%13ccc(Cl)cc%13)ccc%11-%12)ccc9-%10)cc8)ccc6-7)cc5)ccc3-4)cc21] |
| 15 | CAS 19828 9-16-6 | D4 | 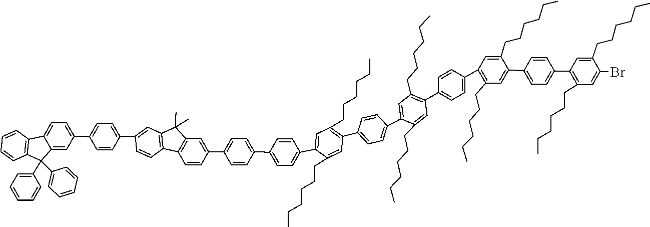 [SMILES: CCCCCCc1cc(-c2ccc(-c3cc(CCCCCC)c(-c4ccc(-c5cc(CCCCCC)c(-c6ccc(-c7cc(CCCCCC)c(-c8ccc(-c9ccc(-c%10ccc%11c(c%10)C(C)(C)c%10cc(-c%12ccc(-c%13ccc%14c(c%13)C(c%13ccccc%13)(c%13ccccc%13)c%13ccccc%13-%14)cc%12)ccc%10-%11)cc9)cc8)cc7CCCCCC)cc6)cc5CCCCCC)cc4)cc3CCCCCC)cc2)c(CCCCCC)cc1Br] |
| 16 | CAS 19828 9-16-6 | CAS 21714 83-74- 0 | 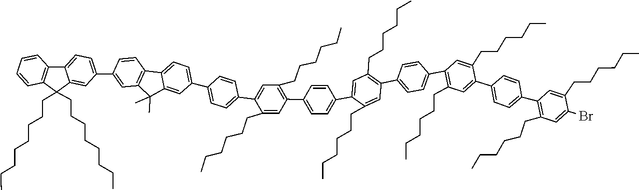 [SMILES: CCCCCCCCC1(CCCCCCCC)c2ccccc2-c2ccc(-c3ccc4c(c3)C(C)(C)c3cc(-c5ccc(-c6cc(CCCCCC)c(-c7ccc(-c8cc(CCCCCC)c(-c9ccc(-c%10cc(CCCCCC)c(-c%11ccc(-c%12cc(CCCCCC)c(Br)cc%12CCCCCC)cc%11)cc%10CCCCCC)cc9)cc8CCCCCC)cc7)cc6CCCCCC)cc5)ccc3-4)cc21] |
| 17 | CAS 18812 30-18- 7 | D2 | 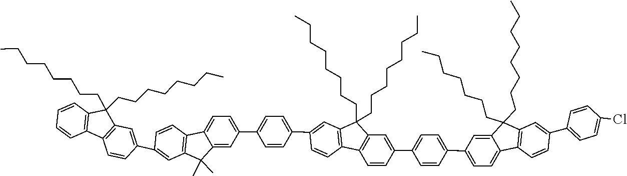 [SMILES: CCCCCCCCC1(CCCCCCC)c2cc(-c3ccc(Cl)cc3)ccc2-c2ccc(-c3ccc(-c4ccc5c(c4)C(CCCCCCCC)(CCCCCCCC)c4cc(-c6ccc(-c7ccc8c(c7)C(C)(C)c7cc(-c9ccc%10c(c9)C(CCCCCCCC)(CCCCCCCC)c9ccccc9-%10)ccc7-8)cc6)ccc4-5)cc3)cc21] |
| 18 | CAS 53220- 829 | D6 | 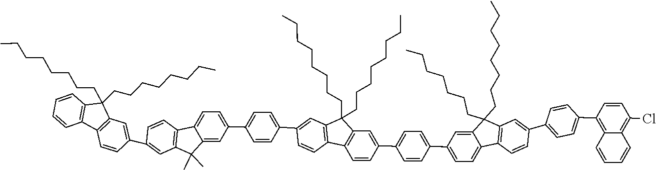 [SMILES: CCCCCCCCC1(CCCCCCC)c2cc(-c3ccc(-c4ccc5c(c4)C(CCCCCCCC)(CCCCCCCC)c4cc(-c6ccc(-c7ccc8c(c7)C(C)(C)c7cc(-c9ccc%10c(c9)C(CCCCCCCC)(CCCCCCCC)c9ccccc9-%10)ccc7-8)cc6)ccc4-5)cc3)ccc2-c2ccc(-c3ccc(-c4ccc(Cl)c5ccccc45)cc3)cc21] |
| 19 | CAS 18812 30-18- 7 | D7 | 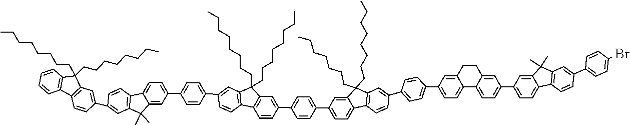 [SMILES: CCCCCCCCC1(CCCCCCC)c2cc(-c3ccc(-c4ccc5c(c4)CCc4cc(-c6ccc7c(c6)C(C)(C)c6cc(-c8ccc(Br)cc8)ccc6-7)ccc4-5)cc3)ccc2-c2ccc(-c3ccc(-c4ccc5c(c4)C(CCCCCCCC)(CCCCCCCC)c4cc(-c6ccc(-c7ccc8c(c7)C(C)(C)c7cc(-c9ccc%10c(c9)C(CCCCCCCC)(CCCCCCCC)c9ccccc9-%10)ccc7-8)cc6)ccc4-5)cc3)cc21] |
| 20 | CAS 19828 9-16-6 | D8 | 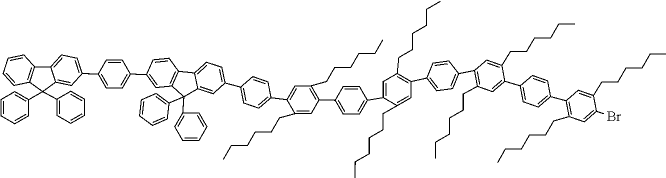 [SMILES: CCCCCCc1cc(-c2ccc(-c3cc(CCCCCC)c(-c4ccc(-c5cc(CCCCCC)c(-c6ccc(-c7cc(CCCCCC)c(-c8ccc(-c9ccc%10c(c9)C(c9ccccc9)(c9ccccc9)c9cc(-c%11ccc(-c%12ccc%13c(c%12)C(c%12ccccc%12)(c%12ccccc%12)c%12ccccc%12-%13)cc%11)ccc9-%10)cc8)cc7CCCCCC)cc6)cc5CCCCCC)cc4)cc3CCCCCC)cc2)c(CCCCCC)cc1Br] |
| 21 | CAS 19828 9-16-6 | D9 | 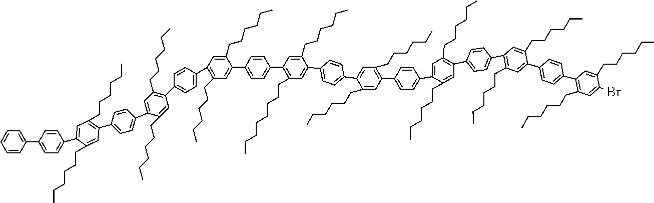 [SMILES: CCCCCCCCc1cc(-c2ccc(-c3cc(CCCCCC)c(-c4ccc(-c5cc(CCCCCC)c(-c6ccc(-c7cc(CCCCCC)c(-c8ccc(-c9cc(CCCCCC)c(Br)cc9CCCCCC)cc8)cc7CCCCCC)cc6)cc5CCCCCC)cc4)cc3CCCCCC)cc2)c(CCCCCC)cc1-c1ccc(-c2cc(CCCCCC)c(-c3ccc(-c4cc(CCCCCC)c(-c5ccc(-c6cc(CCCCCC)c(-c7ccc(-c8ccccc8)cc7)cc6CCCCCC)cc5)cc4CCCCCC)cc3)cc2CCCCCC)cc1] |
| 22 | B14 | D8 | 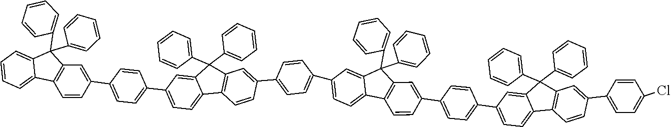 [SMILES: Clc1ccc(-c2ccc3c(c2)C(c2ccccc2)(c2ccccc2)c2cc(-c4ccc(-c5ccc6c(c5)C(c5ccccc5)(c5ccccc5)c5cc(-c7ccc(-c8ccc9c(c8)C(c8ccccc8)(c8ccccc8)c8cc(-c%10ccc(-c%11ccc%12c(c%11)C(c%11ccccc%11)(c%11ccccc%11)c%11ccccc%11-%12)cc%10)ccc8-9)cc7)ccc5-6)cc4)ccc2-3)cc1] |
| 23 | B1 | D10 | 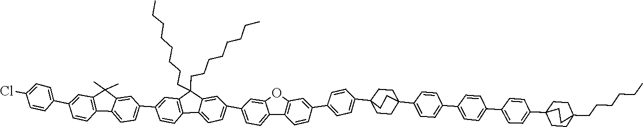 [SMILES: CCCCCCCCC1(CCCCCCCC)c2cc(-c3ccc4c(c3)C(C)(C)c3cc(-c5ccc(Cl)cc5)ccc3-4)ccc2-c2ccc(-c3ccc4c(c3)oc3cc(-c5ccc(C67CCC(c8ccc(-c9ccc(-c%10ccc(C%11%12CCC(CCCCCC)(CC%11)CC%12)cc%10)cc9)cc8)(CC6)CC7)cc5)ccc34)cc21] |

Synthesis of Intermediate Int-1

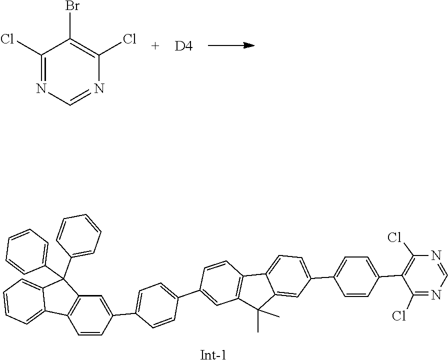 [SMILES: Clc1ncnc(Cl)c1Br ; "D4" ; CC1(C)c2cc(-c3ccc(-c4ccc5c(c4)C(c4ccccc4)(c4ccccc4)c4ccccc4-5)cc3)ccc2-c2ccc(-c3ccc(-c4c(Cl)ncnc4Cl)cc3)cc21]

3 g (13.2 mmol) of CAS 68797-61-5, 10.4 g (13.2 mmol) of D4, 3.7 g (27 mmol) of potassium carbonate and 0.76 g (0.66 mmol) of tetrakis(triphenylphosphine)palladium(0) are mixed in 500 ml of toluene/ethanol/water (2:1:1) and heated under reflux for 18 h. On completion of conversion, the reaction mixture is cooled down to room temperature. The organic phase is extended with toluene and washed twice with water and once with saturated aqueous sodium chloride solution. The organic phases are combined and concentrated on a rotary evaporator. The product is purified by column chromatography (SiO₂; THE/heptane). Yield: 4.3 g (5.3 mmol; 40%).

Synthesis of Intermediate Int-2

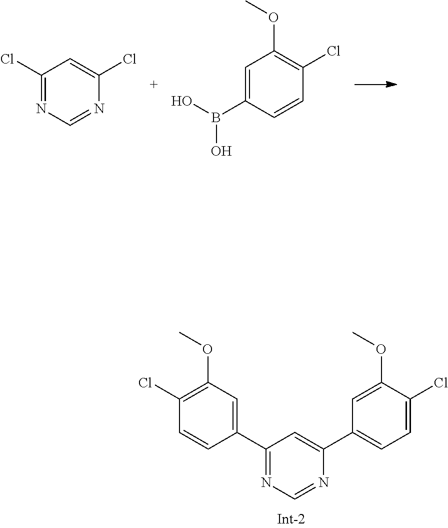 [SMILES: Clc1cc(Cl)ncn1 ; COc1cc(B(O)O)ccc1Cl ; COc1cc(-c2cc(-c3ccc(Cl)c(OC)c3)ncn2)ccc1Cl]

15.0 g (100.7 mmol) of 4,6-dichloropyrimidine, 38.5 g of (4-chloro-3-methoxyphenyl)boronic acid, 55.7 g (402.7 mmol) of potassium carbonate and 2.8 g (4.0 mmol) of bis(triphenylphosphine)Pd(II) chloride are dissolved in 300 ml of acetonitrile/ethanol (2:1) and heated under reflux for 16 h. On completion of conversion, the reaction mixture is left to cool down to room temperature. The precipitated solids are filtered off with suction and washed with toluene and methanol. The filtrate is concentrated on a rotary evaporator. The solids obtained are purified by crystallization from dichloromethane/methanol. Yield: 20.9 g (57.9 mmol; 58%)

The following compound can be prepared analogously from the

| | Boronic acid | Reactant | Product |
|---|---|---|---|
| Int-2b | CAS 1679-18-1 | Int-1 | 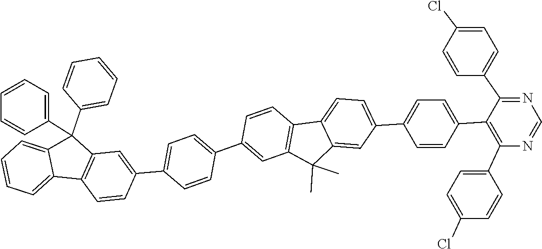 [SMILES: CC1(C)c2cc(-c3ccc(-c4ccc5c(c4)C(c4ccccc4)(c4ccccc4)c4ccccc4-5)cc3)ccc2-c2ccc(-c3ccc(-c4c(-c5ccc(Cl)cc5)ncnc4-c4ccc(Cl)cc4)cc3)cc21] |

Synthesis of Intermediate Int-3

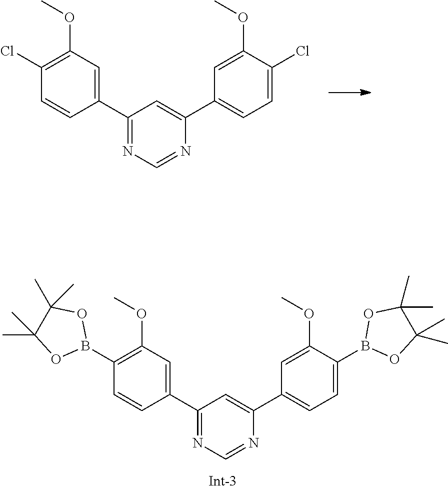

16.0 g (44.3 mmol) of Int-2, 24.3 g (95.7 mmol) of bis(pinacolato)diborane and 17.4 g (177.2 mmol) of potassium acetate are dissolved in 1000 ml of THF. After addition of 1.87 g (2.2 mmol) of Xphos Pd G3, the reaction mixture is heated under reflux for 48 h. Subsequently, the reaction mixture is cooled down to room temperature and the solids are filtered off. The filtrate is concentrated on a rotary evaporator and purified by column chromatography (SiO₂, heptane/ethyl acetate), and the product is isolated.

Yield: 12.4 g (22.7 mmol; 51%).

The following compound can be prepared analogously from the corresponding boronic ester:

| | Chloride | Product |
|---|---|---|
| Int-3b | Int-2b | 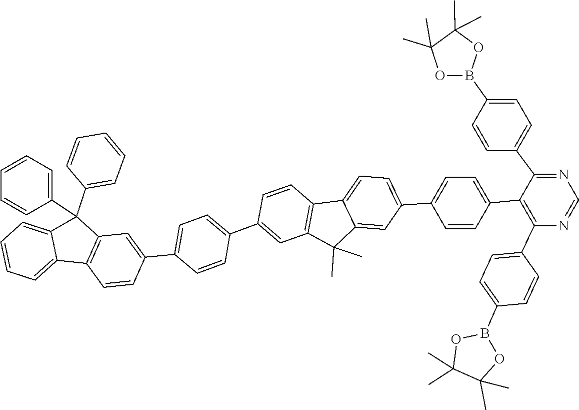 [SMILES: CC1(C)c2cc(-c3ccc(-c4ccc5c(c4)C(c4ccccc4)(c4ccccc4)c4ccccc4-5)cc3)ccc2-c2ccc(-c3ccc(-c4c(-c5ccc(B6OC(C)(C)C(C)(C)O6)cc5)ncnc4-c4ccc(B5OC(C)(C)C(C)(C)O5)cc4)cc3)cc21] |

Synthesis of the Emitter Base Structure Stage 1

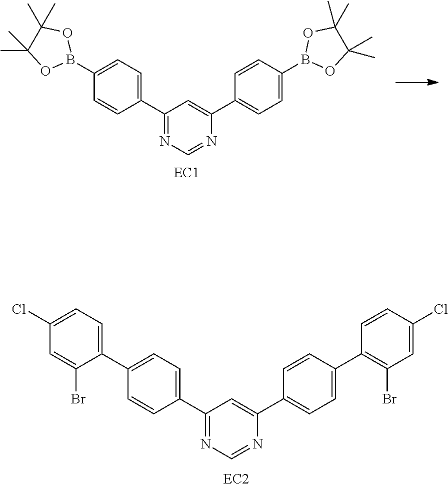

An initial charge of 39.2 g (81 mmol) of EC1 (2202712-51-2), 54.0 g (170 mmol) of 2-bromo-4-chloro-1-iodobenzene, 44.8 g (324 mmol) of potassium carbonate and 570 mg (0.81 mmol) of bis(triphenylphosphine)palladium(II) chloride in 600 ml of toluene is stirred at 80° C. After 16 h, 300 ml of water is added. The phases are separated and the aqueous phase is extracted repeatedly with toluene, and the organic phase is washed repeatedly with water. The organic phases are combined and concentrated under reduced pressure. The resultant residue is stirred repeatedly with hot ethanol. The resultant solids are subjected to hot extraction with toluene over alumina. The precipitated solids are filtered. Yield: 35.1 g (57.5 mmol); 71% of theory.

The following compounds can be prepared analogously from the corresponding boronic esters:

| | Boronic ester | Product |
|---|---|---|
| EC2b | Int-3 | 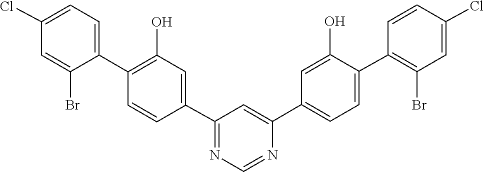 [SMILES: Oc1cc(-c2cc(-c3ccc(-c4ccc(Cl)cc4Br)c(O)c3)ncn2)ccc1-c1ccc(Cl)cc1Br] |
| EC2c | Int-3b | 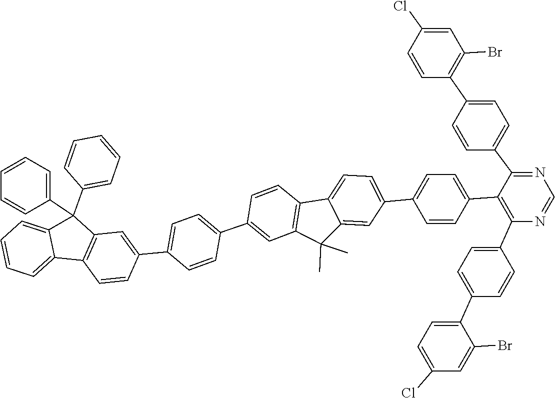 [SMILES: CC1(C)c2cc(-c3ccc(-c4ccc5c(c4)C(c4ccccc4)(c4ccccc4)c4ccccc4-5)cc3)ccc2-c2ccc(-c3ccc(-c4c(-c5ccc(-c6ccc(Cl)cc6Br)cc5)ncnc4-c4ccc(-c5ccc(Cl)cc5Br)cc4)cc3)cc21] |

Synthesis of the Emitter Base Structure Stage 2

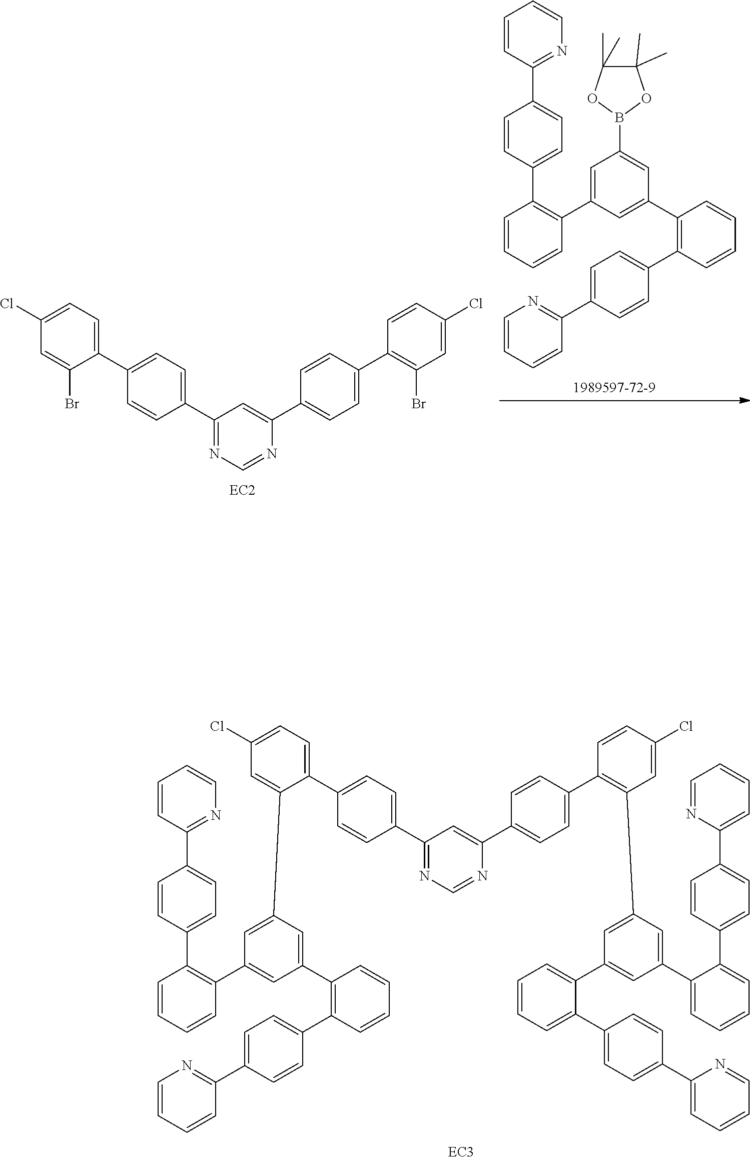

34.6 g (57 mmol) of EC2, 78.8 g (118 mmol) of 1989597-72-9 and 24 g (226 mmol) of sodium carbonate are suspended in 1.2 l of THE/water (2:1). After addition of 400 mg (0.57 mmol) of Pd(amphos)Cl₂, the reaction mixture is refluxed for 16 h. The solids that precipitate out on cooling to room temperature are filtered and purified by means of repeated hot extraction over alumina (with dichloromethane as eluent) and subsequent crystallization from dichloromethane/methanol. Yield: 52.3 g (34.4 mmol), 61% of theory.

The following compounds can be prepared analogously from the corresponding boronic esters:

| | Boronic ester | Product |
|---|---|---|
| EC3b | 2245948-53-0 | 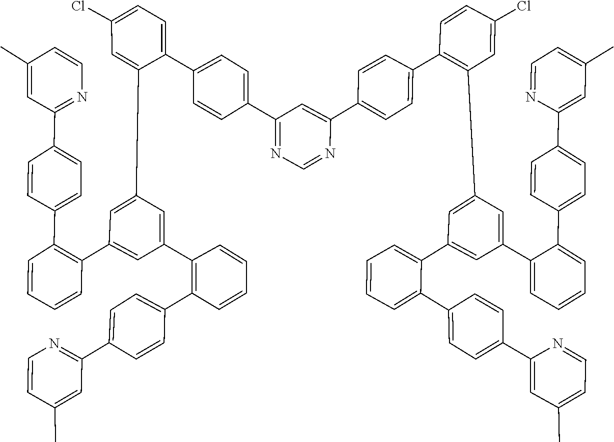 |
| EC3c | 2350247-89-9 | 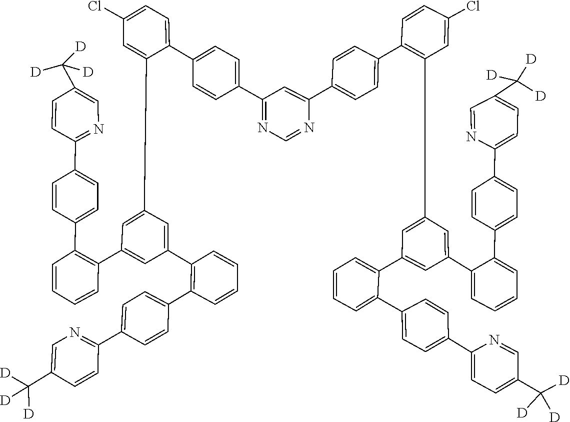 [SMILES: [2H]C([2H])([2H])c1ccc(-c2ccc(-c3ccccc3-c3cc(-c4ccccc4-c4ccc(-c5ccc(C([2H])([2H])[2H])cn5)cc4)cc(-c4cc(Cl)ccc4-c4ccc(-c5cc(-c6ccc(-c7ccc(Cl)cc7-c7cc(-c8ccccc8-c8ccc(-c9ccc(C([2H])([2H])[2H])cn9)cc8)cc(-c8ccccc8-c8ccc(-c9ccc(C([2H])([2H])[2H])cn9)cc8)c7)cc6)ncn5)cc4)c3)cc2)nc1] |
| EC3d | 2202718-90-7 | 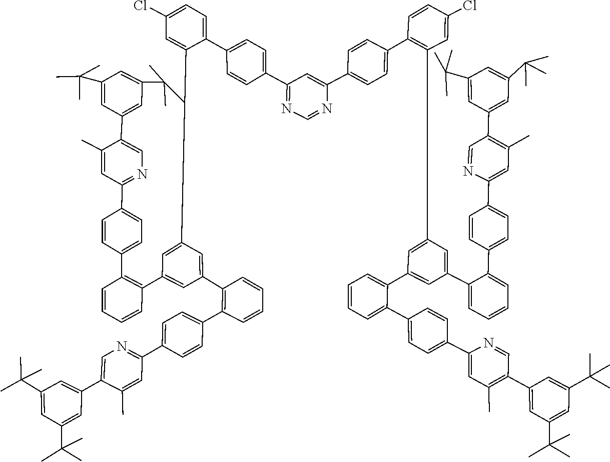 [SMILES: Cc1cc(-c2ccc(-c3ccccc3-c3cc(-c4ccccc4-c4ccc(-c5cc(C)c(-c6cc(C(C)(C)C)cc(C(C)(C)C)c6)cn5)cc4)cc(-c4cc(Cl)ccc4-c4ccc(-c5cc(-c6ccc(-c7ccc(Cl)cc7C7c8cc(-c9ccccc9-c9ccc(-c%10cc(C)c(-c%11cc(C(C)(C)C)cc(C(C)(C)C)c%11)cn%10)cc9)cc(c8)-c8ccccc8-c8ccc(cc8)-c8cc(C)c(cn8)-c8cc(C(C)(C)C)cc(c8)C7(C)C)cc6)ncn5)cc4)c3)cc2)ncc1-c1cc(C(C)(C)C)cc(C(C)(C)C)c1] |
| EC3e | 2178101-83-0 | 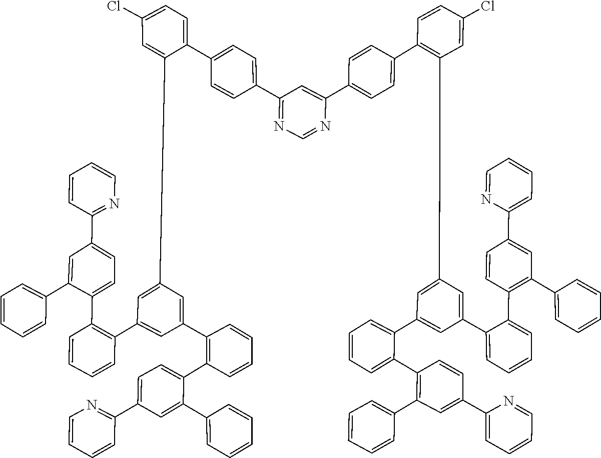 [SMILES: Clc1ccc(-c2ccc(-c3cc(-c4ccc(-c5ccc(Cl)cc5-c5cc(-c6ccccc6-c6ccc(-c7ccccn7)cc6-c6ccccc6)cc(-c6ccccc6-c6ccc(-c7ccccn7)cc6-c6ccccc6)c5)cc4)ncn3)cc2)c(-c2cc(-c3ccccc3-c3ccc(-c4ccccn4)cc3-c3ccccc3)cc(-c3ccccc3-c3ccc(-c4ccccn4)cc3-c3ccccc3)c2)c1] |
| EC3f | 2178101-83-0 Bromide: EC2b | 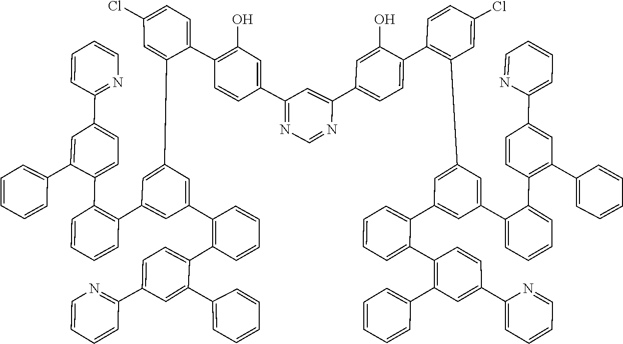 [SMILES: Oc1cc(-c2cc(-c3ccc(-c4ccc(Cl)cc4-c4cc(-c5ccccc5-c5ccc(-c6ccccn6)cc5-c5ccccc5)cc(-c5ccccc5-c5ccc(-c6ccccn6)cc5-c5ccccc5)c4)c(O)c3)ncn2)ccc1-c1ccc(Cl)cc1-c1cc(-c2ccccc2-c2ccc(-c3ccccn3)cc2-c2ccccc2)cc(-c2ccccc2-c2ccc(-c3ccccn3)cc2-c2ccccc2)c1] |
| EC3g | 1989597-72-9 Bromide: EC2b | 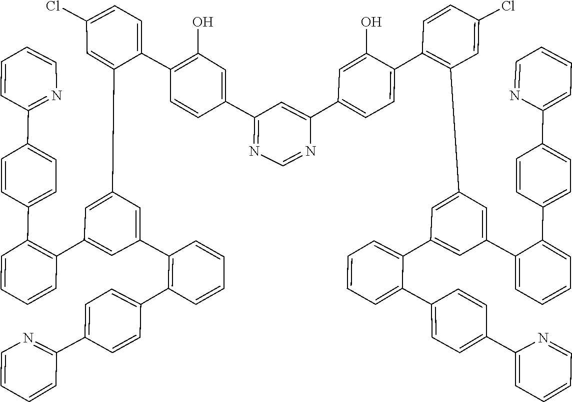 [SMILES: Oc1cc(-c2cc(-c3ccc(-c4ccc(Cl)cc4-c4cc(-c5ccccc5-c5ccc(-c6ccccn6)cc5)cc(-c5ccccc5-c5ccc(-c6ccccn6)cc5)c4)c(O)c3)ncn2)ccc1-c1ccc(Cl)cc1-c1cc(-c2ccccc2-c2ccc(-c3ccccn3)cc2)cc(-c2ccccc2-c2ccc(-c3ccccn3)cc2)c1] |
| EC3h | 2178101-83-0 Bromide: EC2c | 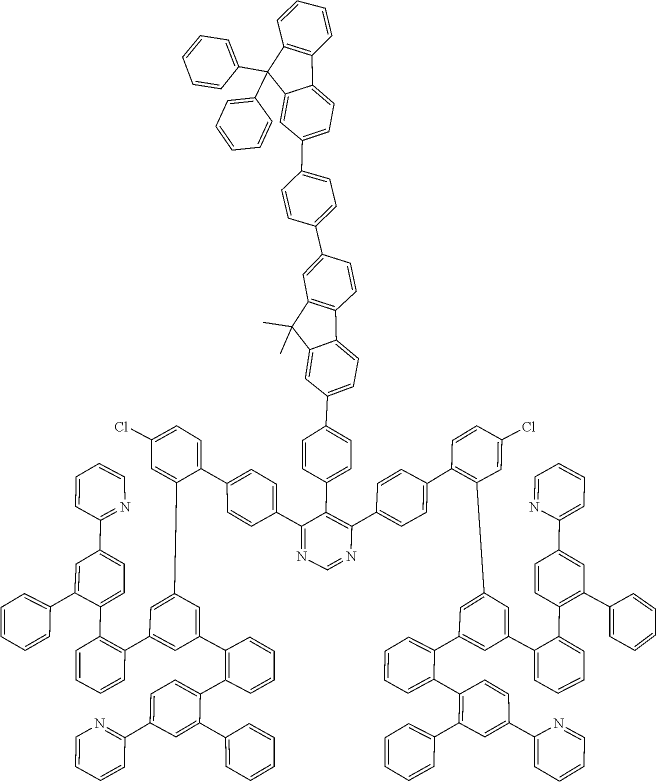 [SMILES: CC1(C)c2cc(-c3ccc(-c4ccc5c(c4)C(c4ccccc4)(c4ccccc4)c4ccccc4-5)cc3)ccc2-c2ccc(-c3ccc(-c4c(-c5ccc(-c6ccc(Cl)cc6-c6cc(-c7ccccc7-c7ccc(-c8ccccn8)cc7-c7ccccc7)cc(-c7ccccc7-c7ccc(-c8ccccn8)cc7-c7ccccc7)c6)cc5)ncnc4-c4ccc(-c5ccc(Cl)cc5-c5cc(-c6ccccc6-c6ccc(-c7ccccn7)cc6-c6ccccc6)cc(-c6ccccc6-c6ccc(-c7ccccn7)cc6-c6ccccc6)c5)cc4)cc3)cc21] |

Synthesis of the Emitter Core Stage 2-Int

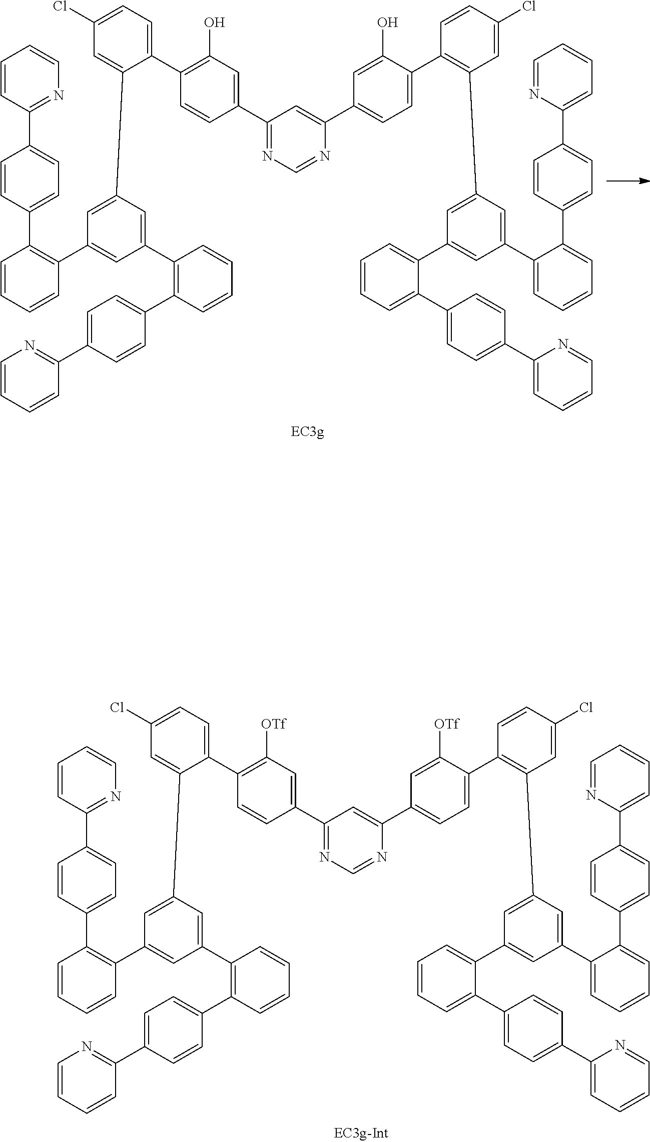 [SMILES: Oc1cc(-c2cc(-c3ccc(-c4ccc(Cl)cc4-c4cc(-c5ccccc5-c5ccc(-c6ccccn6)cc5)cc(-c5ccccc5-c5ccc(-c6ccccn6)cc5)c4)c(O)c3)ncn2)ccc1-c1ccc(Cl)cc1-c1cc(-c2ccccc2-c2ccc(-c3ccccn3)cc2)cc(-c2ccccc2-c2ccc(-c3ccccn3)cc2)c1 ; O=S(=O)(Oc1cc(-c2cc(-c3ccc(-c4ccc(Cl)cc4-c4cc(-c5ccccc5-c5ccc(-c6ccccn6)cc5)cc(-c5ccccc5-c5ccc(-c6ccccn6)cc5)c4)c(OS(=O)(=O)C(F)(F)F)c3)ncn2)ccc1-c1ccc(Cl)cc1-c1cc(-c2ccccc2-c2ccc(-c3ccccn3)cc2)cc(-c2ccccc2-c2ccc(-c3ccccn3)cc2)c1)C(F)(F)F]

28.2 g (18.1 mmol) of EC3g is dissolved in 250 ml of dichloromethane. After addition of 9 ml of pyridine, the mixture is cooled to 0° C., and 12 ml (73 mmol) of trifluoromethanesulfonic anhydride is added dropwise such that the temperature does not exceed 2° C. The mixture is stirred at this temperature for a further hour and then stirred at room temperature for 16 h. Subsequently, the reaction mixture is poured onto 600 ml of ice and stirred for 30 minutes. The mixture is transferred to a separating funnel, and the organic phase is extended with dichloromethane and washed three times with water. The combined aqueous phases are extracted twice with dichloromethane. The combined organic phases are filtered through silica gel and washed through with ethyl acetate. After the solvent had been removed on a rotary evaporator, the residue is extracted repeatedly by stirring with ethyl acetate at 60° C. After cooling to room temperature, the solids are filtered off and the product is obtained. Yield 28.1 g (15.4 mmol; 85%).

The following compound can be prepared analogously from the corresponding boronic ester:

| | Reactant | Product |
|---|---|---|
| EC3f- Int | EC3f | 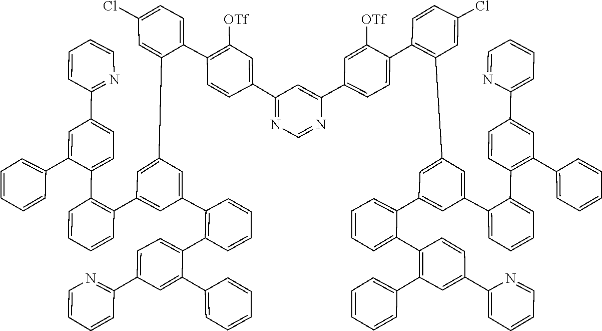 [SMILES: O=S(=O)(Oc1cc(-c2cc(-c3ccc(-c4ccc(Cl)cc4-c4cc(-c5ccccc5-c5ccc(-c6ccccn6)cc5-c5ccccc5)cc(-c5ccccc5-c5ccc(-c6ccccn6)cc5-c5ccccc5)c4)c(OS(=O)(=O)C(F)(F)F)c3)ncn2)ccc1-c1ccc(Cl)cc1-c1cc(-c2ccccc2-c2ccc(-c3ccccn3)cc2-c2ccccc2)cc(-c2ccccc2-c2ccc(-c3ccccn3)cc2-c2ccccc2)c1)C(F)(F)F] |

Synthesis of EC3i

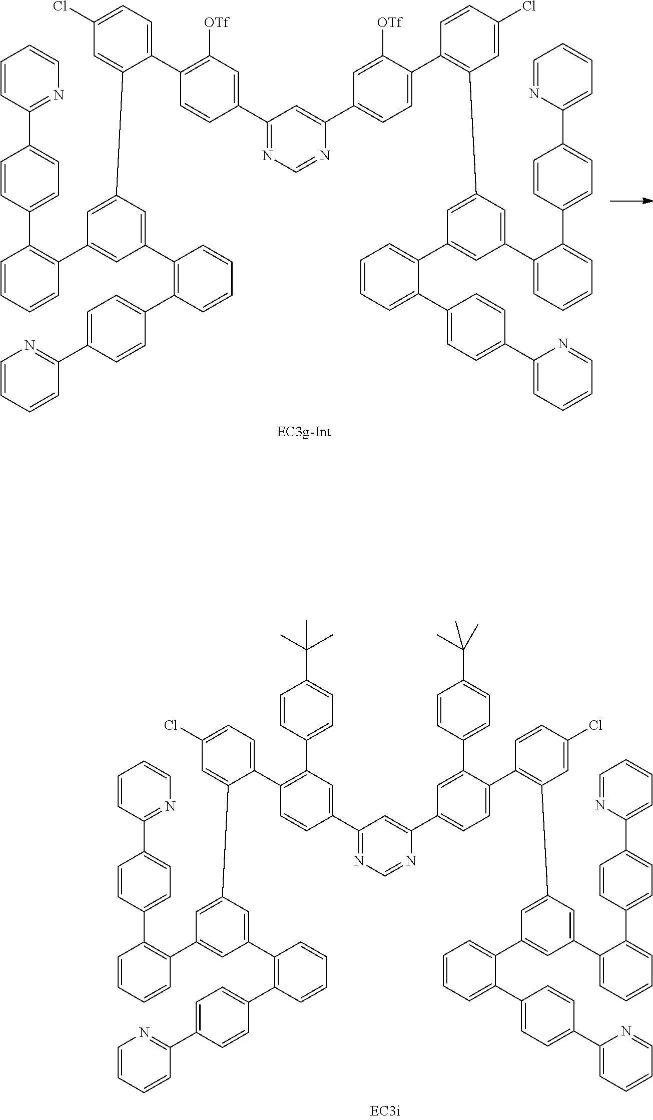 [SMILES: O=S(=O)(Oc1cc(-c2cc(-c3ccc(-c4ccc(Cl)cc4-c4cc(-c5ccccc5-c5ccc(-c6ccccn6)cc5)cc(-c5ccccc5-c5ccc(-c6ccccn6)cc5)c4)c(OS(=O)(=O)C(F)(F)F)c3)ncn2)ccc1-c1ccc(Cl)cc1-c1cc(-c2ccccc2-c2ccc(-c3ccccn3)cc2)cc(-c2ccccc2-c2ccc(-c3ccccn3)cc2)c1)C(F)(F)F ; CC(C)(C)c1ccc(-c2cc(-c3cc(-c4ccc(-c5ccc(Cl)cc5-c5cc(-c6ccccc6-c6ccc(-c7ccccn7)cc6)cc(-c6ccccc6-c6ccc(-c7ccccn7)cc6)c5)c(-c5ccc(C(C)(C)C)cc5)c4)ncn3)ccc2-c2ccc(Cl)cc2-c2cc(-c3ccccc3-c3ccc(-c4ccccn4)cc3)cc(-c3ccccc3-c3ccc(-c4ccccn4)cc3)c2)cc1]

15.5 g (8.5 mmol) of EC3g-Int, 6.4 g (34.1 mmol) of 4-tert-butylphenylboronic acid, 4.7 g (34.1 mmol) of potassium carbonate, 0.73 g (1.7 mmol) of dppb and 0.39 g (0.43 mmol) of tris(dibenzylideneacetone)dipalladium(0) are dissolved in 1000 ml of dioxane/water (3:1), and stirred at 90° C. for 16 h. On completion of conversion, the organic phase is extended with ethyl acetate, and the phases are separated. The aqueous phase is extracted twice with ethyl acetate, and the combined organic phases are washed twice with water, dried over magnesium sulfate and filtered through silica gel. The desired product is obtained after purification by column chromatography (SiO₂; toluene/ethyl acetate). Yield: 6.1 g (3.4 mmol; 40%).

The following compounds can be prepared analogously from the corresponding boronic esters:

| | Reactants | Product |
|---|---|---|
| EC3j | Triflate: EC3g-Int Boronic ester: D1 | 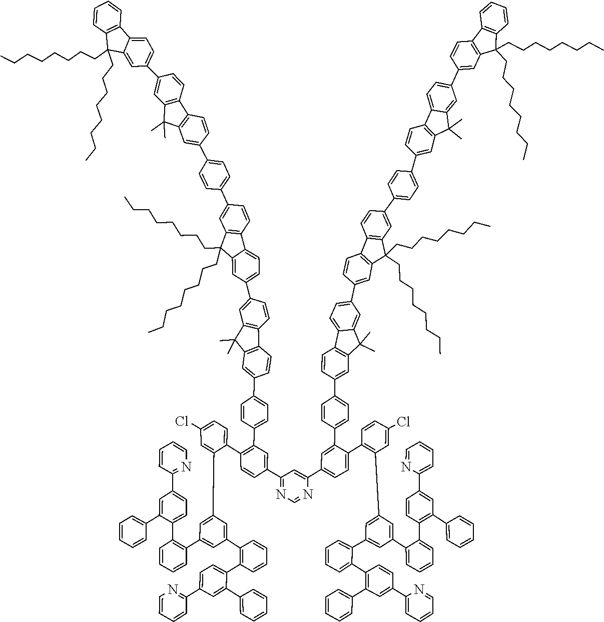 |
| EC3k | Triflate: EC3f-Int Boronic acid: 4-tert- butylphenylboronic acid | 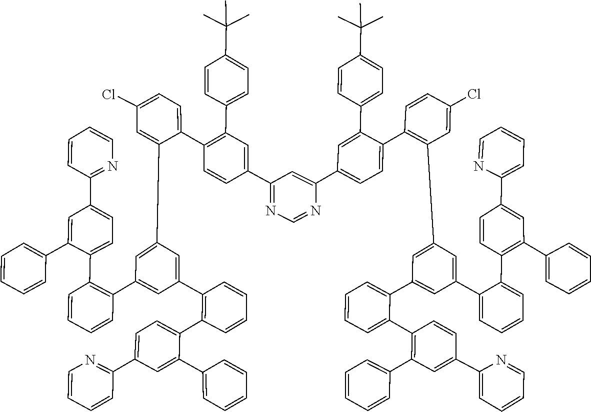 [SMILES: CC(C)(C)c1ccc(-c2cc(-c3cc(-c4ccc(-c5ccc(Cl)cc5-c5cc(-c6ccccc6-c6ccc(-c7ccccn7)cc6-c6ccccc6)cc(-c6ccccc6-c6ccc(-c7ccccn7)cc6-c6ccccc6)c5)c(-c5ccc(C(C)(C)C)cc5)c4)ncn3)ccc2-c2ccc(Cl)cc2-c2cc(-c3ccccc3-c3ccc(-c4ccccn4)cc3-c3ccccc3)cc(-c3ccccc3-c3ccc(-c4ccccn4)cc3-c3ccccc3)c2)cc1] |

Synthesis of the Emitter Base Structure Stage 3

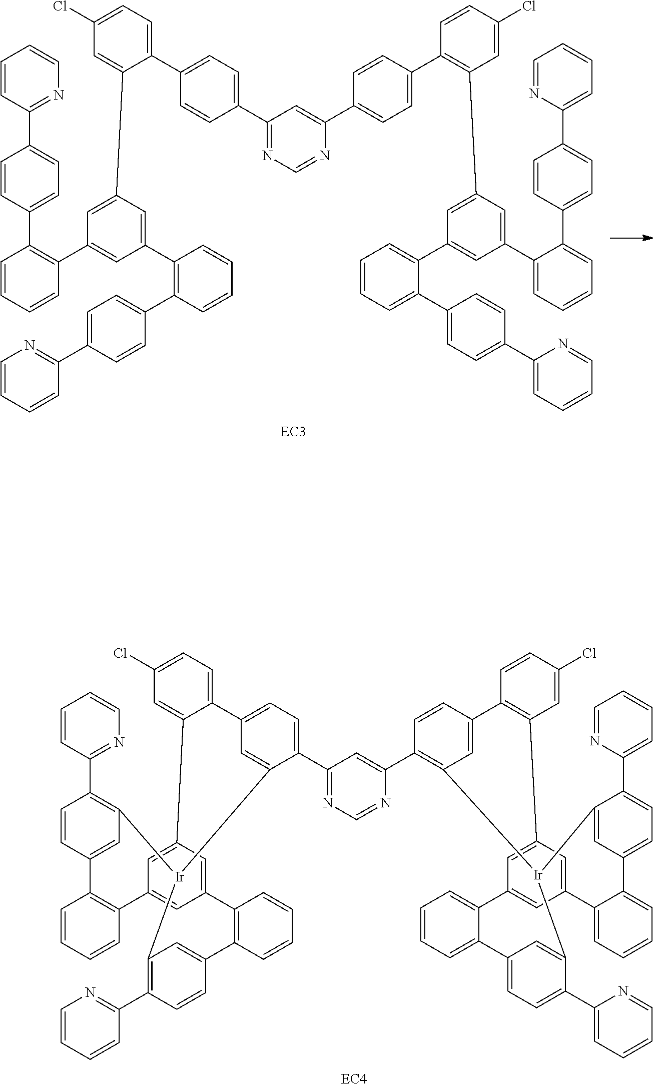

An initial charge of 52.3 g (34.4 mmol) of EC3, 35 g (71.5 mmol) of tris(acetylacetonato)iridium(III) and 523 g of hydroquinone is heated to 260° C. and stirred at that temperature for 2 h. Subsequently, the reaction mixture is allowed to cool, with dropwise addition of 500 ml of ethylene glycol at 220° C. and 2 l of methanol starting from 120° C. After cooling to room temperature, the precipitated solids are filtered through a double-ended frit. The diastereomeric metal complex mixture containing AA and AA isomers (racemic) and AA isomer (meso) in a molar ratio of 1:1 (determined by ¹H NMR) is dissolved in 300 ml of dichloromethane, applied to 100 g of silica gel and separated by chromatography with a silica gel column in the form of a toluene slurry, with maximum exclusion of light. The foremost spot, called isomer 1 (I1) hereinafter, is eluted first, followed by the later-eluting isomer, called isomer 2 (I2) hereinafter. And, after removing the solvents, a deep red solid is obtained. Yield: I1: 29 g (15.2 mmol), 45% of theory, I2: 24.3 g (12.7 mmol), 37% of theory.

The metal complexes shown below can in principle be purified by chromatography (typically using an automated column system (Torrent from Axel Semrau), recrystallization or hot extraction). Images of complexes adduced hereinafter typically show only one isomer. The isomer mixture can be separated, but can also be used in the OLED as an isomer mixture. However, there are also ligand systems in which only one pair of diastereomers forms for steric reasons.

The compounds which follow can be synthesized in an analogous manner. The chromatographic separation of the diastereomer mixture which is typically obtained is effected on flash silica gel in an automated column system (Torrent from Axel Semrau):

| | Reactant | Product |
|---|---|---|
| EC4b | EC3b | 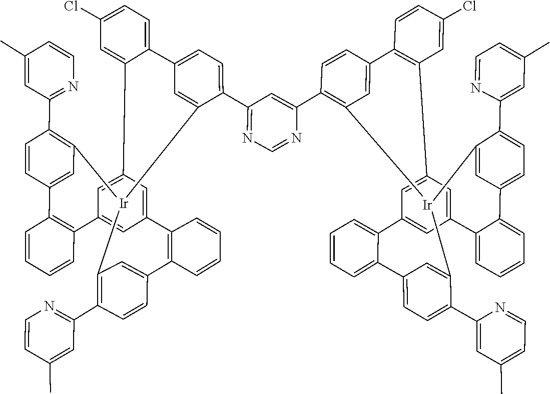 |
| EC4c | EC3c | 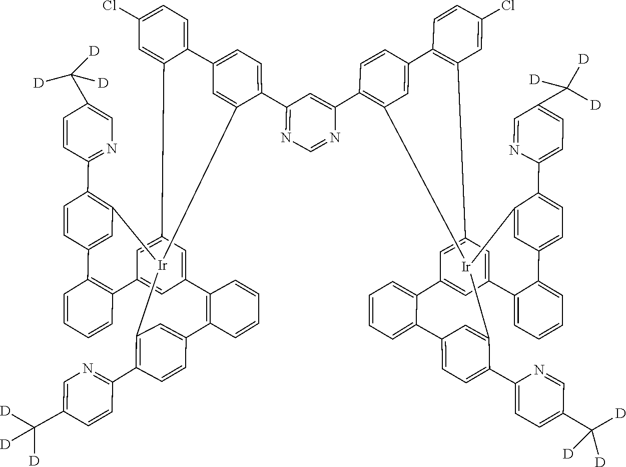 |
| EC4d | EC3d | 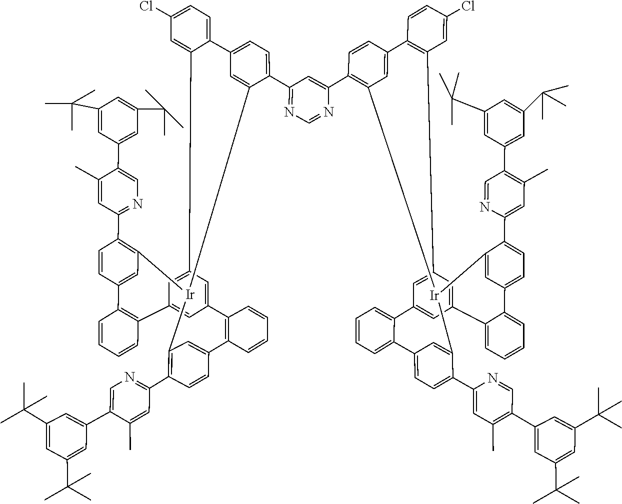 |
| EC4e | EC3e | 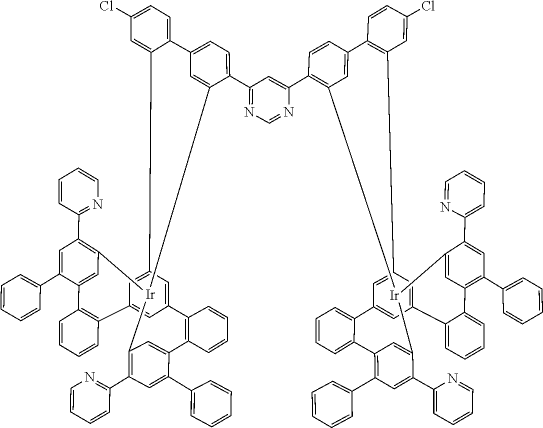 |
| EC4f | EC3h | 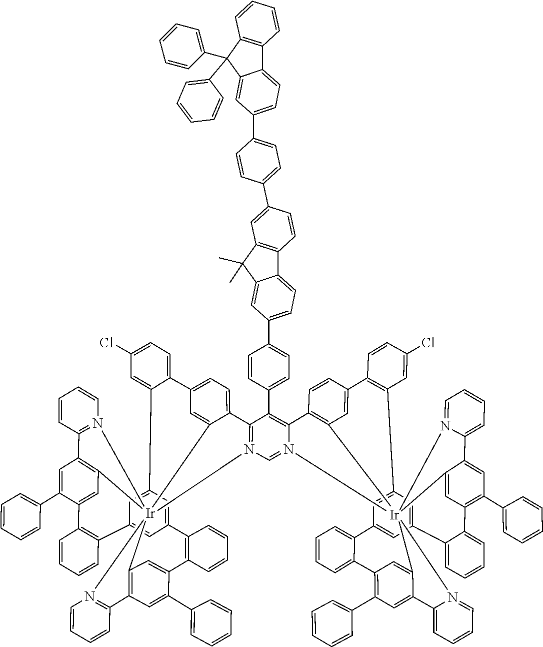 |
| EC4g | EC3k | 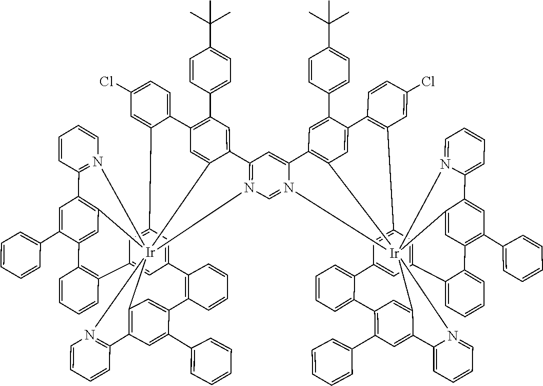 |
| EC4h | EC3j | 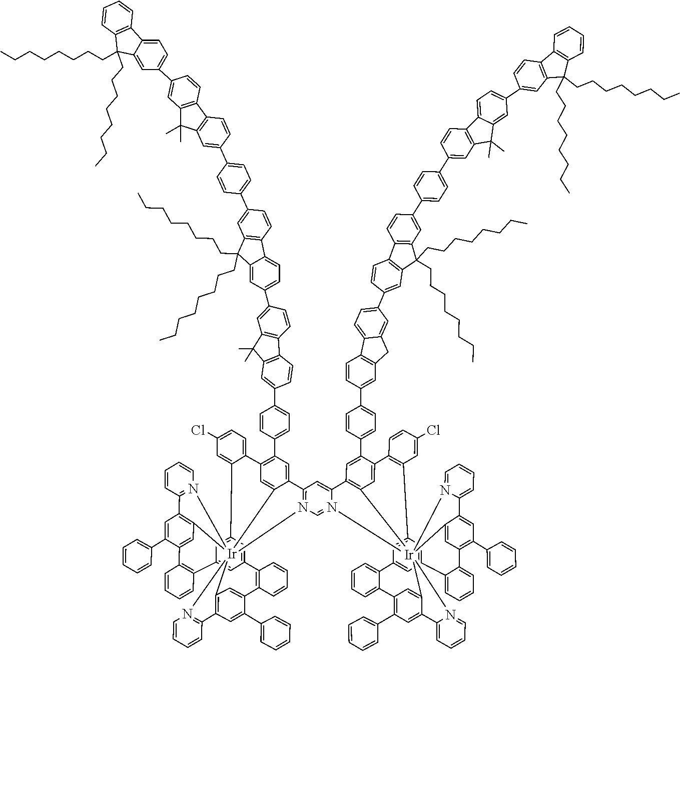 |
| EC4i | EC3i | 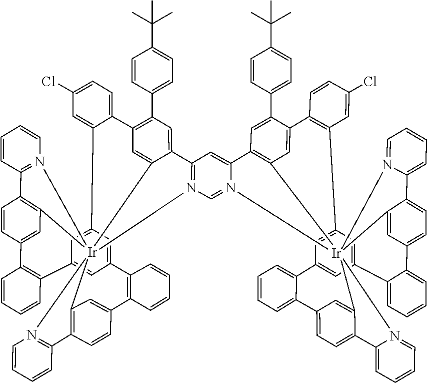 |

Synthesis of the Emitter Base Structure Stage 4

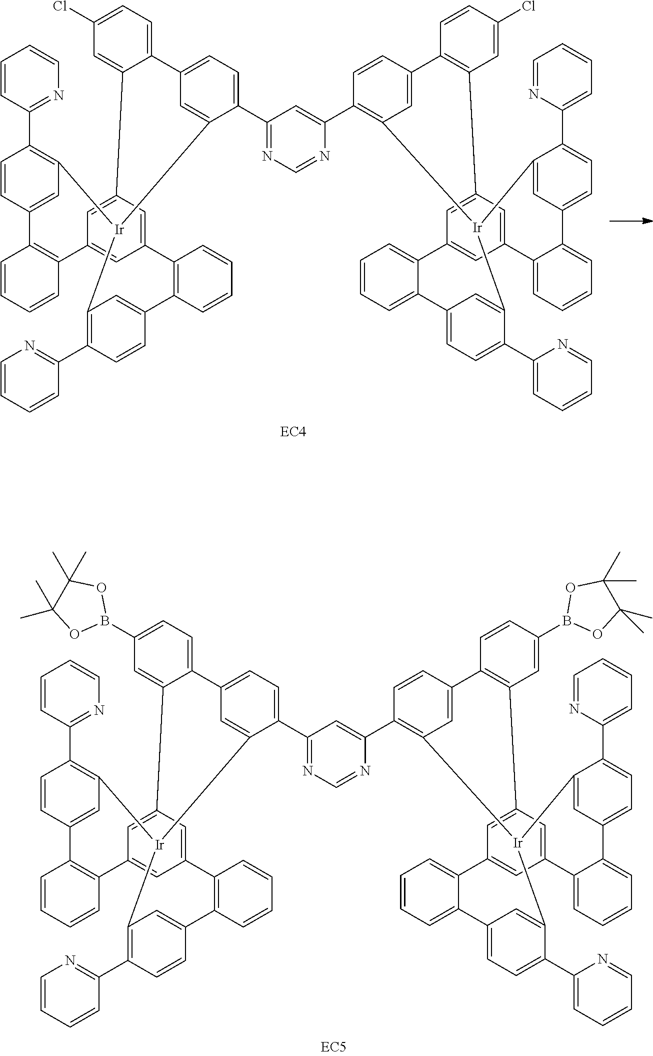

An initial charge of 11.7 g (6.2 mmol) of EC4, 3.3 g (13 mmol) of bis(pinacolato)diboron, 2.4 g (25 mmol) of potassium acetate and 453 mg (0.61 mmol) of trans-dichlorobis(tricyclohexylphosphine)palladium(II) in 600 ml of dioxane is refluxed for 16 h. After cooling to room temperature, 400 ml of water is added, followed by repeated extraction with dichloromethane, and the combined organic phases are extracted repeatedly with water. The organic phase is subsequently filtered through silica gel (dichloromethane) and concentrated under reduced pressure. The residue obtained is crystallized from dichloromethane/methanol. Yield 12.8 g (6.1 mmol), 98% of theory.

The following compounds can be prepared analogously:

| | Reactant | Product |
|---|---|---|
| EC5b | EC4b | 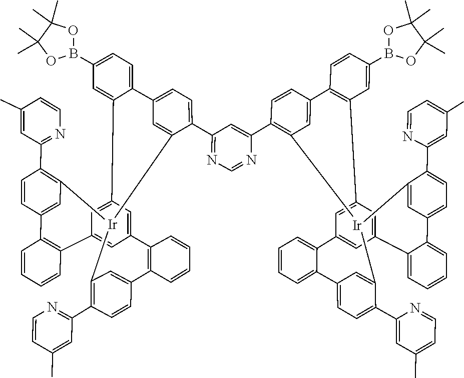 |
| EC5c | EC4c | 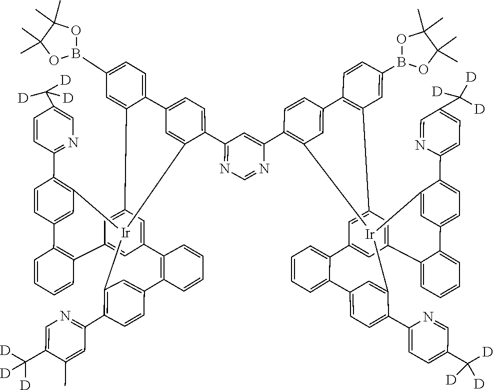 |
| EC5d | EC4d | 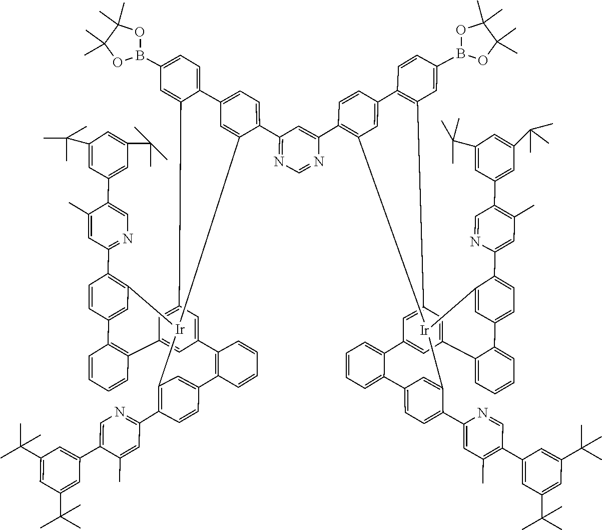 |
| EC5e | EC4e | 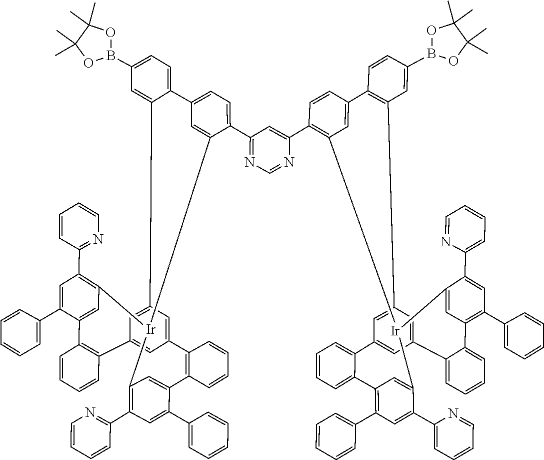 |
| EC5f | EC4f | 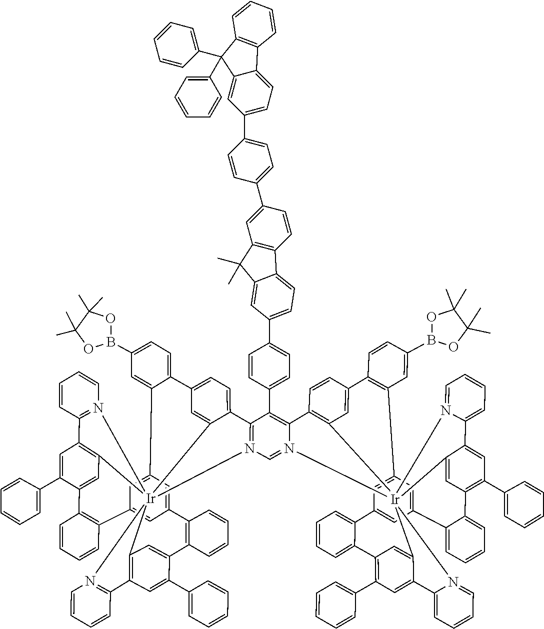 |
| EC5g | EC4g | 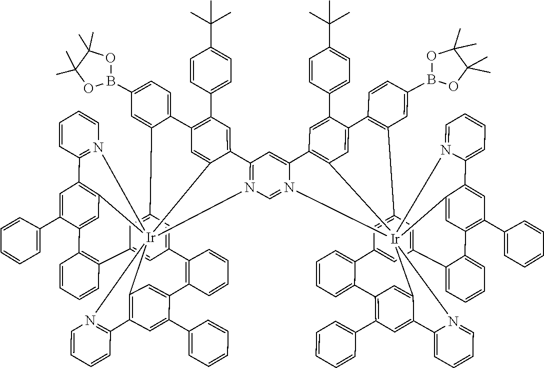 |
| EC5h | EC4h | 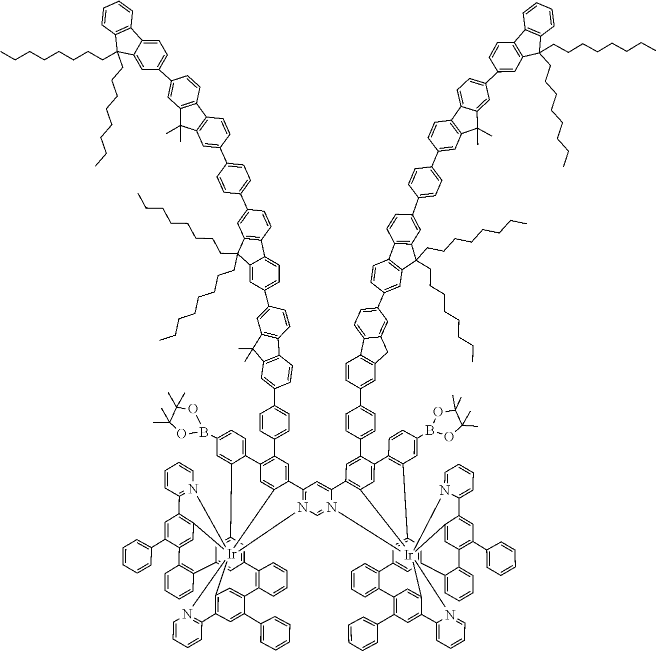 |
| EC5i | EC4i | 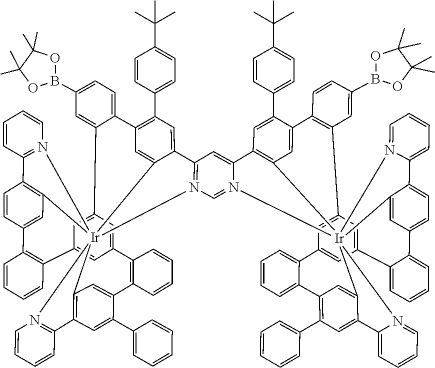 |

Synthesis of the Emitter Em1

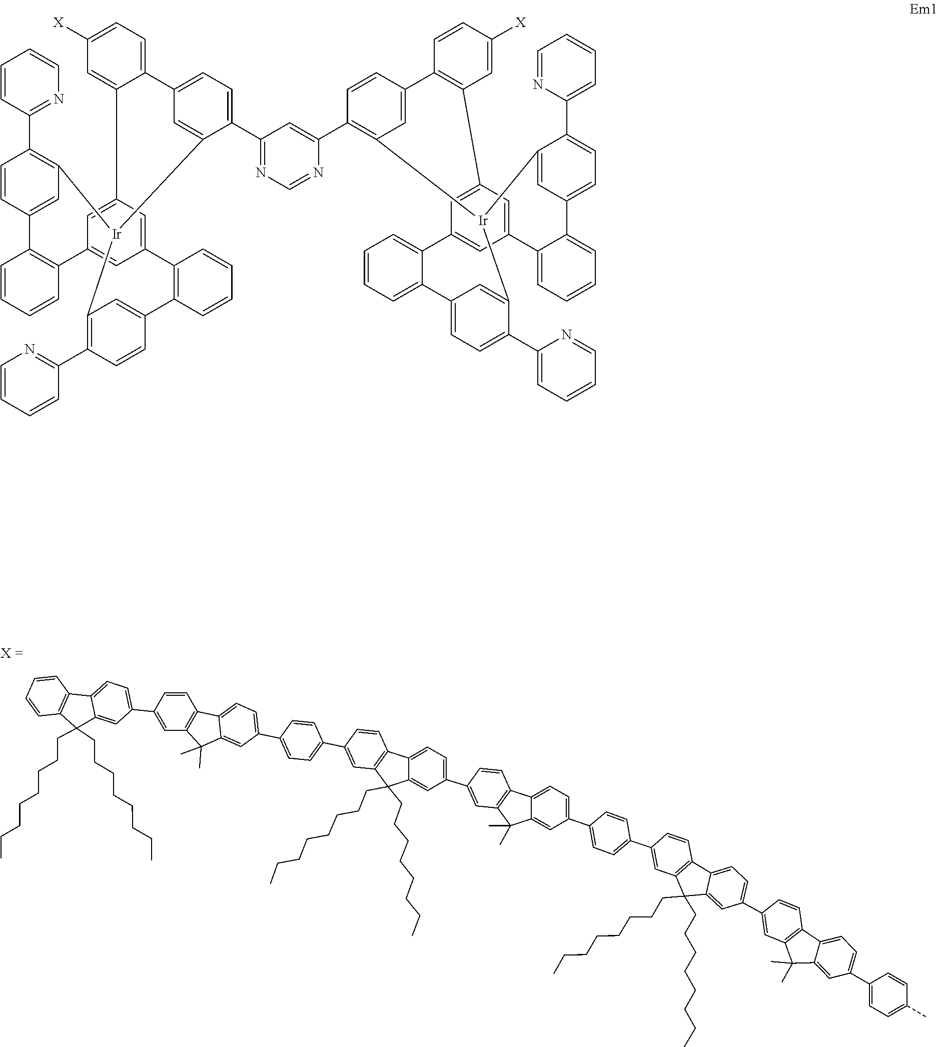

2.7 g (1.3 mmol) of EC5, 5.3 g (2.6 mmol) of E1, 0.79 g (5.2 mmol) of caesium fluoride and 97 mg (0.13 mmol) of trans-dichlorobis(tricyclohexylphosphine)palladium(II) are dissolved in 80 ml of dioxane and refluxed for 16 h. After cooling to room temperature, dichloromethane and water are added to the reaction mixture, and the organic phase is removed. The aqueous phase is extracted twice with dichloromethane, and the combined organic phases are extracted with water and then concentrated under reduced pressure. The residue is repeatedly purified by chromatography (SiO₂, heptane/dichloromethane) and then crystallized once again from dichloromethane/methanol. The resultant solids are dried under reduced pressure at 200° C. Yield: 2.7 g (0.47 mmol), 36% of theory.

The following compounds can be prepared analogously:

| Reactant A | Reactant B |
|---|---|
| EC5b | E1 |

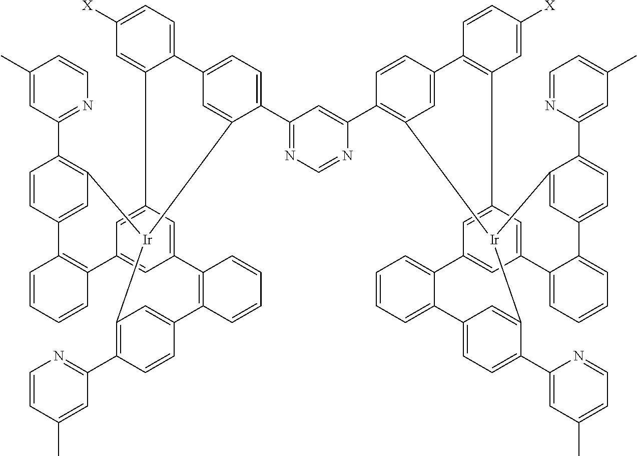

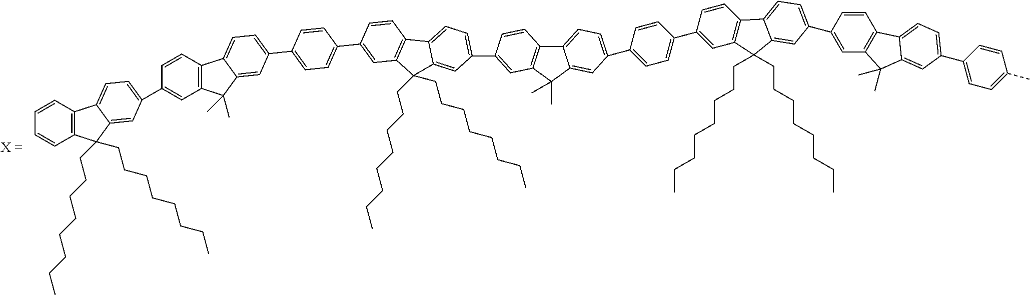

Em2

| | |
|---|---|
| EC5c | E1 |

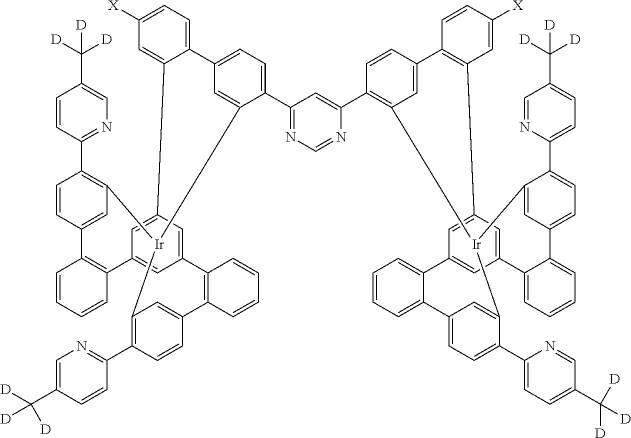

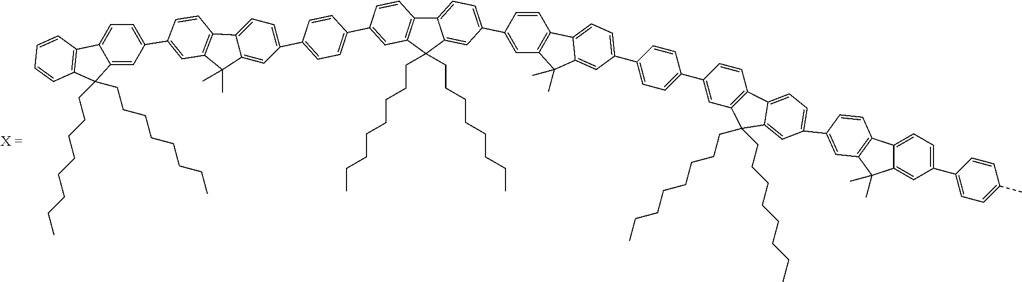

Em3

| | |
|---|---|
| EC5d | E1 |

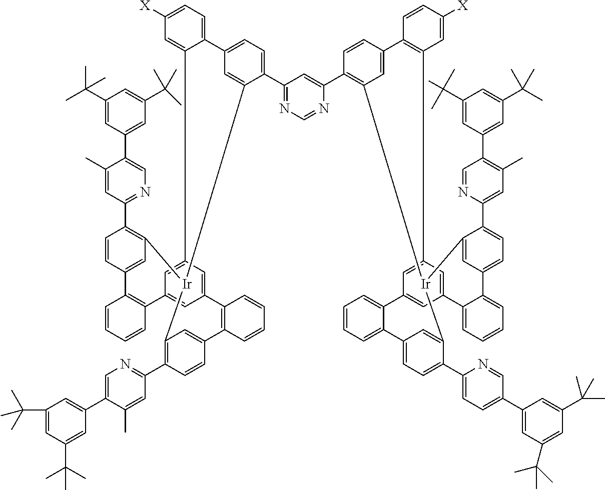

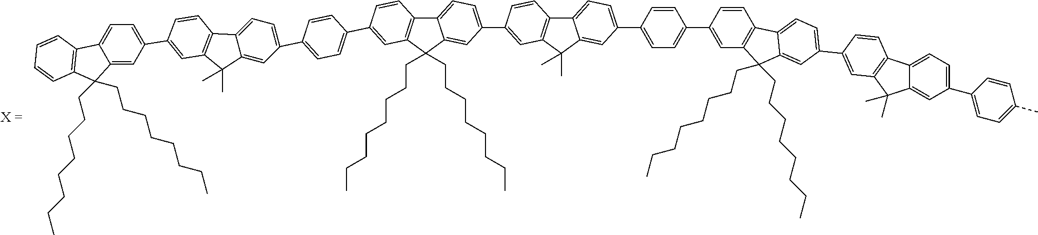

Em4

| | |
|---|---|
| EC5e | E1 |

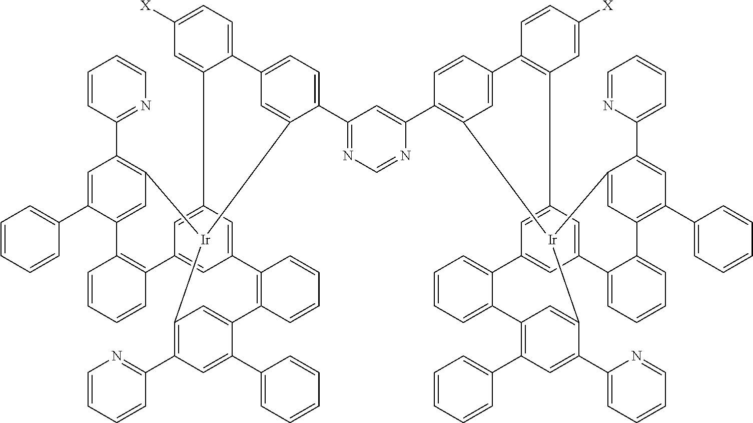

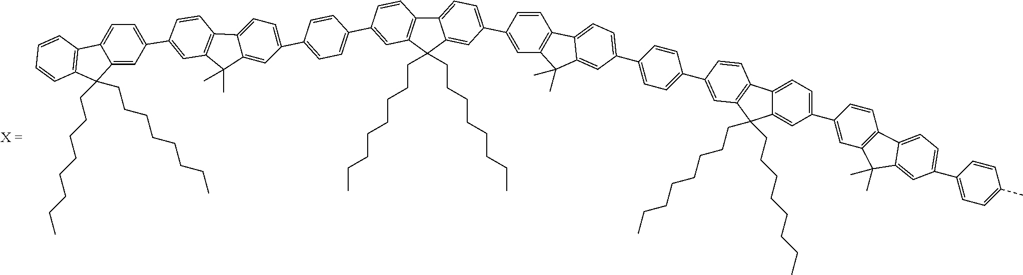

Em5

| | |
|---|---|
| EC5a | E7 |

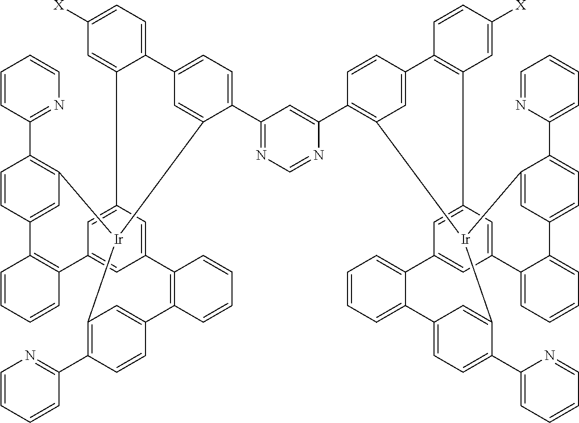

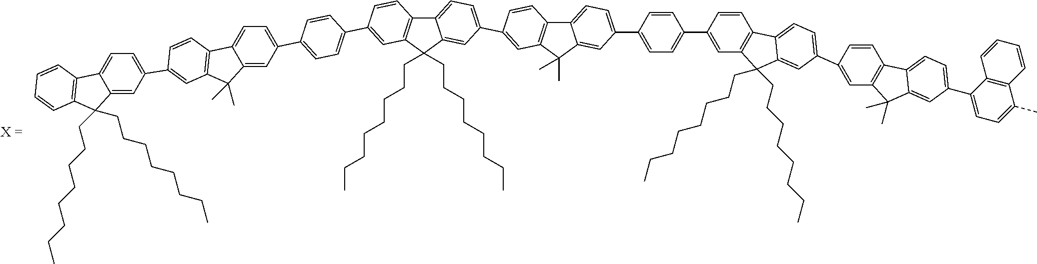

Em6

| | |
|---|---|
| EC5a | B7 |

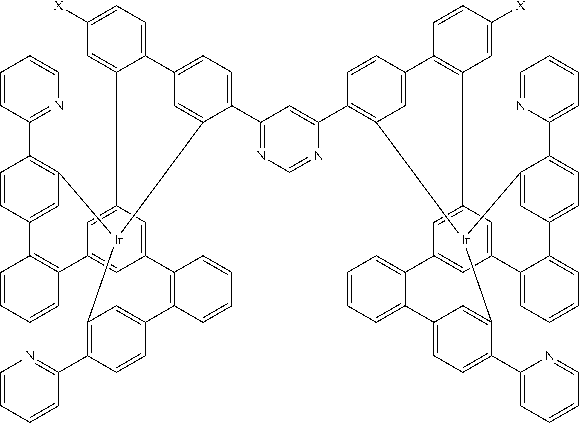

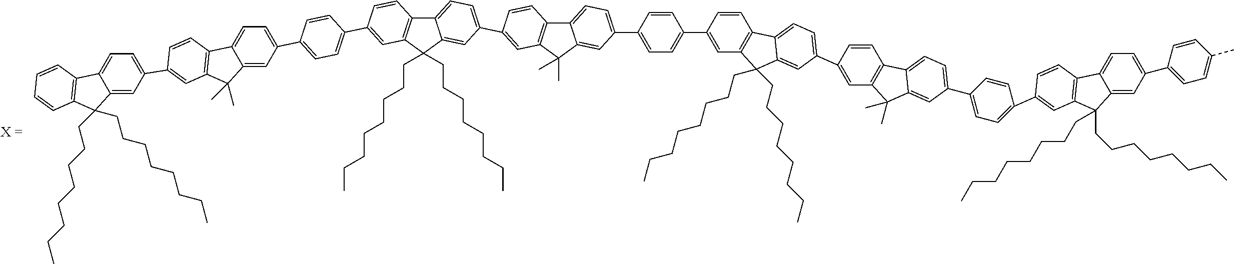

Em7

| | |
|---|---|
| EC5a | 2179264-15-2 |

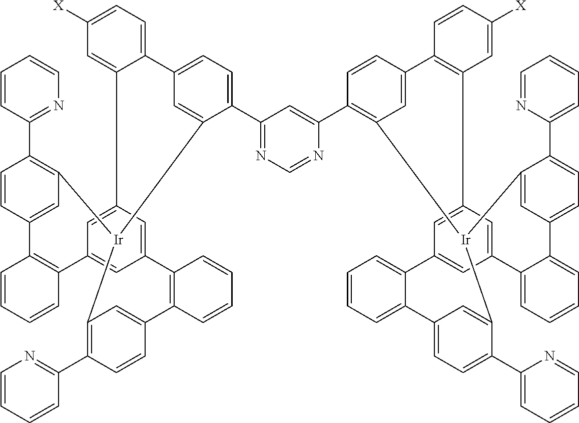

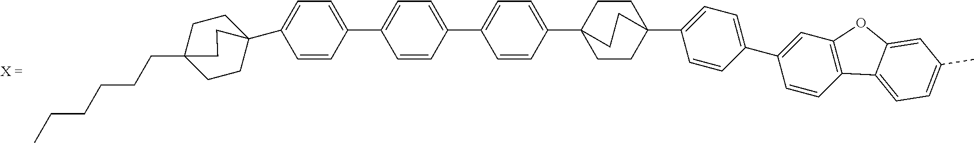

Em8

| | |
|---|---|
| EC5a | E15 |

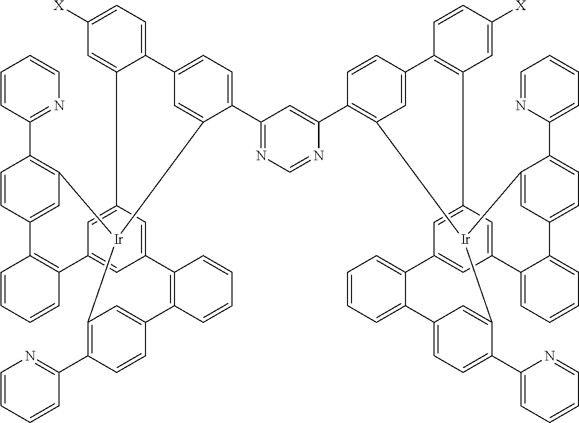

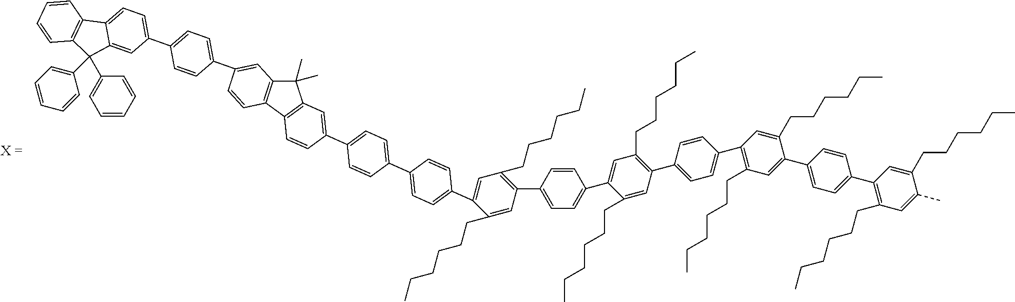

Em9

| | |
|---|---|
| EC5a | E16 |

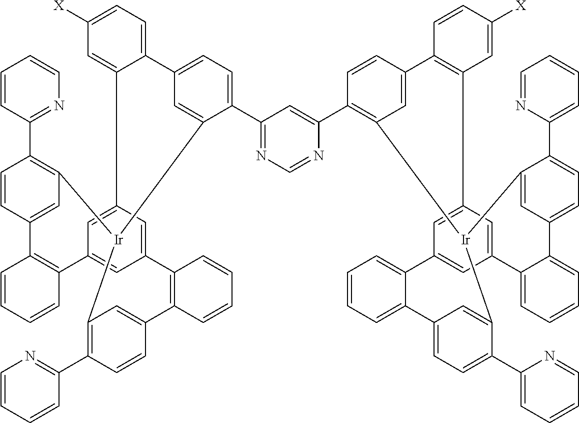

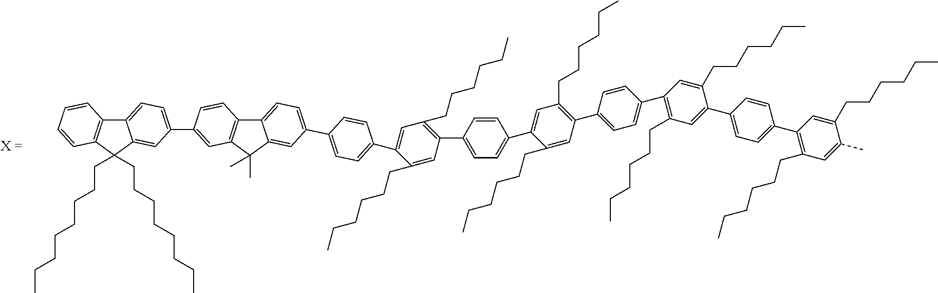

Em10

| | |
|---|---|
| EC5a | E17 |

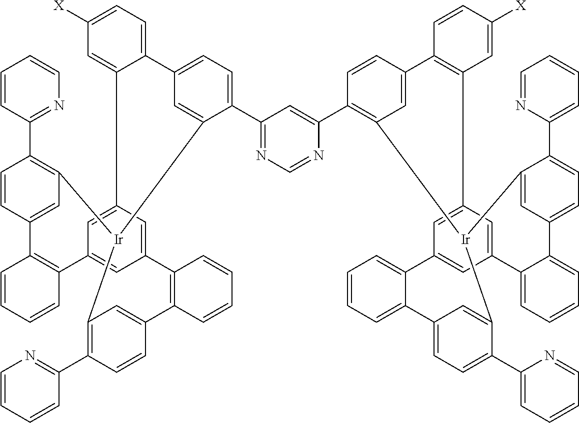

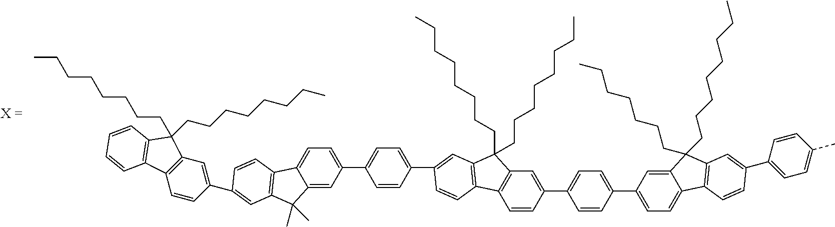

Em11

| | |
|---|---|
| EC5a | E18 |

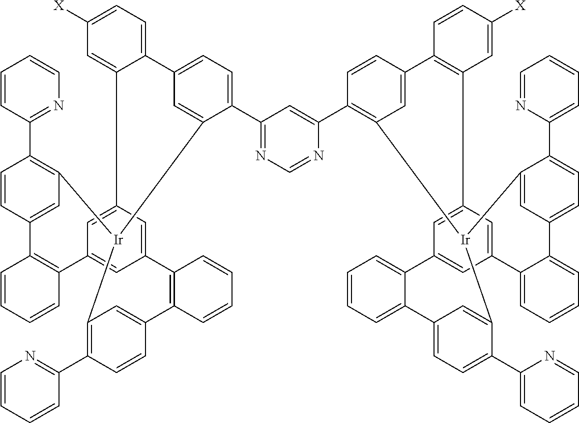

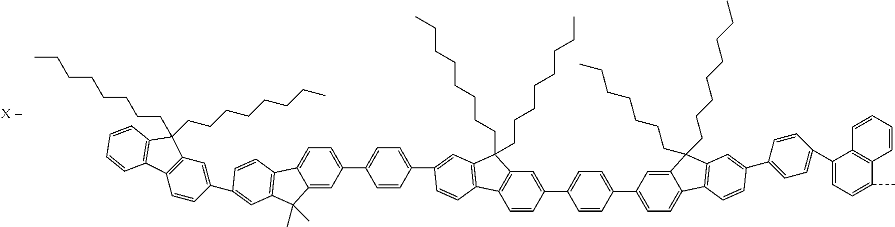

Em12

| | |
|---|---|
| E19 | EC5a |

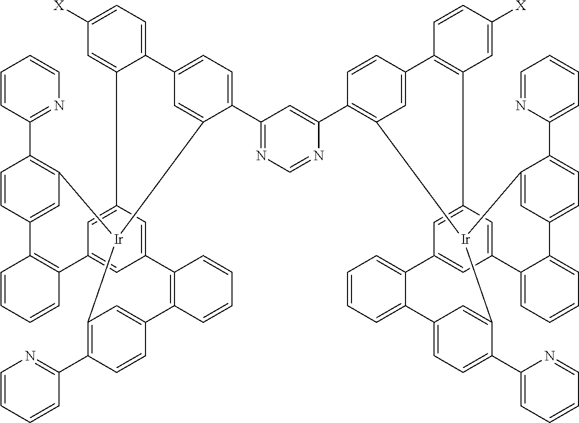

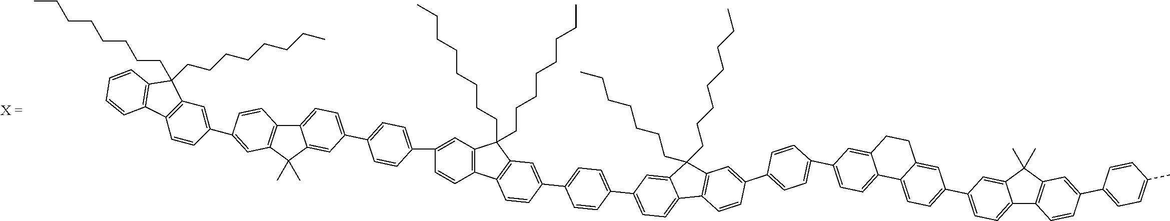

Em13

| | |
|---|---|
| E20 | EC5a |

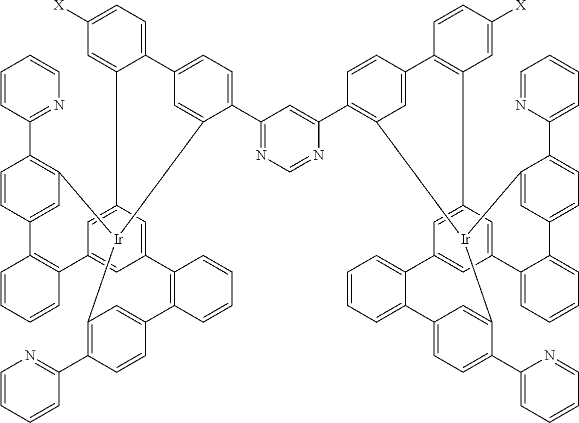

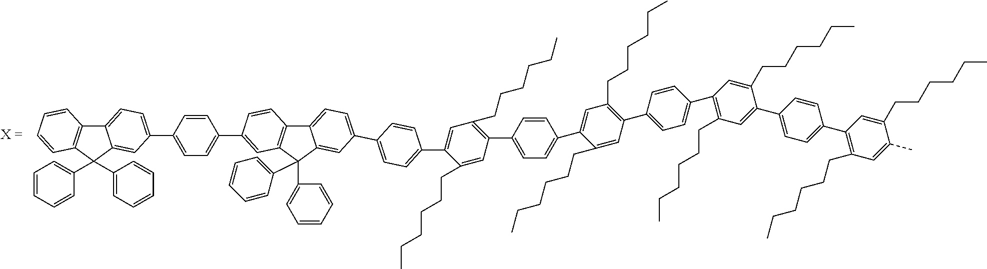

Em14

| | |
|---|---|
| EC5e | E21 |

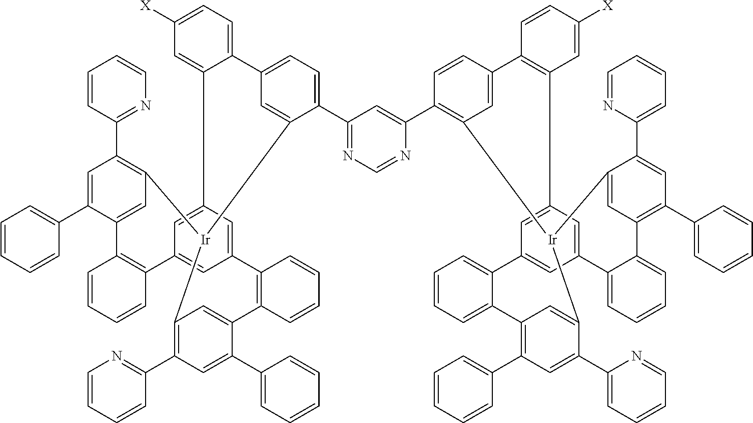

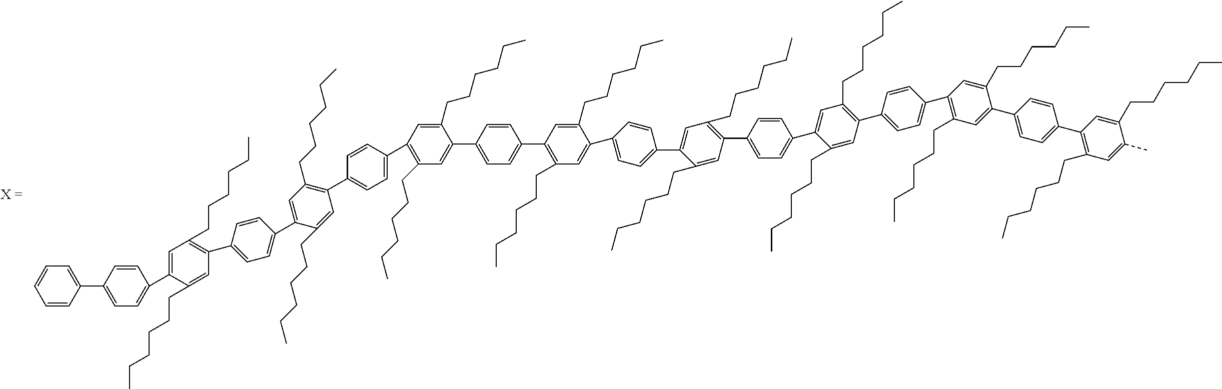

Em15

| | |
|---|---|
| EC5e | E22 |

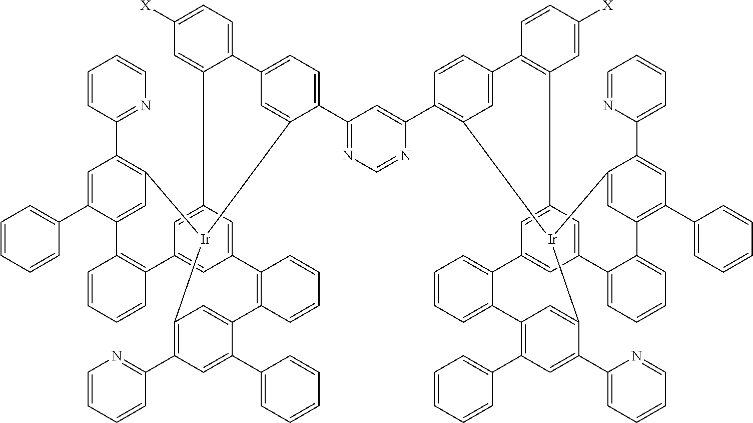

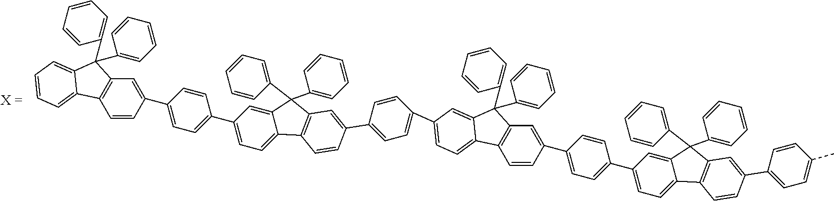

Em16

| | |
|---|---|
| EC5a | E23 |

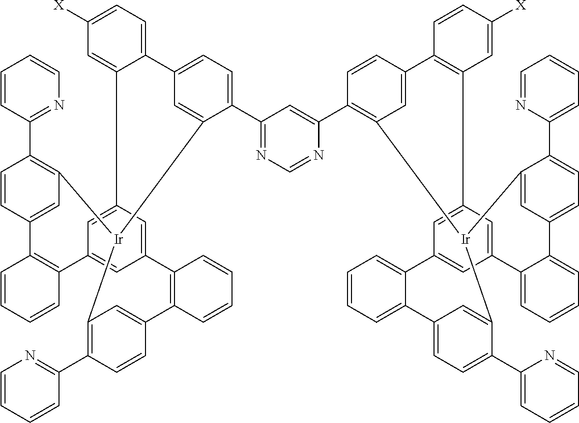

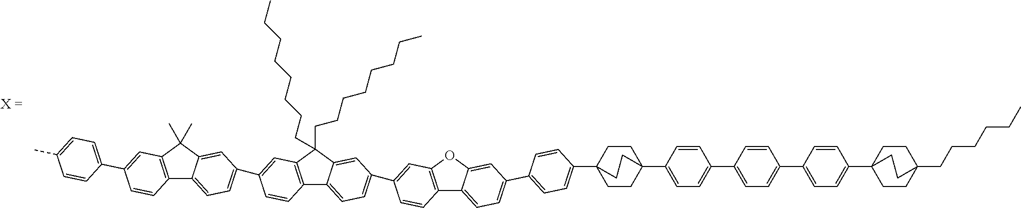

Em17

| | |
|---|---|
| E20 | EC5g |

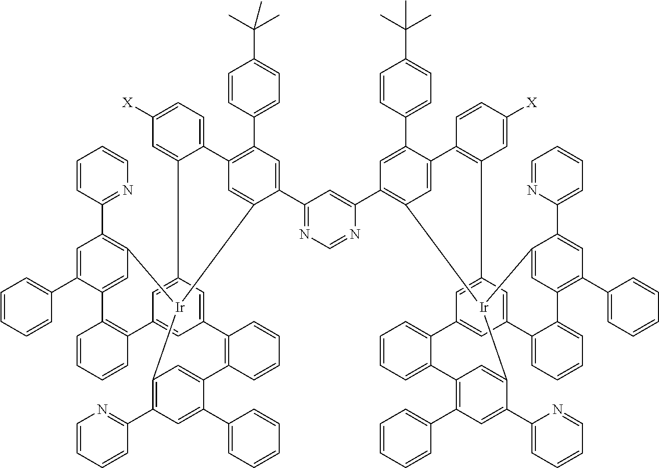

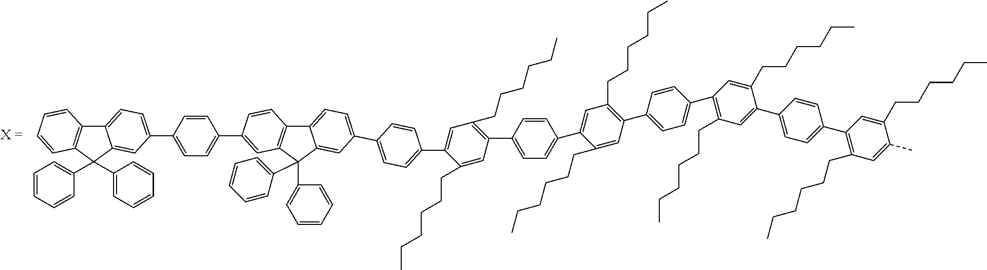

Em18

| | |
|---|---|
| C1 | EC5h |

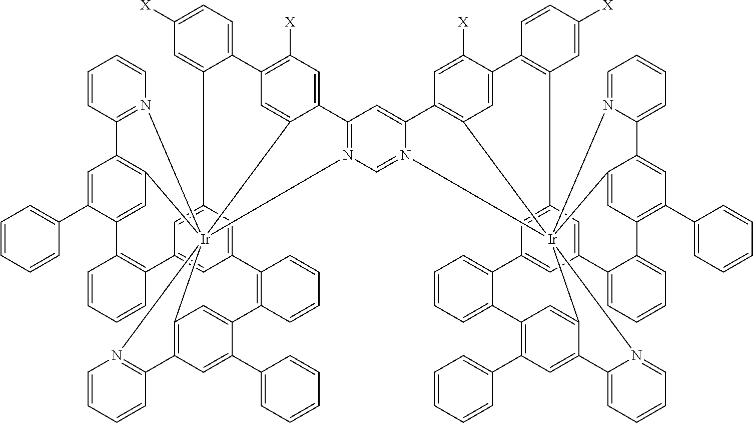

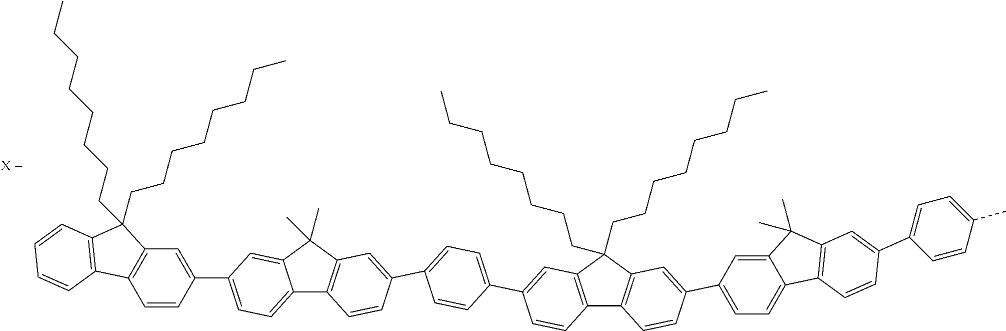

Em19

| | |
|---|---|
| E1 | EC5h |

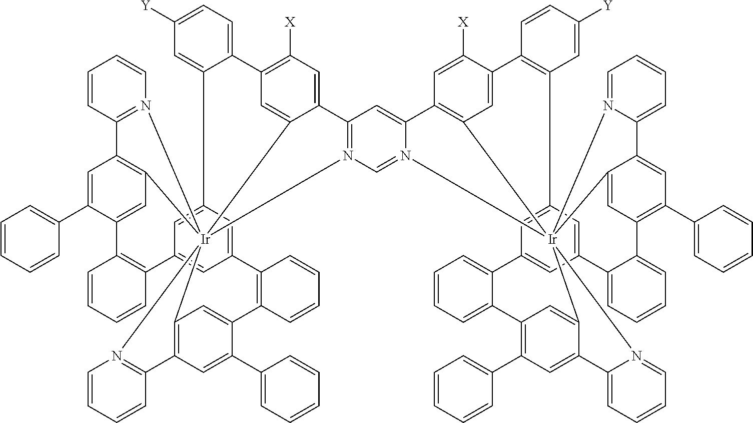

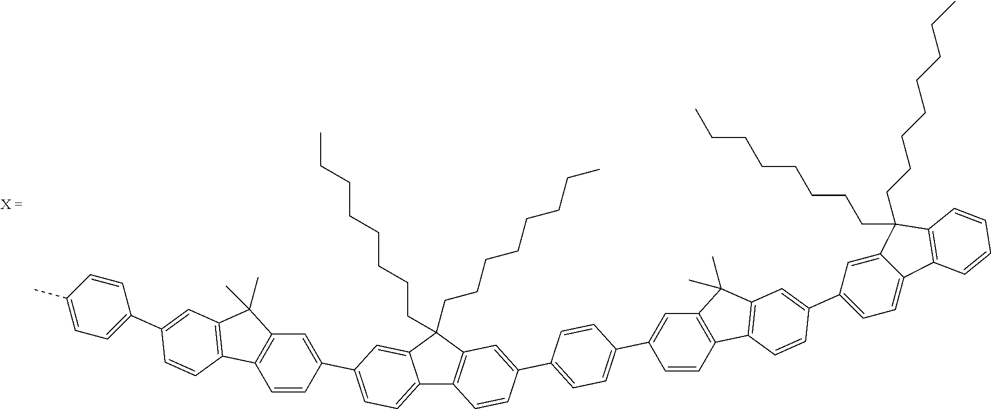

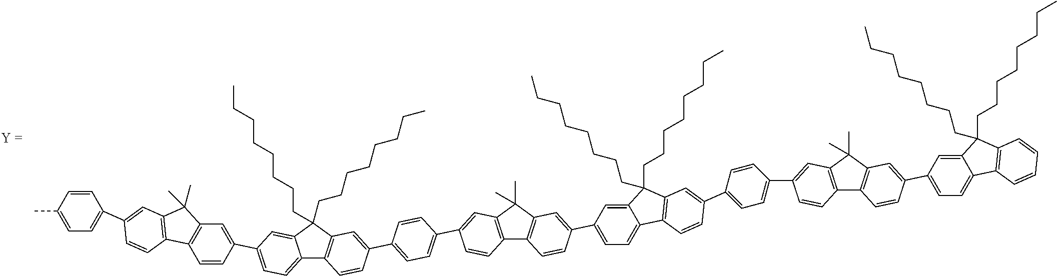

Em20

| | |
|---|---|
| E1 | EC5f |

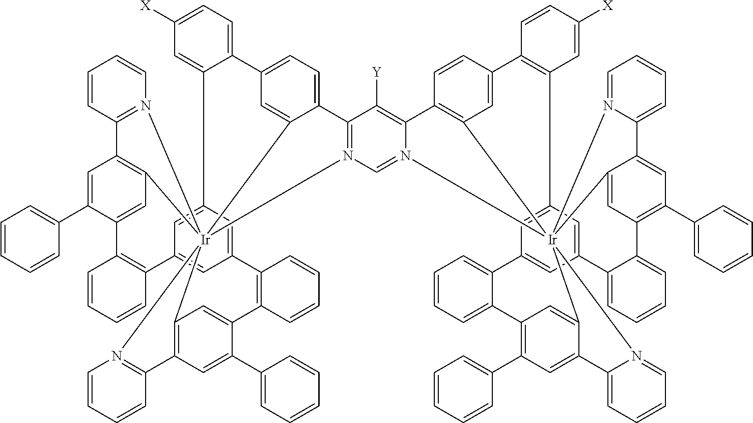

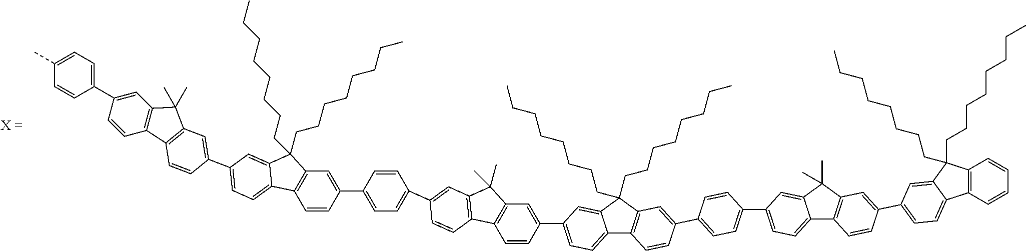

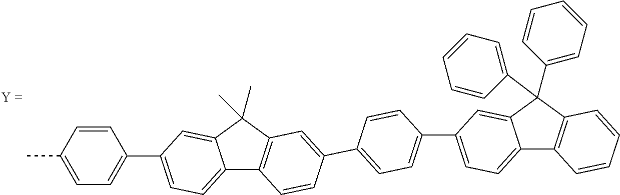

Em21

| | |
|---|---|
| E1 | EC5i |

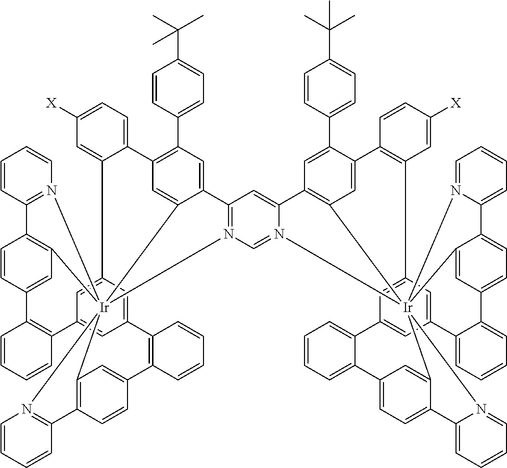

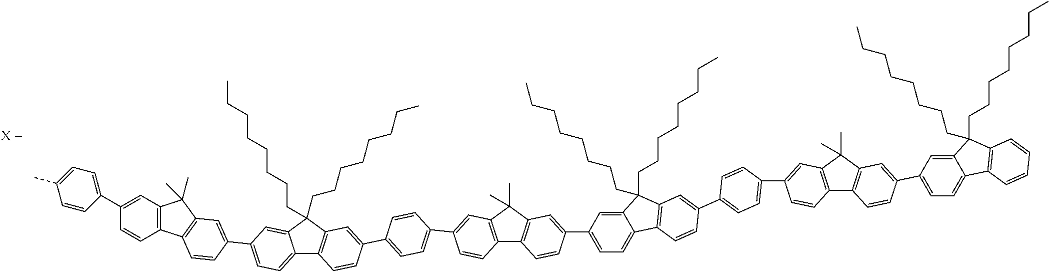

Em22

### Physics Examples

Production of the OLEDs and of the Films for the Photophysical Characterization

The complexes of the invention can be processed from solution. There are already many descriptions of the production of completely solution-based OLEDs in the literature, for example in WO 2004/037887 by means of spin coating. There have likewise been many previous descriptions of the production of vacuum-based OLEDs, including in WO 2004/058911. In the examples discussed hereinafter, layers applied in a solution-based and vacuum-based manner are combined within an OLED, and so the processing up to and including the emission layer is effected from solution and in the subsequent layers (hole blocker layer and electron transport layer) from vacuum. For this purpose, the previously described general methods are matched to the circumstances described here (layer thickness variation, materials) and combined as described hereinafter. The general structure is as follows: substrate/ITO (50 nm)/hole injection layer (HIL) (60 nm)/hole transport layer (HTL) (20 nm)/emission layer (EML) (60 nm)/hole blocker layer (HBL) (10 nm)/electron transport layer (ETL) (40 nm)/cathode (aluminium, 100 nm). The substrates used are glass plates coated with structured ITO (indium tin oxide) of thickness 50 nm. For better processing, they are coated with PEDOT:PSS (poly(3,4-ethylenedioxy-2,5-thiophene) polystyrenesulfonate, purchased from Heraeus Precious Metals GmbH & Co. KG, Germany). PEDOT:PSS is spun on from water under air and subsequently baked under air at 180° C. for 10 minutes in order to remove residual water. The hole transport layer and the emission layer are applied to these coated glass plates. The hole transport layer used is crosslinkable. A polymer of the structure depicted below is used, which can be synthesized according to WO 2013/156130:

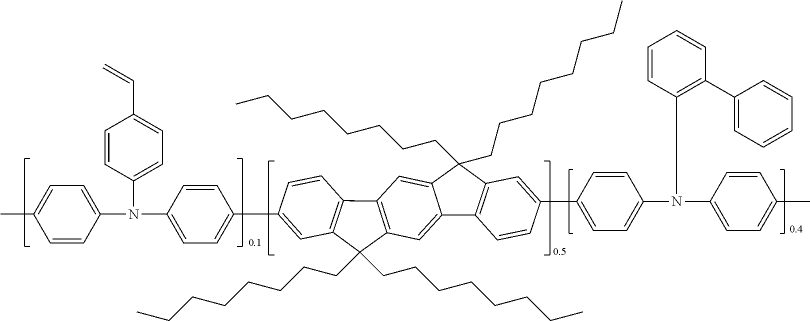

The hole transport polymer is dissolved in toluene. The typical solids content of such solutions is about 5 g/I when, as here, the layer thickness of 20 nm which is typical of a device is to be achieved by means of spin-coating. The layers are spun on in an inert gas atmosphere, argon in the present case, and baked at 220° C. for 30 minutes.

The emission layer is always composed of at least one matrix material (host material) and an emitting dopant (emitter). In addition, it is possible to use mixtures of a plurality of matrix materials and co-dopants. What is meant here by details given in such a form as TMM-A (92%):dopant (8%) is that the material TMM-A is present in the emission layer in a proportion by weight of 92% and dopant in a proportion by weight of 8%. The mixture for the emission layer is dissolved in toluene or optionally chlorobenzene. The typical solids content of such solutions is about 17 g/I when, as here, the layer thickness of 60 nm which is typical of a device is to be achieved by means of spin-coating. The layers are spun on in an inert gas atmosphere, argon in the present case, and baked at 160° C. for 10 minutes. The materials used in the present case are shown in table 1.

TABLE 1
EML materials used

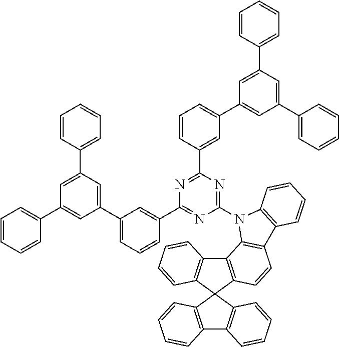 [SMILES: c1ccc(-c2cc(-c3ccccc3)cc(-c3cccc(-c4nc(-c5cccc(-c6cc(-c7ccccc7)cc(-c7ccccc7)c6)c5)nc(-n5c6ccccc6c6ccc7c(c65)-c5ccccc5C75c6ccccc6-c6ccccc65)n4)c3)c2)cc1]

A-1
See WO14094963

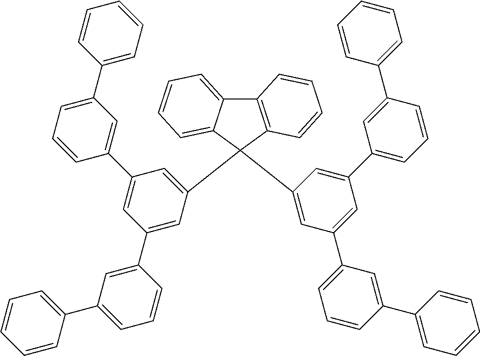 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5ccccc54)c3)c2)cc1]

B-1
See WO09124627

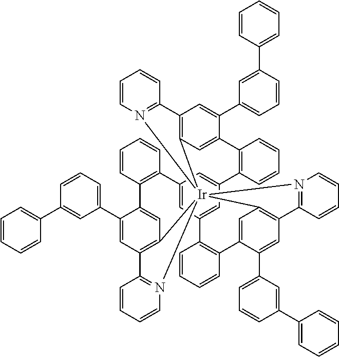

C-1
See WO 2016/124304

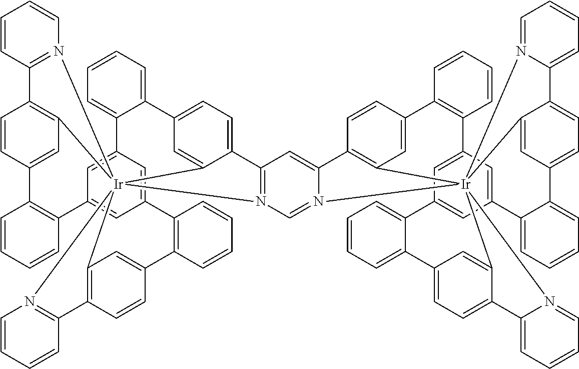

D-1
(WO 2018/041769)

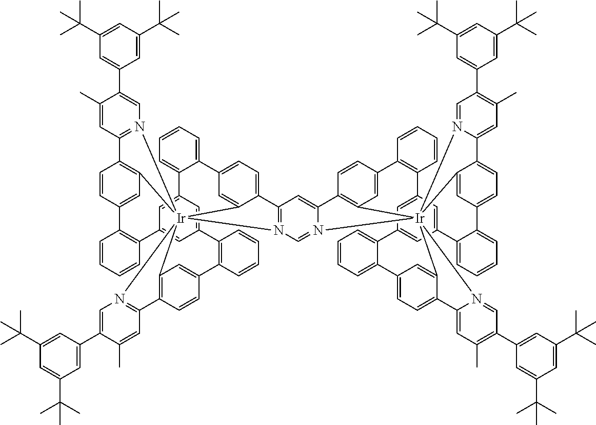

D-2
(WO 2018/041769)

The materials for the hole blocker layer and electron transport layer are applied by thermal vapour deposition in a vacuum chamber. The electron transport layer, for example, may consist of more than one material, the materials being added to one another by co-evaporation in a particular proportion by volume. Details given in such a form as ETM1:ETM2 (50%:50%) mean here that the ETM1 and ETM2 materials are present in the layer in a proportion by volume of 50% each. The materials used in the present case are shown in table 2. In the OLED components described here, ETM3 was used as HBL material, and ETM1:ETM2 (50:50) as ETL mixture.

TABLE 2
HBL and ETL materials used

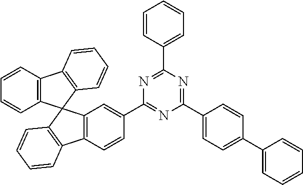 [SMILES: c1ccc(-c2ccc(-c3nc(-c4ccccc4)nc(-c4ccc5c(c4)C4(c6ccccc6-c6ccccc64)c4ccccc4-5)n3)cc2)cc1]

ETM1
[1819335-36-8]

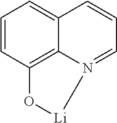

ETM2
[25387-93-3]

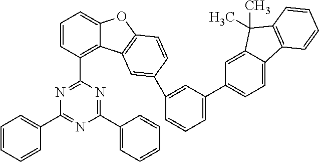 [SMILES: CC1(C)c2ccccc2-c2ccc(-c3cccc(-c4ccc5oc6cccc(-c7nc(-c8ccccc8)nc(-c8ccccc8)n7)c6c5c4)c3)cc21]

ETM3
[2392900-45-5]

The cathode is formed by the thermal evaporation of a 100 nm aluminium layer. The samples are encapsulated.

Films for photophysical characterization are produced as a single layer on quartz glass substrates by the process described above for emission layers. B1 is used here as host material, and 30 nm-thick films are produced. The samples are encapsulated.

Characterization:

Measurement of Emitter Orientation in the Solution-Processed Film

In the measurement setup, the solution-processed film containing the complex is irradiated with a laser, the molecules are excited and then the photoluminescence spectrum emitted is measured in an angle-dependent manner. The measured optical properties of the pure matrix material, using physical laws of optics, can be used to calculate a result for a potential 100% horizontal and 100% vertical orientation of the molecules. Subsequently, the measurements are fitted to the extreme orientations calculated and hence the orientation factor (optical orientation anisotropy) is determined. A perfect horizontal orientation of the molecules is described by Θ=0, the isotropic case by Θ=0.33, and the completely vertically aligned case by Θ=1. This value reflects the averaged orientation over all molecules in the layer that have been excited by the photoluminescence process, meaning that all complex molecules lie within the measurement spot irradiated by the laser. It is not possible to determine the orientation of a single molecule by this method. Frischeisen et al., Applied Physics Letters 96, 073302 (2010) and Schmidt et al., Phys. Rev. Appl. 8, 037001 (2017) describe the performance of such optical measurements for determination of emitter orientation.

Table 3 summarizes the optical orientation of the comparative material and the selected materials of the invention. The complexes of the invention are used in somewhat higher percentages by weight in order to compensate for the higher molecular weight. It is found that the two comparative complexes have an isotropic arrangement in the film, whereas complexes of the invention have more of a horizontal alignment.

TABLE 3
Optical orientation anisotropy ⊖

| | | % in | |
|---|---|---|---|
| | | host | |
| | Complex | B1 | ⊖ |
| V1 | D1 | 10 | 0.33 |
| E1 | Em1 | 15 | 0.26 |
| V2 | D2 | 10 | 0.33 |
| E2 | Em4 | 15 | 0.26 |
| E3 | Em5 | 15 | 0.26 |
| E4 | Em8 | 15 | 0.29 |
| E5 | Em16 | 15 | 0.27 |
| E6 | Em13 | 15 | 0.26 |
| E7 | Em12 | 15 | 0.28 |
| E8 | Em6 | 15 | 0.26 |
| E9 | Em11 | 15 | 0.28 |
| E10 | Em15 | 15 | 0.25 |
| E11 | Em10 | 15 | 0.28 |
| E12 | Em7 | 15 | 0.24 |
| E13 | Em14 | 15 | 0.27 |
| E14 | Em2 | 15 | 0.26 |
| E15 | Em3 | 15 | 0.26 |
| E16 | Em9 | 15 | 0.26 |
| E17 | Em17 | 15 | 0.27 |
| E30 | Em18 | 15 | 0.27 |
| E31 | Em19 | 15 | 0.28 |
| E32 | Em20 | 15 | 0.25 |
| E33 | Em21 | 15 | 0.26 |
| E34 | Em22 | 15 | 0.26 |

OLED Components:

The OLEDs are characterized in a standard manner. For this purpose, the electroluminescent spectra and the current-voltage-luminance characteristics (IUL characteristics) are determined assuming Lambertian radiation characteristics, and external quantum efficiency at a particular brightness is calculated as a performance figure.

All the components examined luminesce in the red. The EML mixtures used and results achieved are collated in table 4. The complexes of the invention are used in somewhat higher percentages by weight in order to compensate for the higher molecular weight. It is found that complexes of the invention with their more horizontal alignment achieve a distinct increase in quantum efficiency in the OLED component. More particularly, it is found that, in a direct comparison, for the same auxiliary ligand (D2 compared to Em4; D1 compared to Em1, Em13, Em12, Em7, Em14, Em9 and Em17), the substituents of the invention lead to an increase in quantum efficiency.

Any of the complexes of the invention adduced above can be used analogously and lead to comparable results.

TABLE 4
Results for solution-processed OLEDs
(measured at a brightness of 1000 cd/m²)

| | | EQE | Mixing ratio of |
|---|---|---|---|
| Ex. | Emitter | [%] | A1:B1:C1:emitter |
| V3 | D1 | 18.7 | 40:35:17:8 |
| E18 | Em1 | 26.1 | 40:33:17:10 |
| V4 | D2 | 21.8 | 40:35:17:8 |
| E19 | Em4 | 26.5 | 40:33:17:10 |
| E20 | Em5 | 26.2 | 40:33:17:10 |
| E21 | Em13 | 25.9 | 40:33:17:10 |
| E22 | Em12 | 23.2 | 40:33:17:10 |
| E23 | Em15 | 26.3 | 40:33:17:10 |
| E24 | Em7 | 26.5 | 40:33:17:10 |
| E25 | Em14 | 23.9 | 40:33:17:10 |
| E26 | Em2 | 25.7 | 40:33:17:10 |
| E27 | Em3 | 26.0 | 40:33:17:10 |
| E28 | Em9 | 26.0 | 40:33:17:10 |
| E29 | Em17 | 24.1 | 40:33:17:10 |
| E35 | Em18 | 24.2 | 40:33:17:10 |
| E36 | Em19 | 23.4 | 40:33:17:10 |
| E37 | Em20 | 26.4 | 40:33:17:10 |
| E38 | Em22 | 26.2 | 40:33:17:10 |

1.-15. (canceled)

16. A compound of formula (1) 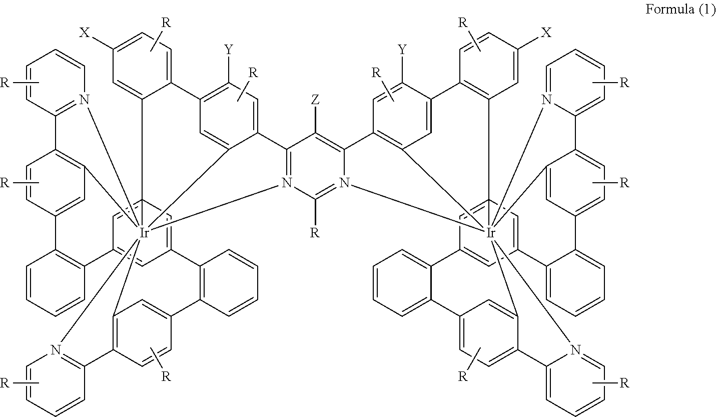
where the symbols and indices used are as follows:
X is the same or different at each instance and is a group of the formula —(Ar)ₙ—R;
Y is the same or different at each instance and is R or X;
Z is the same or different and is R or X;
Ar is the same or different at each instance and is a divalent group selected from the structures (Ar1) to (Ar7) 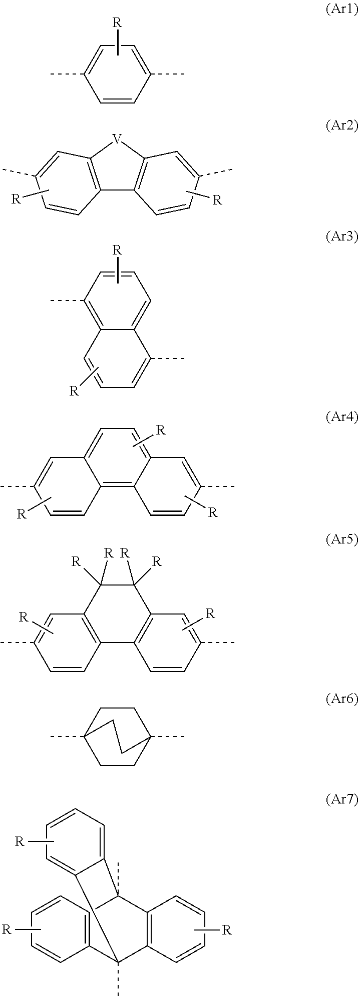
where the dotted bond represents the linkage of the units and V is CR₂, O, S or NR;
n is the same or different at each instance and is an integer from 3 to 20, with the proviso that, in each —(Ar)ₙ—R unit, at least 5 phenyl and/or cyclohexyl groups are joined to one another in a linear manner;
R may occur once or more than once and is the same or different at each instance and is H, D, F, Cl, Br, I, N(R¹)₂, CN, NO₂, OR′, SR′, COOH, C(═O)N(R¹)₂, Si(R¹)₃, B(OR¹)₂, C(═O)R′, P(═O)(R¹)₂, S(═O)R¹, S(═O)₂R¹, OSOR¹, a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R¹ radicals, where one or more nonadjacent CH₂ groups may be replaced by Si(R¹)₂, C═O, NR¹, O, S or CONR¹, or an aromatic or heteroaromatic ring system which has 5 to 40 aromatic ring atoms and may be substituted in each case by one or more R¹ radicals; at the same time, two R radicals together may also form a ring system;
R¹ is the same or different at each instance and is H, D, F, Cl, Br, I, N(R²)₂, CN, NO₂, OR², SR², Si(R²)₃, B(OR²)₂, C(═O)R², P(═O)(R²)₂, S(═O)R², S(═O)₂R², OSOR², a straight-chain alkyl group having 1 to 20 carbon atoms or an alkenyl or alkynyl group having 2 to 20 carbon atoms or a branched or cyclic alkyl group having 3 to 20 carbon atoms, where the alkyl, alkenyl or alkynyl group may in each case be substituted by one or more R² radicals, where one or more nonadjacent CH₂ groups may be replaced by Si(R²)₂, C═O, NR², O, S or CONR², or an aromatic or heteroaromatic ring system which has 5 to 40 aromatic ring atoms and may be substituted in each case by one or more R² radicals; at the same time, two or more R¹ radicals together may form a ring system;
R² is the same or different at each instance and is H, D, F or an aliphatic, aromatic or heteroaromatic organic radical, especially a hydrocarbyl radical, having 1 to 20 carbon atoms, in which one or more hydrogen atoms may also be replaced by F.

17. The compound according to claim 16 of formula (1a) 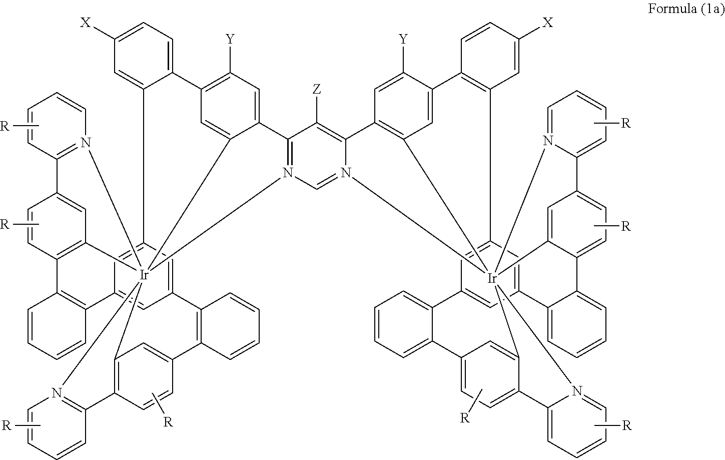
where the symbols have the definitions given in claim 16.

18. The compound according to claim 16, wherein the two substituents X are the same.

19. The compound according to claim 16, selected from the structures of the formulae (1a-1), (1a-2) and (1a-3) 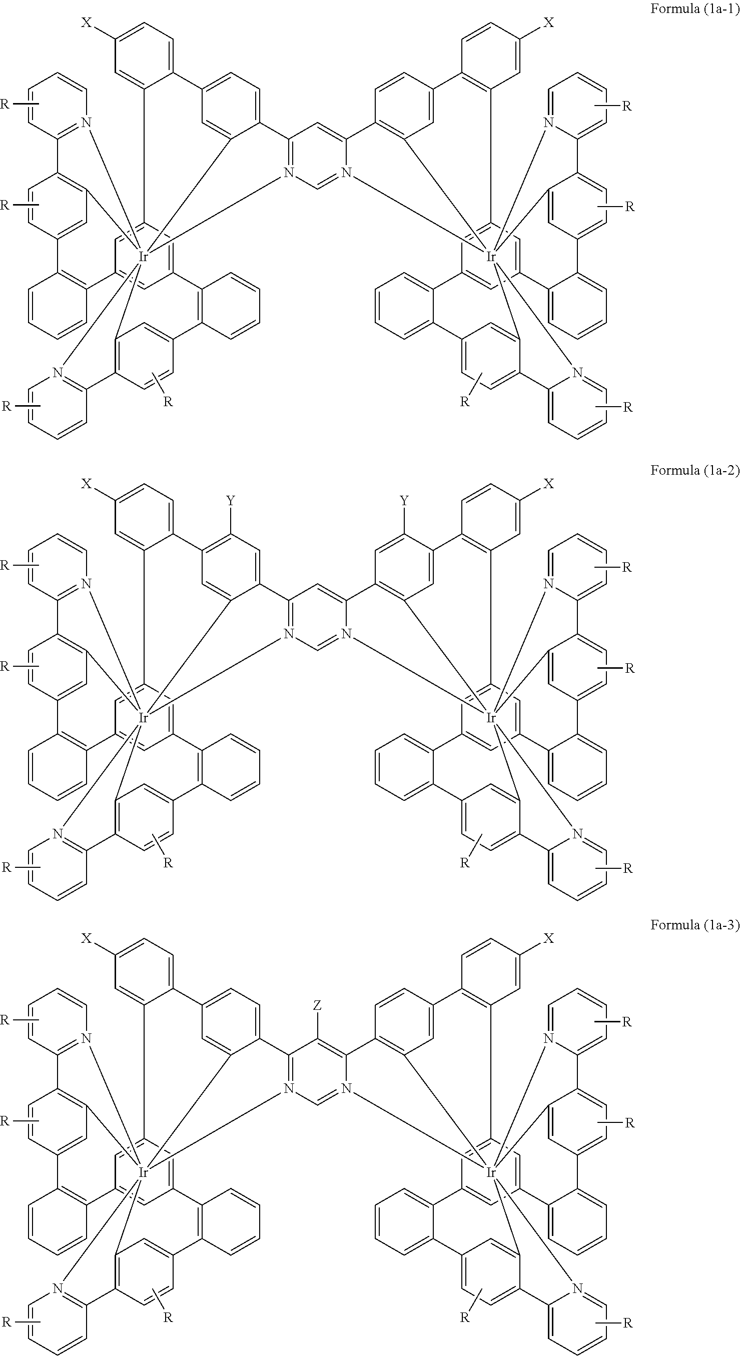
where the two groups X chosen are the same, and where the Y groups in formula (1a-2) are each a —(Ar)ₙ—R group and are the same, and where the Z group in formula (1a-3) is a —(Ar)ₙ—R group.

20. The compound according to claim 16, wherein the R radical in the —(Ar)ₙ—R group is the same or different at each instance and is H, a linear alkyl group having 1 to 10 carbon atoms or a branched or cyclic alkyl group having 3 to 10 carbon atoms.

21. The compound according to claim 16, wherein the structures (Ar1) are selected from the structures (Ar1a) to (Ar1f) 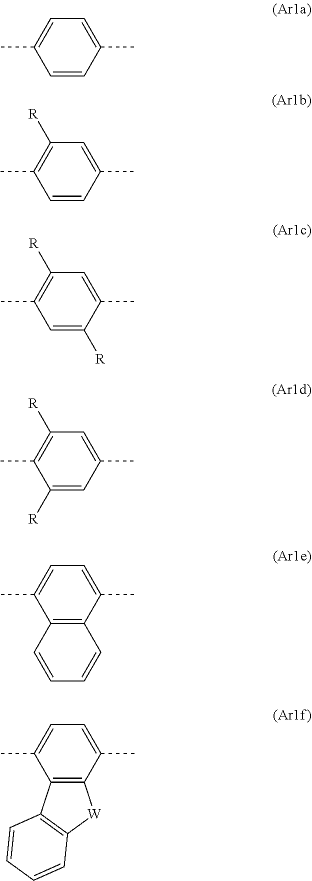
where the dotted bonds represent the linkage of the structures, W is C(R¹)₂, O, S or NR¹, and R and R¹ have the definitions given in claim 16;
and in that the structures (Ar2) are selected from the structures (Ar2a) and (Ar2b), 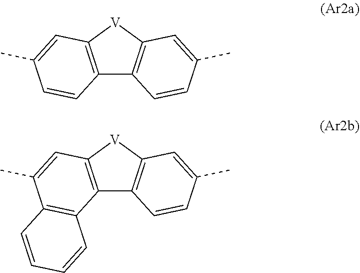
where the dotted bonds represent the linkage of the structures, and R and V have the definitions given in claim 16;
and in that the structures (Ar3) are selected from the structures (Ar3a), 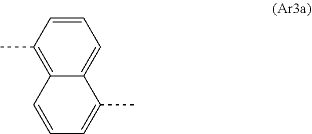
where the dotted bonds represent the linkage of the structure;
and in that the structures (Ar4) are selected from the structures (Ar4a) and (Ar4b), 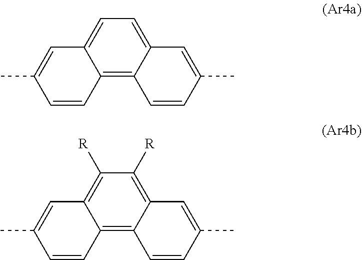
where the dotted bonds represent the linkage of the structure, and R has the definitions given in claim 16;
and in that the structures (Ar5) are selected from the structures (Ar5a) and (Ar5b), 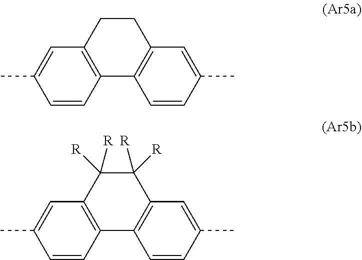
where the dotted bonds represent the linkage of the structure, and R has the definitions given in claim 16;
and in that the structures (Ar7) are selected from the structures (Ar7a), 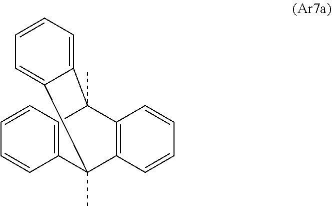 [SMILES: C[C@]12c3ccccc3[C@@](C)(c3ccccc31)c1ccccc12]
where the dotted bonds represent the linkage of the structure.

22. The compound according to claim 16, wherein at least one Ar group is the same or different at each instance and is selected from the structures (Ar1) and/or (Ar2).

23. The compound according to claim 16, wherein n is an integer from 5 to 20, wherein the groups (Ar1) to (Ar7) are chosen such that a total of 8 to 24 phenyl or cyclohexane groups are joined to one another in a linear manner.

24. The compound according to claim 16 of formula (2), 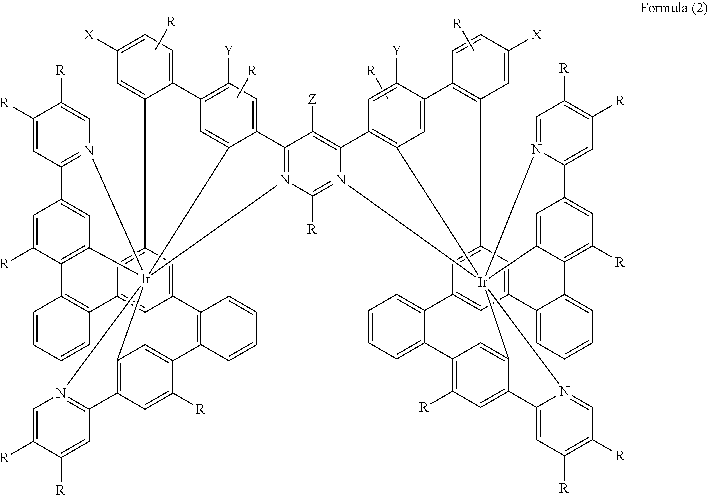
where the symbols used have the definitions listed in claim 16.

25. The compound according to claim 16, wherein all four phenylpyridine subligands have the same substitution.

26. A process for preparing the compound according to claim 16 comprising reacting a compound substituted by reactive leaving groups in place of X and optionally Y and/or Z with a compound A-(Ar)ₙ—R, where A is a reactive leaving group.

27. A formulation comprising at least one compound according to claim 16 and at least one further compound and/or at least one solvent.

28. A method comprising incorporating the compound according to claim 16 in an electronic device.

29. An electronic device comprising at least one compound according to claim 16.

30. The electronic device according to claim 29 which is an organic electroluminescent device, wherein the compound is used as an emitting compound in one or more emitting layers in combination with one or more matrix materials and/or in combination with one or more further triplet emitters.
